(19) United States
(12) Patent Application Publication
(10) Pub. No.: US 2021/0057667 A1
(43) Pub. Date: Feb. 25, 2021

(54) LIGHT-EMITTING ELEMENT, DISPLAY DEVICE, ELECTRONIC APPLIANCE, ORGANIC COMPOUND, AND LIGHTING DEVICE

(71) Applicant: SEMICONDUCTOR ENERGY LABORATORY CO., LTD., ATSUGI-SHI, KANAGAWA-KEN (JP)

(72) Inventors: Nobuharu OHSAWA, Zama, Kanagawa (JP); Satoshi SEO, Sagamihara, Kanagawa (JP)

(73) Assignee: SEMICONDUCTOR ENERGY LABORATORY CO., LTD., ATSUGI-SHI, KANAGAWA-KEN (JP)

(21) Appl. No.: 17/052,245

(22) PCT Filed: Apr. 26, 2019
(86) PCT No.: PCT/IB2019/053434

§ 371 Date: Nov. 2, 2020

(30) Foreign Application Priority Data
May 11, 2018 (JP) 2018-092509

(51) Int. Cl. H01L 51/50; H01L 51/00; H01L 27/32

(52) U.S. Cl. CPC H01L 51/5016; H01L 27/322; H01L 51/0058

(57) ABSTRACT

A light-emitting element with high emission efficiency and high reliability is provided. The light-emitting element includes a light-emitting layer that contains a material serving as an energy donor and a light-emitting material. The material serving as an energy donor has a function of converting triplet excitation energy into light emission and the light-emitting material emits fluorescence. The light-emitting material has a molecular structure that includes a luminophore and protecting groups; one molecule of a guest material includes 5 or more protecting groups. Introduction of protecting groups in a molecule inhibits the energy transfer of triplet excitation energy from the material serving as an energy donor to the light-emitting material by the Dexter mechanism. An alkyl group or a branched-chain alkyl group is used as the protecting group. Light emission is obtained from both the light-emitting material and the material serving as an energy donor.

### TECHNICAL FIELD

One embodiment of the present invention relates to a light-emitting element, or a display device, an electronic appliance, an organic compound, and a lighting device including the light-emitting element.

Note that one embodiment of the present invention is not limited to the above technical field. The technical field of one embodiment of the invention disclosed in this specification and the like relates to an object, a method, or a manufacturing method. Another embodiment of the present invention relates to a process, a machine, manufacture, or a composition of matter. Accordingly, specific examples of the technical field of one embodiment of the present invention disclosed in this specification include a semiconductor device, a display device, a liquid crystal display device, a light-emitting device, a lighting device, a power storage device, a memory device, a driving method thereof, and a manufacturing method thereof.

### BACKGROUND ART

In recent years, research and development has been extensively conducted on light-emitting elements utilizing electroluminescence (EL). The basic structure of these light-emitting elements is a structure in which a layer containing a light-emitting substance (an EL layer) is interposed between a pair of electrodes. By application of a voltage between the electrodes of this element, light emission from the light-emitting substance can be obtained.

Since the above light-emitting element is a self-luminous type, a display device using this has advantages such as high visibility, no necessity of a backlight, and low power consumption. The display device also has advantages in that it can be fabricated to be thin and lightweight and has high response speed, for example.

In the case of a light-emitting element (e.g., an organic EL element) in which an organic compound is used as a light-emitting substance and an EL layer containing the light-emitting organic compound is provided between a pair of electrodes, application of a voltage between the pair of electrodes causes injection of electrons from a cathode and holes (holes) from an anode into the light-emitting EL layer and thus a current flows. Then, by recombination of the injected electrons and holes, the light-emitting organic compound is brought into an excited state, and light emission can be obtained from the excited light-emitting organic compound.

The types of excited states formed by an organic compound are a singlet excited state (S*) and a triplet excited state (T*); light emission from the singlet excited state is referred to as fluorescence, and light emission from the triplet excited state is referred to as phosphorescence. The statistical formation ratio of them in the light-emitting element is S*:T*=1:3. For this reason, a light-emitting element using a compound that emits phosphorescence (phosphorescent material) can have higher emission efficiency than a light-emitting element using a compound that emits fluorescence (fluorescent material). Therefore, light-emitting elements using phosphorescent materials capable of converting energy of the triplet excited state into light emission have been actively developed in recent years.

Among light-emitting elements using phosphorescent materials, a light-emitting element that emits blue light in particular has not yet been put into practical use because it is difficult to develop a stable compound having a high triplet excitation energy level. For this reason, the development of a light-emitting element using a fluorescent material, which is more stable, has been conducted and a technique for improving the emission efficiency of a light-emitting element using a fluorescent material (fluorescent element) has been searched.

As a material capable of converting part or all of energy of the triplet excited state into light emission, a thermally activated delayed fluorescent (TADF) material is known in addition to a phosphorescent material. In a TADF material, a singlet excited state is generated from a triplet excited state by reverse intersystem crossing, and the singlet excited state is converted into light emission.

In order to improve the emission efficiency of a light-emitting element using a TADF material, not only efficient generation of a singlet excited state from a triplet excited state but also efficient light emission from a singlet excited state, that is, high fluorescence quantum yield, is important in the TADF material. It is, however, difficult to design a light-emitting material that simultaneously meets these two.

A method in which in a light-emitting element containing a thermally activated delayed fluorescent material and a fluorescent material, singlet excitation energy of the thermally activated delayed fluorescent material is transferred to the fluorescent material and light emission is obtained from the fluorescent material has been proposed (see Patent Document 1).

### REFERENCE

### Patent Document

[Patent Document 1] Japanese Published Patent Application No. 2014-45179

### Non-Patent Document

[Non-Patent Document 1] Hiroki Noda et al., “SCIENCE ADVANCES”, 2018, vol. 4, no. 6, eaao6910

### SUMMARY OF THE INVENTION

### Problems to be Solved by the Invention

A multicolor light-emitting element typified by a white light-emitting device is expected to be applied to a display and the like. An example of a device structure for obtaining the multicolor light-emitting element is a light-emitting element in which a plurality of EL layers are provided with a charge-generation layer therebetween (such a light-emitting element is also referred to as a tandem element). The tandem element, which can use materials that emit light of different colors for different EL layers, is suitable for fabrication of a multicolor light-emitting element. However, the tandem element has a problem in that its many layers increase the number of manufacturing steps.

In view of the above, a light-emitting element where light of a plurality of colors can be obtained from one EL layer is needed. In order to obtain a plurality of emission colors, two or more kinds of light-emitting materials are used in a light-emitting layer, and the development of a multicolor light-emitting element using a fluorescent material is demanded in terms of reliability.

As described above, the efficiency of a fluorescent element is improved as follows, for example: in a light-emitting layer containing a host material and a guest material, triplet excitons of the host material are converted into singlet excitons, and then, singlet excitation energy is transferred to a fluorescent material, which is the guest material. However, the process where the triplet excitation energy of the host material is converted into the singlet excitation energy is in competition with a process where the triplet excitation energy is deactivated. Therefore, the triplet excitation energy of the host material is not sufficiently converted into the singlet excitation energy in some cases. In the case where a fluorescent material is used as a guest material in a light-emitting layer of a light-emitting device, a possible pathway where the triplet excitation energy is deactivated is, for example, a deactivation pathway where the triplet excitation energy of a host material is transferred to the lowest triplet excitation energy level (T₁ level) of the fluorescent material. The energy transfer in the deactivation pathway does not contribute to light emission, which might decrease the emission efficiency of a fluorescent device.

In order to improve the emission efficiency and reliability of a fluorescent element, it is preferred that triplet excitation energy in a light-emitting layer be efficiently converted into singlet excitation energy and the triplet excitation energy be efficiently transferred as singlet excitation energy to a fluorescent material. Hence, it is required to develop a method for efficiently generating a singlet excited state of a guest material from a triplet excited state of a host material to further improve the emission efficiency and reliability of a light-emitting element.

Thus, an object of one embodiment of the present invention is to provide a light-emitting element where light of a plurality of colors can be obtained from one EL layer. Another object of one embodiment of the present invention is to provide a light-emitting element with high emission efficiency. Another object of one embodiment of the present invention is to provide a highly reliable light-emitting element. Another object of one embodiment of the present invention is to provide a light-emitting element with reduced power consumption. Another object of one embodiment of the present invention is to provide a novel light-emitting element. Another object of one embodiment of the present invention is to provide a novel light-emitting device. Another object of one embodiment of the present invention is to provide a novel display device.

Note that the description of the above objects does not disturb the existence of other objects. In one embodiment of the present invention, there is no need to achieve all of these objects. Objects other than those described above are apparent from the description of the specification and the like and objects other than those described above can be derived from the description of the specification and the like.

### Means for Solving the Problems

As described above, the development of a method for efficiently converting triplet excitation energy into light emission in a light-emitting element that emits fluorescence is required. Thus, it is necessary to improve energy transfer efficiency between materials used in a light-emitting layer. This needs inhibition of the transfer of triplet excitation energy by the Dexter mechanism between an energy donor and an energy acceptor.

Thus, one embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and five or more protecting groups; the luminophore is a condensed aromatic ring or a condensed heteroaromatic ring; the five or more protecting groups each independently have any one of an alkyl group having 1 to 10 carbon atoms, a substituted or unsubstituted cycloalkyl group having 3 to 10 carbon atoms, and a trialkylsilyl group having 3 to 12 carbon atoms; and light emission is obtained from both the first material and the second material.

In the above structure, it is preferable that at least four of the five protecting groups be each independently any one of an alkyl group having 3 to 10 carbon atoms, a substituted or unsubstituted cycloalkyl group having 3 to 10 carbon atoms, and a trialkylsilyl group having 3 to 12 carbon atoms.

Another embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and at least four protecting groups; the luminophore is a condensed aromatic ring or a condensed heteroaromatic ring; the four protecting groups are not directly bonded to the condensed aromatic ring or the condensed heteroaromatic ring; the four protecting groups each independently have any one of an alkyl group having 3 to 10 carbon atoms, a substituted or unsubstituted cycloalkyl group having 3 to 10 carbon atoms, and a trialkylsilyl group having 3 to 12 carbon atoms; and light emission is obtained from both the first material and the second material.

Another embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and two or more diarylamino groups; the luminophore is a condensed aromatic ring or a condensed heteroaromatic ring; the condensed aromatic ring or the condensed heteroaromatic ring is bonded to the two or more diarylamino groups; the two or more diarylamino groups each independently have at least one protecting group; the protecting groups each independently have any one of an alkyl group having 3 to 10 carbon atoms, a substituted or unsubstituted cycloalkyl group having 3 to 10 carbon atoms, and a trialkylsilyl group having 3 to 12 carbon atoms; and light emission is obtained from both the first material and the second material.

Another embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and two or more diarylamino groups; the luminophore is a condensed aromatic ring or a condensed heteroaromatic ring; the condensed aromatic ring or the condensed heteroaromatic ring is bonded to the two or more diarylamino groups; the two or more diarylamino groups each independently have at least two protecting groups; the protecting groups each independently have any one of an alkyl group having 3 to 10 carbon atoms, a substituted or unsubstituted cycloalkyl group having 3 to 10 carbon atoms, and a trialkylsilyl group having 3 to 12 carbon atoms; and light emission is obtained from both the first material and the second material.

In the above structure, the diarylamino group is preferably a diphenylamino group.

In the above structure, the alkyl group is preferably a branched-chain alkyl group.

Another embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and a plurality of protecting groups; the luminophore is a condensed aromatic ring or a condensed heteroaromatic ring; at least one atom of the plurality of protecting groups is positioned directly on one plane of the condensed aromatic ring or the condensed heteroaromatic ring and at least one atom of the plurality of protecting groups is positioned directly on the other plane of the condensed aromatic ring or the condensed heteroaromatic ring; and light emission is obtained from both the first material and the second material.

Another embodiment of the present invention is a light-emitting element including a light-emitting layer between a pair of electrodes. The light-emitting layer contains a first material having a function of converting triplet excitation energy into light emission and a second material having a function of converting singlet excitation energy into light emission; the second material includes a luminophore and two or more diphenylamino groups; the luminophore is a condensed aromatic ring or a condensed heteroaromatic ring; the condensed aromatic ring or the condensed heteroaromatic ring is bonded to the two or more diphenylamino groups; phenyl groups in the two or more diphenylamino groups each independently have protecting groups at the 3-position and the 5-position; the protecting groups each independently have any one of an alkyl group having 3 to 10 carbon atoms, a substituted or unsubstituted cycloalkyl group having 3 to 10 carbon atoms, and a trialkylsilyl group having 3 to 12 carbon atoms; and light emission is obtained from both the first material and the second material.

In the above structure, the alkyl group is preferably a branched-chain alkyl group.

In the above structure, the branched-chain alkyl group preferably has quaternary carbon.

In the above structure, the condensed aromatic ring or the condensed heteroaromatic ring preferably contains any one of naphthalene, anthracene, fluorene, chrysene, triphenylene, pyrene, tetracene, perylene, coumarin, quinacridone, and naphthobisbenzofuran.

In the above structure, preferably, the first material includes a first organic compound and a second organic compound, and the first organic compound and the second organic compound form an exciplex. Further preferably, the first organic compound emits phosphorescence.

In the above structure, the peak wavelength of the emission spectrum of the first material is preferably located on the shorter wavelength side than the peak wavelength of the emission spectrum of the second material.

In the above structure, the first material is preferably a compound that emits phosphorescence or delayed fluorescence.

In the above structure, the emission spectrum of the first material preferably overlaps with an absorption band on the longest wavelength side of the absorption spectrum of the second material.

In the above structure, the concentration of the second material in the light-emitting layer is preferably greater than or equal to 0.01 wt % and less than or equal to 2 wt %.

Another embodiment of the present invention is a display device including the light-emitting element having any of the above structures and at least one of a color filter and a transistor. Another embodiment of the present invention is an electronic appliance including the display device and at least one of a housing and a touch sensor. Another embodiment of the present invention is a lighting device including the light-emitting element having any of the above structures and at least one of a housing and a touch sensor. The category of one embodiment of the present invention includes not only a light-emitting device including a light-emitting element but also an electronic appliance including a light-emitting device. Accordingly, a light-emitting device in this specification refers to an image display device or a light source (including a lighting device). In some cases, the light-emitting device includes a display module in which a connector, for example, an FPC (Flexible Printed Circuit) or a TCP (Tape Carrier Package), is connected to a light-emitting element, a display module in which a printed wiring board is provided on the tip of a TCP, or a display module in which an IC (integrated circuit) is directly mounted on a light-emitting element by a COG (Chip On Glass) method.

### Effect of the Invention

According to one embodiment of the present invention, a light-emitting element where light of a plurality of colors can be obtained from one EL layer can be provided. According to another embodiment of the present invention, a light-emitting element with high emission efficiency can be provided. According to another embodiment of the present invention, a highly reliable light-emitting element can be provided. According to another embodiment of the present invention, a light-emitting element with reduced power consumption can be provided. According to another embodiment of the present invention, a novel light-emitting element can be provided. According to another embodiment of the present invention, a novel light-emitting device can be provided. According to another embodiment of the present invention, a novel display device can be provided.

Note that the description of these effects does not disturb the existence of other effects. In one embodiment of the present invention, there is no need to achieve all of these effects. Other effects are apparent from the description of the specification, drawings, claims, and the like and other effects can be derived from the description of the specification, drawings, claims, and the like.

### BRIEF DESCRIPTION OF THE DRAWINGS

FIG. 1 (A) A schematic cross-sectional view of a light-emitting element of one embodiment of the present invention. (B) A schematic cross-sectional view of a light-emitting layer in a light-emitting device of one embodiment of the present invention. (C) A diagram illustrating the correlation of energy levels of a light-emitting layer in a light-emitting device of one embodiment of the present invention.

FIG. 2 (A) A conceptual diagram of a conventional guest material. (B) A conceptual diagram of a guest material used in a light-emitting element of one embodiment of the present invention.

FIG. 3 (A) A structural formula of a guest material used in a light-emitting element of one embodiment of the present invention. (B) A ball-and-stick image of a guest material used in a light-emitting element of one embodiment of the present invention.

FIG. 4 (A) A schematic cross-sectional view of a light-emitting layer in a light-emitting element of one embodiment of the present invention. (B) to (D) Diagrams illustrating the correlation of energy levels of a light-emitting layer in a light-emitting device of one embodiment of the present invention.

FIG. 5 (A) A schematic cross-sectional view of a light-emitting layer in a light-emitting element of one embodiment of the present invention. (B) and (C) Diagrams illustrating the correlation of energy levels of a light-emitting layer in a light-emitting device of one embodiment or the present invention.

FIG. 6 (A) A schematic cross-sectional view of a light-emitting layer in a light-emitting element of one embodiment of the present invention. (B) and (C) Diagrams illustrating the correlation of energy levels of a light-emitting layer in a light-emitting device of one embodiment or the present invention.

FIG. 7 A schematic cross-sectional view of a light-emitting element of one embodiment of the present invention.

FIG. 8 (A) A top view illustrating a display device of one embodiment of the present invention. (B) A schematic cross-sectional view illustrating a display device of one embodiment of the present invention.

FIGS. 9 (A) and (B) Schematic cross-sectional views illustrating a display device of one embodiment of the present invention.

FIGS. 10 (A) and (B) Schematic cross-sectional views illustrating a display device of one embodiment of the present invention.

FIG. 11 (A) to (D) Perspective views illustrating display modules of one embodiment of the present invention.

FIG. 12 (A) to (C) Diagrams illustrating electronic appliances of one embodiment of the present invention.

FIGS. 13 (A) and (B) Perspective views illustrating a display device of one embodiment of the present invention.

FIG. 14 A diagram illustrating lighting devices of one embodiment of the present invention.

FIG. 15 A graph showing external quantum efficiency-luminance characteristics of light-emitting elements in Example.

FIG. 16 A graph showing electroluminescence spectra of light-emitting elements and absorption and emission spectra of a compound in Example.

FIG. 17 A graph showing reliability measurement results of light-emitting elements in Example.

FIG. 18 A graph showing external quantum efficiency-luminance characteristics of light-emitting elements in Example.

FIG. 19 A graph showing electroluminescence spectra of light-emitting elements and absorption and emission spectra of a compound in Example.

FIG. 20 A graph showing electroluminescence spectra of light-emitting elements and absorption and emission spectra of a compound in Example.

FIG. 21 A graph showing reliability measurement results of light-emitting elements in Example.

FIG. 22 A graph showing external quantum efficiency-luminance characteristics of light-emitting elements in Example.

FIG. 23 A graph showing electroluminescence spectra of light-emitting elements and absorption and emission spectra of a compound in Example.

FIG. 24 A graph showing reliability measurement results of light-emitting elements in Example.

FIGS. 25 (A) and (B) Graphs showing NMR charts of a compound in a reference example.

FIG. 26 A graph showing an NMR chart of a compound in a reference example.

FIGS. 27 (A) and (B) Graphs showing NMR charts of a compound in a reference example.

FIG. 28 A graph showing an NMR chart of a compound in a reference example.

FIG. 29 A graph showing external quantum efficiency-luminance characteristics of a light-emitting element in Example.

FIG. 30 A graph showing electroluminescence spectra of light-emitting elements and absorption and emission spectra of a compound in Example.

FIG. 31 A graph showing emission lifetime measurement results of a light-emitting element in Example.

FIG. 32 A graph showing reliability measurement results of light-emitting elements in Example.

FIG. 33 A graph showing external quantum efficiency-luminance characteristics of light-emitting elements in Example.

FIG. 34 A graph showing electroluminescence spectra of light-emitting elements and absorption and emission spectra of a compound in Example.

FIG. 35 A graph showing external quantum efficiency-luminance characteristics of light-emitting elements in Example.

FIG. 36 A graph showing electroluminescence spectra of light-emitting elements and absorption and emission spectra of a compound in Example.

FIG. 37 A graph showing electroluminescence spectra of light-emitting elements and absorption and emission spectra of a compound in Example.

FIGS. 38 (A) and (B) Graphs showing NMR charts of a compound in a reference example.

FIG. 39 A graph showing an NMR chart of a compound in a reference example.

FIGS. 40 (A) and (B) Graphs showing NMR charts of a compound in a reference example.

FIGS. 41 (A) and (B) Graphs showing NMR charts of a compound in a reference example.

FIG. 42 A graph showing an NMR chart of a compound in a reference example.

FIG. 43 A graph showing emission lifetime measurement results of a light-emitting element in Example.

### MODE FOR CARRYING OUT THE INVENTION

Embodiments of the present invention are described in detail below with reference to drawings. Note that the present invention is not limited to the following description, and the modes and details of the present invention can be modified in various ways without departing from the spirit and scope of the present invention. Accordingly, the present invention should not be interpreted as being limited to the description of the embodiments below.

Note that the position, size, range, or the like of each component illustrated in drawings and the like is not accurately represented in some cases for easy understanding. Therefore, the disclosed invention is not necessarily limited to the position, size, range, or the like disclosed in drawings and the like.

In this specification and the like, the ordinal numbers such as first and second are used for convenience, and do not denote the order of steps or the stacking order of layers in some cases. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In describing structures of the invention in this specification and the like with reference to drawings, common numerals are used for the same components in different drawings in some cases.

Moreover, in this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In this specification and the like, a singlet excited state (S*) refers to a singlet state having excitation energy. An S1 level means the lowest level of the singlet excitation energy level, that is, the excitation energy level of the lowest singlet excited state (S1 state). A triplet excited state (T*) refers to a triplet state having excitation energy. A T1 level means the lowest level of the triplet excitation energy level, that is, the excitation energy level of the lowest triplet excited state (T1 state). Note that in this specification and the like, simple expressions singlet excited state and singlet excitation energy level mean the S1 state and the S1 level, respectively, in some cases. In addition, expressions triplet excited state and triplet excitation energy level mean the T1 state and the T1 level, respectively, in some cases.

In this specification and the like, a fluorescent material refers to a compound that supplies light emission in the visible light region when the relaxation from the singlet excited state to the ground state occurs. A phosphorescent material refers to a compound that supplies light emission in the visible light region at room temperature when the relaxation from the triplet excited state to the ground state occurs. In other words, a phosphorescent material refers to one of compounds that can convert triplet excitation energy into visible light.

Note that in this specification and the like, room temperature refers to a temperature in the range of higher than or equal to 0° C. and lower than or equal to 40° C.

In this specification and the like, a wavelength range of blue is greater than or equal to 400 nm and less than 490 nm, and blue light has at least one emission spectrum peak in that wavelength range. A wavelength range of green is greater than or equal to 490 nm and less than 580 nm, and green light has at least one emission spectrum peak in that wavelength range. A wavelength range of red is greater than or equal to 580 nm and less than or equal to 680 nm, and red light has at least one emission spectrum peak in that wavelength range. In the case where two kinds of emission spectra have emission spectrum peaks in the same wavelength range and the peak wavelengths are different from each other, the two kinds of emission spectra are regarded as those of light emission of different colors in some cases. Note that the emission spectrum peak is assumed to include the local maximum value or a shoulder.

### Embodiment 1

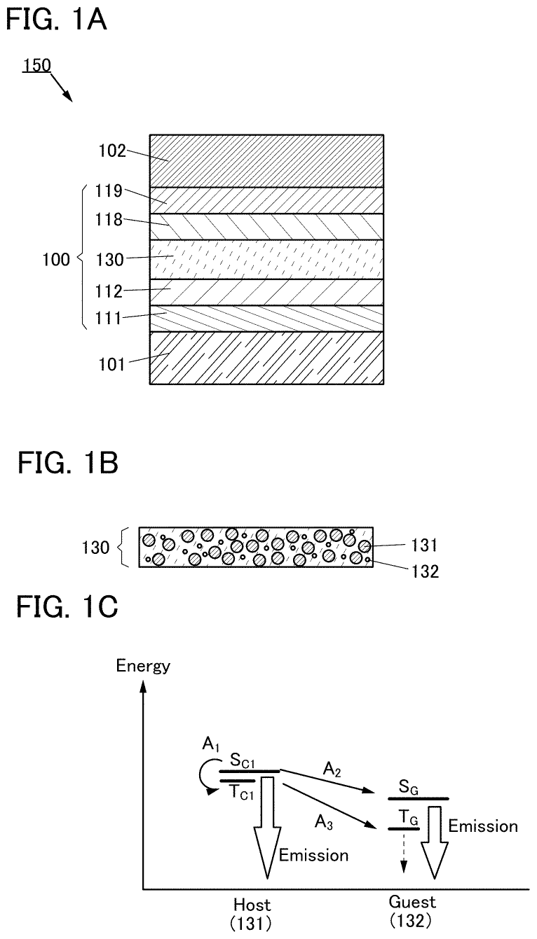

In this embodiment, a light-emitting element of one embodiment of the present invention will be described below with reference to FIG. 1 to FIG. 6.

### <Structure Example of Light-Emitting Element>

First, a structure of the light-emitting element of one embodiment of the present invention will be described below with reference to FIG. 1.

FIG. 1(A) is a schematic cross-sectional view of a light-emitting element 150 of one embodiment of the present invention.

The light-emitting element 150 includes a pair of electrodes (an electrode 101 and an electrode 102) and an EL layer 100 provided between the pair of electrodes. The EL layer 100 includes at least a light-emitting layer 130.

The EL layer 100 illustrated in FIG. 1(A) includes, in addition to the light-emitting layer 130, functional layers such as a hole-injection layer 111, a hole-transport layer 112, an electron-transport layer 118, and an electron-injection layer 119.

Although description in this embodiment is given assuming that the electrode 101 and the electrode 102 of the pair of electrodes serve as an anode and a cathode, respectively, the structure of the light-emitting element 150 is not limited thereto. That is, the electrode 101 may serve as a cathode, the electrode 102 may serve as an anode, and the stacking order of the layers between the electrodes may be reversed. In other words, the hole-injection layer 111, the hole-transport layer 112, the light-emitting layer 130, the electron-transport layer 118, and the electron-injection layer 119 may be stacked in this order from the anode side.

The structure of the EL layer 100 is not limited to the structure illustrated in FIG. 1(A), and a structure including at least one selected from the hole-injection layer 111, the hole-transport layer 112, the electron-transport layer 118, and the electron-injection layer 119 can be employed. Alternatively, the EL layer 100 may have a structure including a functional layer which has a function of lowering a hole- or electron-injection barrier, improving a hole- or electron-transport property, inhibiting a hole- or electron-transport property, inhibiting a quenching phenomenon by an electrode, or the like. Note that the functional layers may each be a single layer or have a structure in which a plurality of layers are stacked.

### <Light Emission Mechanism of Light-Emitting Element>

Next, a light emission mechanism of the light-emitting layer 130 will be described below.

In the light-emitting element 150 of one embodiment of the present invention, voltage application between the pair of electrodes (the electrode 101 and the electrode 102) allows electrons and holes to be injected from the cathode and the anode, respectively, into the EL layer 100 and thus current flows. The ratio of singlet excitons to triplet excitons (hereinafter, exciton generation probability) which are generated by recombination of carriers (electrons and holes) is 1:3 according to the statistically obtained probability. In other words, the generation probability of singlet excitons is 25% and the generation probability of triplet excitons is 75%; thus, it is important to make the triplet excitons contribute to light emission in order to improve the emission efficiency of the light-emitting element. For this reason, a material that has a function of converting triplet excitation energy into light emission is preferably used for the light-emitting layer 130.

As the material that has a function of converting triplet excitation energy into light emission, a compound that can emit phosphorescence (hereinafter, also referred to as a phosphorescent material) is given. A phosphorescent material in this specification and the like is a compound that exhibits phosphorescence but does not exhibit fluorescence at a temperature higher than or equal to low temperatures (e.g., 77 K) and lower than or equal to room temperature (i.e., higher than or equal to 77 K and lower than or equal to 313 K). The phosphorescent material preferably contains a metal element with large spin-orbit interaction, specifically a transition metal element. It is particularly preferable that a platinum group element (ruthenium (Ru), rhodium (Rh), palladium (Pd), osmium (Os), iridium (Ir), or platinum (Pt)), especially iridium, be contained, in which case the transition probability relating to direct transition between the singlet ground state and the triplet excited state can be increased.

As the material that has a function of converting triplet excitation energy into light emission, a TADF material is given. Note that the TADF material is a material that has a small difference between the S1 level and the T1 level and can convert triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. An exciplex (also referred to as Exciplex) whose excited state is formed by two kinds of substances has an extremely small difference between the S1 level and the T1 level and functions as a TADF material that can convert triplet excitation energy into singlet excitation energy.

Note that a phosphorescent spectrum observed at low temperatures (e.g., 10 K) is used for an index of the T1 level. When the level of energy with a wavelength of the line obtained by extrapolating a tangent to the fluorescent spectrum at room temperature or low temperatures at a tail on the short wavelength side is the S1 level and the level of energy with a wavelength of the line obtained by extrapolating a tangent to the phosphorescent spectrum at a tail on the short wavelength side is the T1 level, the difference between S1 and T1 of the TADF material is preferably smaller than or equal to 0.2 eV.

As the material that has a function of converting triplet excitation energy into light emission, a nanostructure of a transition metal compound having a perovskite structure is also given. In particular, a nanostructure of a metal-halide perovskite material is preferable. The nanostructure is preferably a nanoparticle or a nanorod.

FIG. 1(B) is a schematic cross-sectional view illustrating the light-emitting layer 130 of the light-emitting element of one embodiment of the present invention. In one embodiment of the present invention, the light-emitting layer 130 contains a compound 131 and a compound 132. The compound 131 has a function of converting triplet excitation energy into light emission and the compound 132 has a function of converting singlet excitation energy into light emission. A fluorescent material is preferably used as the compound 132 in order to obtain a highly reliable light-emitting element. Here, in the light-emitting layer 130, the compound 131 serves as an energy donor and the compound 132 serves as an energy acceptor. That is, in FIG. 1(C), the host material has a function of an energy donor and the guest material has a function of an energy acceptor. In the light-emitting element of one embodiment of the present invention, the compound 131 has a function of converting triplet excitation energy into light emission as described above; thus, light emission from the compound 131 that is an energy donor and light emission from the compound 132 that is an energy acceptor can be obtained from the light-emitting layer 130. The light-emitting element described above, in which an energy donor has a function of converting triplet excitation energy into light emission and a fluorescent material is used as an energy acceptor, is sometimes referred to as a triplet sensitizing element in this specification.

### <Structure Example 1 of Light-Emitting Layer>

FIG. 1(C) shows an example of the correlation between energy levels in the light-emitting layer of the light-emitting element of one embodiment of the present invention. In this structure example, the case where a TADF material is used as the compound 131 is described.

FIG. 1(C) shows the correlation between the energy levels of the compound 131 and the compound 132 in the light-emitting layer 130. The following explains what the terms and numerals in FIG. 1(C) represent.

Host (131): compound 131

Guest (132): compound 132

T_{C1}: T1 level of compound 131

S_{C1}: S1 level of compound 131

S_{G}: S1 level of compound 132

T_{G}: T1 level of compound 132

Here, the triplet excitation energy of the compound 131 generated by current excitation is focused on. The compound 131 has a TADF property. Therefore, the compound 131 has a function of converting triplet excitation energy into singlet excitation energy by upconversion (Route A₁ in FIG. 1(C)). The singlet excitation energy of the compound 131 can be transferred to the compound 132 (Route A₂ in FIG. 1(C)). At this time, S_{C1}≥S_{G} is preferably satisfied. Here, the process of Route A₂ is in competition with the process of light emission of the compound 131 (transition from the S1 level to the ground state of the compound 131). That is, the singlet excitation energy of the compound 131 is converted into light emission of the compound 131 and light emission of the compound 132. This enables the light-emitting element of one embodiment of the present invention to obtain two kinds of light emission: light emission from the compound 131 and light emission from the compound 132. Note that the singlet excitation energy of the compound 131 that is generated by current excitation is also converted into light emission of the compound 131 and light emission of the compound 132.

Note that specifically, when the level of energy with a wavelength of the line obtained by extrapolating a tangent to the fluorescent spectrum of the compound 131 at a tail on the short wavelength side is S_{C1} and the level of energy with a wavelength of the absorption edge of the absorption spectrum of the compound 132 is S_{G}, S_{C1}≥S_{G} is preferably satisfied. In addition, the emission spectrum of the compound 131 preferably overlaps with the absorption band on the longest wavelength side in the absorption spectrum of the compound 132.

The triplet excitation energy generated in the compound 131 is transferred to the S1 level of the compound 132, which is a guest material, through Route A₁ and Route A₂ described above and the compound 132 emits light, whereby the triplet excitation energy can be efficiently converted into fluorescence. In Route A₂, the compound 131 serves as an energy donor and the compound 132 serves as an energy acceptor. In the light-emitting element of one embodiment of the present invention, the compound 131 serves as a light-emitting material as well as an energy donor.

In order for the compound 131 to serve as a light-emitting material as well as an energy donor, the concentration of the compound 132 is preferably greater than or equal to 0.01 wt % and less than or equal to 2 wt % with respect to that of the compound 131. With such a structure, the excitation energy of the compound 131 can be efficiently converted into light emission of the compound 131 and light emission of the compound 132, so that a multicolor light-emitting element with high efficiency can be obtained. The emission color can be changed by adjusting the concentrations of the compound 131 and the compound 132.

As shown in FIG. 1(C), the S1 level of the compound 131 is higher than the S1 level of the compound 132. Thus, the obtained emission spectrum of the compound 131 is closer to the short wavelength side than that of the compound 132 is. More specifically, the peak wavelength of the emission spectrum of the compound 131 is located on the shorter wavelength side than the peak wavelength of the emission spectrum of the compound 132. With such a structure, the energy can be efficiently transferred from the compound 131 to the compound 132, so that a multicolor light-emitting element with high emission efficiency can be obtained.

Here, in the light-emitting layer 130, the compound 131 and the compound 132 are mixed. Thus, a process where the triplet excitation energy of the compound 131 is converted into the triplet excitation energy of the compound 132 (Route A₃ in FIG. 1(C)) is likely to occur in competition with Route A₁ and Route A₂ described above. Since the compound 132 is a fluorescent material, the triplet excitation energy of the compound 132 does not contribute to light emission. In other words, when the energy transfer through Route A₃ occurs, the emission efficiency of the light-emitting element decreases. Note that in practice, the energy transfer from T_{C1} to T_{G} (Route A₃) can be, not a direct route, a pathway where T_{C1} is once transferred to the triplet excited state at a level higher than T_{G} of the compound 132 and then the triplet excited state is converted into T_{G} by internal conversion; the process is omitted in the drawing. Hereinafter, the same applies to all undesired thermal deactivation processes, that is, all the deactivation processes to T_{G} in this specification.

As mechanisms of the intermolecular energy transfer, the Förster mechanism (dipole-dipole interaction) and the Dexter mechanism (electron exchange interaction) are known. Since the compound 132, which is an energy acceptor, is a fluorescent material, the Dexter mechanism is dominant as the mechanism of energy transfer through Route A₃. In general, the Dexter mechanism occurs significantly when the distance between the compound 131, which is an energy donor, and the compound 132, which is an energy acceptor, is less than or equal to 1 nm. Therefore, to inhibit Route A₃, it is important that the distance between the host material and the guest material, that is, the energy donor and the energy acceptor be large.

Note that since direct transition from a singlet ground state to a triplet excited state in the compound 132 is forbidden, energy transfer from the singlet excitation energy level (S_{C1}) of the compound 131 to the triplet excitation energy level (T_{G}) of the compound 132 is unlikely to be a main energy transfer process; thus, the energy transfer is not illustrated.

T_{G} in FIG. 1(C) is the energy level derived from a luminophore in the energy acceptor in many cases. Therefore, specifically, to inhibit Route A₃, it is important that the energy donor and the luminophore of the energy acceptor be made away from each other.

In view of the above, the present inventors have found that the use of a fluorescent material having protecting groups, as an energy acceptor, for keeping a distance from the energy donor can inhibit the above-described decrease in the emission efficiency.

### <Concept of Fluorescent Material Having Protecting Groups>

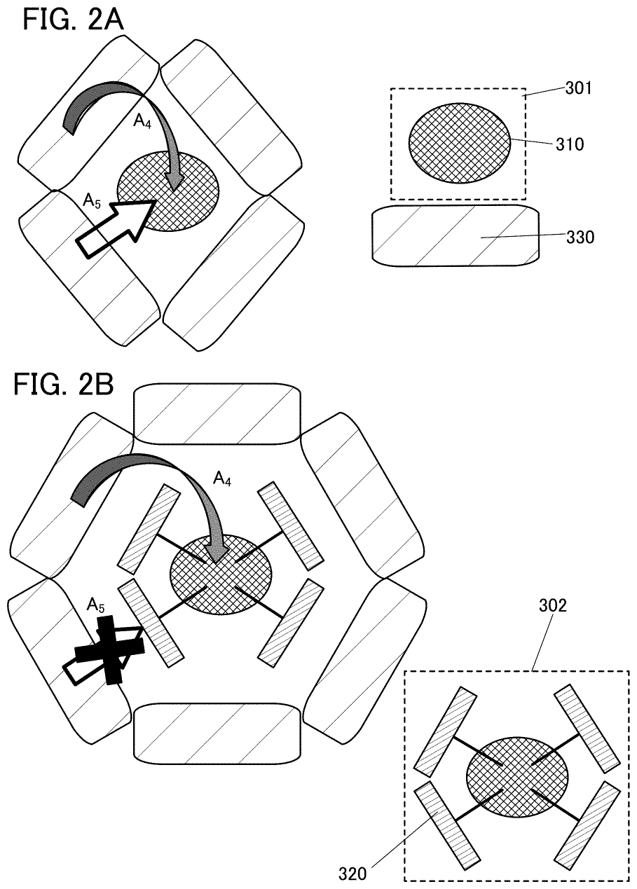

FIG. 2(A) is a conceptual diagram illustrating the case where a typical fluorescent material having no protecting group is dispersed as a guest material to a host material. FIG. 2(B) is a conceptual diagram illustrating the case where a fluorescent material having protecting groups, which is used for the light-emitting element of one embodiment of the present invention, is dispersed as a guest material to a host material. The host material may be rephrased as an energy donor, and the guest material may be replaced with an energy acceptor. Here, the protecting groups have a function of making a luminophore and the host material away from each other. In FIG. 2(A), a guest material 301 includes a luminophore 310. In FIG. 2(B), a guest material 302 includes the luminophore 310 and protecting groups 320. In FIGS. 2(A) and 2(B), the guest material 301 and the guest material 302 are surrounded by host materials 330. Since the luminophore is close to the host materials in FIG. 2(A), both energy transfer by the Forster mechanism (Route A₄ in FIGS. 2(A) and 2(B)) and energy transfer by the Dexter mechanism (Route A₅ in FIGS. 2(A) and 2(B)) can occur as the energy transfer from the host materials 330 to the guest material 301. In the case where the guest material is a fluorescent material, when the triplet excitation energy transfer from the host material to the guest material is caused by the Dexter mechanism and the triplet exited state of the guest material is generated, non-radiative decay of the triplet excitation energy occurs, contributing to a reduction in the emission efficiency.

In contrast, the guest material 302 in FIG. 2(B) has the protecting groups 320. Thus, the luminophore 310 and the host materials 330 can be kept away from each other. This inhibits energy transfer by the Dexter mechanism (Route A₅).

Here, in order that the guest material 302 emits light, the guest material 302 needs to receive energy from the host materials 330 by the Forster mechanism because the Dexter mechanism is inhibited. In other words, it is preferable that energy transfer by the Forster mechanism be efficiently utilized while energy transfer by the Dexter mechanism is inhibited. It is known that energy transfer by the Forster mechanism is also affected by the distance between a host material and a guest material. In general, the Dexter mechanism is dominant when the distance between the host material 330 and the guest material 302 is less than or equal to 1 nm, and the Forster mechanism is dominant when the distance therebetween is greater than or equal to 1 nm and less than or equal to 10 nm. Energy transfer is generally unlikely to occur when the distance between the host material 330 and the guest material 302 is greater than or equal to 10 nm. Here, the distance between the host material 330 and the guest material 302 can be rephrased as the distance between the host material 330 and the luminophore 310.

Thus, the protecting groups 320 preferably spread in an area 1 nm or more and 10 nm or less away from the luminophore 310. They further preferably spread in an area 1 nm or more and 5 nm or less away from the luminophore 310. With such a structure, energy transfer by the Förster mechanism from the host material 330 to the guest material 302 can be efficiently utilized while energy transfer by the Dexter mechanism is inhibited. Thus, a light-emitting element with high emission efficiency can be fabricated.

In the light-emitting element of one embodiment of the present invention, a guest material in which a luminophore has protecting groups is used for a light-emitting layer. In one embodiment of the present invention, energy transfer by the Förster mechanism can be efficiently utilized while energy transfer by the Dexter mechanism is inhibited; thus, a light-emitting element with high emission efficiency can be obtained. In addition, the use of a material having a function of converting triplet excitation energy into light emission as a host material allows fabrication of a fluorescent element having emission efficiency as high as that of a phosphorescent element. Since the emission efficiency can be improved using a fluorescent material having high stability, a highly reliable light-emitting element can be fabricated. Furthermore, light emission can be obtained also from a material that has a function of converting triplet excitation energy utilized for a host material into light emission, allowing a multicolor light-emitting element, which is usually obtained only with stacked light-emitting layers, to be obtained with a single light-emitting layer.

Here, the luminophore refers to an atomic group (skeleton) that causes light emission in a fluorescent material. The luminophore generally has a π bond and preferably has an aromatic ring, further preferably a condensed aromatic ring or a condensed heteroaromatic ring. As another embodiment, the luminophore can be regarded as an atomic group (skeleton) having an aromatic ring having a transition dipole vector on a ring plane. In the case where one fluorescent material has a plurality of condensed aromatic rings or condensed heteroaromatic rings, a skeleton having the lowest S1 level among the plurality of condensed aromatic rings or condensed heteroaromatic rings is considered as a luminophore of the fluorescent material in some cases. In other cases, a skeleton having an absorption edge on the longest wavelength side among the plurality of condensed aromatic rings or condensed heteroaromatic rings may be considered as the luminophore of the fluorescent material. The luminophore of the fluorescent material can be presumed from the shapes of the emission spectra of the plurality of condensed aromatic rings or condensed heteroaromatic rings in some cases.

As the condensed aromatic ring or the condensed heteroaromatic ring, a phenanthrene skeleton, a stilbene skeleton, an acridone skeleton, a phenoxazine skeleton, a phenothiazine skeleton, and the like are given. Specifically, fluorescent materials having a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton are preferable because of their high fluorescence quantum yields.

A substituent used as the protecting group needs to have a triplet excitation energy level higher than the T1 levels of the luminophore and the host material. Thus, a saturated hydrocarbon group is preferably used. That is because a substituent having no π bond has a high triplet excitation energy level. In addition, a substituent having no π bond has a poor function of transporting carriers (electrons or holes). Thus, a saturated hydrocarbon group can make the luminophore and the host material away from each other with little influence on the excited state or the carrier-transport property of the host material. In an organic compound including a substituent having no π bond and a substituent having a π-conjugated system, frontier orbitals {HOMO (Highest Occupied Molecular Orbital) and LUMO (Lowest Unoccupied Molecular Orbital)} are present on the side of the substituent having a π-conjugated system in many cases; in particular, the luminophore tends to have the frontier orbitals. As described later, the overlap of the HOMOs of the energy donor and the energy acceptor and the overlap of the LUMOs of the energy donor and the energy acceptor are important for energy transfer by the Dexter mechanism. Therefore, the use of a saturated hydrocarbon group as the protecting group enables a large distance between the frontier orbitals of the host material, which is an energy donor, and the frontier orbitals of the guest material, which is an energy acceptor, leading to inhibition of energy transfer by the Dexter mechanism.

A specific example of the protecting group is an alkyl group having 1 to 10 carbon atoms. In addition, the protecting group is preferably a bulky substituent because it needs to make the luminophore and the host material away from each other. Thus, an alkyl group having 3 to 10 carbon atoms, a substituted or unsubstituted cycloalkyl group having 3 to 10 carbon atoms, or a trialkylsilyl group having 3 to 12 carbon atoms can be suitably used. In particular, the alkyl group is preferably a bulky branched-chain alkyl group. Furthermore, the substituent preferably has quaternary carbon, in which case it becomes a bulky substituent.

One luminophore preferably has five or more protecting groups. With such a structure, the luminophore can be entirely covered with the protecting groups, so that the distance between the host material and the luminophore can be adjusted as appropriate. In FIG. 2(B), the protecting groups are directly bonded to the luminophore; however, the protecting groups are preferably not directly bonded to the luminophore. For example, the protecting groups may each be bonded to the luminophore via a substituent with a valence of 2 or more, such as an arylene group or an amino group. Bonding of each of the protecting groups to the luminophore via the substituent can effectively make the luminophore away from the host material. Thus, in the case where the protecting groups are not directly bonded to the luminophore, four or more protecting groups for one luminophore can effectively inhibit energy transfer by the Dexter mechanism.

Furthermore, the substituent with a valence of 2 or more that bonds the luminophore and each of the protecting groups is preferably a substituent having a π-conjugated system. With such a structure, the physical properties of the guest material, such as the emission color, the HOMO level, and the glass transition point, can be adjusted. Note that the protecting groups are preferably positioned on the outermost side when the molecular structure is observed with the luminophore positioned at the center.

### <Examples of Fluorescent Material Having Protecting Groups and its Molecular Structure>

Here, a structure of N,N′-[(2-tert-butylanthracene)-9,10-diyl]-N,N′-bis(3,5-di-tert-butylphenyl)amine (abbreviation: 2tBu-mmtBuDPhA2Anth), a fluorescent material that is represented by Structural Formula (102) shown below and can be used for the light-emitting element of one embodiment of the present invention, is shown. In 2tBu-mmtBuDPhA2Anth, an anthracene ring is a luminophore and tertiary butyl groups (tBu groups) serve as protecting groups.

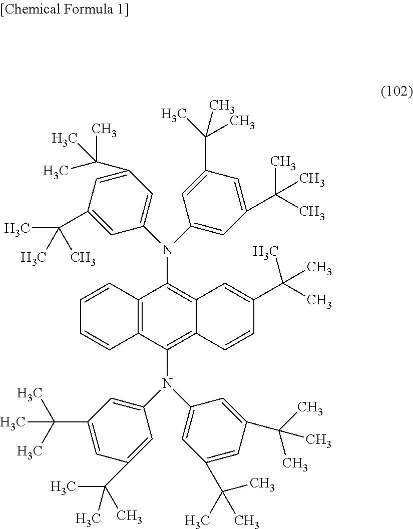 [SMILES: CC(C)(C)c1cc(N(c2cc(C(C)(C)C)cc(C(C)(C)C)c2)c2c3ccccc3c(N(c3cc(C(C)(C)C)cc(C(C)(C)C)c3)c3cc(C(C)(C)C)cc(C(C)(C)C)c3)c3cc(C(C)(C)C)ccc23)cc(C(C)(C)C)c1]

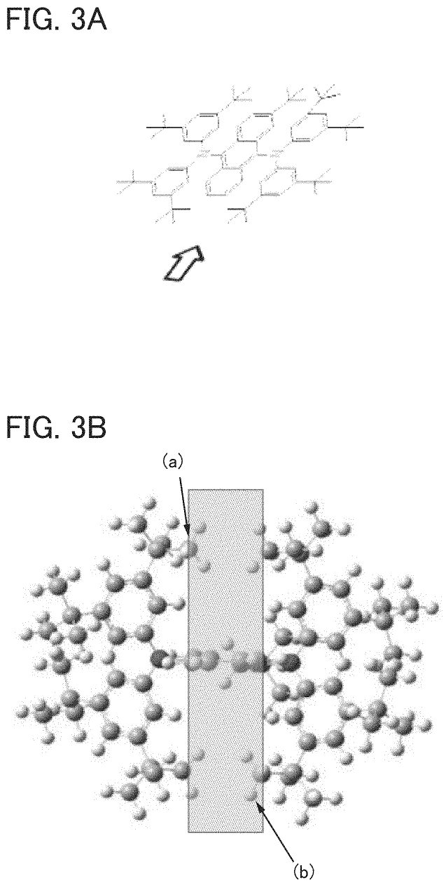

FIG. 3(B) shows a ball-and-stick model image of 2tBu-mmtBuDPhA2Anth shown above. Note that FIG. 3(B) shows the state where 2tBu-mmtBuDPhA2Anth is viewed in the direction indicated by an arrow in FIG. 3(A) (the direction parallel to the anthracene ring plane). The hatched portion in FIG. 3(B) represents an overhead portion of the anthracene ring plane, which is a luminophore, and the overhead portion includes a region overlapping with tBu groups, which are protecting groups. For example, in FIG. 3(B), an atom indicated by an arrow (a) is a carbon atom of the tBu group overlapping with the hatched portion, and an atom indicated by an arrow (b) is a hydrogen atom of the tBu group overlapping with the hatched portion. In other words, in 2tBu-mmtBuDPhA2Anth, atoms included in protecting groups are positioned directly on one plane of the luminophore, and atoms included in protecting groups are also positioned directly on the other plane. With such a structure, even in the state where a guest material is dispersed in a host material, the anthracene ring, which is the luminophore, and the host material can be away from each other in both the horizontal direction and the vertical direction of the anthracene ring, leading to inhibition of energy transfer by the Dexter mechanism.

In addition, for example, when the transition related to energy transfer is transition between HOMO and LUMO, the overlap of the HOMOs of the host material and the guest material and the overlap of LUMOs of the host material and the guest material are important for energy transfer by the Dexter mechanism. The overlap of the HOMOs of both of the materials and the overlap of LUMOs thereof significantly cause the Dexter mechanism. Therefore, it is important to prevent the overlap of the HOMOs of both of the materials and the overlap of LUMOs thereof in order to inhibit the Dexter mechanism. In other words, it is important that the distance between the skeleton and the host material, which are related to the excited state, be large. In a fluorescent material, both HOMO and LUMO are included in a luminophore in many cases. For example, in the case where the HOMO and LUMO of a guest material extend above and below the luminophore plane (above and below the anthracene ring in 2tBu-mmtBuDPhA2Anth), it is important that the upper and lower planes of the luminophore be covered with protecting groups in the molecular structure.

A condensed aromatic ring and a condensed heteroaromatic ring serving as a luminophore, such as a pyrene ring or an anthracene ring, has a transition dipole vector on the ring plane. Thus, in FIG. 3(B), 2tBu-mmtBuDPhA2Anth preferably includes a region overlapping with a tBu group, which is a protecting group, on the plane where the transition dipole vector is present, that is, directly on the plane of the anthracene ring. Specifically, at least one of atoms of a plurality of protecting groups (the tBu groups in FIGS. 3(A) and 3(B)) is positioned directly on one plane of a condensed aromatic ring or a condensed heteroaromatic ring (the anthracene ring in FIGS. 3(A) and 3(B)), and at least one of atoms of the plurality of protecting groups is positioned directly on the other plane of the condensed aromatic ring or the condensed heteroaromatic ring. With such a structure, even in the state where a guest material is dispersed in a host material, the luminophore and the host material can be away from each other, leading to inhibition of energy transfer by the Dexter mechanism. Furthermore, tBu groups are preferably positioned to cover a luminophore such as an anthracene ring.

### <Structure Example 2 of Light-Emitting Layer>

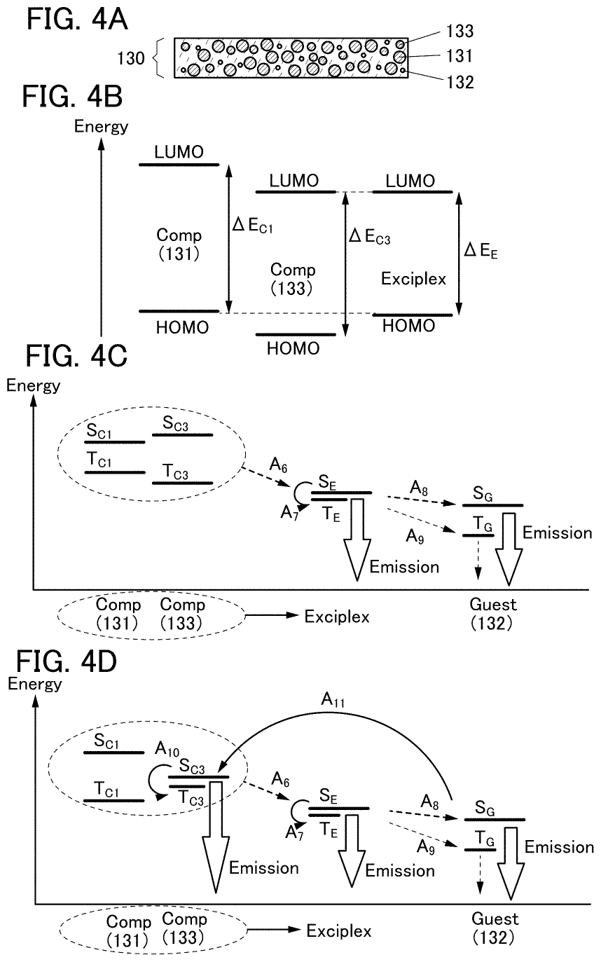

FIG. 4(C) shows an example of the correlation between energy levels in the light-emitting layer 130 of the light-emitting element 150 of one embodiment of the present invention. The light-emitting layer 130 illustrated in FIG. 4(A) contains the compound 131, the compound 132, and also a compound 133. In one embodiment of the present invention, the compound 132 is preferably a fluorescent material. In this structure example, the compound 131 and the compound 133 form an exciplex in combination.

Although any combination of the compound 131 and the compound 133 that can form an exciplex is acceptable, it is further preferable that one of them be a compound having a function of transporting holes (hole-transport property) and the other be a compound having a function of transporting electrons (electron-transport property). In that case, a donor-acceptor exciplex is easily formed; thus, efficient formation of an exciplex is possible. In the case where the combination of the compound 131 and the compound 133 is a combination of a compound having a hole-transport property and a compound having an electron-transport property, the carrier balance can be easily controlled by the mixture ratio. Specifically, the ratio of the compound having a hole-transport property to the compound having an electron-transport property is preferably within the range of 1:9 to 9:1 (weight ratio). Since the carrier balance can be easily controlled with the structure, a carrier recombination region can also be controlled easily.

For the combination of host materials for forming an exciplex efficiently, it is preferable that the HOMO level of one of the compound 131 and the compound 133 be higher than the HOMO level of the other and the LUMO level of the one of the compounds be higher than the LUMO level of the other. Note that the HOMO level of the compound 131 may be equivalent to the HOMO level of the compound 133, or the LUMO level of the compound 131 may be equivalent to the LUMO level of the compound 133.

Note that the LUMO levels and the HOMO levels of the compounds can be derived from the electrochemical characteristics (reduction potentials and oxidation potentials) of the compounds that are measured by cyclic voltammetry (CV) measurement.

When the compound 131 has a hole-transport property and the compound 133 has an electron-transport property, for example, it is preferable that the HOMO level of the compound 131 be higher than the HOMO level of the compound 133 and that the LUMO level of the compound 131 be higher than the LUMO level of the compound 133, as in an energy band diagram in FIG. 4(B). Such energy level correlation is suitable because holes and electrons, which are carriers injected from the pair of electrodes (the electrode 101 and the electrode 102), are easily injected into the compound 131 and the compound 133, respectively.

As to terms and reference numerals in FIG. 4(B), Comp (131) represents the compound 131, Comp (133) represents the compound 133, ΔE_{C1} represents the energy difference between the LUMO level and the HOMO level of the compound 131, ΔE_{C3} represents the energy difference between the LUMO level and the HOMO level of the compound 133, and ΔE_{E} represents the energy difference between the LUMO level of the compound 133 and the HOMO level of the compound 131.

The exciplex formed by the compound 131 and the compound 133 is an exciplex that has HOMO of the molecular orbital in the compound 131 and LUMO of the molecular orbital in the compound 133. The excitation energy of the exciplex substantially corresponds to the energy difference (ΔE_{E}) between the LUMO level of the compound 133 and the HOMO level of the compound 131, which is smaller than the energy difference (ΔE_{C1}) between the LUMO level and the HOMO level of the compound 131 and the energy difference (ΔE_{C3}) between the LUMO level and the HOMO level of the compound 133. Thus, when the compound 131 and the compound 133 form an exciplex, an excited state can be formed with lower excitation energy. Having lower excitation energy, the exciplex can form a stable excited state.

FIG. 4(C) shows the correlation between the energy levels of the compound 131, the compound 132, and the compound 133 in the light-emitting layer 130. The following explains what the terms and numerals in FIG. 4(C) represent.

Comp (131): compound 131

Comp (133): compound 133

Guest (132): compound 132

S_{C1}: S1 level of compound 131

T_{C1}: T1 level of compound 131

S_{C3}: S1 level of compound 133

T_{C3}: S1 level of compound 133

S_{G}: S1 level of compound 132

T_{G}: T1 level of compound 132

S_{E}: S1 level of exciplex

T_{E}: T1 level of exciplex

In the light-emitting element of one embodiment of the present invention, the compound 131 and the compound 133 contained in the light-emitting layer 130 form an exciplex. The S1 level (S_{E}) of the exciplex and the T1 level (T_{E}) of the exciplex are energy levels adjacent to each other (see Route A₆ in FIG. 4(C)).

Because the excitation energy levels (S_{E} and T_{E}) of the exciplex are lower than the S1 levels (S_{C1} and S_{C3}) of the substances (the compound 131 and the compound 133) that form an exciplex, an excited state can be formed with lower excitation energy. Accordingly, the driving voltage of the light-emitting element 150 can be reduced.

Since the S1 level (S_{E}) and the T1 level (T_{E}) of the exciplex are energy levels adjacent to each other, reverse intersystem crossing occurs easily, i.e., the exciplex has a TADF property. Therefore, the exciplex has a function of converting triplet excitation energy into singlet excitation energy by upconversion (Route A₇ in FIG. 4(C)). The singlet excitation energy of the exciplex can rapidly be transferred to the compound 132 (Route A₈ in FIG. 4(C)). At this time, S_{E} S_{G} is preferably satisfied. In Route A₈, the exciplex serves as an energy donor and the compound 132 serves as an energy acceptor. Here, the process of Route A₈ is in competition with the process of light emission of the exciplex (transition from the S1 level to the ground state of the exciplex or transition from the T1 level to the ground state of the exciplex). That is, the singlet and triplet excitation energy of the exciplex is converted into light emission of the exciplex and light emission of the compound 132. This enables the light-emitting element of one embodiment of the present invention to obtain light emission from the exciplex and light emission from the compound 132.

In order for the exciplex to serve as a light-emitting material as well as an energy donor, the concentration of the compound 132 is preferably greater than or equal to 0.01 wt % and less than or equal to 2 wt % with respect to the total amount of the compound 131 and the compound 133. With such a structure, the excitation energy of the exciplex can be efficiently converted into light emission of the exciplex and light emission of the compound 132, so that a multicolor light-emitting element with high efficiency can be obtained. The emission color can be changed by adjusting the concentrations of the compound 131, the compound 132, and the compound 133.

Specifically, S_{E}≥S_{G} is preferably satisfied when S_{E} is energy with a wavelength of the line obtained by extrapolating a tangent to the fluorescent spectrum of the exciplex at a tail on the short wavelength side and S_{G} is energy with a wavelength of the absorption edge of the absorption spectrum of the compound 132. An emission spectrum of the exciplex preferably has a region overlapping with an absorption band on the longest wavelength side in an absorption spectrum of the compound 132.

Note that in order to improve the TADF property of the exciplex, it is preferable that the T1 levels of both of the compound 131 and the compound 133, that is, T_{C1} and T_{C3} be higher than or equal to T_{E}. As the index for them, the emission peak wavelengths of the phosphorescent spectra of the compound 131 and the compound 133 on the shortest wavelength side are each preferably less than or equal to the maximum emission peak wavelength of the exciplex. When the level of energy with a wavelength of the line obtained by extrapolating a tangent to the fluorescent spectrum of the exciplex at a tail on the short wavelength side is S_{E} and the levels of energies with wavelengths of the lines obtained by extrapolating tangents to the phosphorescent spectra of the compound 131 and the compound 133 at a tail on the short wavelength side are T_{C1} and T_{C3}, respectively, S_{E}−T_{C1}≤0.2 eV and S_{E}−T_{C3}≤0.2 eV are preferably satisfied.

Triplet excitation energy generated in the light-emitting layer 130 is transferred through Route A₆ and from the S1 level of the exciplex to the S1 level of the guest material (Route A₈), resulting in light emission of the guest material. Thus, the use of a combination of materials that form an exciplex in the light-emitting layer 130 can improve the emission efficiency of the fluorescent element.

In the light-emitting element of one embodiment of the present invention, a guest material in which a luminophore has protecting groups is used as the compound 132. Such a structure can inhibit energy transfer by the Dexter mechanism that is represented by Route A₉ as described above, leading to inhibition of deactivation of triplet excitation energy. Thus, a fluorescent element with high emission efficiency can be obtained.

The above-described processes through Routes A₆ to A₈ may be referred to as ExSET (Exciplex-Singlet Energy Transfer) or ExEF (Exciplex-Enhanced Fluorescence) in this specification and the like. In other words, in the light-emitting layer 130, excitation energy is supplied from the exciplex to the fluorescent material.

### <Structure Example 3 of Light-Emitting Layer>

In this structure example, the case where a phosphorescent material is used as the compound 133 of the light-emitting element utilizing the above ExEF will be described. That is, the case where a phosphorescent material is used as one of the compounds that form an exciplex will be described.

In this structure example, a compound containing a heavy atom is used as one of the compounds that form an exciplex. Thus, intersystem crossing between a singlet state and a triplet state is promoted. Thus, an exciplex capable of transition from a triplet excited state to a singlet ground state (i.e., capable of exhibiting phosphorescence) can be formed. In this case, unlike in the case of a typical exciplex, the triplet excitation energy level (T_{E}) of the exciplex is the level of an energy donor; thus, T_{E} is preferably higher than or equal to the singlet excitation energy level (S_{G}) of the compound 132, which is a light-emitting material. Specifically, T_{E} S_{G} is preferably satisfied when T_{E} is the level of energy with a wavelength of the line obtained by extrapolating a tangent to the emission spectrum of the exciplex containing a heavy atom at a tail on the short wavelength side and S_{G} is the level of energy with a wavelength of the absorption edge of the absorption spectrum of the compound 132.

With such energy level correlation, the triplet excitation energy of the formed exciplex can be transferred from the triplet excitation energy level (T_{E}) of the exciplex to the singlet excitation energy level (S_{G}) of the compound 132. Note that it is difficult to clearly distinguish fluorescence and phosphorescence from each other in an emission spectrum in some cases because the S1 level (S_{E}) and the T1 level (T_{E}) of the exciplex are energy levels adjacent to each other. In that case, fluorescence and phosphorescence can be sometimes distinguished from each other by the emission lifetime.

Note that the phosphorescent material used in the above structure preferably contains a heavy atom such as Ir, Pt, Os, Ru, or Pd. That is, energy transfer from the triplet excitation energy level of the exciplex to the singlet excitation energy level of the guest material is acceptable as long as it is allowable transition. The energy transfer from the phosphorescent material or the exciplex formed using a phosphorescent material to the guest material is preferred, in which case energy transfer from the triplet excitation energy level of the energy donor to the singlet excitation energy level of the guest material (energy acceptor) is allowable transition. Thus, without through the process of Route A₇ in FIG. 4(C), the triplet excitation energy of the exciplex can be transferred to the S1 level (S_{G}) of the guest material through the process of Route A₈. That is, triplet and singlet excitation energy can be transferred to the S1 level of the guest material only through the processes of Route A₆ and Route A₈. In Route A₈, the exciplex serves as an energy donor and the compound 132 serves as an energy acceptor. Here, the process of Route A₈ is in competition with the process of light emission of the exciplex (transition from the S1 level or the T1 level to the ground state of the exciplex). That is, the singlet excitation energy or the triplet excitation of the exciplex is converted into light emission of the compound 131 and light emission of the compound 132. This enables the light-emitting element of one embodiment of the present invention to obtain light emission from the compound 131 and light emission from the compound 132. In this structure example, the light emission derived from the compound 133 can also be obtained by adjusting the concentration of the compound 133 in the light-emitting layer 130.

In order for the compound 133 and the exciplex to serve as a light-emitting material as well as an energy donor, the concentration of the compound 132 is preferably greater than or equal to 0.01 wt % and less than or equal to 2 wt % with respect to the total amount of the compound 131 and the compound 133. With such a structure, the excitation energy of the compound 133 and the exciplex can be efficiently converted into light emission of the exciplex and light emission of the compound 132, so that a multicolor light-emitting element with high efficiency can be obtained. The emission color can be changed by adjusting the concentrations of the compound 131, the compound 132, and the compound 133.

In the light-emitting element of one embodiment of the present invention, a guest material in which a luminophore has protecting groups is used as the compound 132. Such a structure can inhibit energy transfer by the Dexter mechanism that is represented by Route A₉ as described above, leading to inhibition of deactivation of triplet excitation energy. Thus, a fluorescent element with high emission efficiency can be obtained.

### <Structure Example 4 of Light-Emitting Layer>

In this structure example, the case where a material having a TADF property is used as the compound 133 of the light-emitting element utilizing the above ExEF will be described with reference to FIG. 4(D).

Since the compound 133 is the TADF material, the compound 133 that does not form an exciplex has a function of converting triplet excitation energy into singlet excitation energy by upconversion (Route A₁₀ in FIG. 4(D)). The singlet excitation energy of the compound 133 can be rapidly transferred to the compound 132. (Route Au in FIG. 4(D)). At this time, S_{C3}≥S_{G} is preferably satisfied.

As described in the above structure example of the light-emitting layer, the light-emitting element of one embodiment of the present invention has a pathway where the triplet excitation energy is transferred to the compound 132, which is a guest material, through Route A₆ to Route

A₈ in FIG. 4(D) and a pathway where the triplet excitation energy is transferred to the compound 132 through Route A₁₀ and Route A₁₁ in FIG. 4(D). A plurality of pathways through each of which the triplet excitation energy is transferred to the fluorescent material can further improve the emission efficiency. In Route A₈, the exciplex serves as an energy donor and the compound 132 serves as an energy acceptor. In Route A₁₁, the compound 133 serves as an energy donor and the compound 132 serves as an energy acceptor. Here, the process of Route A₁₁ is in competition with the process of light emission of the compound 133 (transition from the S1 level to the ground state of the compound 133). That is, the singlet excitation energy of the compound 133 is converted into light emission of the compound 133 and light emission of the compound 132. This enables the light-emitting element of one embodiment of the present invention to obtain light emission from the compound 133 and light emission from the compound 132. As described above, the process of Route A₈ is in competition with the process of light emission of the exciplex (transition from the S1 level to the ground state of the exciplex). That is, the singlet excitation energy of the exciplex is converted into light emission of the exciplex and light emission of the compound 132. This enables the light-emitting element of one embodiment of the present invention to obtain light emission from the exciplex and light emission from the compound 132.

In order for the compound 133 and the exciplex to serve as a light-emitting material as well as an energy donor, the concentration of the compound 132 is preferably greater than or equal to 0.01 wt % and less than or equal to 2 wt % with respect to the total amount of the compound 131 and the compound 133. With such a structure, the excitation energy of the compound 133 and the exciplex can be efficiently converted into light emission of the exciplex and light emission of the compound 132, so that a multicolor light-emitting element with high efficiency can be obtained. The emission color can be changed by adjusting the concentrations of the compound 131, the compound 132, and the compound 133.

In this structure example, the exciplex and the compound 133 serve as energy donors, and the compound 132 serves as an energy acceptor.

### <Structure Example 5 of Light-Emitting Layer>

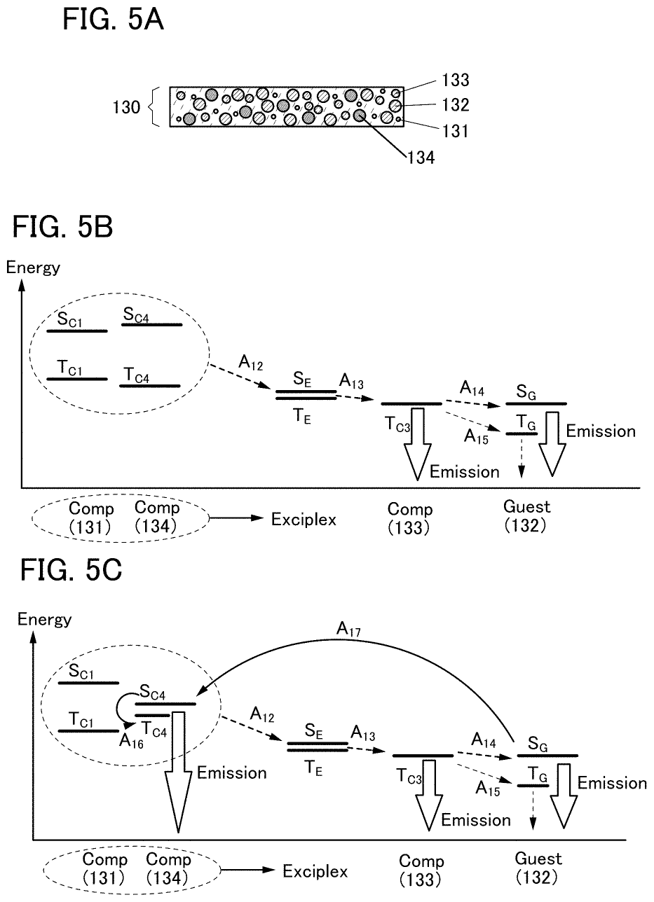

FIG. 5(A) illustrates the case where four kinds of materials are used in the light-emitting layer 130. The light-emitting layer 130 in FIG. 5(A) contains the compound 131, the compound 132, the compound 133, and a compound 134. In one embodiment of the present invention, the compound 133 has a function of converting triplet excitation energy into light emission. In this structure example, the case where the compound 133 is a phosphorescent material is described.

The compound 132 is a guest material that emits fluorescence. The compound 131 is an organic compound that forms an exciplex together with the compound 134.

FIG. 5(B) shows the correlation between the energy levels of the compound 131, the compound 132, the compound 133, and the compound 134 in the light-emitting layer 130. The following explains what the terms and numerals in FIG. 5(B) represent, and the other terms and numerals are the same as those in FIG. 4(C).

Comp (134): compound 134

S_{C4}: S1 level of compound 134

T_{C4}: T1 level of compound 134

In the light-emitting element of one embodiment of the present invention described in this structure example, the compound 131 and the compound 134 contained in the light-emitting layer 130 form an exciplex. The S1 level (S_{E}) of the exciplex and the T1 level (T_{E}) of the exciplex are energy levels adjacent to each other (see Route A₁₂ in FIG. 5(B)).

As described above, when the exciplex formed through the above process loses excitation energy, the two substances that have formed the exciplex individually behave as the original separate substances.

Because the excitation energy levels (S_{E} and T_{E}) of the exciplex are lower than the S1 levels (S_{C1} and S_{C4}) of the substances (the compound 131 and the compound 134) that form an exciplex, an excited state can be formed with lower excitation energy. Accordingly, the driving voltage of the light-emitting element 150 can be reduced.

Here, when the compound 133 is a phosphorescent material, intersystem crossing between a singlet state and a triplet state is allowed. Hence, both the singlet excitation energy and the triplet excitation energy of the exciplex are rapidly transferred to the compound 133 (Route A₁₃). At this time, T_{E}≥T_{C3} is preferably satisfied. In addition, the triplet excitation energy of the compound 133 can be efficiently converted into the singlet excitation energy of the compound 132 (Route A₁₄). Here, T_{E}≥T_{C3}≥S_{G} as shown in FIG. 5(B) is preferable, in which case the excitation energy of the compound 133 is efficiently transferred as the singlet excitation energy to the compound 132, which is the guest material. Specifically, when the level of energy with a wavelength of the line obtained by extrapolating a tangent to the phosphorescent spectrum of the compound 133 at a tail on the short wavelength side is S_{C3} and the level of energy with a wavelength of the absorption edge of the absorption spectrum of the compound 132 is S_{G}, S_{C3}≥S_{G} is preferably satisfied. In addition, the peak wavelength of the emission spectrum of the compound 133 preferably overlaps with the absorption band on the longest wavelength side in the absorption spectrum of the compound 132. In Route A₁₄, the compound 133 serves as an energy donor and the compound 132 serves as an energy acceptor. Here, the process of Route A₁₄ is in competition with the process of light emission of the compound 133 (transition from the T1 level to the ground state of the compound 133). That is, the triplet excitation energy of the compound 133 is converted into light emission of the compound 133 and light emission of the compound 132. This enables the light-emitting element of one embodiment of the present invention to obtain light emission from the compound 133 and light emission from the compound 132.

Although any combination of the compound 131 and the compound 134 that can form an exciplex is acceptable, it is further preferable that one of them be a compound having a hole-transport property and the other be a compound having an electron-transport property.

In order for the compound 133 to serve as a light-emitting material as well as an energy donor, the concentration of the compound 132 is preferably greater than or equal to 0.01 wt % and less than or equal to 2 wt % with respect to the total amount of the compound 131, the compound 133, and the compound 134. With such a structure, the excitation energy of the compound 133 can be efficiently converted into light emission of the compound 133 and light emission of the compound 132, so that a multicolor light-emitting element with high efficiency can be obtained. The emission color can be changed by adjusting the concentrations of the compound 131, the compound 132, the compound 133, and the compound 134.

For the combination of materials for forming an exciplex efficiently, it is preferable that the HOMO level of one of the compound 131 and the compound 134 be higher than the HOMO level of the other and the LUMO level of the one of the compounds be higher than the LUMO level of the other.

The correlation between the energy levels of the compound 131 and the compound 134 is not limited to that shown in FIG. 5(B). In other words, the singlet excitation energy level (S_{C1}) of the compound 131 may be higher or lower than the singlet excitation energy level (S_{C4}) of the compound 134. The triplet excitation energy level (T_{C1}) of the compound 131 may be higher or lower than the triplet excitation energy level (T_{C4}) of the compound 134.

In the light-emitting element of one embodiment of the present invention, the compound 131 preferably has a π-electron deficient skeleton. Such a composition lowers the LUMO level of the compound 131, which is suitable for formation of an exciplex.

In the light-emitting element of one embodiment of the present invention, the compound 131 preferably has a π-electron rich skeleton. Such a composition increases the HOMO level of the compound 131, which is suitable for formation of an exciplex.

In the light-emitting element of one embodiment of the present invention, a guest material in which a luminophore has protecting groups is used as the compound 132. Such a structure can inhibit energy transfer by the Dexter mechanism that is represented by Route A₁₅ as described above, leading to inhibition of deactivation of triplet excitation energy. Thus, a fluorescent element with high emission efficiency can be obtained.

Note that the above-described processes through Routes A₁₂ and A₁₃ may be referred to as ExTET (Exciplex-Triplet Energy Transfer) in this specification and the like. In other words, in the light-emitting layer 130, excitation energy is supplied from the exciplex to the compound 133. Thus, this structure example can be referred to as a structure in which a fluorescent material having protecting groups is mixed in a light-emitting layer capable of utilizing ExTET.

### <Structure Example 6 of Light-Emitting Layer>

In this structure example, the case where a material having a TADF property is used as the compound 134 described in above Structure Example 5 of Light-Emitting Layer will be described.

FIG. 5(C) shows the case where four kinds of materials are used in the light-emitting layer 130. The light-emitting layer 130 in FIG. 5(C) contains the compound 131, the compound 132, the compound 133, and the compound 134. In one embodiment of the present invention, the compound 133 has a function of converting triplet excitation energy into light emission. The compound 132 is a guest material that emits fluorescence. The compound 131 is an organic compound that forms an exciplex together with the compound 134.

Here, since the compound 134 is the TADF material, the compound 134 that does not form an exciplex has a function of converting triplet excitation energy into singlet excitation energy by upconversion (Route A₁₆ in FIG. 5(C)). The singlet excitation energy of the compound 134 can be rapidly transferred to the compound 132 (Route A₁₇ in FIG. 5(C)). At this time, S_{C4}≥S_{G} is preferably satisfied. Here, the process of Route A₁₇ is in competition with the process of light emission of the compound 134 (transition from the S1 level to the ground state of the compound 134). That is, the singlet excitation energy of the compound 134 is converted into light emission of the compound 134 and light emission of the compound 132. This enables the light-emitting element of one embodiment of the present invention to obtain light emission from the compound 134 and light emission from the compound 132. Furthermore, as shown in Structure Example 5 of Light-Emitting Layer, the triplet excitation energy of the compound 133 can be efficiently converted into the singlet excitation energy of the compound 132 (Route A₁₄), so that light emission from the compound 133 can also be obtained.

In order for the compound 133 and the compound 134 to serve as a light-emitting material as well as an energy donor, the concentration of the compound 132 is preferably greater than or equal to 0.01 wt % and less than or equal to 2 wt % with respect to the total amount of the compound 131, the compound 133, and the compound 134. With such a structure, the excitation energy of the compound 133 and the compound 134 can be efficiently converted into light emission of the compound 133 and light emission of the compound 132, so that a multicolor light-emitting element with high efficiency can be obtained. The emission color can be changed by adjusting the concentrations of the compound 131, the compound 132, the compound 133, and the compound 134.

Specifically, when the level of energy with a wavelength of the line obtained by extrapolating a tangent to the fluorescent spectrum of the compound 134 at a tail on the short wavelength side is S_{C4} and the level of energy with a wavelength of the absorption edge of the absorption spectrum of the compound 132 is S_{G}, S_{C4}≥S_{G} is preferably satisfied. In addition, the emission spectrum of the compound 134 preferably overlaps with the absorption band on the longest wavelength side in the absorption spectrum of the compound 132.

As described in the above structure example of the light-emitting layer, the light-emitting element of one embodiment of the present invention has a pathway where the triplet excitation energy is transferred to the compound 132, which is a guest material, through Route Au to Route A₁₄ in FIG. 5(C) and a pathway where the triplet excitation energy is transferred to the compound 132 through Route A₁₆ and Route A₁₇ in FIG. 5(C). A plurality of pathways through each of which the triplet excitation energy is transferred to the fluorescent material can further improve the emission efficiency. In Route A₁₄, the compound 133 serves as an energy donor and the compound 132 serves as an energy acceptor. In Route A₁₇, the compound 134 serves as an energy donor and the compound 132 serves as an energy acceptor.

As described above, the light-emitting element of one embodiment of the present invention can emit multicolor light through energy transfer pathways. The emission color can be changed by adjusting the concentrations of the compound 132, the compound 133, and the compound 134 in the light-emitting layer 130. That is, the intensity of emission from the compound 132, the intensity of emission from the compound 133, and the intensity of emission from the exciplex can be changed by adjusting the concentrations of the compound 132, the compound 133, and the compound 134 in the light-emitting layer 130.

### <Structure Example 7 of Light-Emitting Layer>

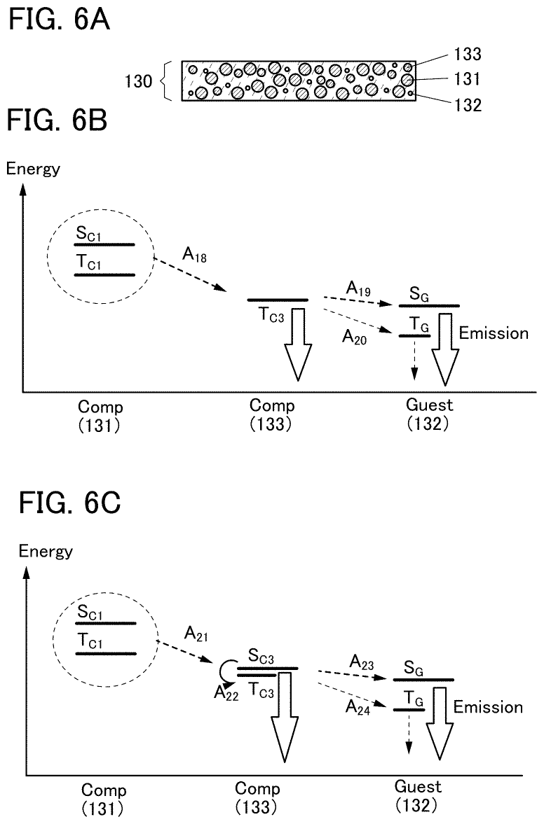

FIG. 6(B) shows an example of the correlation between energy levels in the light-emitting layer 130 of the light-emitting element 150 of one embodiment of the present invention. The light-emitting layer 130 illustrated in FIG. 6(A) contains the compound 131, the compound 132, and also the compound 133. In one embodiment of the present invention, the compound 132 is a fluorescent material having protecting groups. The compound 133 has a function of converting triplet excitation energy into light emission. In this structure example, the case where the compound 133 is a phosphorescent material will be described.

The following explains what the terms and numerals in FIG. 6(B) and FIG. 6(C) described later represent.

Comp (131): compound 131

Comp (133): compound 133

Guest (132): compound 132

S_{C1}: S1 level of compound 131

T_{C1}: T1 level of compound 131

T_{C3}: T1 level of compound 133

T_{G}: T1 level of compound 132

S_{G}: S1 level of compound 132

In the light-emitting element of one embodiment of the present invention, when carrier recombination mainly occurs in the compound 131 contained in the light-emitting layer 130, singlet excitons and triplet excitons are generated. Since the compound 133 is a phosphorescent material, selecting materials that have a relation of T_{C3}≤T_{C1} allows both of the singlet excitation energy and the triplet excitation energy generated in the compound 131 to be transferred to the T_{C3} level of the compound 133 (Route A₁₈ in FIG. 6(B)). Some of the carriers can be recombined in the compound 133.

Note that the phosphorescent material used in the above structure preferably contains a heavy atom such as Ir, Pt, Os, Ru, or Pd. A phosphorescent material is preferably used as the compound 133, in which case energy transfer from the triplet excitation energy level of the energy donor to the singlet excitation energy level of the guest material (energy acceptor) is allowable transition. Thus, the triplet excitation energy of the compound 133 can be transferred to the S1 level (S_{G}) of the guest material through the process of Route A₁₉. In Route A₁₉, the compound 133 serves as an energy donor and the compound 132 serves as an energy acceptor. In that case, T_{C3}≥S_{G} is preferable because the excitation energy of the compound 133 is efficiently transferred to the singlet excited state of the compound 132, which is a guest material. Here, the process of Route A₁₉ is in competition with the process of light emission of the compound 133 (transition from the T1 level to the ground state of the compound 133). That is, the triplet excitation energy of the compound 133 is converted into light emission of the compound 133 and light emission of the compound 132. This enables the light-emitting element of one embodiment of the present invention to obtain light emission from the compound 133 and light emission from the compound 132.

In order for the compound 133 to serve as a light-emitting material as well as an energy donor, the concentration of the compound 132 is preferably greater than or equal to 0.01 wt % and less than or equal to 2 wt % with respect to the total amount of the compound 131 and the compound 133. With such a structure, the excitation energy of the compound 133 can be efficiently converted into light emission of the compound 133 and light emission of the compound 132, so that a multicolor light-emitting element with high efficiency can be obtained. The emission color can be changed by adjusting the concentrations of the compound 131, the compound 132, and the compound 133.

Specifically, when the level of energy with a wavelength of the line obtained by extrapolating a tangent to the phosphorescent spectrum of the compound 133 at a tail on the short wavelength side is T_{C3} and the level of energy with a wavelength of the absorption edge of the absorption spectrum of the compound 132 is S_{G}, T_{C3}≥S_{G} is preferably satisfied. In addition, the emission spectrum of the compound 133 preferably overlaps with the absorption band on the longest wavelength side in the absorption spectrum of the compound 132.

In the light-emitting element of one embodiment of the present invention, a guest material in which a luminophore has protecting groups is used as the compound 132. Such a structure can inhibit energy transfer by the Dexter mechanism that is represented by Route A₂₀ as described above, leading to inhibition of deactivation of triplet excitation energy. Thus, a fluorescent element with high emission efficiency can be obtained.

### <Structure Example 8 of Light-Emitting Layer>

FIG. 6(C) shows an example of the correlation between energy levels in the light-emitting layer 130 of the light-emitting element 150 of one embodiment of the present invention. The light-emitting layer 130 illustrated in FIG. 6(C) contains the compound 131, the compound 132, and also the compound 133. In one embodiment of the present invention, the compound 132 is a fluorescent material having protecting groups. The compound 133 has a function of converting triplet excitation energy into light emission. In this structure example, the case where the compound 133 is a compound having a TADF property will be described.

The following explains what the terms and numerals in FIG. 6(C) represent, and the other terms and numerals are the same as those in FIG. 6(B).

S_{c3}: S1 Level of Compound 133

In the light-emitting element of one embodiment of the present invention, when carrier recombination mainly occurs in the compound 131 contained in the light-emitting layer 130, singlet excitons and triplet excitons are generated. Selecting materials that have a relation of S_{C3}≤S₁ and T_{C3}≤T_{C1} allows both of the singlet excitation energy and the triplet excitation energy generated in the compound 131 to be transferred to the S_{C3} and T_{C3} levels of the compound 133 (Route A₂₁ in FIG. 6(C)). Some of the carriers can be recombined in the compound 133.

Here, the compound 133 is the TADF material and thus has a function of converting triplet excitation energy into singlet excitation energy by upconversion (Route A₂₂ in FIG. 6(C)). The singlet excitation energy of the compound 133 can be rapidly transferred to the compound 132 (Route A₂₃ in FIG. 6(C)). At this time, S_{C3}≥S_{G} is preferably satisfied. Here, the process of Route A₂₃ is in competition with the process of light emission of the compound 133 (transition from the S1 level to the ground state of the compound 133). That is, the singlet excitation energy of the compound 133 is converted into light emission of the compound 133 and light emission of the compound 132. This enables the light-emitting element of one embodiment of the present invention to obtain light emission from the compound 133 and light emission from the compound 132.

In order for the compound 133 to serve as a light-emitting material as well as an energy donor, the concentration of the compound 132 is preferably greater than or equal to 0.01 wt % and less than or equal to 2 wt % with respect to the total amount of the compound 131 and the compound 133. With such a structure, the excitation energy of the compound 133 can be efficiently converted into light emission of the compound 133 and light emission of the compound 132, so that a multicolor light-emitting element with high efficiency can be obtained. The emission color can be changed by adjusting the concentrations of the compound 131, the compound 132, and the compound 133.

Specifically, when the level of energy with a wavelength of the line obtained by extrapolating a tangent to the phosphorescent spectrum of the compound 133 at a tail on the short wavelength side is S_{C3} and the level of energy with a wavelength of the absorption edge of the absorption spectrum of the compound 132 is S_{G}, S_{C3}≥S_{G} is preferably satisfied. In addition, the emission spectrum of the compound 133 preferably overlaps with the absorption band on the longest wavelength side in the absorption spectrum of the compound 132. Through the processes of Route A₂₁ to Route A₂₃, triplet excitation energy in the light-emitting layer 130 can be converted into fluorescence of the compound 132. In Route A₂₃, the compound 133 serves as an energy donor and the compound 132 serves as an energy acceptor.

In the light-emitting element of one embodiment of the present invention, a guest material in which a luminophore has protecting groups is used as the compound 132. Such a structure can inhibit energy transfer by the Dexter mechanism that is represented by Route A₂₄ as described above, leading to inhibition of deactivation of triplet excitation energy. Thus, a fluorescent element with high emission efficiency can be obtained.

### <Energy Transfer Mechanism>

Here, the Förster mechanism and the Dexter mechanism will be described. As to supply of excitation energy from a first material in an excited state to a second material in a ground state, an intermolecular energy transfer process between the first material and the second material will be described here; the same can be applied to the case where one of them is an exciplex.

### <<Förster Mechanism>>

In the Forster mechanism, energy transfer does not require direct intermolecular contact and energy is transferred through a resonant phenomenon of dipolar oscillation between a first material and a second material. By the resonant phenomenon of dipolar oscillation, the first material provides energy to the second material, and thus, the first material in an excited state is brought into a ground state and the second material in a ground state is brought into an excited state. Note that the rate constant k_{h→g} of the Förster mechanism is expressed by Formula (1).

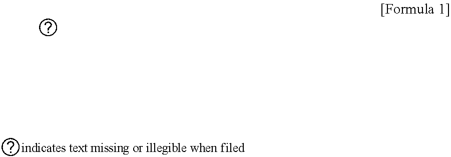

In Formula (1), v denotes a frequency; f′ₕ(v), a normalized emission spectrum of the first material (a fluorescent spectrum in the case where energy transfer from a singlet excited state is discussed, or a phosphorescent spectrum in the case where energy transfer from a triplet excited state is discussed); ε_{g}(v) a molar absorption coefficient of the second material; N, Avogadro's number; n, a refractive index of a medium; R, an intermolecular distance between the first material and the second material; τ, a measured lifetime of an excited state (fluorescence lifetime or phosphorescence lifetime); c, the speed of light; ϕ, a luminescence quantum yield (a fluorescence quantum yield in the case where energy transfer from a singlet excited state is discussed, or a phosphorescence quantum yield in the case where energy transfer from a triplet excited state is discussed); and K², a coefficient (0 to 4) of orientation of a transition dipole moment between the first material and the second material. Note that K²=⅔ in random orientation.

### <<Dexter Mechanism>>

In the Dexter mechanism, the first material and the second material are close to a contact effective range where their orbitals overlap, and the first material in an excited state and the second material in a ground state exchange their electrons, which leads to energy transfer. Note that the rate constant k_{h*→g} of the Dexter mechanism is expressed by Formula (2).

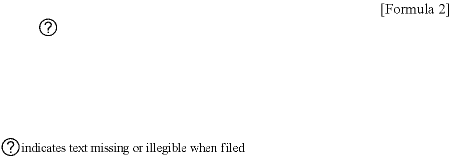

In Formula (2), h denotes a Planck constant; K, a constant having an energy dimension; v, a frequency; f′ₕ(v), a normalized emission spectrum of the first material (the fluorescent spectrum in the case where energy transfer from a singlet excited state is discussed, or the phosphorescent spectrum in the case where energy transfer from a triplet excited state is discussed), ε′_{g}(v), a normalized absorption spectrum of the second material; L, an effective molecular radius; and R, an intermolecular distance between the first material and the second material.

Here, the efficiency of energy transfer ϕ_{ET} from the first material to the second material is expressed by Formula (3). Note that kᵣ denotes a rate constant of a light-emission process (fluorescence in the case where energy transfer from a singlet excited state is discussed, or phosphorescence in the case where energy transfer from a triplet excited state is discussed) of the first material; kₙ, a rate constant of a non-light-emission process (thermal deactivation or intersystem crossing) of the second material; and τ, a measured lifetime of an excited state of the first material.

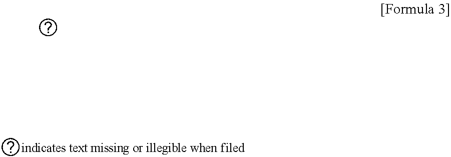

According to Formula (3), it is found that the energy transfer efficiency ϕ_{ET} can be increased by increasing the rate constant k_{h*→g} of energy transfer so that another competing rate constant kᵣ+kₙ (=1/τl) becomes relatively small.

### <<Concept for Promoting Energy Transfer>>

First, energy transfer by the Forster mechanism is considered. When Formula (1) is substituted into Formula (3), r can be eliminated. Thus, in the case of the Förster mechanism, the energy transfer efficiency ϕ_{ET} does not depend on the lifetime τ of the excited state of the first material. Furthermore, it can be said that high energy transfer efficiency ϕ_{ET} is obtained when the emission quantum yield ϕ is high.

Furthermore, it is preferable that the emission spectrum of the first material largely overlap with the absorption spectrum of the second material (absorption corresponding to transition from a singlet ground state to a singlet excited state). Moreover, it is preferable that the molar absorption coefficient of the second material be also high. This means that the emission spectrum of the first material overlaps with the absorption band of the second material which is on the longest wavelength side. Note that since direct transition from the singlet ground state to the triplet excited state of the second material is forbidden, the molar absorption coefficient of the second material in the triplet excited state can be ignored. Thus, a process of energy transfer from an excited state of the first material to a triplet excited state of the second material by the Förster mechanism can be ignored, and only a process of energy transfer to a singlet excited state of the second material is considered.

The rate of energy transfer by the Forster mechanism is inversely proportional to the 6th power of the intermolecular distance R between the first material and the second material, according to Formula (1). As described above, when R is less than or equal to 1 nm, energy transfer by the Dexter mechanism is dominant. Therefore, to increase the rate of energy transfer by the Förster mechanism while inhibiting energy transfer by the Dexter mechanism, the intermolecular distance is preferably greater than or equal to 1 nm and less than or equal to 10 nm. This requires the above protecting groups to be not too bulky; thus, the number of carbon atoms of the protecting groups is preferably 3 to 10.

Next, energy transfer by the Dexter mechanism is considered. According to Formula (2), in order to increase the rate constant k_{h*→g}, it is preferable that the emission spectrum of the first material (the fluorescent spectrum in the case where energy transfer from a singlet excited state is discussed, or the phosphorescent spectrum in the case where energy transfer from a triplet excited state is discussed) largely overlap with an absorption spectrum of the second material (absorption corresponding to transition from a singlet ground state to a singlet excited state). Therefore, the energy transfer efficiency can be optimized by making the emission spectrum of the first material overlap with the absorption band of the second material which is on the longest wavelength side.

When Formula (2) is substituted into Formula (3), it is found that the energy transfer efficiency ϕ_{ET} in the Dexter mechanism depends on r. In the Dexter mechanism, which is a process of energy transfer based on the electron exchange, as well as the energy transfer from the singlet excited state of the first material to the singlet excited state of the second material, energy transfer from the triplet excited state of the first material to the triplet excited state of the second material occurs.

In the light-emitting element of one embodiment of the present invention in which the second material is a fluorescent material, the efficiency of energy transfer to the triplet excited state of the second material is preferably low. That is, the efficiency of energy transfer based on the Dexter mechanism from the first material to the second material is preferably low and the efficiency of energy transfer based on the Forster mechanism from the first material to the second material is preferably high.

As described above, the energy transfer efficiency in the Förster mechanism does not depend on the lifetime τ of the excited state of the first material. In contrast, the energy transfer efficiency in the Dexter mechanism depends on the excitation lifetime τ of the first material; to reduce the energy transfer efficiency in the Dexter mechanism, the excitation lifetime τ of the first material is preferably short.

Thus, in one embodiment of the present invention, an exciplex, a phosphorescent material, or a TADF material is used as the first material. These materials each have a function of converting triplet excitation energy into light emission. The energy transfer efficiency of the Förster mechanism depends on the emission quantum yield of the energy donor; thus, the excitation energy of the first material capable of converting triplet excitation energy into light emission, such as a phosphorescent material, an exciplex, or a TADF material, can be transferred to the second material by the Förster mechanism. Meanwhile, with the structure of one embodiment of the present invention, reverse intersystem crossing from the triplet excited state to the singlet excited state of the first material (exciplex or TADF material) can be promoted, and the excitation lifetime τ of the triplet excited state of the first material can be short. Furthermore, transition from the triplet excited state to the singlet ground state of the first material (phosphorescent material or exciplex using a phosphorescent material) can be promoted, and the excitation lifetime τ of the triplet excited state of the first material can be short. As a result, the energy transfer efficiency from the triplet excited state of the first material to the triplet excited state of the fluorescent material (second material) in the Dexter mechanism can be reduced.

In the light-emitting element of one embodiment of the present invention, a fluorescent material having protecting groups is used as the second material, as described above. Therefore, the intermolecular distance between the first material and the second material can be large. In the light-emitting element of one embodiment of the present invention, a material having a function of converting triplet excitation energy into light emission is used as the first material, and a fluorescent material having protecting groups is used as the second material, whereby the efficiency of energy transfer by the Dexter mechanism can be reduced. As a result, non-radiative decay of the triplet excitation energy in the light-emitting layer 130 can be inhibited, so that a light-emitting element with high emission efficiency can be provided.

### <Material>

Next, components of the light-emitting element of one embodiment of the present invention will be described in detail below.

### <<Light-Emitting Layer>>

Materials that can be used for the light-emitting layer 130 are described below. In the light-emitting layer of the light-emitting element of one embodiment of the present invention, an energy acceptor having a function of converting triplet excitation energy into light emission and an energy donor in which a luminophore has protecting groups are used. As the material having a function of converting triplet excitation energy into light emission, a TADF material and a phosphorescent material are given.

Examples of the luminophore included in the compound 132 serving as an energy acceptor include a phenanthrene skeleton, a stilbene skeleton, an acridone skeleton, a phenoxazine skeleton, and a phenothiazine skeleton. Specifically, fluorescent materials having a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton are preferable because of their high fluorescence quantum yields.

The protecting group is preferably an alkyl group having 1 to 10 carbon atoms, a cycloalkyl group having 3 to 10 carbon atoms, a branched-chain alkyl group having 3 to 10 carbon atoms, or a trialkylsilyl group having 3 to 12 carbon atoms.

Examples of the alkyl group having 1 to 10 carbon atoms include a methyl group, an ethyl group, a propyl group, a pentyl group, and a hexyl group; a branched-chain alkyl group having 3 to 10 carbon atoms, which is described later, is particularly preferable. Note that the alkyl group is not limited thereto.

Examples of the cycloalkyl group having 3 to 10 carbon atoms include a cyclopropyl group, a cyclobutyl group, a cyclohexyl group, a norbomyl group, and an adamantyl group. The cycloalkyl group is not limited thereto. In the case where the cycloalkyl group has a substituent, examples of the substituent include an alkyl group having 1 to 7 carbon atoms, such as a methyl group, an ethyl group, a propyl group, an isopropyl group, a butyl group, an isobutyl group, a sec-butyl group, a tert-butyl group, a pentyl group, or a hexyl group, a cycloalkyl group having 5 to 7 carbon atoms, such as a cyclopentyl group, a cyclohexyl group, a cycloheptyl group, or a 8,9,10-trinorbornanyl group, and an aryl group having 6 to 12 carbon atoms, such as a phenyl group, a naphthyl group, or a biphenyl group.

Examples of the branched-chain alkyl group having 3 to 10 carbon atoms include an isopropyl group, a sec-butyl group, an isobutyl group, a tert-butyl group, an isopentyl group, a sec-pentyl group, a tert-pentyl group, a neopentyl group, an isohexyl group, a 3-methylpentyl group, a 2-methylpentyl group, a 2-ethylbutyl group, a 1,2-dimethylbutyl group, and a 2,3-dimethylbutyl group. The branched-chain alkyl group is not limited thereto.

Examples of the trialkylsilyl group having 3 to 12 carbon atoms include a trimethylsilyl group, a triethylsilyl group, and a tert-butyl dimethylsilyl group. The trialkylsilyl group is not limited thereto.

In the molecular structure of the energy acceptor, it is preferable that two or more diarylamino groups be bonded to a luminophore and aryl groups of the diarylamino groups each have at least one protecting group. It is further preferable that at least two protecting groups be bonded to each of the aryl groups. This is because a larger number of protecting groups more effectively inhibit energy transfer by the Dexter mechanism in the case where the guest material is used for the light-emitting layer. To inhibit an increase in molecular weight and keep the sublimation property, the diarylamino groups are preferably diphenylamino groups.

Furthermore, when two or more amino groups are bonded to a luminophore, a fluorescent material whose emission color can be adjusted and which has a high quantum yield can be obtained. The amino groups are preferably bonded to the luminophore at symmetric positions. With such a structure, the fluorescent material can have a high quantum yield.

The protecting groups may be introduced to the luminophore via the aryl groups of the diarylamine, not directly introduced to the luminophore. Such a structure is preferably employed, in which case the protecting groups can be arranged to cover the luminophore, allowing the host material and the luminophore to be away from each other from any direction. In the case where the protecting groups are not directly bonded to the luminophore, four or more protecting groups are preferably introduced to one luminophore.

Furthermore, it is preferable that at least one of atoms of the plurality of protecting groups be positioned directly on one plane of the luminophore, that is, the condensed aromatic ring or the condensed heteroaromatic ring, and at least one of atoms of the plurality of protecting groups be positioned directly on the other plane of the condensed aromatic ring or the condensed heteroaromatic ring, as shown in FIG. 3. The following structure is given as a specific method. In other words, the condensed aromatic ring or the condensed heteroaromatic ring, which is a luminophore, is bonded to two or more diphenylamino groups, and the phenyl groups of the two or more diphenylamino groups each independently have protecting groups at the 3-position and the 5-position.

Such a structure enables a steric configuration in which the protecting groups at the 3-position and the 5-position of the phenyl groups are positioned directly on the condensed aromatic ring or the condensed heteroaromatic ring, which is a luminophore, as shown in FIG. 3. As a result, the upper and lower planes of the condensed aromatic ring or the condensed heteroaromatic ring can be efficiently covered, inhibiting energy transfer by the Dexter mechanism.

As the energy acceptor material described above, for example, an organic compound represented by General Formula (G1) or (G2) shown below can be suitably used.

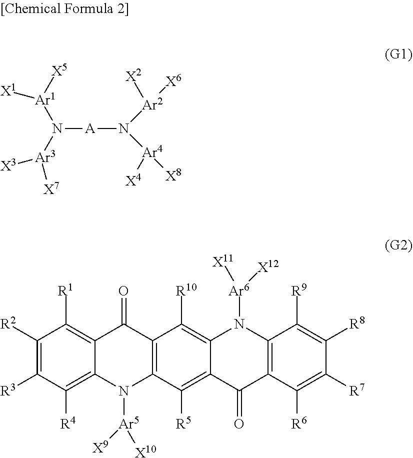

In General Formulae (G1) and (G2), A represents a substituted or unsubstituted condensed aromatic ring having 10 to 30 carbon atoms or a substituted or unsubstituted condensed heteroaromatic ring having 10 to 30 carbon atoms, Ar¹ to Ar⁶ each independently represent a substituted or unsubstituted aromatic hydrocarbon group having 6 to 13 carbon atoms, X¹ to X¹² each independently represent any one of a branched-chain alkyl group having 3 to 10 carbon atoms, a substituted or unsubstituted cycloalkyl group having 3 to 10 carbon atoms, and a trialkylsilyl group having 3 to 12 carbon atoms, and R¹ to R¹⁰ each independently represent any one of hydrogen, an alkyl group having 3 to 10 carbon atoms, a substituted or unsubstituted cycloalkyl group having 3 to 10 carbon atoms, and a trialkylsilyl group having 3 to 12 carbon atoms.

Examples of the aromatic hydrocarbon group having 6 to 13 carbon atoms include a phenyl group, a biphenyl group, a naphthyl group, and a fluorenyl group. Note that the aromatic hydrocarbon group is not limited thereto. In the case where the aromatic hydrocarbon group has a substituent, examples of the substituent include an alkyl group having 1 to 7 carbon atoms, such as a methyl group, an ethyl group, a propyl group, an isopropyl group, a butyl group, an isobutyl group, a sec-butyl group, a tert-butyl group, a pentyl group, or a hexyl group, a cycloalkyl group having 5 to 7 carbon atoms, such as a cyclopentyl group, a cyclohexyl group, a cycloheptyl group, or an 8,9,10-trinorbornanyl group, and an aryl group having 6 to 12 carbon atoms, such as a phenyl group, a naphthyl group, or a biphenyl group.

In General Formula (G1), the substituted or unsubstituted condensed aromatic ring having 10 to 30 carbon atoms or the substituted or unsubstituted condensed heteroaromatic ring having 10 to 30 carbon atoms represents the luminophore; any of the above skeletons can be used. In General Formulae (G1) and (G2), X¹ to X¹² represent protecting groups.

In General Formula (G2), the protecting groups are bonded to a quinacridone skeleton, which is a luminophore, via arylene groups. With this structure, the protecting groups can be arranged to cover the luminophore; thus, energy transfer by the Dexter mechanism can be inhibited. Note that any of the protecting groups may be directly bonded to the luminophore.

As the energy acceptor material, an organic compound represented by General Formula (G3) or (G4) can be suitably used.

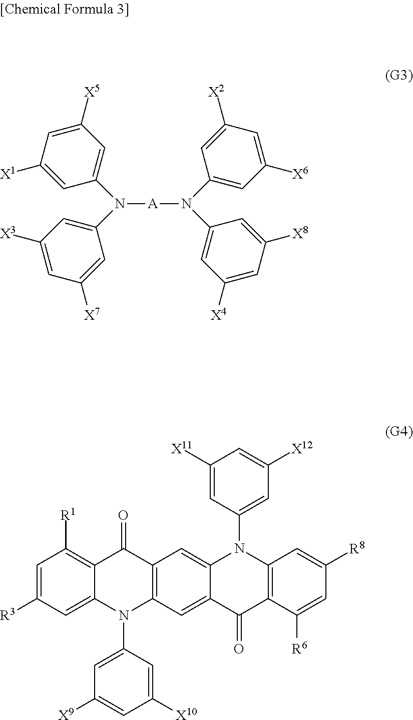

In General Formulae (G3) and (G4), A represents a substituted or unsubstituted condensed aromatic ring having 10 to 30 carbon atoms or a substituted or unsubstituted condensed heteroaromatic ring having 10 to 30 carbon atoms, and X¹ to X¹² each independently represent any one of a branched-chain alkyl group having 3 to 10 carbon atoms, a substituted or unsubstituted cycloalkyl group having 3 to 10 carbon atoms, and a trialkylsilyl group having 3 to 12 carbon atoms.

The protecting groups are each preferably bonded to the luminophore via a phenylene group. With this structure, the protecting groups can be arranged to cover the luminophore; thus, energy transfer by the Dexter mechanism can be inhibited. In the case where the protecting groups are each bonded to the luminophore via a phenylene group and two protecting groups are bonded to the phenylene group, the two protecting groups are preferably bonded to the phenylene group at the meta-positions as shown in General Formulae (G3) and (G4). With such a structure, the luminophore can be efficiently covered; thus, energy transfer by the Dexter mechanism can be inhibited. An example of the organic compound represented by General Formula (G3) is 2tBu-mmtBuDPhA2Anth described above. That is, in one embodiment of the present invention, General Formula (G3) is a particularly preferable example.

As the energy acceptor material, an organic compound represented by General Formula (G5) shown below can be suitably used.

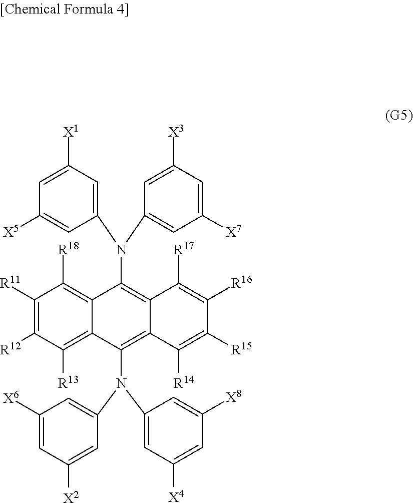

In General Formula (G5), X¹ to X⁸ each independently represent any one of a branched-chain alkyl group having 3 to 10 carbon atoms, a substituted or unsubstituted cycloalkyl group having 3 to 10 carbon atoms, and a trialkylsilyl group having 3 to 12 carbon atoms, and R¹¹ to R¹⁸ each independently represent any one of hydrogen, a branched-chain alkyl group having 3 to 10 carbon atoms, a substituted or unsubstituted cycloalkyl group having 3 to 10 carbon atoms, a trialkylsilyl group having 3 to 12 carbon atoms, and a substituted or unsubstituted aryl group having 6 to 25 carbon atoms.

Examples of the aryl group having 6 to 25 carbon atoms include a phenyl group, a naphthyl group, a biphenyl group, a fluorenyl group, and a spirofluorenyl group. Note that an aryl group having 6 to 25 carbon atoms is not limited thereto. In the case where the aryl group has a substituent, examples of the substituent include the alkyl group having 1 to 10 carbon atoms, the branched-chain alkyl group having 3 to 10 carbon atoms, the substituted or unsubstituted cycloalkyl group having 3 to 10 carbon atoms, and the trialkylsilyl group having 3 to 12 carbon atoms, which are described above.

An anthracene compound has a high emission quantum yield and a small area of the luminophore; therefore, the upper and lower planes of anthracene can be efficiently covered with the protecting groups. An example of the organic compound represented by General Formula (G5) is 2tBu-mmtBuDPhA2Anth described above.

Examples of the compounds represented by General Formulae (G1) to (G5) are shown by Structural Formulae (102) to (105) and (200) to (284) below. Note that the compounds represented by General Formulae (G1) to (G5) are not limited thereto. The compounds represented by Structural Formulae (102) to (105) and (200) to (284) can be suitably used as a guest material of the light-emitting element of one embodiment of the present invention. Note that the guest material is not limited thereto.

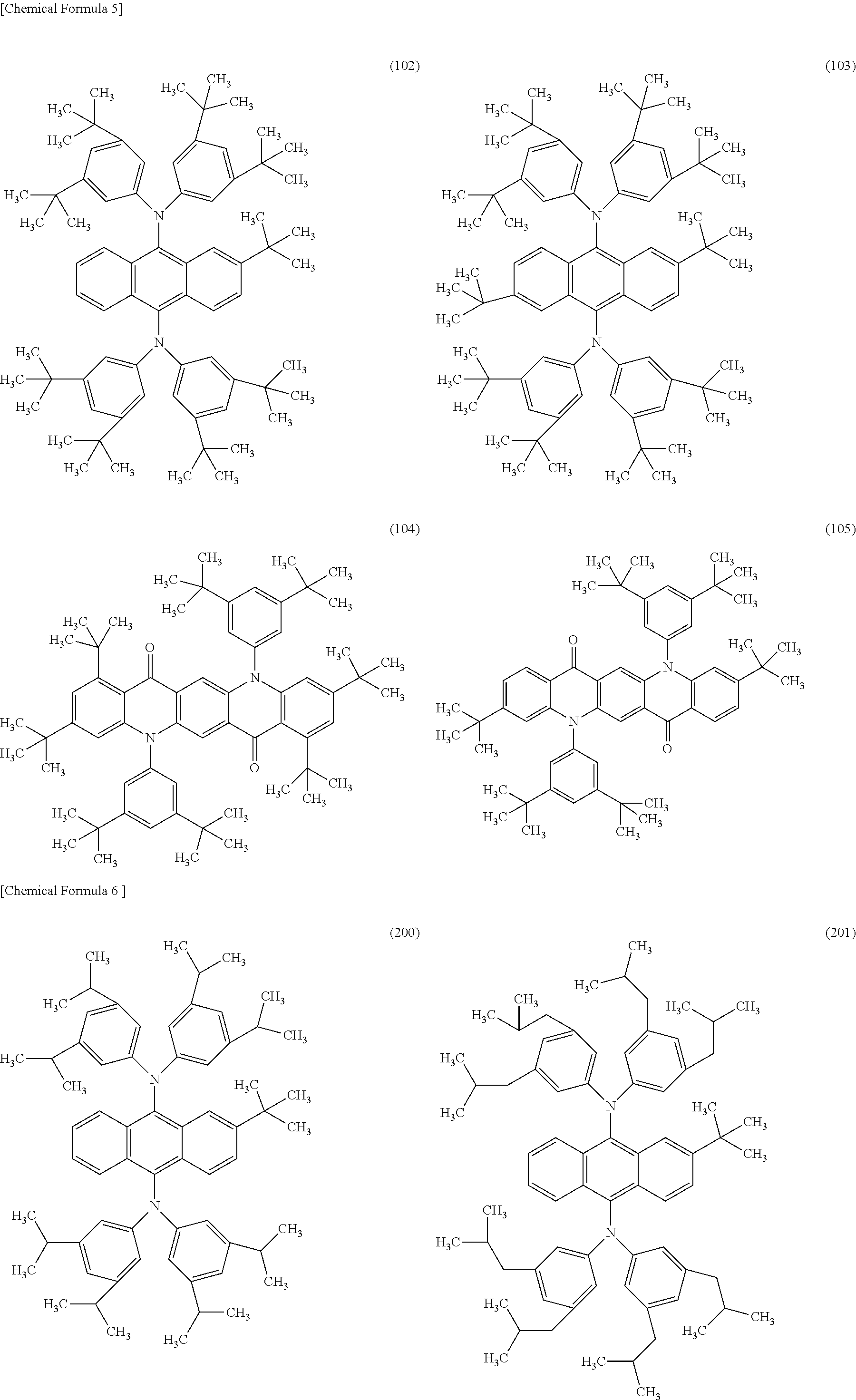

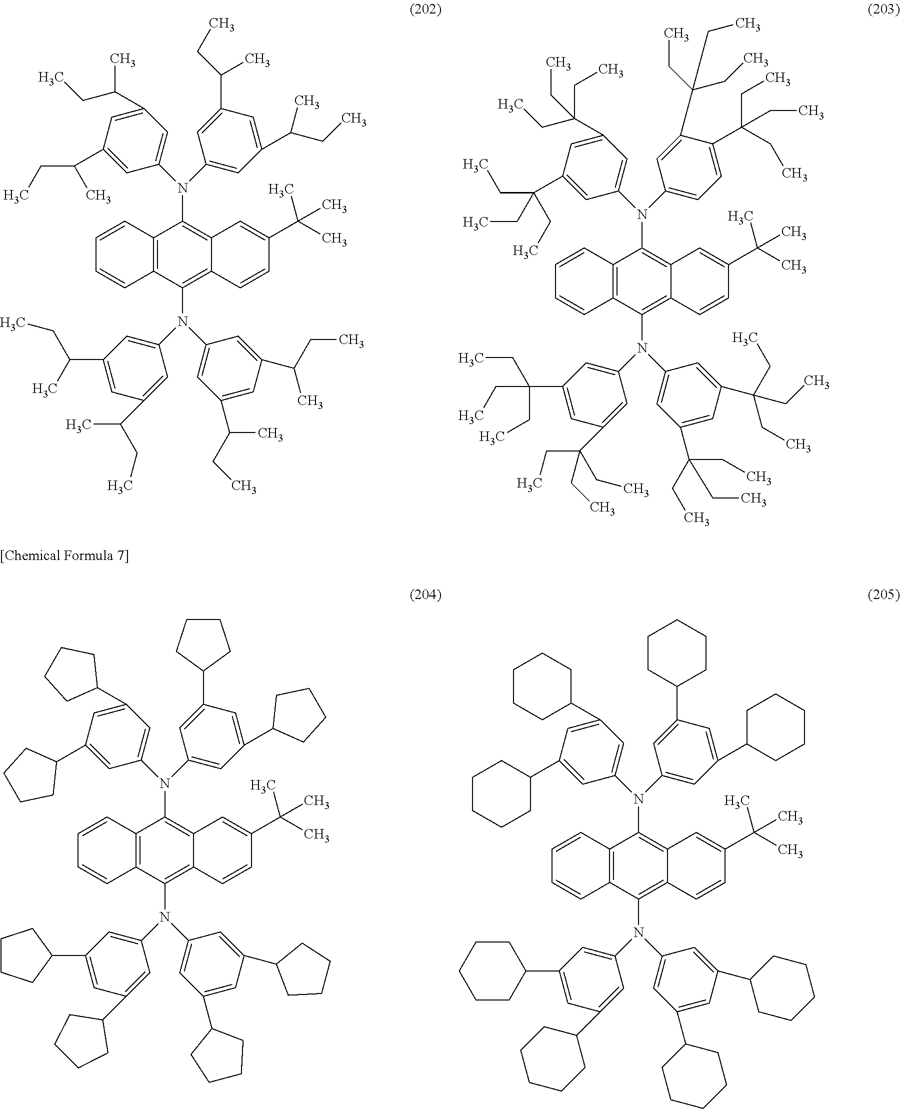

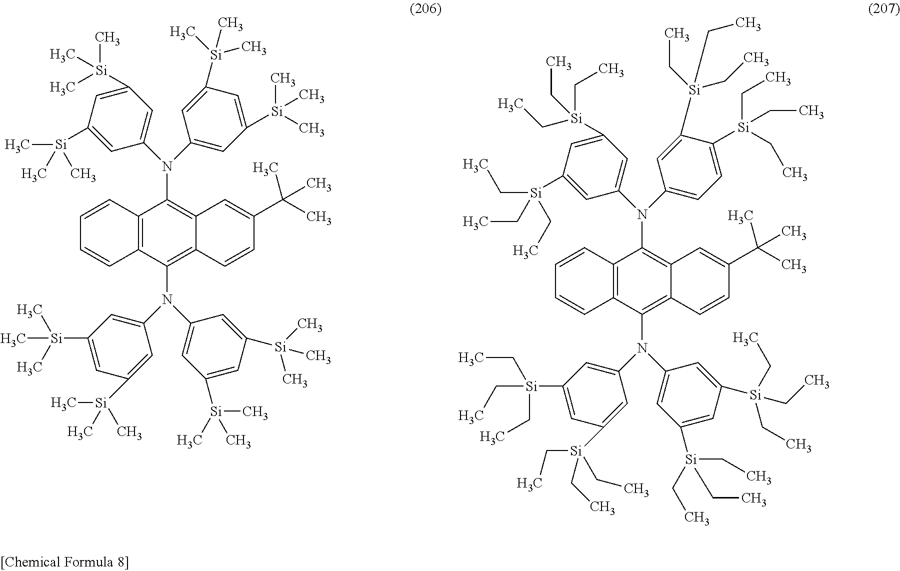 [SMILES: CC(C)(C)c1ccc2c(N(c3cc([Si](C)(C)C)cc([Si](C)(C)C)c3)c3cc([Si](C)(C)C)cc([Si](C)(C)C)c3)c3ccccc3c(N(c3cc([Si](C)(C)C)cc([Si](C)(C)C)c3)c3cc([Si](C)(C)C)cc([Si](C)(C)C)c3)c2c1 ; CC[Si](CC)(CC)c1cc(N(c2cc([Si](CC)(CC)CC)cc([Si](CC)(CC)CC)c2)c2c3ccccc3c(N(c3cc([Si](CC)(CC)CC)cc([Si](CC)(CC)CC)c3)c3ccc([Si](CC)(CC)CC)c([Si](CC)(CC)CC)c3)c3cc(C(C)(C)C)ccc23)cc([Si](CC)(CC)CC)c1]

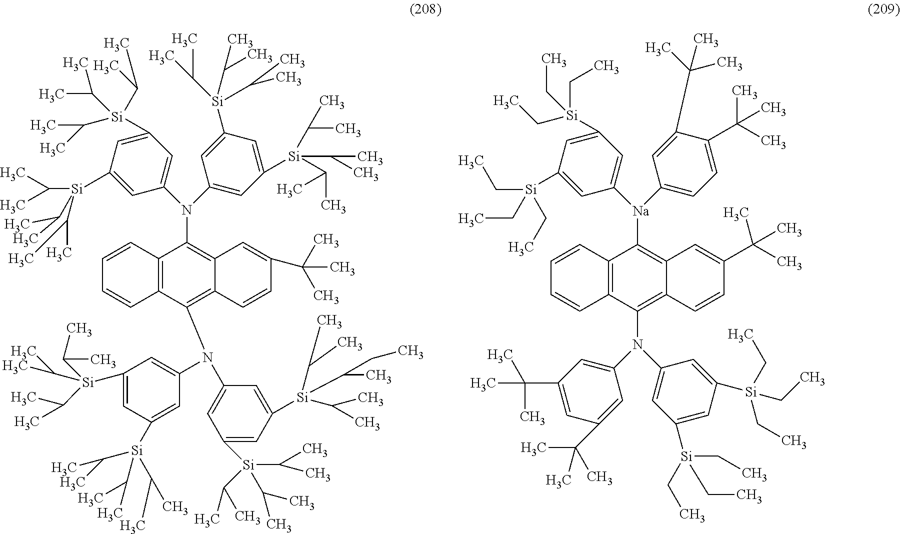

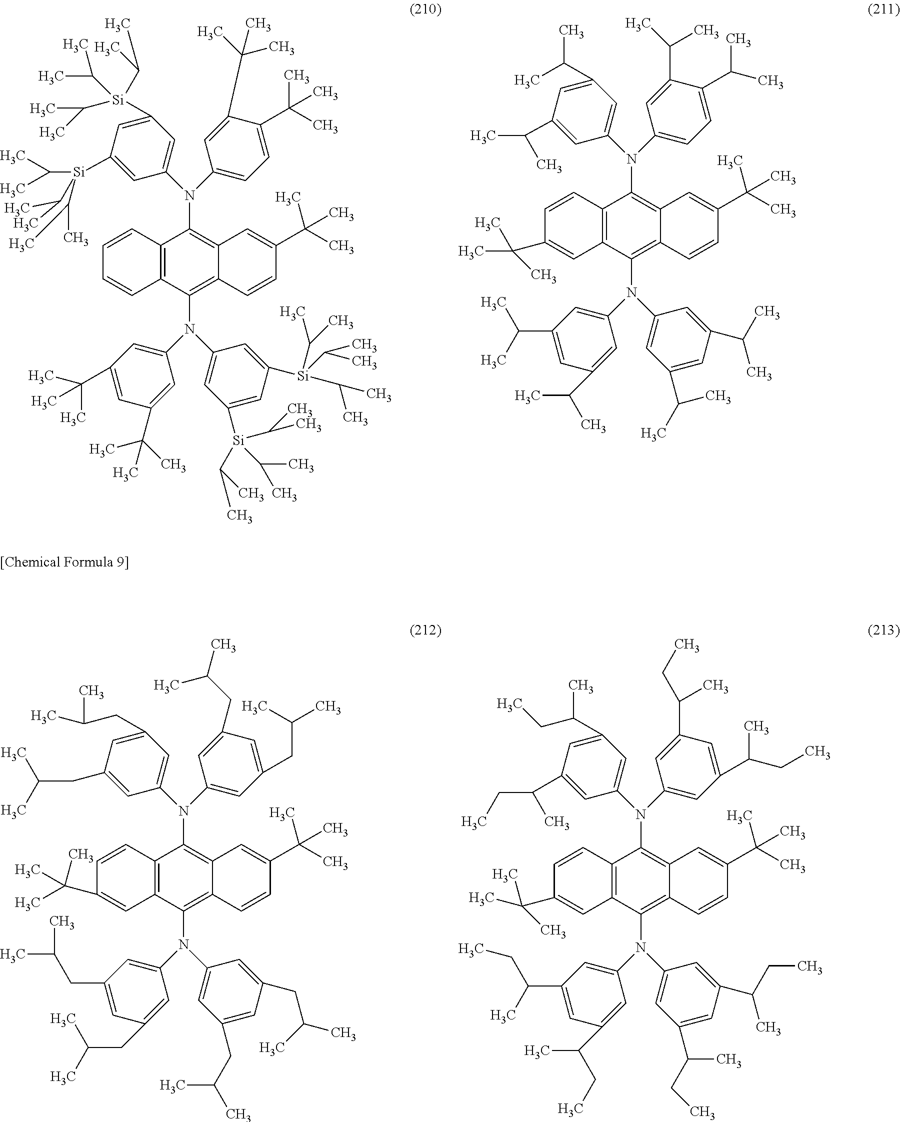

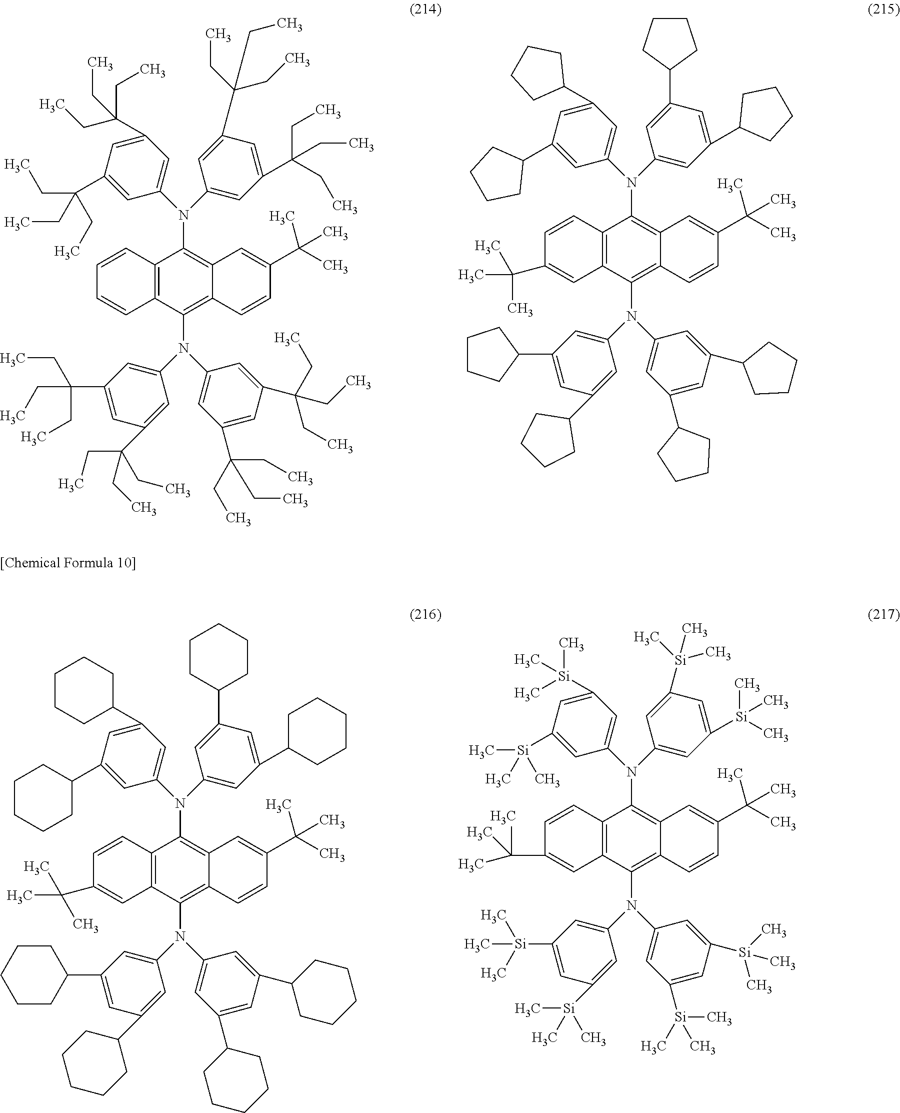

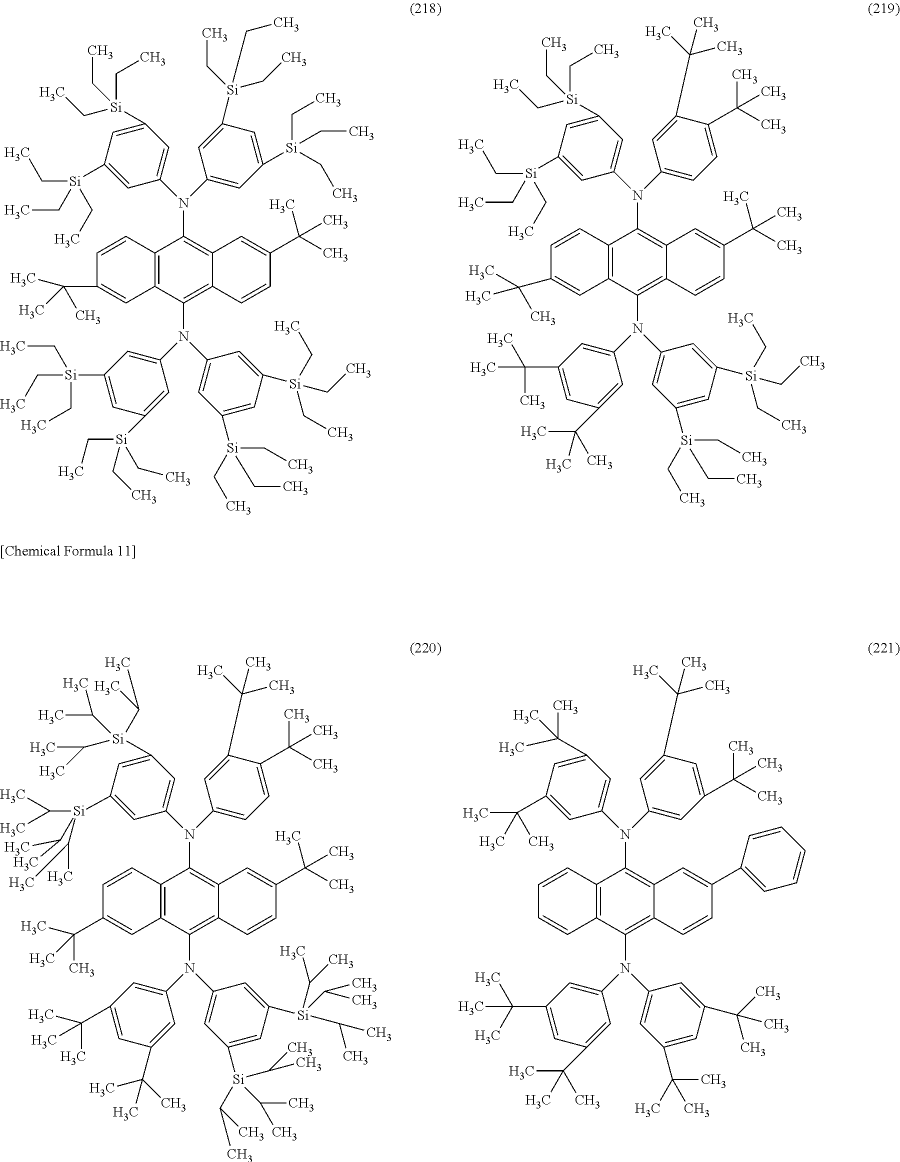

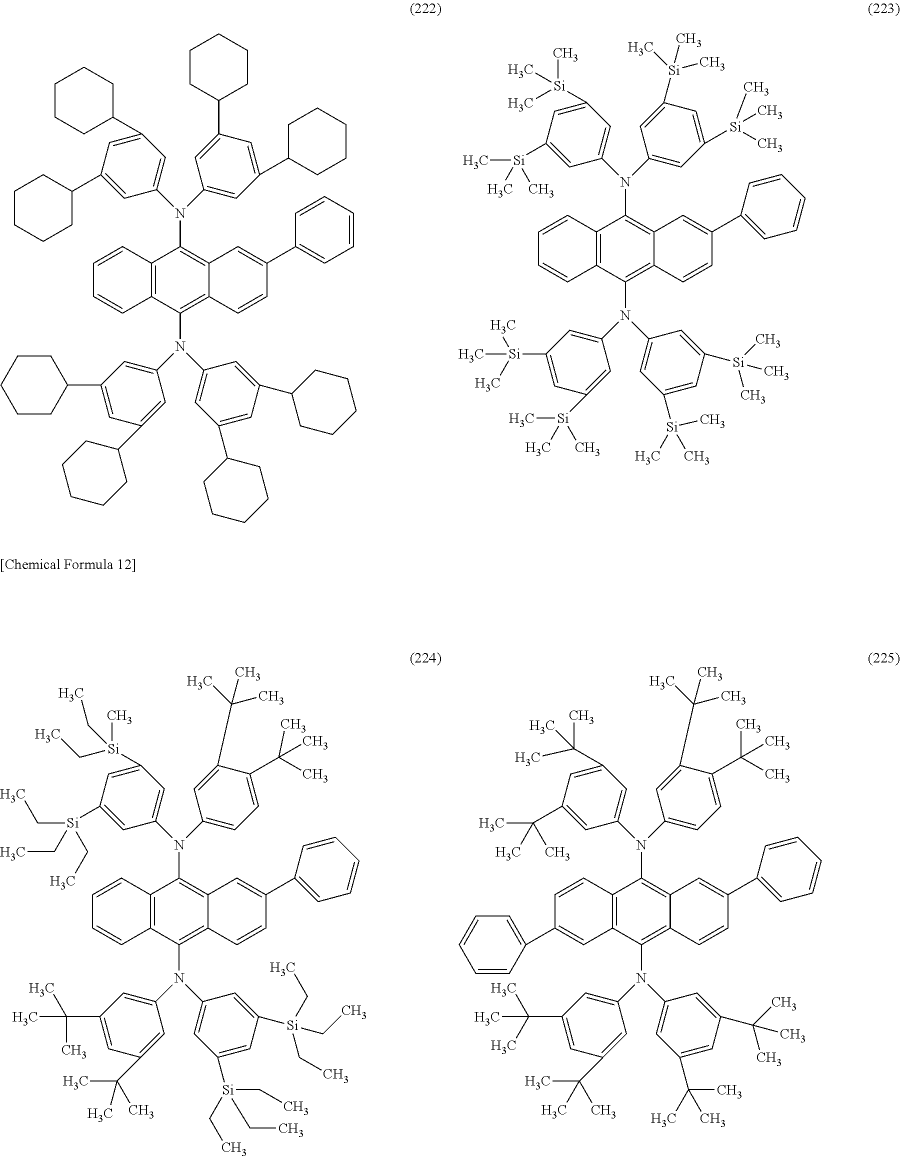

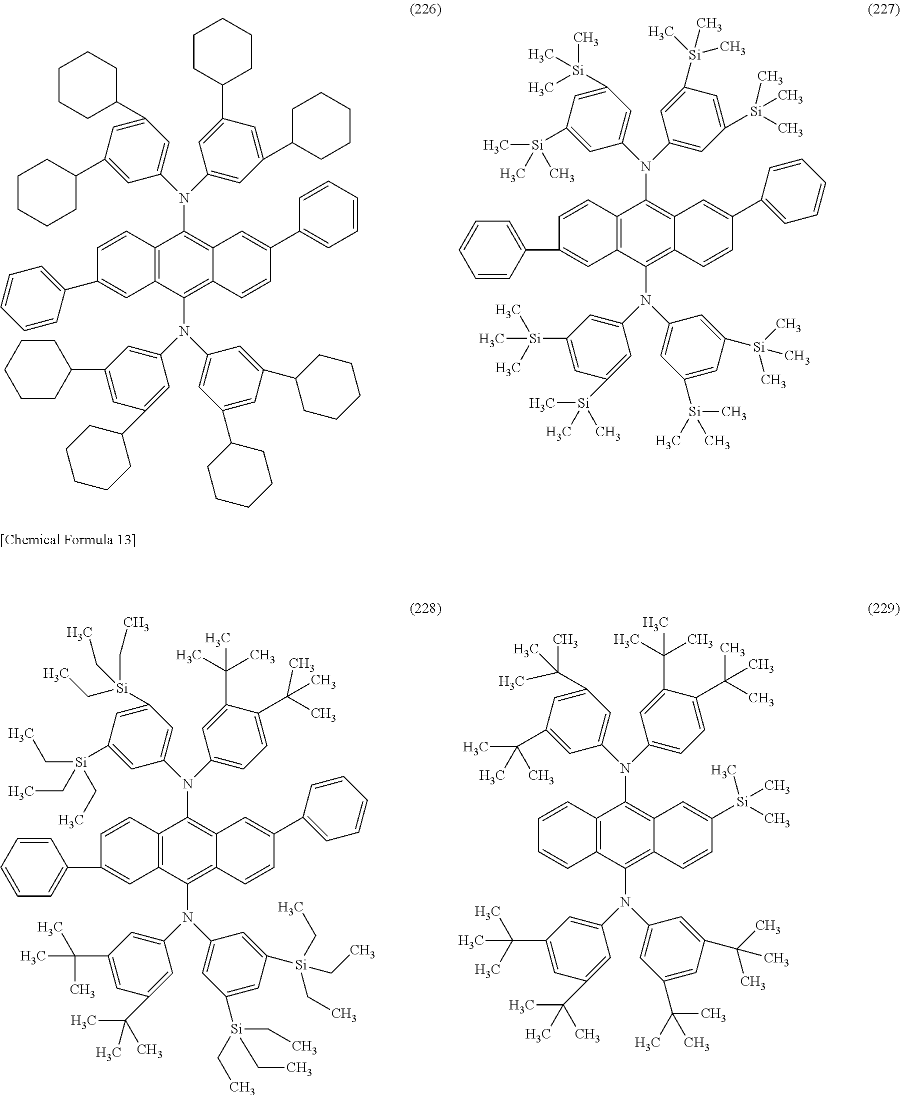

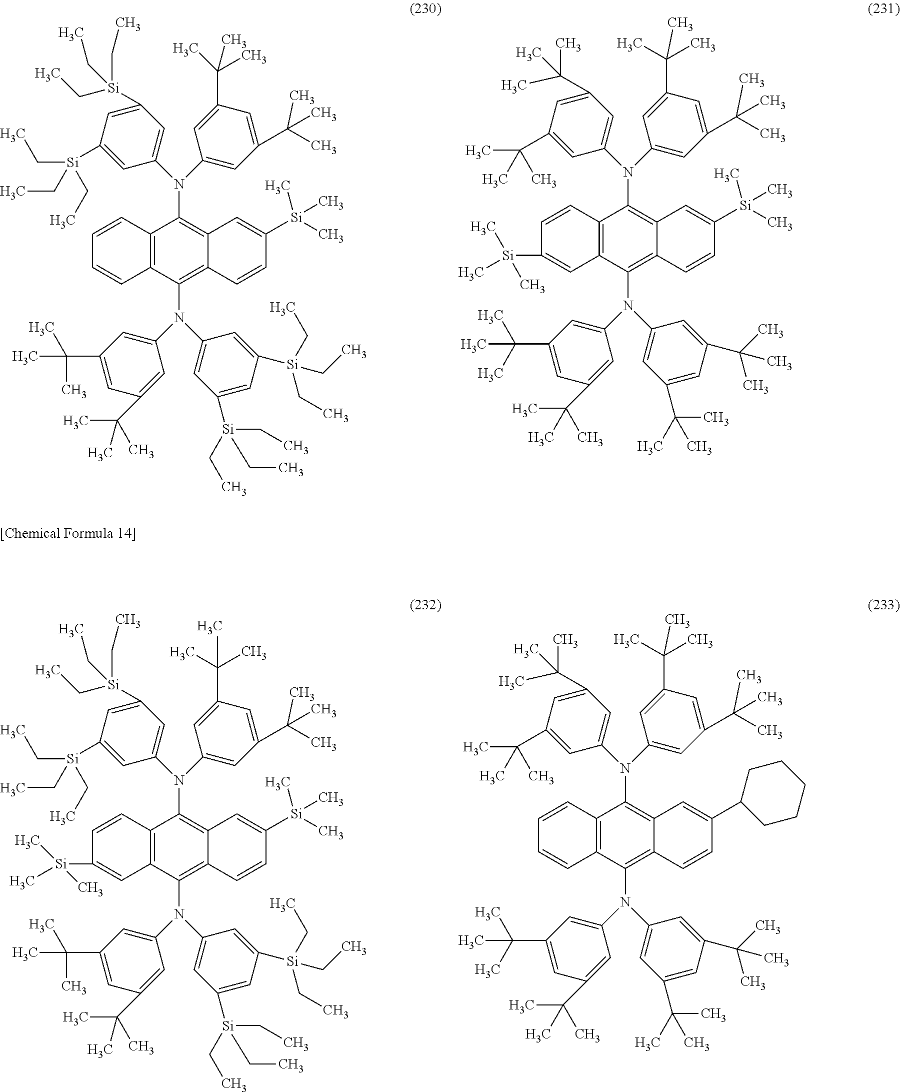

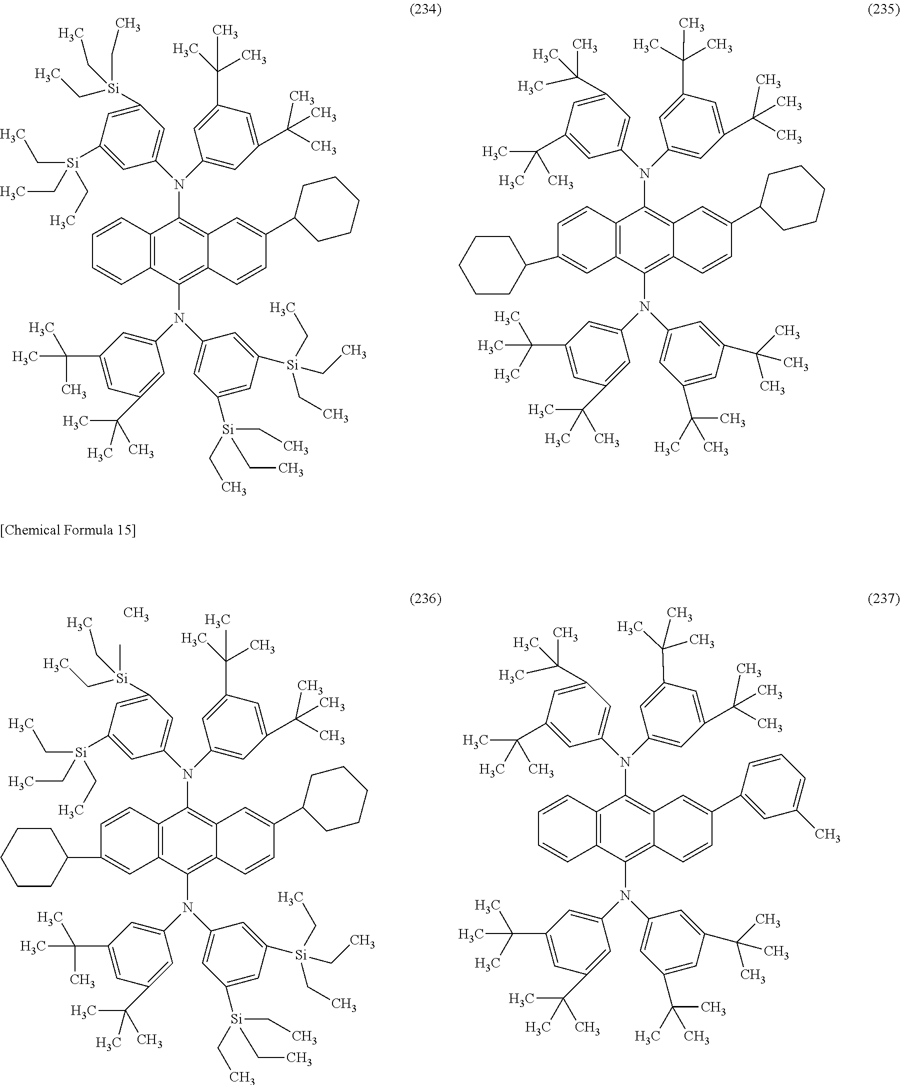

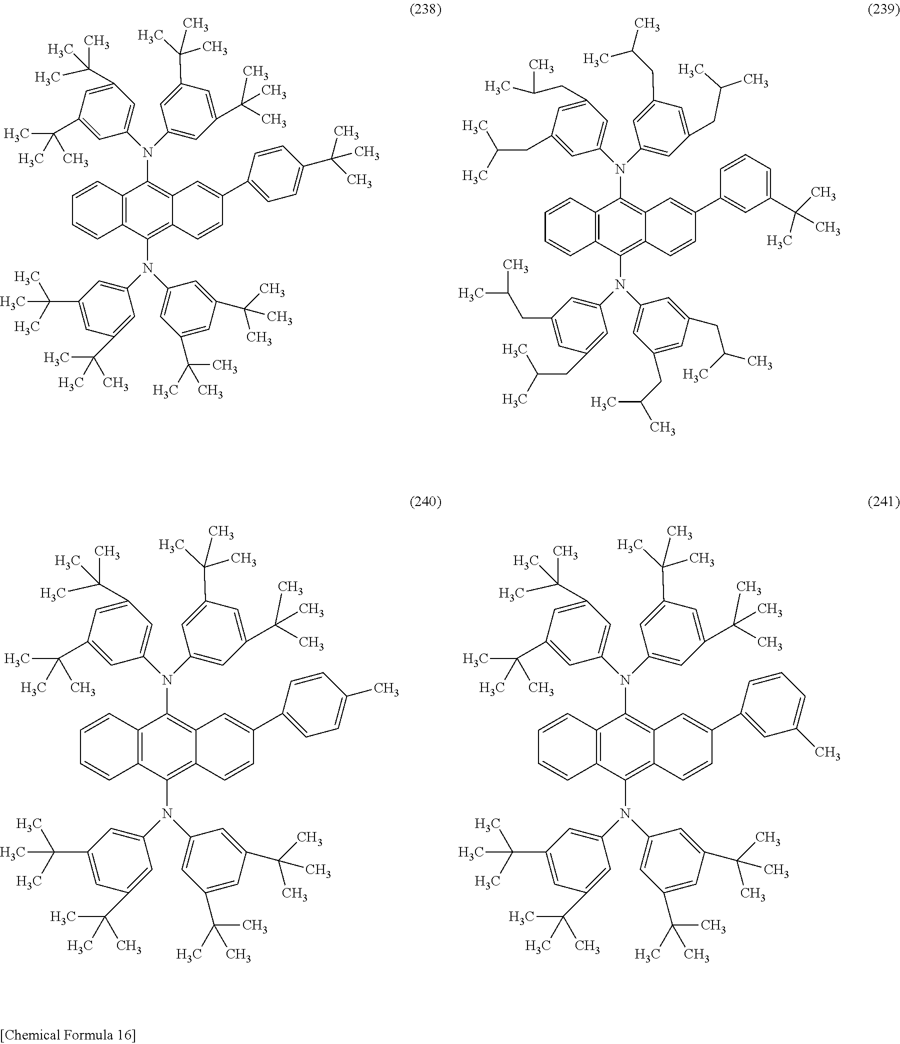

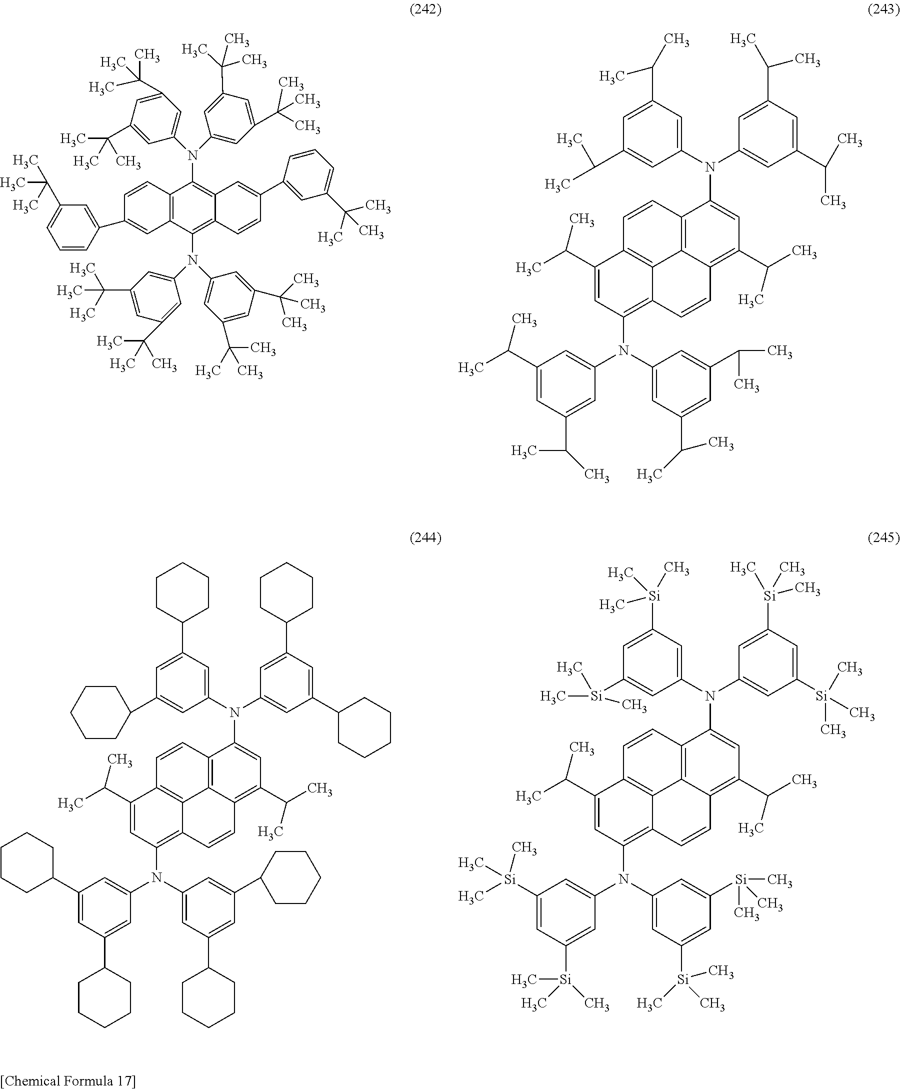

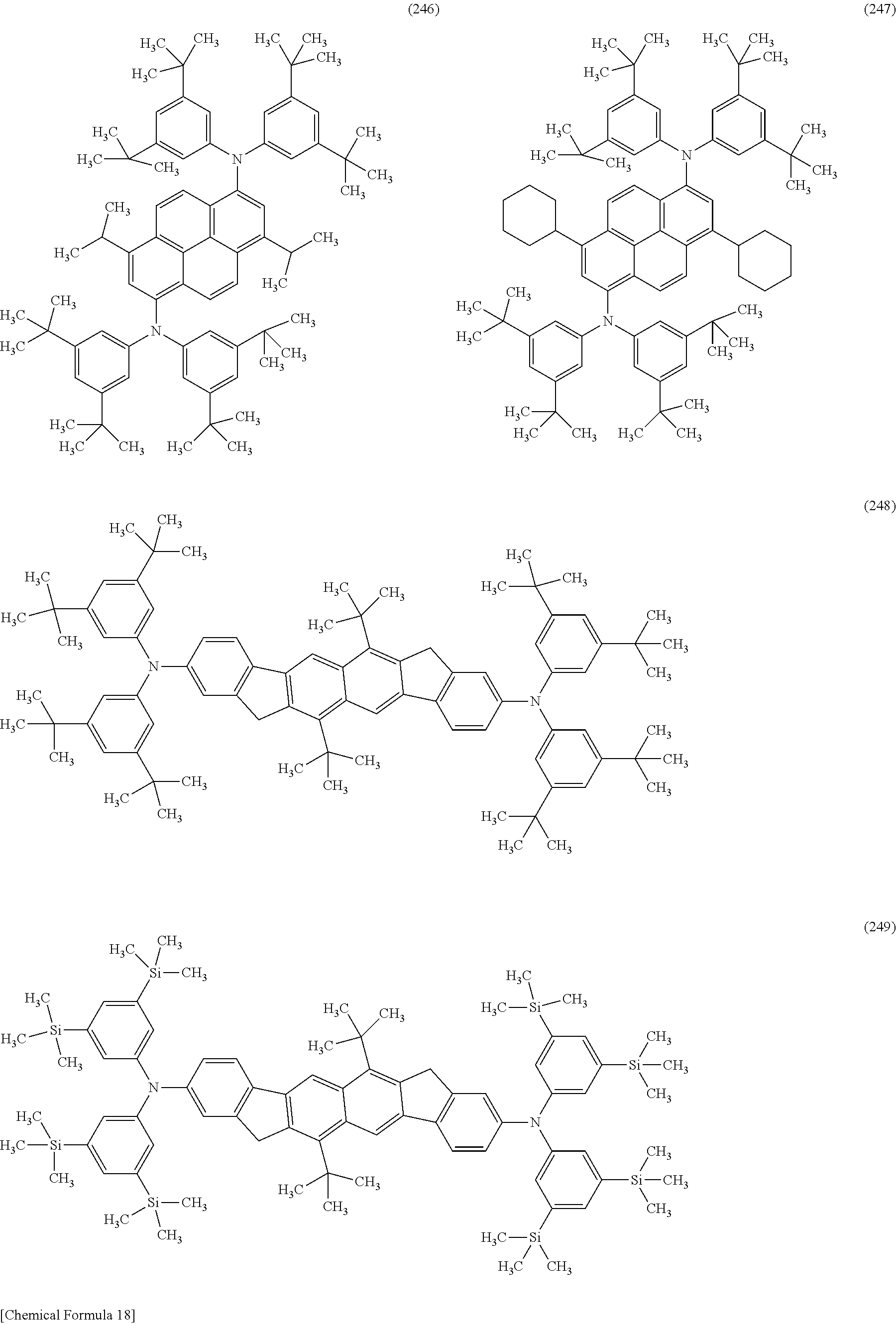

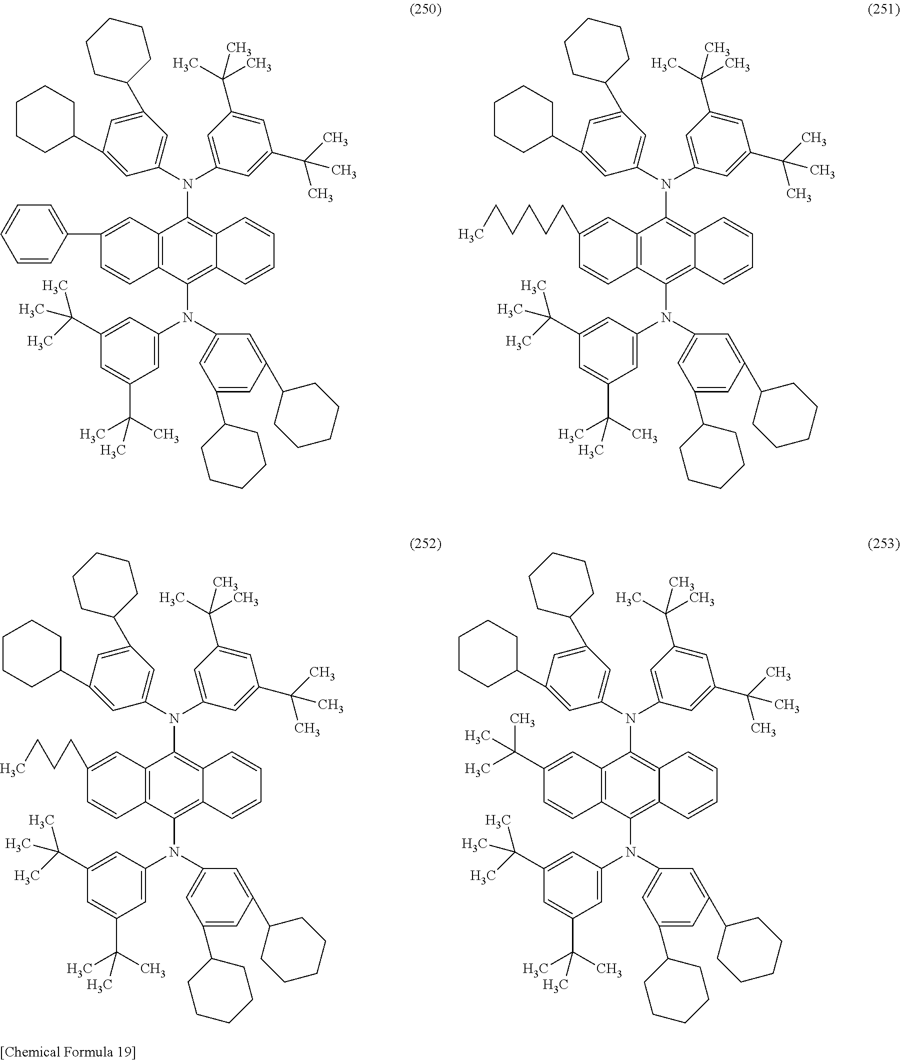

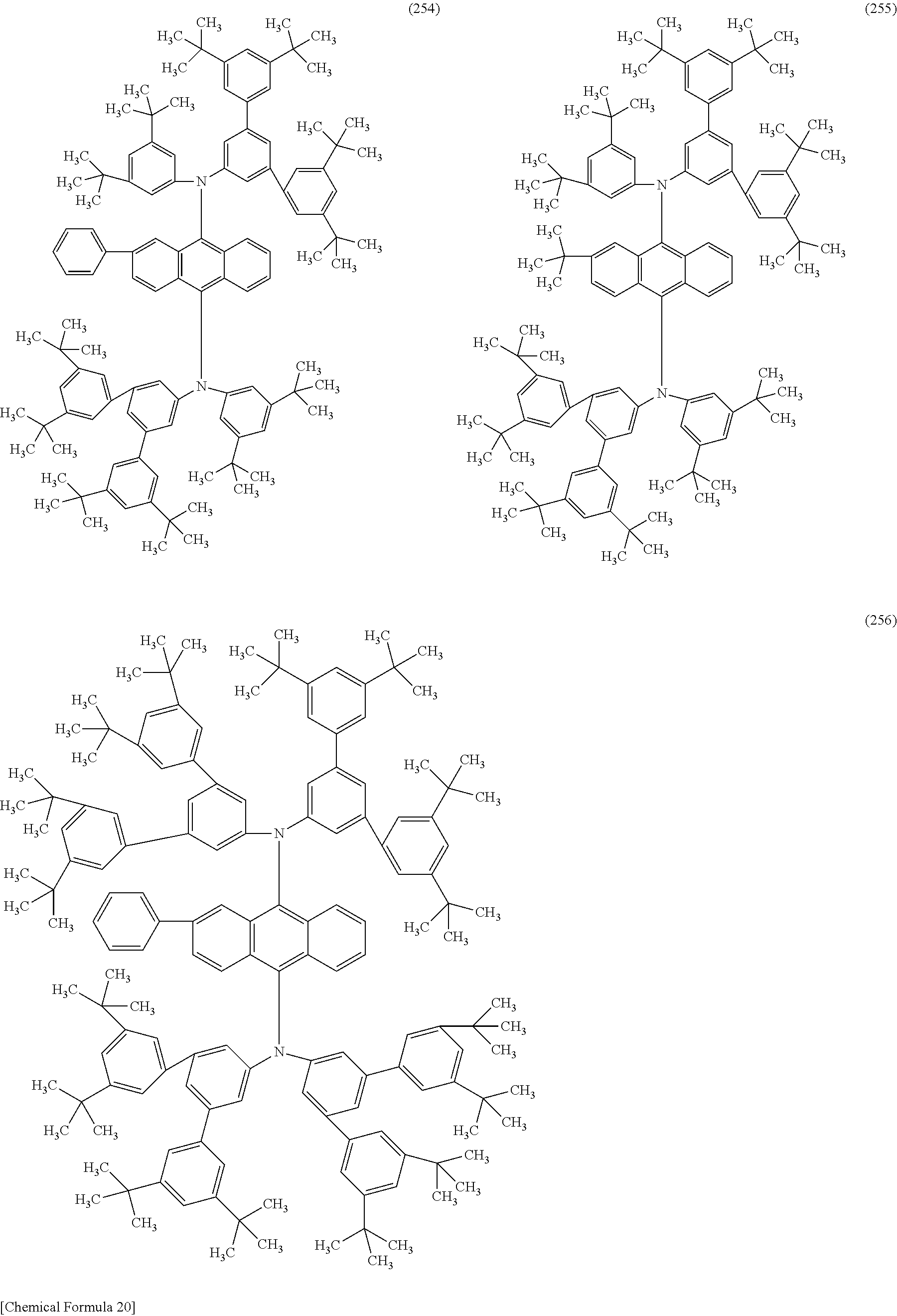

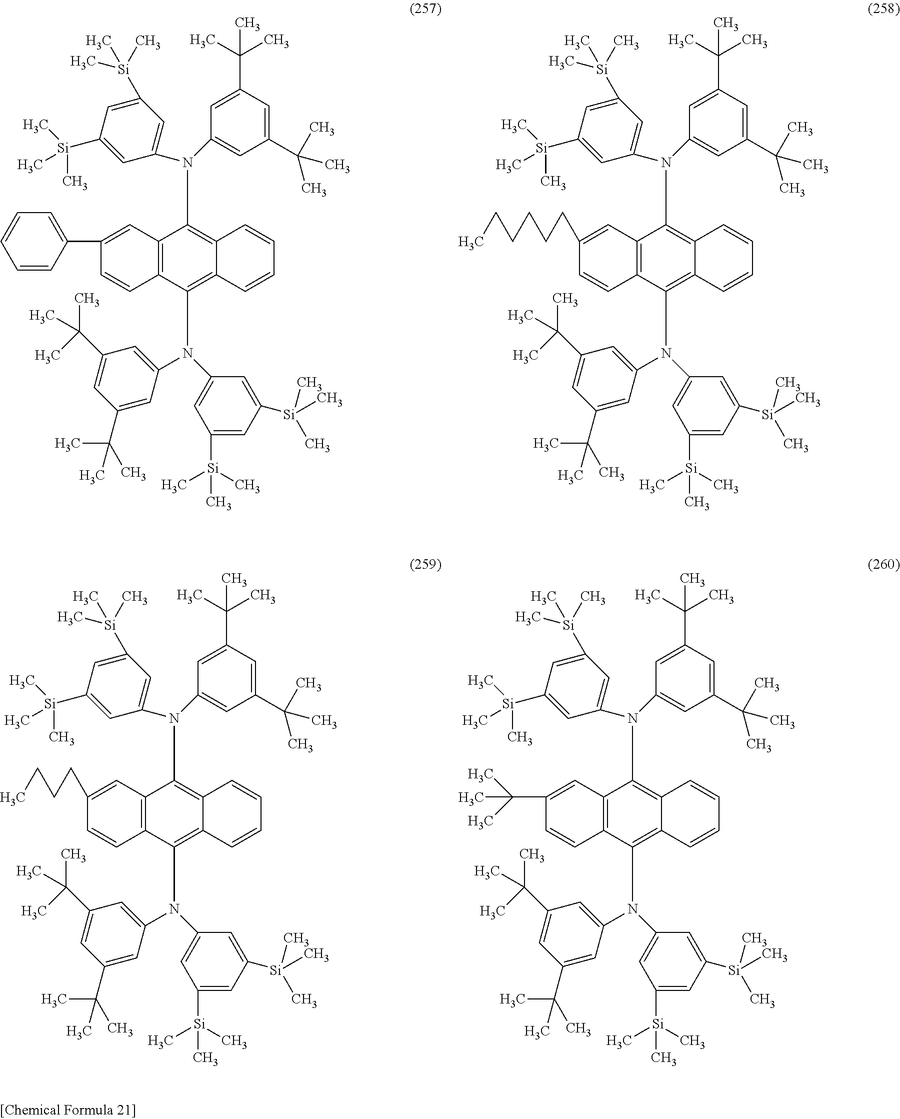

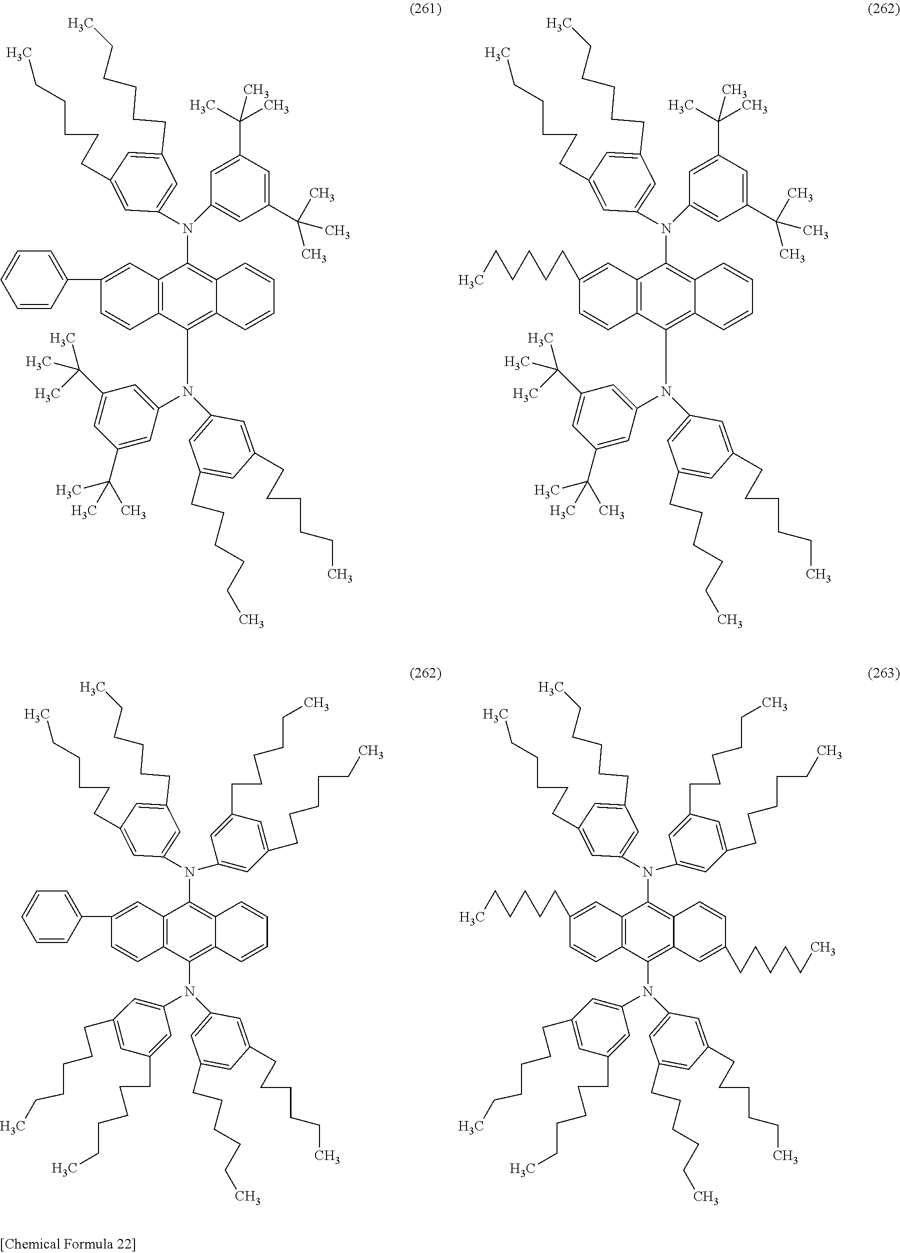

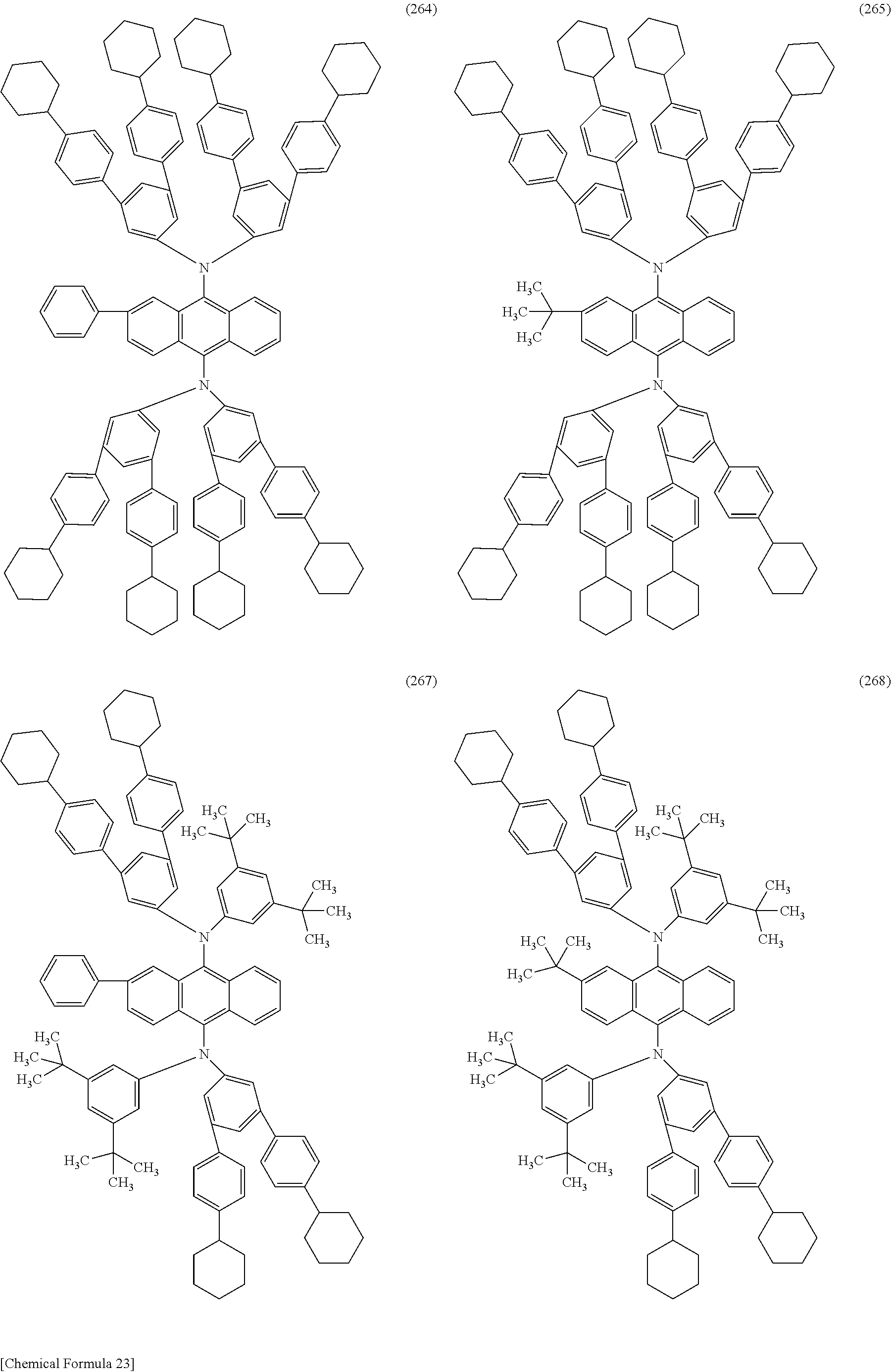

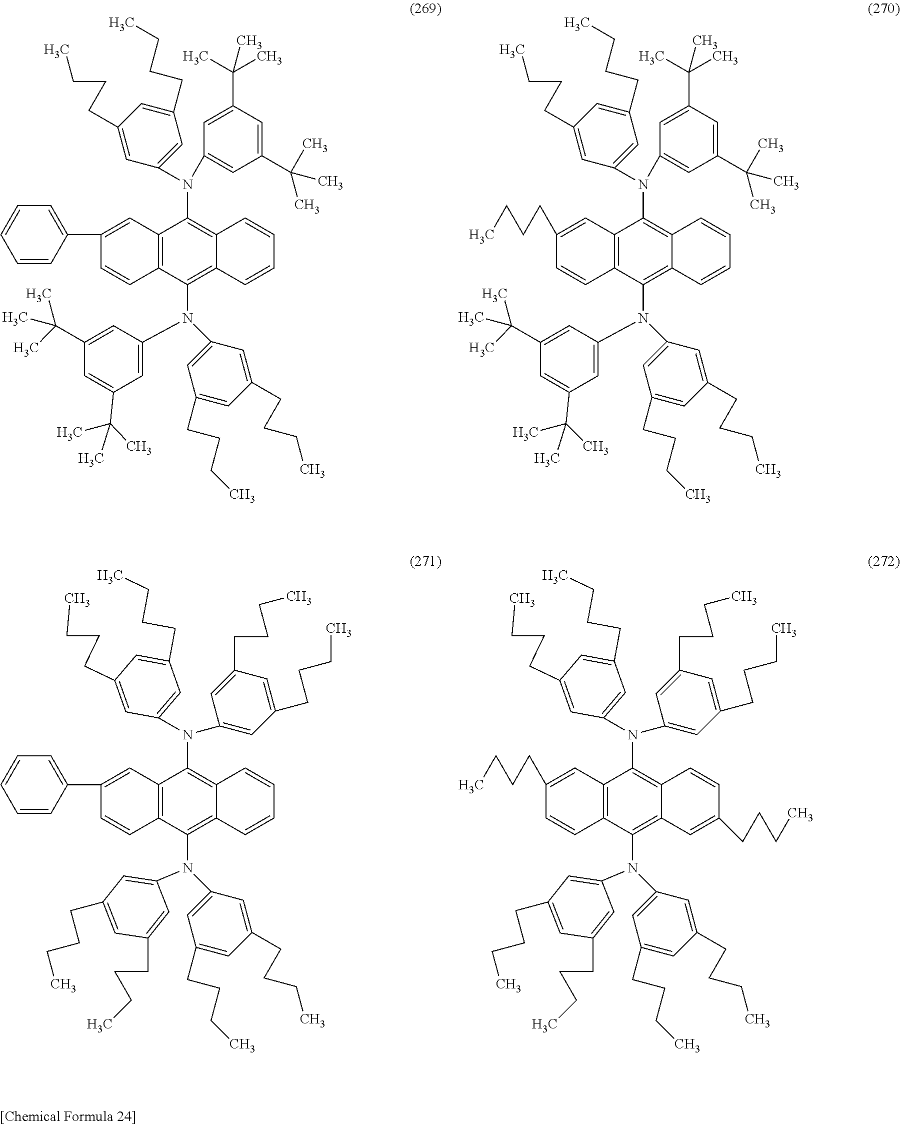

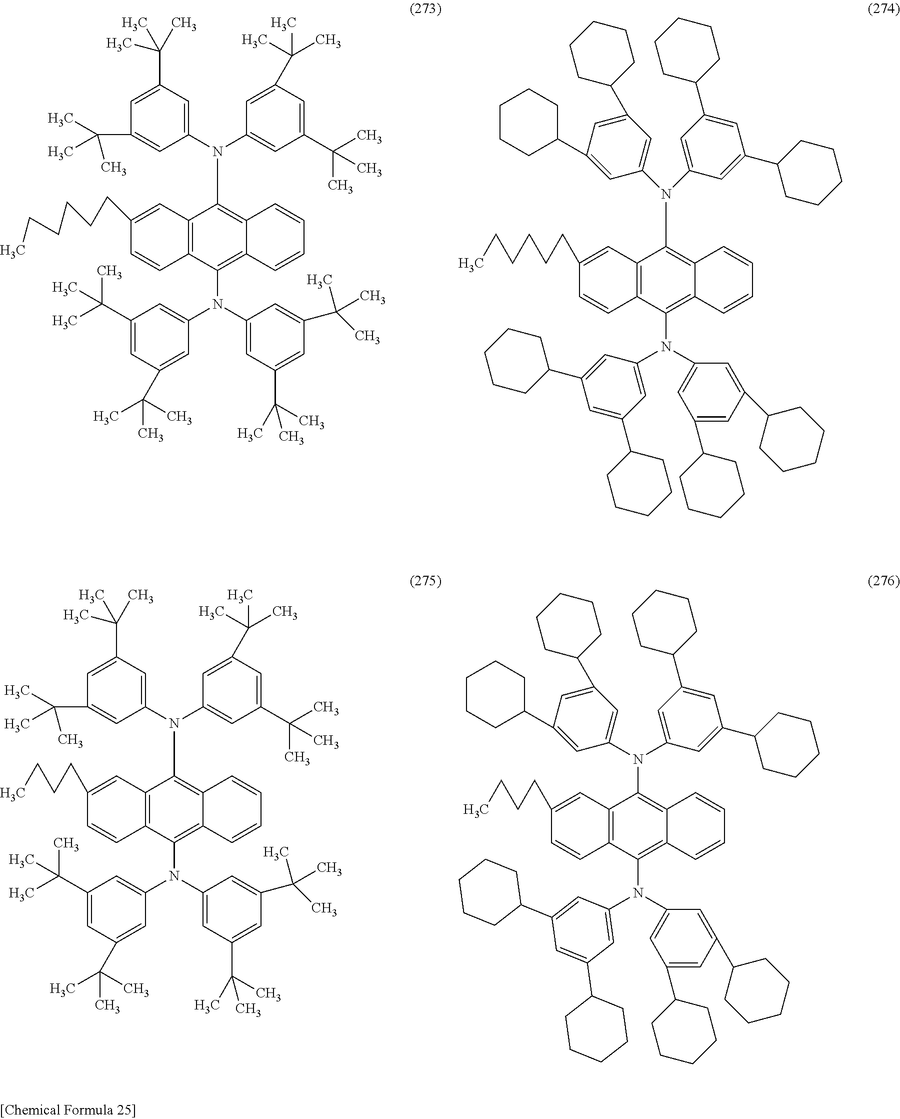

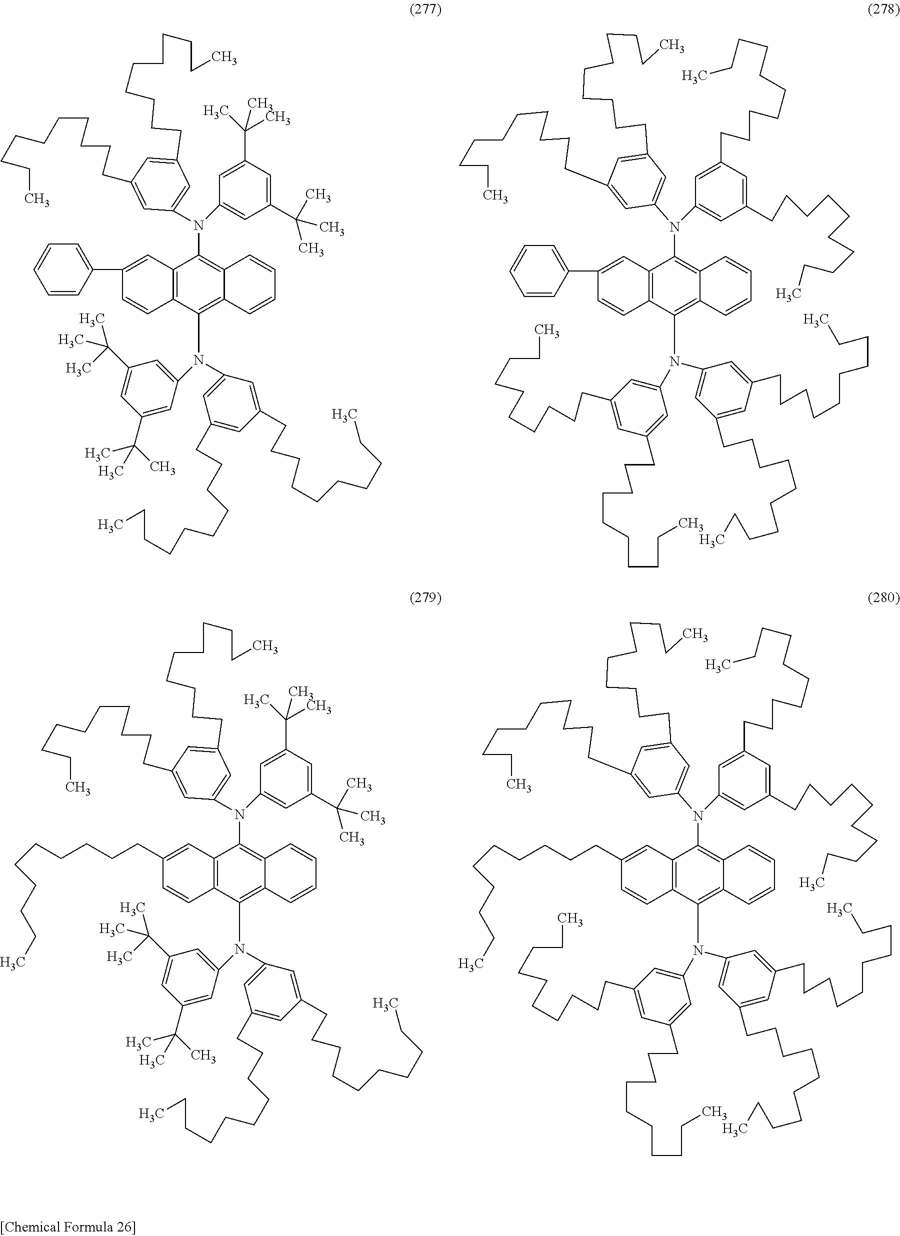

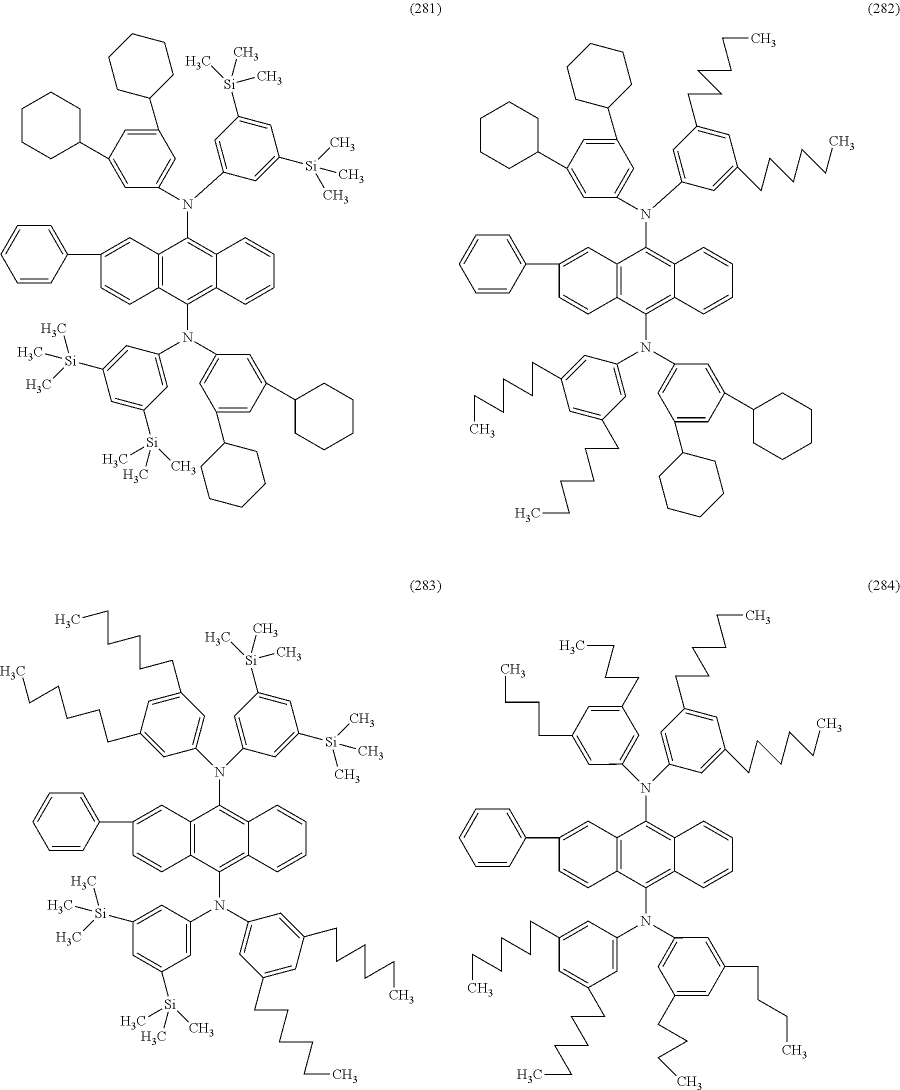

Examples of materials that can be suitably used as a guest material of the light-emitting element of one embodiment of the present invention are shown by Structural Formulae (100) and (101). Note that the guest material is not limited thereto.

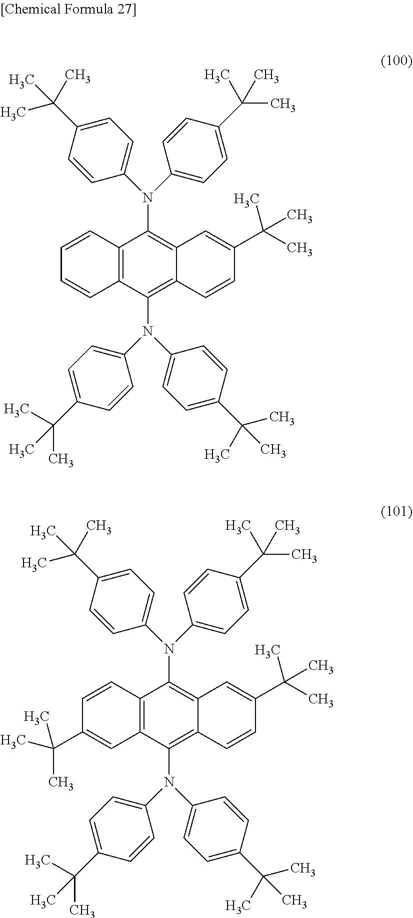

When the compound 133 serves as an energy donor, a TADF material can be used, for example. The energy difference between the S1 level and the T1 level of the compound 133 is preferably small, specifically, greater than 0 eV and less than or equal to 0.2 eV.

The compound 133 preferably includes a skeleton having a hole-transport property and a skeleton having an electron-transport property. Alternatively, the compound 133 preferably has a π-electron rich skeleton or an aromatic amine skeleton, and a π-electron deficient skeleton. In that case, a donor-acceptor excited state is easily formed in a molecule. Furthermore, to improve both the donor property and the acceptor property in the molecule of the compound 133, the skeleton having an electron-transport property and the skeleton having a hole-transport property are preferably directly bonded to each other. Alternatively, the π-electron deficient skeleton is preferably directly bonded to the π-electron rich skeleton or the aromatic amine skeleton. By improving both the donor property and the acceptor property in the molecule, an overlap between a region where the HOMO is distributed and a region where the LUMO is distributed in the compound 133 can be small, and the energy difference between the singlet excitation energy level and the triplet excitation energy level of the compound 133 can be small. Moreover, the triplet excitation energy level of the compound 133 can be kept high.

In the case where a TADF material is composed of one kind of material, the following materials can be used, for example.

First, a fullerene, a derivative thereof, an acridine derivative such as proflavine, eosin, and the like are given. Furthermore, metal-containing porphyrins containing magnesium (Mg), zinc (Zn), cadmium (Cd), tin (Sn), platinum (Pt), indium (In), palladium (Pd), and the like are given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP).

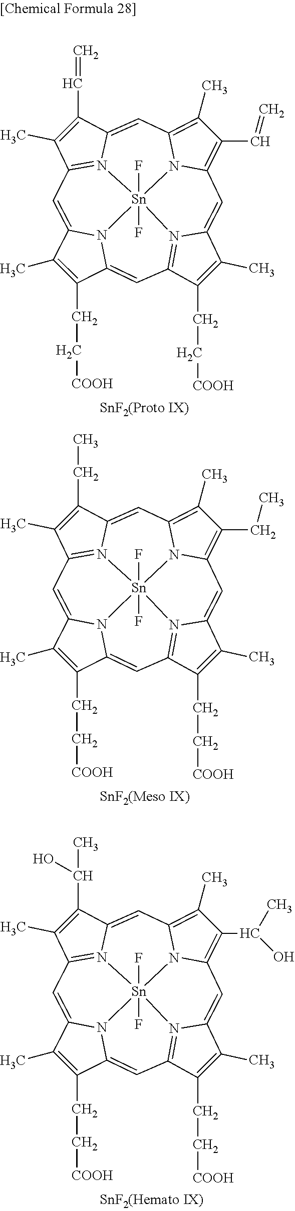

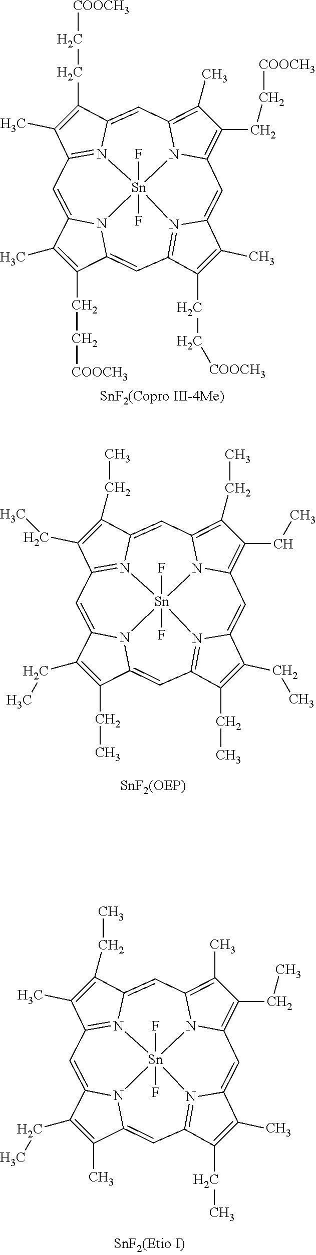

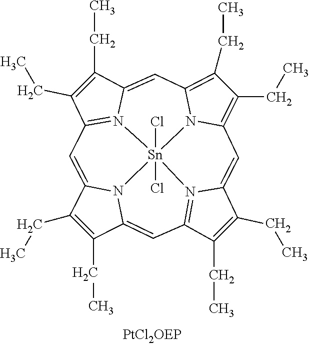

As the TADF material composed of one kind of material, a heterocyclic compound having a π-electron rich heteroaromatic skeleton and a π-electron deficient heteroaromatic skeleton can also be used. Specific examples include 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), and 9-[3-(4,6-diphenyl-1,3,5-triazin-2-yl)phenyl]-9′-phenyl-2,3′-bi-9H-carbazole (abbreviation: mPCCzPTzn-02). The heterocyclic compounds are preferable because of their high electron-transport property and hole-transport property due to the t-electron rich heteroaromatic ring and the t-electron deficient heteroaromatic ring contained therein. Among skeletons having the π-electron deficient heteroaromatic ring, a pyridine skeleton, a diazine skeleton (a pyrimidine skeleton, a pyrazine skeleton, or a pyridazine skeleton) and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor property and reliability. Among skeletons having the t-electron rich heteroaromatic ring, an acridine skeleton, a phenoxazine skeleton, a phenothiazine skeleton, a furan skeleton, a thiophene skeleton, and a pyrrole skeleton have stability and high reliability; therefore, at least one of these skeletons is preferably included. As the furan skeleton, a dibenzofuran skeleton is preferable; as the thiophene skeleton, a dibenzothiophene skeleton is preferable. Furthermore, as a pyrrole skeleton, an indole skeleton, a carbazole skeleton, a bicarbazole skeleton, and a 3-(9-phenyl-9H-carbazol-3-yl)-9H-carbazole skeleton are particularly preferable. Note that a substance in which the t-electron rich heteroaromatic ring is directly bonded to the t-electron deficient heteroaromatic ring is particularly preferable because the donor property of the t-electron rich heteroaromatic ring and the acceptor property of the t-electron deficient heteroaromatic ring are both improved and the difference between the level of the singlet excited state and the level of the triplet excited state becomes small. Note that an aromatic ring to which an electron-withdrawing group such as a cyano group is bonded may be used instead of the t-electron deficient heteroaromatic ring.

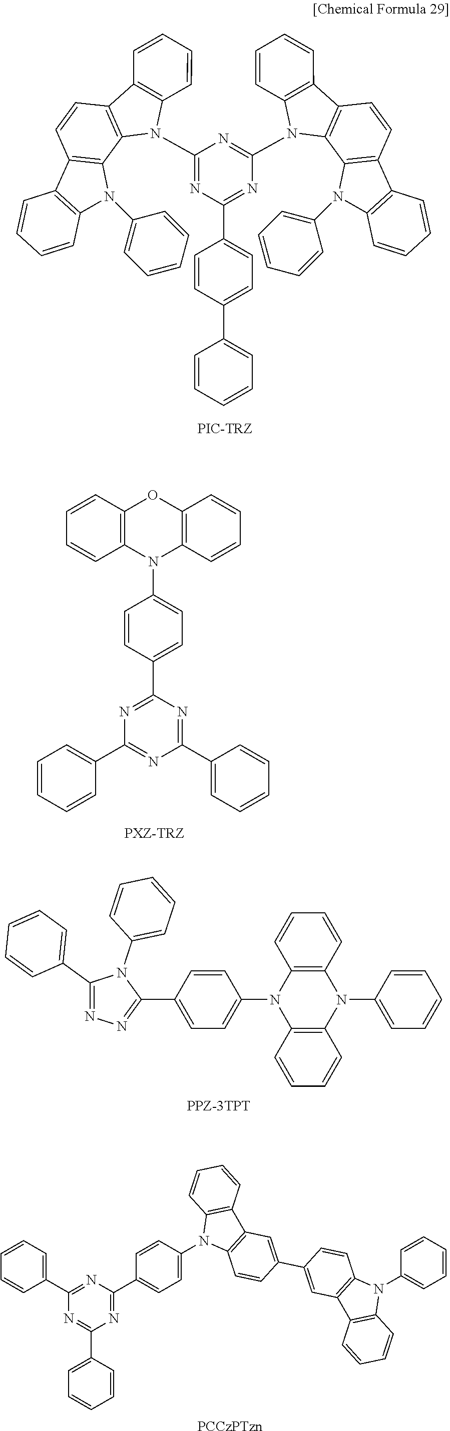 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; "PPZ-3TPT" ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; "PCCzPTzn"]

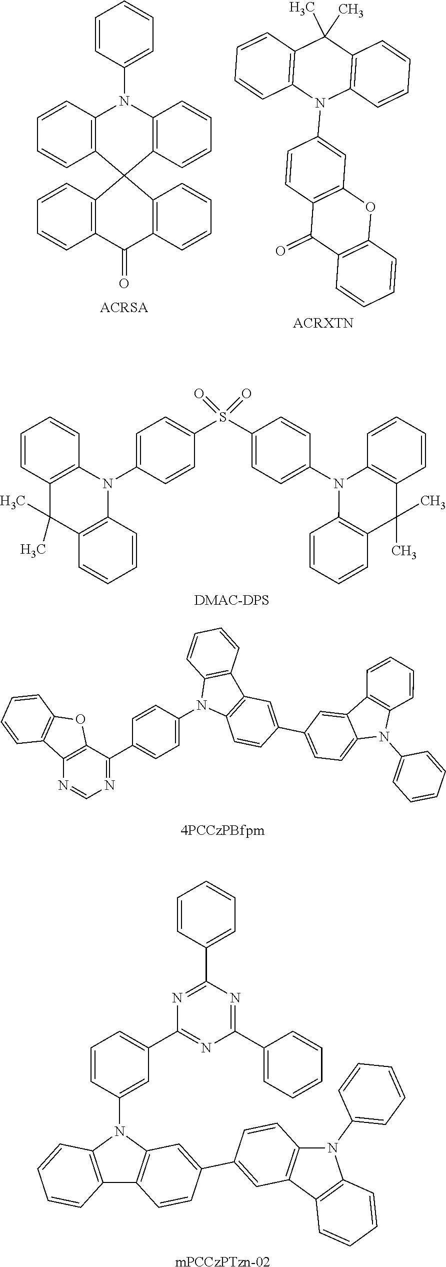

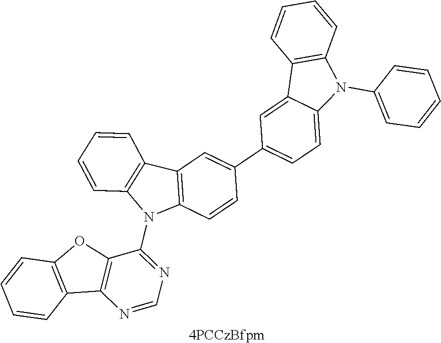 [SMILES: c1ccc(-n2c3ccccc3c3cc(-c4ccc5c(c4)c4ccccc4n5-c4ncnc5c4oc4ccccc45)ccc32)cc1 ; "4PCCzBfpm"]

In the case where the compound 133 does not have a function of converting triplet excitation energy into light emission, a combination of the compound 131 and the compound 133 or the compound 131 and the compound 134 is preferably, but is not particularly limited to, a combination that forms an exciplex. It is preferable that one have a function of transporting electrons and the other have a function of transporting holes. Examples of the organic compound 131 include, in addition to zinc- and aluminum-based metal complexes, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, and a phenanthroline derivative. Other examples include an aromatic amine and a carbazole derivative.

In addition, the following hole-transport materials and electron-transport materials can be used.

As the hole-transport material, a material having a property of transporting more holes than electrons can be used, and a material having a hole mobility of 1×10⁻⁶ cm²/Vs or higher is preferable. Specifically, an aromatic amine, a carbazole derivative, an aromatic hydrocarbon, a stilbene derivative, or the like can be used. Furthermore, the hole-transport material may be a high molecular compound.

Examples of the aromatic amine compound, which is a material having a high hole-transport property, include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B).

Specific examples of the carbazole derivative include 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples of the carbazole derivative include 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene.

Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl] anthracene, 9,10-bis[2-(1-naphthyl)phenyl] anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Besides, pentacene, coronene, and the like can be used. Thus, the use of aromatic hydrocarbons having a hole mobility of 1×10⁻⁻⁶ cm²/Vs or higher and having 14 to 42 carbon atoms is further preferable.

The aromatic hydrocarbons may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA).

It is also possible to use high molecular compounds such as poly(N-vinylcarbazole) (abbreviation: PVK), poly(-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N-bis(4-butylphenyl)-N,N′-bis(phenyl)benzidine] (abbreviation: poly-TPD).

As the material having a high hole-transport property, the following aromatic amine compounds can be used for example: 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenyl amine (abbreviation: MTDATA), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 4-phenyl-4′-(9-phenyl-9H-carbazol-3-yl)triphenylamine (abbreviation: PCBA1BP), 4,4′-diphenyl-4″-(9-phenyl-9-H-carbazol-3-yl)triphenylamine (abbreviation: PCBBi1BP), 4-(1-naphthyl)-4′-(9-phenyl-9H-carbazol-3-yl)-triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), 9,9-dimethyl-N-phenyl-N-[4-(9-phenyl-9H-carbazol-3-yl)phenyl]-fluoren-2-amine (abbreviation: PCBAF), N-phenyl-N-[4-(9-phenyl-9H-carbazol-3-yl)phenyl]-spiro-9,9′-bifluoren-2-amine (abbreviation: PCBASF), 2-[N-(9-phenylcarbazol-3-yl)-N-phenylamino] spiro-9,9′-bifluorene (abbreviation: PCASF), 2,7-bis[N-(4-diphenylaminophenyl)-N-phenylamino]-spiro-9,9′-bifluorene (abbreviation: DPA2SF), N-[4-(9H-carbazol-9-yl)phenyl]-N-(4-phenyl)phenylaniline (abbreviation: YGA1BP), and N,N-bis[4-(carbazol-9-yl)phenyl]-N,N-diphenyl-9,9-dimethylfluorene-2,7-diamine (abbreviation: YGA2F). It is also possible to use an amine compound, a carbazole compound, a thiophene compound, a furan compound, a fluorene compound, a triphenylene compound, a phenanthrene compound, or the like such as 3-[4-(1-naphthyl)-phenyl]-9-phenyl-9H-carbazole (abbreviation: PCPN), 3-[4-(9-phenanthryl)-phenyl]-9-phenyl-9H-carbazole (abbreviation: PCPPn), 3,3′-bis(9-phenyl-9H-carbazole) (abbreviation: PCCP), 1,3-bis(N-carbazolyl)benzene (abbreviation: mCP), 3,6-bis(3,5-diphenylphenyl)-9-phenylcarbazole (abbreviation: CzTP), 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), 1,3,5-tri(dibenzothiophen-4-yl)-benzene (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or 4-[3-(triphenylen-2-yl)phenyl]dibenzothiophene (abbreviation: mDBTPTp-II). The substances given here are mainly substances having a hole mobility of 1×10⁻⁶ cm²/Vs or higher. Note that other substances may also be used as long as they have a property of transporting more holes than electrons.

A material having a property of transporting more electrons than holes can be used as the electron-transport material, and a material having an electron mobility of 1×10⁻⁶ cm²/Vs or higher is preferable. A π-electron deficient heteroaromatic compound such as a nitrogen-containing heteroaromatic compound, a metal complex, or the like can be used as the material that easily accepts electrons (the material having an electron-transport property). Specific examples include metal complexes having a quinoline ligand, a benzoquinoline ligand, an oxazole ligand, and a thiazole ligand; an oxadiazole derivative; a triazole derivative; a phenanthroline derivative; a pyridine derivative; a bipyridine derivative; and a pyrimidine derivative.

Examples include metal complexes having a quinoline skeleton or a benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), and bis(8-quinolinolato)zinc(II) (abbreviation: Znq). Alternatively, a metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like can be used. Furthermore, other than the metal complexes, it is possible to use a heterocyclic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), bathophenanthroline (abbreviation: BPhen), 2,9-bis(naphthalen-2-yl)-4,7-diphenyl-1,10-phenanthroline (abbreviation: NBPhen), or bathocuproine (abbreviation: BCP); a heterocyclic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h] quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h] quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h] quinoxaline (abbreviation: 6mDBTPDBq-II), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,6-bis[3-(9H-carbazol-9-yl)phenyl]pyrimidine (abbreviation: 4,6mCzP2Pm); a heterocyclic compound having a triazine skeleton, such as 2-{4-[3-(N-phenyl-9H-carbazol-3-yl)-9H-carbazol-9-yl]phenyl}-4,6-diphenyl-1,3,5-triazine (abbreviation: PCCzPTzn); a heterocyclic compound having a pyridine skeleton, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); or a heteroaromatic compound such as 4,4′-bis(5-methylbenzoxazol-2-yl)stilbene (abbreviation: BzOs). Furthermore, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can be used. The substances given here are mainly substances having an electron mobility of 1×10⁻⁶ cm²/Vs or higher. Note that other substances may also be used as long as they have a property of transporting more electrons than holes.

As the compound 133 or the compound 134, a material that can form an exciplex together with the compound 131 is preferable. Specifically, the hole-transport materials and electron-transport materials given above can be used. In that case, it is preferable that the compound 131 and the compound 133, the compound 131 and the compound 134, and the compound 132 (fluorescent material) be selected such that the emission peak of the exciplex formed by the compound 131 and the compound 133 or the compound 131 and the compound 134 overlaps with an absorption band on the longest wavelength side (low energy side) of the compound 132 (fluorescent material). This makes it possible to provide a light-emitting element with drastically improved emission efficiency.

A phosphorescent material can be used as the compound 133. Examples of the phosphorescent material include an iridium-, rhodium-, or platinum-based organometallic complex and metal complex. Another example is a platinum complex or organoiridium complex having a porphyrin ligand; in particular, an organoiridium complex such as an iridium-based ortho-metalated complex is preferable, for example. Examples of an ortho-metalated ligand include a 4H-triazole ligand, a 1H-triazole ligand, an imidazole ligand, a pyridine ligand, a pyrimidine ligand, a pyrazine ligand, and an isoquinoline ligand. In that case, the compound 133 (phosphorescent material) has an absorption band of triplet MLCT (Metal to Ligand Charge Transfer) transition. It is preferable that the compound 133 and the compound 132 (fluorescent material) be selected such that the emission peak of the compound 133 overlaps with an absorption band on the longest wavelength side (low energy side) of the compound 132 (fluorescent material). This makes it possible to provide a light-emitting element with drastically improved emission efficiency. Even in the case where the compound 133 is a phosphorescent material, it may form an exciplex together with the compound 131. When an exciplex is formed, the phosphorescent material does not need to emit light at room temperature and emits light at room temperature after an exciplex is formed. In that case, for example, Ir(ppz)₃ or the like can be used as the phosphorescent material.

Examples of the substance that has an emission peak in blue or green include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: Ir(mpptz-dmp)₃), tris(5-methyl-3,4-diphenyl-4H-1,2,4-triazolato)iridium(III) (abbreviation: Ir(Mptz)₃), tris[4-(3-biphenyl)-5-isopropyl-3-phenyl-4H-1,2,4-triazolato]iridium(III) (abbreviation: Ir(iPrptz-3b)₃), and tris[3-(5-biphenyl)-5-isopropyl-4-phenyl-4H-1,2,4-triazolato]iridium(III) (abbreviation: Ir(iPr5btz)₃); organometallic iridium complexes having a 1H-triazole skeleton, such as tris[3-methyl-1-(2-methylphenyl)-5-phenyl-1H-1,2,4-triazolato]iridium(III) (abbreviation: Ir(Mptz1-mp)₃) and tris(1-methyl-5-phenyl-3-propyl-1H-1,2,4-triazolato)iridium(III) (abbreviation: Ir(Prptz1-Me)₃); organometallic iridium complexes having an imidazole skeleton, such as fac-tris[1-(2,6-diisopropylphenyl)-2-phenyl-1H-imidazole]iridium(III) (abbreviation: Ir(iPrpmi)₃) and tris[3-(2,6-dimethylphenyl)-7-methylimidazo[1,2-f]phenanthridinato]iridium(III) (abbreviation: Ir(dmpimpt-Me)₃); and organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: Fir6), bis[2-(4′,6′-difluorophenyl)pyridinato-N,C^{2′}]iridium(III) picolinate (abbreviation: Firpic), bis{2-[3′,5′-bis(trifluoromethyl)phenyl]pyridinato-N,C^{2′}}iridium(III) picolinate (abbreviation: Ir(CF₃ppy)₂(pic)), and bis[2-(4′,6′-difluorophenyl)pyridinato-N,C^{2′}]iridium(III) acetylacetonate (abbreviation: FIr(acac)). Among the materials given above, the organometallic iridium complexes having a nitrogen-containing five-membered heterocyclic skeleton, such as a 4H-triazole skeleton, a 1H-triazole skeleton, or an imidazole skeleton have high triplet excitation energy, reliability, and emission efficiency and are thus especially preferable.

Examples of the substance that has an emission peak in green or yellow include organometallic iridium complexes having a pyrimidine skeleton, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(III) (abbreviation: Ir(tBuppm)₂(acac)), (acetylacetonato)bis[4-(2-norbornyl)-6-phenylpyrimidinato]iridium(III) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), (acetylacetonato)bis{4,6-dimethyl-2-[6-(2,6-dimethylphenyl)-4-pyrimidinyl-κN³]phenyl-κC}iridium(III) (abbreviation: Ir(dmppm-dmp)₂(acac)), and (acetylacetonato)bis(4,6-diphenylpyrimidinato)iridium(III) (abbreviation: Ir(dppm)₂(acac)); organometallic iridium complexes having a pyrazine skeleton, such as (acetylacetonato)bis(3,5-dimethyl-2-phenylpyrazinato)iridium(III) (abbreviation: Ir(mppr-Me)₂(acac)) and (acetylacetonato)bis(5-isopropyl-3-methyl-2-phenylpyrazinato)iridium(III) (abbreviation: Ir(mppr-iPr)₂(acac)); organometallic iridium complexes having a pyridine skeleton, such as tris(2-phenylpyridinato-N,C^{2′})iridium(III) (abbreviation: Ir(ppy)₃), bis(2-phenylpyridinato-N,C^{2′})iridium(III) acetylacetonate (abbreviation: Ir(ppy)₂(acac)), bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N,C^{2′})iridium(III) (abbreviation: Ir(pq)₃), and bis(2-phenylquinolinato-N,C^{2′})iridium(III) acetylacetonate (abbreviation: Ir(pq)₂(acac)); organometallic iridium complexes such as bis(2,4-diphenyl-1,3-oxazolato-N,C^{2′})iridium(III) acetylacetonate (abbreviation: Ir(dpo)₂(acac)), bis{2-[4′-(perfluorophenyl)phenyl]pyridinato-N,C^{2′}}iridium(III) acetylacetonate (abbreviation: Ir(p-PF-ph)₂(acac)), and bis(2-phenylbenzothiazolato-N,C^{2′})iridium(III) acetylacetonate (abbreviation: Ir(bt)₂(acac)); and a rare earth metal complex such as tris(acetylacetonato)(monophenanthroline)terbium(III) (abbreviation: Tb(acac)₃(Phen)). Among the materials given above, the organometallic iridium complexes having a pyrimidine skeleton have distinctively high reliability and emission efficiency and are thus especially preferable.

Examples of the substance that has an emission peak in yellow or red include organometallic iridium complexes having a pyrimidine skeleton, such as (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), and bis[4,6-di(naphthalen-1-yl)pyrimidinato](dipivaloylmethanato)iridium(III) (abbreviation: Ir(dlnpm)₂(dpm)); organometallic iridium complexes having a pyrazine skeleton, such as (acetylacetonato)bis(2,3,5-triphenylpyrazinato)iridium(III) (abbreviation: Ir(tppr)₂(acac)), bis(2,3,5-triphenylpyrazinato)(dipivaloylmethanato)iridium(III) (abbreviation: Ir(tppr)₂(dpm)), and (acetylacetonato)bis[2,3-bis(4-fluorophenyl)quinoxalinato]iridium(III) (abbreviation: Ir(Fdpq)₂(acac)); organometallic iridium complexes having a pyridine skeleton, such as tris(1-phenylisoquinolinato-N,C^{2′})iridium(III) (abbreviation: Ir(piq)₃) and bis(1-phenylisoquinolinato-N,C^{2′})iridium(III) acetylacetonate (abbreviation: Ir(piq)₂(acac)); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: Eu(DBM)₃(Phen)) and tris[1-(2-thenoyl)-3,3,3-trifluoroacetonato] (monophenanthroline)europium(III) (abbreviation: Eu(TTA)₃(Phen)). Among the materials given above, the organometallic iridium complexes having a pyrimidine skeleton have distinctively high reliability and emission efficiency and are thus especially preferable. Furthermore, the organometallic iridium complexes having a pyrazine skeleton can emit red light with favorable chromaticity.

Examples of a material that can be used as the above-described energy donor include metal-halide perovskites. The metal-halide perovskites can be represented by any of General Formulae (g1) to (g3) below.

(SA)MX₃: (g1)

(LA)₂(SA)ₙ₋₁MₙX₃ₙ₊₁: (g2)

(PA)(SA)ₙ₋₁MₙX3ₙ₊₁: (g3)

In the above general formulae, M represents a divalent metal ion, and X represents a halogen ion.

As the divalent metal ion, specifically, a divalent cation of lead, tin, or the like is used.

As the halogen ion, specifically, an anion of chlorine, bromine, iodine, fluorine, or the like is used.

Note that n represents an integer of 1 to 10. In the case where n is larger than 10 in General Formula (g2) or General Formula (g3), the properties are close to those of the metal-halide perovskite represented by General Formula (g1).

In addition, LA represents an ammonium ion represented by R³⁰—NH₃⁺.

In the ammonium ion represented by the general formula R³⁰—NH₃⁺, R³⁰ represents any one of an alkyl group, an aryl group, and a heteroaryl group each having 2 to 20 carbon atoms, or a group in which any one of an alkyl group, an aryl group, and a heteroaryl group each having 2 to 20 carbon atoms is combined with an alkylene group and a vinylene group each having 1 to 12 carbon atoms and an arylene group and a heteroarylene group each having 6 to 13 carbon atoms; in the latter case, a plurality of alkylene groups, arylene groups, and heteroarylene groups may be coupled, and a plurality of groups of the same kind may be used. In the case where a plurality of alkylene groups, vinylene groups, arylene groups, and heteroarylene groups are coupled, the total number of alkylene groups, vinylene groups, arylene groups, and heteroarylene groups is preferably smaller than or equal to 35.

Furthermore, SA represents a monovalent metal ion or an ammonium ion represented by R³¹—NH₃⁺ in which R³¹ is an alkyl group having 1 to 6 carbon atoms.

Moreover, PA represents NH₃⁺—R³²—NH₃⁺, NH₃⁺—R³³—R³⁴—R³⁵—NH₃⁺, or a part or whole of branched polyethyleneimine including ammonium cations, and the valence of this portion is +2. Note that charges are roughly in balance in the general formula.

Here, charges of the metal-halide perovskite are not necessarily in balance strictly in every portion of the material in the above formula as long as the neutrality is roughly maintained in the material as a whole. In some cases, other ions such as a free ammonium ion, a free halogen ion, or an impurity ion exist locally in the material and neutralize the charges. In addition, in some cases, the neutrality is not maintained locally also at a surface of a particle or a film, a crystal grain boundary, or the like; thus, the neutrality is not necessarily maintained in every location.

Note that in the above formula (g2), any of substances represented by General Formulae (a-1) to (a-11) and General Formulae (b-1) to (b-6) shown below, for example, can be used as (LA).

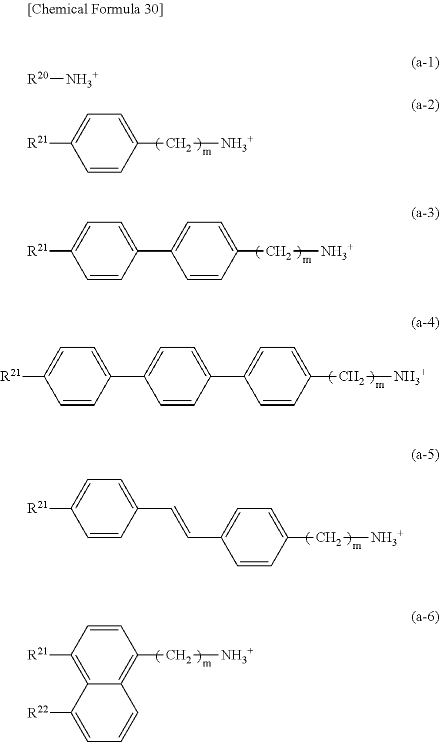

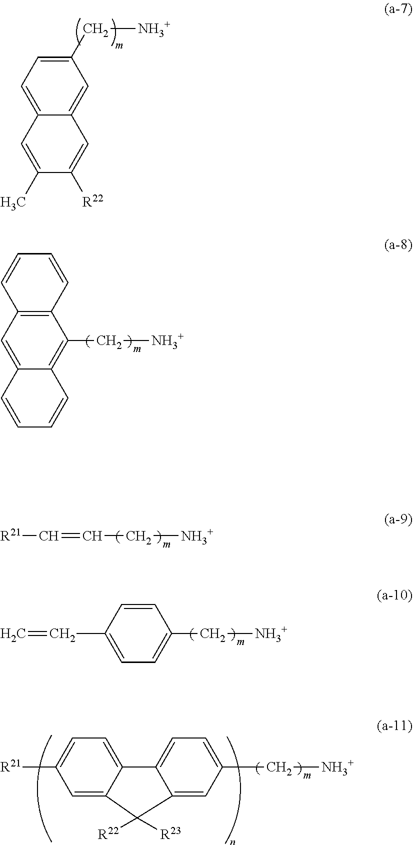

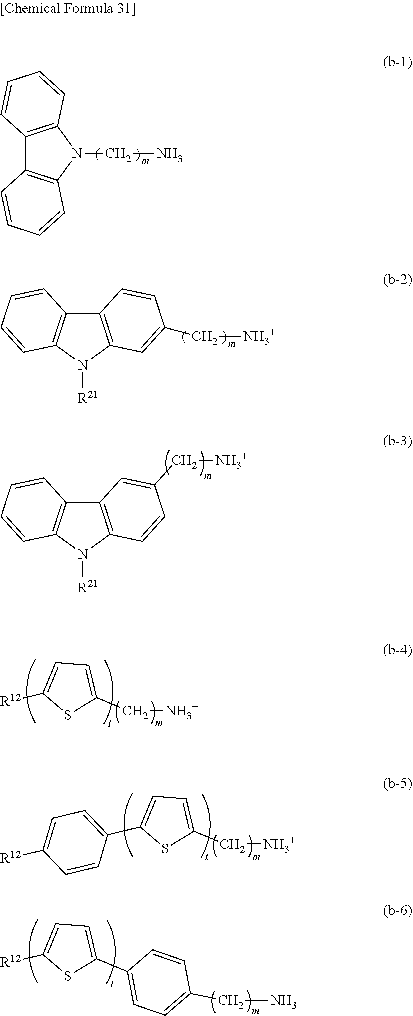

Furthermore, (PA) in General Formula (g3) typically represents any of substances represented by General Formulae (c-1), (c-2), and (d) shown below or a part or whole of branched polyethyleneimine including ammonium cations, and has a valence of +2. These polymers may neutralize charges over a plurality of unit cells; alternatively, one charge of each of two different polymer molecules may neutralize charges of one unit cell.

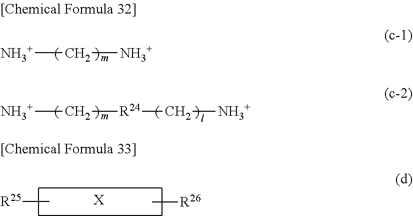

Note that in the above general formulae, R²⁰ represents an alkyl group having 2 to 18 carbon atoms, R²¹, R²², and R²³ represent hydrogen or an alkyl group having 1 to 18 carbon atoms, and R²⁴ represents any of Structural Formulae and General Formulae (R²⁴-1) to (R²⁴-14) shown below. Furthermore, R²⁵ and R²⁶ each independently represent hydrogen or an alkyl group having 1 to 6 carbon atoms. In addition, X has a combination of monomer units A and B represented by any of (d-1) to (d-6) shown above, and represents a structure including u A and v B. Note that the arrangement order of A and B is not limited. Furthermore, m and l are each independently an integer of 0 to 12, and t is an integer of 1 to 18. In addition, u is an integer of 0 to 17, v is an integer of 1 to 18, and u+v is an integer of 1 to 18.

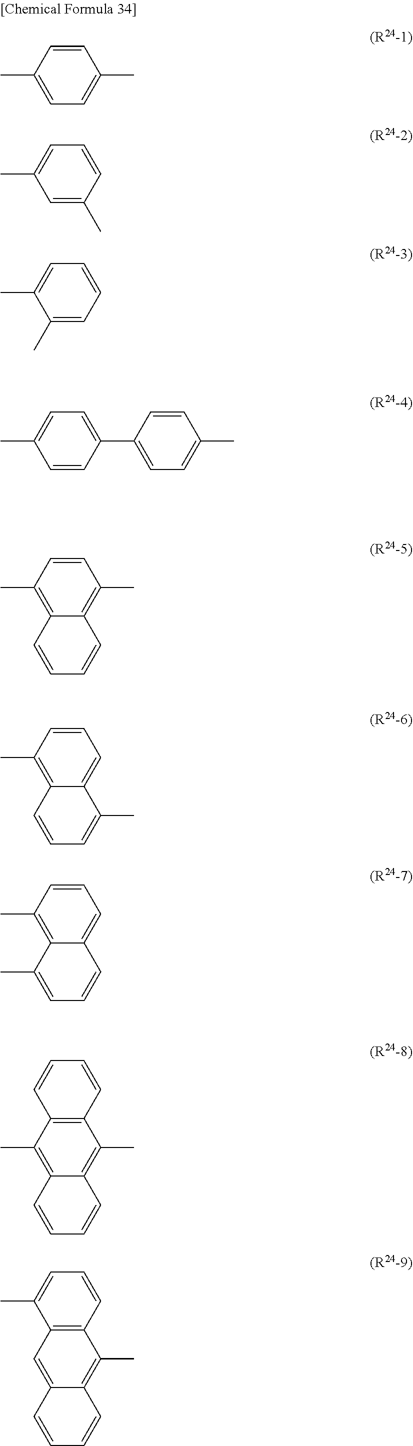

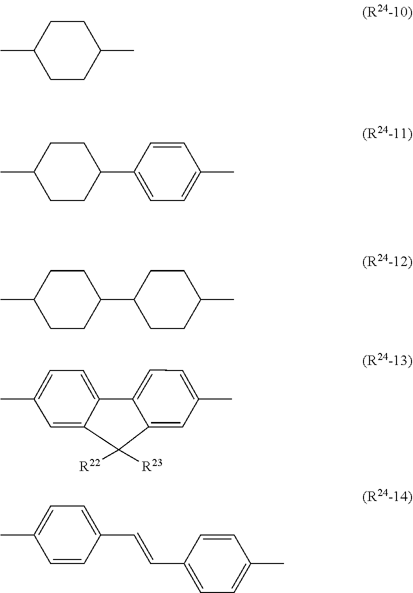

Note that these are examples, and the substances that can be used as (LA) and (PA) are not limited thereto.

In the metal-halide perovskite having a three-dimensional structure including the composition (SA)MX₃ represented by General Formula (g1), regular octahedral structures in each of which a metal atom M is placed at the center and halogen atoms are placed at six vertexes are three-dimensionally arranged by sharing the halogen atoms at the vertexes, so that a skeleton is formed. This regular octahedral structure unit including a halogen atom at each vertex is referred to as a perovskite unit. There are a zero-dimensional structure body in which a perovskite unit exists in isolation, a linear structure body in which perovskite units are one-dimensionally coupled with a halogen atom at the vertex, a sheet-shaped structure body in which perovskite units are two-dimensionally coupled, a structure body in which perovskite units are three-dimensionally coupled, and a complicated two-dimensional structure body formed of a stack of a plurality of sheet-shaped structure bodies in each of which perovskite units are two-dimensionally coupled. Furthermore, there is a more complicated structure body. All of these structure bodies having a perovskite unit are collectively defined as a metal-halide perovskite.

The light-emitting layer 130 can be formed of two or more layers. For example, in the case where the light-emitting layer 130 is formed by stacking a first light-emitting layer and a second light-emitting layer in this order from the hole-transport layer side, a substance having a hole-transport property is used as the host material of the first light-emitting layer and a substance having an electron-transport property is used as the host material of the second light-emitting layer.

The light-emitting layer 130 may contain a material (a compound 135) in addition to the compound 131, the compound 132, the compound 133, and the compound 134. In that case, in order for the compound 131 and the compound 133 (or the compound 134) to efficiently form an exciplex, it is preferable that the HOMO level of one of the compound 131 and the compound 133 (or the compound 134) be the highest HOMO level of the materials in the light-emitting layer 130 and that the LUMO level of the other be the lowest LUMO level of the materials in the light-emitting layer 130. With such an energy level correlation, the reaction for forming an exciplex by the compound 131 and the compound 135 can be inhibited.

In the case where, for example, the compound 131 has a hole-transport property and the compound 133 (or the compound 134) has an electron-transport property, the HOMO level of the compound 131 is preferably higher than the HOMO level of the compound 133 and the HOMO level of the compound 135, and the LUMO level of the compound 133 is preferably lower than the LUMO level of the compound 131 and the LUMO level of the compound 135. In this case, the LUMO level of the compound 135 may be higher or lower than the LUMO level of the compound 131. Furthermore, the HOMO level of the compound 135 may be higher or lower than the HOMO level of the compound 133.

Examples of the material (the compound 135) that can be used for the light-emitting layer 130 are, but not particularly limited to, metal complexes such as tris(8-quinolinolato)aluminum(III) (abbreviation: Alq), tris(4-methyl-8-quinolinolato)aluminum(III) (abbreviation: Almq₃), bis(10-hydroxybenzo[h] quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen), bathocuproine (abbreviation: BCP), and 9-[4-(5-phenyl-1,3,4-oxadiazol-2-yl)phenyl]-9H-carbazole (abbreviation: CO11); and aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), and 4,4′-bis[N-(spiro-9,9′-bifluoren-2-yl)-N-phenylamino]biphenyl (abbreviation: BSPB). Condensed polycyclic aromatic compounds such as anthracene derivatives, phenanthrene derivatives, pyrene derivatives, chrysene derivatives, and dibenzo[g,p]chrysene derivatives are also given; specific examples include 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N,9-diphenyl-N-(9,10-diphenyl-2-anthryl)-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), and 3,3′,3″-(benzene-1,3,5-triyl)tripyrene (abbreviation: TPB3). One or more substances having a wider energy gap than the compound 131 and the compound 132 are selected from these substances and known substances.

### <<Pair of Electrodes>>

The electrode 101 and the electrode 102 have functions of injecting holes and electrons into the light-emitting layer 130. The electrode 101 and the electrode 102 can be formed using a metal, an alloy, a conductive compound, a mixture or a stack thereof, or the like. As the metal, aluminum (Al) is a typical example; besides, a transition metal such as silver (Ag), tungsten, chromium, molybdenum, copper, or titanium, an alkali metal such as lithium (Li) or cesium, or a Group 2 metal such as calcium or magnesium (Mg) can be used. As the transition metal, a rare earth metal such as ytterbium (Yb) may be used. An alloy containing the above metal can be used as the alloy; examples are MgAg and AlLi. Examples of the conductive compound include metal oxides such as indium tin oxide (hereinafter ITO), indium tin oxide containing silicon or silicon oxide (abbreviation: ITSO), indium zinc oxide, and indium oxide containing tungsten and zinc. It is also possible to use an inorganic carbon-based material such as graphene as the conductive compound. As described above, one or both of the electrode 101 and the electrode 102 may be formed by stacking two or more of these materials.

Light emission obtained from the light-emitting layer 130 is extracted through one or both of the electrode 101 and the electrode 102. Therefore, at least one of the electrode 101 and the electrode 102 has a function of transmitting visible light. An example of a conductive material having a function of transmitting light is a conductive material having a visible light transmittance of higher than or equal to 40% and lower than or equal to 100%, preferably higher than or equal to 60% and lower than or equal to 100% and a resistivity of lower than or equal to 1×10⁻² Ω·cm. The electrode through which light is extracted may be formed using a conductive material having a function of transmitting light and a function of reflecting light. An example of the conductive material is a conductive material having a visible light reflectivity of higher than or equal to 20% and lower than or equal to 80%, preferably higher than or equal to 40% and lower than or equal to 70% and a resistivity of lower than or equal to 1×10⁻² Ω·cm. In the case where a material with low light transmittance, such as metal or alloy, is used for the electrode through which light is extracted, one or both of the electrode 101 and the electrode 102 are formed to a thickness that is thin enough to transmit visible light (e.g., a thickness of 1 nm to 10 nm).

Note that in this specification and the like, for the electrode having a function of transmitting light, a material that has a function of transmitting visible light and has conductivity is used; examples include, in addition to a layer of an oxide conductor typified by ITO mentioned above, an oxide semiconductor layer and an organic conductor layer containing an organic substance. Examples of the organic conductor layer containing an organic substance include a layer containing a composite material in which an organic compound and an electron donor (donor) are mixed and a layer containing a composite material in which an organic compound and an electron acceptor (acceptor) are mixed. The resistivity of the transparent conductive layer is preferably lower than or equal to 1×10⁵ Ω·cm, further preferably lower than or equal to 1×10⁴ Ω·cm.

As a method for forming the electrode 101 and the electrode 102, a sputtering method, an evaporation method, a printing method, a coating method, an MBE (Molecular Beam Epitaxy) method, a CVD method, a pulsed laser deposition method, an ALD (Atomic Layer Deposition) method, or the like can be used as appropriate.

### <<Hole-Injection Layer>>

The hole-injection layer 111 has a function of reducing a barrier for hole injection from one of the pair of electrodes (the electrode 101 or the electrode 102) to promote hole injection and is formed using, for example, a transition metal oxide, a phthalocyanine derivative, an aromatic amine, or the like. Examples of the transition metal oxide include molybdenum oxide, vanadium oxide, ruthenium oxide, tungsten oxide, and manganese oxide. Examples of the phthalocyanine derivative include phthalocyanine and metal phthalocyanine. Examples of the aromatic amine include a benzidine derivative and a phenylenediamine derivative. It is also possible to use a high molecular compound such as polythiophene or polyaniline; a typical example thereof is poly(ethylenedioxythiophene)/poly(styrenesulfonic acid), which is self-doped polythiophene.

As the hole-injection layer 111, a layer containing a composite material of a hole-transport material and a material having a property of accepting electrons from the hole-transport material can also be used. Alternatively, a stack of a layer containing a material having an electron-accepting property and a layer containing a hole-transport material may be used. In a steady state or in the presence of an electric field, electric charge can be transferred between these materials. Examples of the material having an electron-accepting property include organic acceptors such as a quinodimethane derivative, a chloranil derivative, and a hexaazatriphenylene derivative. A specific example is a compound having an electron-withdrawing group (in particular, a cyano group or a halogen group such as a fluoro group), such as 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), and 1,3,4,5,7,8-hexafluorotetracyano-naphthoquinodimethane (abbreviation: F6-TCNNQ). A compound in which electron-withdrawing groups are bonded to a condensed aromatic ring having a plurality of heteroatoms, such as HAT-CN, is particularly preferable because it is thermally stable. A [3]radialene derivative including an electron-withdrawing group (in particular, a cyano group or a halogen group such as a fluoro group) has a very high electron-accepting property and thus is preferable; specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. Alternatively, a transition metal oxide such as an oxide of metal from Group 4 to Group 8 can be used. Specific examples include vanadium oxide, niobium oxide, tantalum oxide, chromium oxide, molybdenum oxide, tungsten oxide, manganese oxide, and rhenium oxide. In particular, molybdenum oxide is preferable because it is stable in the air, has a low hygroscopic property, and is easily handled.

As the hole-transport material, a material having a property of transporting more holes than electrons can be used, and a material having a hole mobility of 1×10⁻⁶ cm²/Vs or higher is preferable. Specifically, the aromatic amines and the carbazole derivatives given as the hole-transport material that can be used for the light-emitting layer 130 can be used. Alternatively, the aromatic hydrocarbons, the stilbene derivatives, and the like can be used. Furthermore, the hole-transport material may be a high molecular compound.

Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Besides, pentacene, coronene, and the like can be used. Thus, the use of the aromatic hydrocarbon having a hole mobility of 1×10⁻⁶ cm²/Vs or higher and having 14 to 42 carbon atoms is further preferable.

The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA).

It is also possible to use high molecular compounds such as poly(N-vinylcarbazole) (abbreviation: PVK), poly(-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N′-bis(4-butylphenyl)-N,N-bis(phenyl)benzidine] (abbreviation: poly-TPD).

<<Hole-Transport Layer>>

The hole-transport layer 112 is a layer containing a hole-transport material and can be formed using the materials given as examples of the materials of the hole-injection layer 111. In order that the hole-transport layer 112 has a function of transporting holes injected into the hole-injection layer 111 to the light-emitting layer 130, the hole-transport layer 112 preferably has a HOMO level equal or close to the HOMO level of the hole-injection layer 111.

As the hole-transport material, the materials given as examples of the material of the hole-injection layer 111 can be used. A substance having a hole mobility of 1×10⁻⁶ cm²/Vs or higher is preferable. Note that other substances may also be used as long as they have a property of transporting more holes than electrons. The layer containing a substance having a high hole-transport property is not limited to a single layer, and two or more layers containing the aforementioned substances may be stacked.

### <<Electron-Transport Layer>>

The electron-transport layer 118 has a function of transporting, to the light-emitting layer 130, electrons injected from the other of the pair of electrodes (the electrode 101 or the electrode 102) through the electron-injection layer 119. A material having a property of transporting more electrons than holes can be used as the electron-transport material, and a material having an electron mobility of 1×10⁻⁶ cm²/Vs or higher is preferable. As a compound that easily accepts electrons (a material having an electron-transport property), a π-electron deficient heteroaromatic compound such as a nitrogen-containing heteroaromatic compound, a metal complex, or the like can be used. Specifically, the metal complex having a quinoline ligand, a benzoquinoline ligand, an oxazole ligand, or a thiazole ligand, which is given as the electron-transport material that can be used for the light-emitting layer 130, can be given. Furthermore, an oxadiazole derivative, a triazole derivative, a phenanthroline derivative, a pyridine derivative, a bipyridine derivative, a pyrimidine derivative, and the like can be given. A substance having an electron mobility of 1×10⁻⁶ cm²/Vs or higher is preferable. Note that other substances may also be used for the electron-transport layer as long as they have a property of transporting more electrons than holes. The electron-transport layer 118 is not limited to a single layer, and two or more layers containing the aforementioned substances may be stacked.

A layer that controls transfer of electron carriers may be provided between the electron-transport layer 118 and the light-emitting layer 130. The layer that controls transfer of electron carriers is a layer in which a small amount of a substance having a high electron-trapping property is added to the above-described material having a high electron-transport property, and is capable of adjusting carrier balance by inhibiting transfer of electron carriers. Such a structure is very effective in preventing a problem (such as a reduction in element lifetime) caused when electrons pass through the light-emitting layer.

<<Electron-Injection Layer>>

The electron-injection layer 119 has a function of reducing a barrier for electron injection from the electrode 102 to promote electron injection, and a Group 1 metal and a Group 2 metal, or an oxide, a halide, a carbonate, or the like of them can be used, for example. Alternatively, a composite material of the electron-transport material described above and a material having a property of donating electrons thereto can be used. Examples of the material having an electron-donating property include a Group 1 metal and a Group 2 metal, and an oxide of them. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound such as erbium fluoride (ErF₃) can be used. Electride may also be used for the electron-injection layer 119. Examples of the electride include a substance in which electrons are added at high concentration to a mixed oxide of calcium and aluminum. The substance that can be used for the electron-transport layer 118 can be used for the electron-injection layer 119.

A composite material in which an organic compound and an electron donor (donor) are mixed may also be used for the electron-injection layer 119. Such a composite material has an excellent electron-injection property and an excellent electron-transport property because electrons are generated in the organic compound by the electron donor. In this case, the organic compound is preferably a material that is excellent in transporting the generated electrons; specifically, the above-listed substances contained in the electron-transport layer 118 (the metal complexes, heteroaromatic compounds, and the like) can be used, for example. As the electron donor, a substance showing an electron-donating property with respect to the organic compound is used. Specifically, an alkali metal, an alkaline earth metal, and a rare earth metal are preferable, and lithium, cesium, magnesium, calcium, erbium, ytterbium, and the like are given. In addition, an alkali metal oxide or an alkaline earth metal oxide is preferable, and lithium oxide, calcium oxide, barium oxide, and the like are given. A Lewis base such as magnesium oxide can also be used. An organic compound such as tetrathiafulvalene (abbreviation: TTF) can also be used.

Note that the light-emitting layer, the hole-injection layer, the hole-transport layer, the electron-transport layer, and the electron-injection layer described above can each be formed by a method such as an evaporation method (including a vacuum evaporation method), an inkjet method, a coating method, a nozzle printing method, or gravure printing. Other than the above-described materials, an inorganic compound such as a quantum dot or a high molecular compound (an oligomer, a dendrimer, a polymer, or the like) may be used for the light-emitting layer, the hole-injection layer, the hole-transport layer, the electron-transport layer, and the electron-injection layer described above.

As the quantum dot, a colloidal quantum dot, an alloyed quantum dot, a core-shell quantum dot, a core quantum dot, or the like may be used. Moreover, a quantum dot containing elements belonging to Groups 2 and 16, Groups 13 and 15, Groups 13 and 17, Groups 11 and 17, or Groups 14 and 15 may be used. Alternatively, a quantum dot containing an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

As a liquid medium used for the wet process, for example, an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like can be used.

Examples of the high molecular compound that can be used for the light-emitting layer include polyphenylenevinylene (PPV) derivatives such as poly[2-methoxy-5-(2-ethylhexyloxy)-1,4-phenylenevinylene] (abbreviation: MEH-PPV) and poly(2,5-dioctyl-1,4-phenylenevinylene); polyfluorene derivatives such as poly(9,9-di-n-octylfluorenyl-2,7-diyl) (abbreviation: PF8), poly[(9,9-di-n-octylfluorenyl-2,7-diyl)-alt-(benzo[2,1,3]thiadiazole-4,8-diyl)] (abbreviation: F8BT), poly[(9,9-di-n-octylfluorenyl-2,7-diyl)-alt-(2,2′-bithiophene-5,5′-diyl)] (abbreviation: F8T2), poly[(9,9-dioctyl-2,7-divinylenefluorenylene)-alt-(9,10-anthracene)], or poly[(9,9-dihexylfluorene-2,7-diyl)-alt-(2,5-dimethyl-1,4-phenylene)]; a polyalkylthiophene (PAT) derivative such as poly(3-hexylthiophene-2,5-diyl) (abbreviation: P3HT); and a polyphenylene derivative. These high molecular compounds and high molecular compounds such as PVK, poly(2-vinylnaphthalene), and poly[bis(4-phenyl) (2,4,6-trimethylphenyl)amine] (abbreviation: PTAA) may be doped with a light-emitting compound and used for the light-emitting layer. As the light-emitting compound, the light-emitting compounds given above can be used.

### <<Substrate>>

A light-emitting element of one embodiment of the present invention is formed over a substrate formed of glass, plastic, or the like. As for the order of forming layers over the substrate, layers may be sequentially stacked from the electrode 101 side or sequentially stacked from the electrode 102 side.

For the substrate over which the light-emitting element of one embodiment of the present invention can be formed, glass, quartz, plastic, or the like can be used, for example. Alternatively, a flexible substrate may be used. The flexible substrate is a substrate that can be bent (is flexible), such as a plastic substrate made of polycarbonate or polyarylate, for example. Alternatively, a film, an inorganic vapor deposition film, or the like can be used. Note that materials other than these may be used as long as they function as a support in a manufacturing process of the light-emitting element and an optical element. Alternatively, another material may be used as long as it has a function of protecting the light-emitting element and the optical element.

In this specification and the like, a light-emitting element can be formed using a variety of substrates, for example. The type of substrate is not limited particularly. Examples of the substrate include a semiconductor substrate (e.g., a single-crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, cellulose nanofiber (CNF) and paper which include a fibrous material, and a base material film. Examples of the glass substrate include barium borosilicate glass, aluminoborosilicate glass, and soda lime glass. Examples of the flexible substrate, the attachment film, the base material film, and the like are as follows. The examples include plastics typified by polyethylene terephthalate (PET), polyethylene naphthalate (PEN), polyether sulfone (PES), and polytetrafluoroethylene (PTFE). Another example is a resin such as acrylic. Other examples are polypropylene, polyester, polyvinyl fluoride, and polyvinyl chloride. Furthermore, other examples are polyamide, polyimide, aramid, epoxy, an inorganic vapor deposition film, and paper.

A flexible substrate may be used as the substrate and the light-emitting element may be formed directly on the flexible substrate. Alternatively, a separation layer may be provided between the substrate and the light-emitting element. The separation layer can be used when part or the whole of a light-emitting element formed thereover is separated from the substrate and transferred to another substrate. In such a case, the light-emitting element can be transferred to a substrate having low heat resistance or a flexible substrate as well. For the above separation layer, for example, a stacked structure of inorganic films of a tungsten film and a silicon oxide film, or a structure in which a resin film of polyimide or the like is formed over a substrate can be used.

In other words, after the light-emitting element is formed using one substrate, the light-emitting element may be transferred to and placed over another substrate. Examples of the substrate to which the light-emitting element is transferred include, in addition to the above substrates, a cellophane substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), and the like), a leather substrate, and a rubber substrate. With the use of these substrates, a light-emitting element with high durability, a light-emitting element with high heat resistance, a light-emitting element with reduced weight, or a light-emitting element with reduced thickness can be obtained.

A field-effect transistor (FET), for example, may be formed over the above substrate, and the light-emitting element 150 may be formed over an electrode electrically connected to the FET. Accordingly, an active matrix display device in which the FET controls the driving of the light-emitting element can be fabricated.

The structure described above in this embodiment can be used in appropriate combination with the other embodiments.

### Embodiment 2

In this embodiment, an example of a method for synthesizing an organic compound that can be suitably used for the light-emitting element of one embodiment of the present invention will be described giving the organic compounds represented by General Formulae (G1) and (G2) as an example.

### <Method for Synthesizing Organic Compound Represented by General Formula (G1)>

The organic compound represented by General Formula (G1) shown above can be synthesized by a synthesis method using a variety of reactions. For example, the organic compound can be synthesized by Synthesis Schemes (S-1) and (S-2) shown below. A compound 1, arylamine (compound 2), and arylamine (compound 3) are coupled, whereby a diamine compound (compound 4) is obtained.

Then, the diamine compound (compound 4), halogenated aryl (compound 5), and halogenated aryl (compound 6) are coupled, whereby the organic compound represented by General Formula (G1) shown above can be obtained.

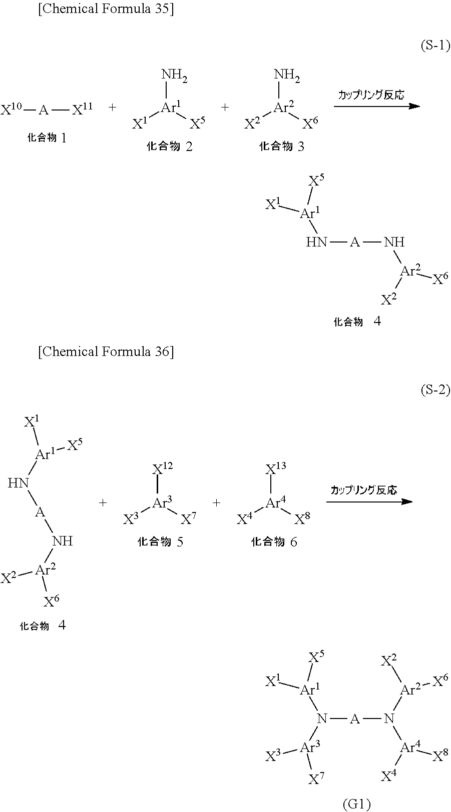

In Synthesis Schemes (S-1) and (S-2) shown above, A represents a substituted or unsubstituted condensed aromatic ring having 10 to 30 carbon atoms or a substituted or unsubstituted condensed heteroaromatic ring having 10 to 30 carbon atoms, Ar¹ to Ar⁴ each independently represent a substituted or unsubstituted aromatic hydrocarbon group having 6 to 13 carbon atoms, X¹ to X⁸ each independently represent any one of an alkyl group having 3 to 10 carbon atoms, a substituted or unsubstituted cycloalkyl group having 3 to 10 carbon atoms, and a trialkylsilyl group having 3 to 12 carbon atoms. Examples of the condensed aromatic ring or condensed heteroaromatic ring include chrysene, phenanthrene, stilbene, acridone, phenoxazine, and phenothiazine. In particular, anthracene, pyrene, coumarin, quinacridone, perylene, tetracene, and naphthobisbenzofuran are preferable.

In the case where the Buchwald-Hartwig reaction using a palladium catalyst is performed in Synthesis Schemes (S-1) and (S-2) shown above, X¹⁰ to X¹³ each represent a halogen group or a triflate group, and the halogen is preferably iodine, bromine, or chlorine. In the reaction, a palladium compound such as bis(dibenzylideneacetone)palladium(0) or palladium(II) acetate and a ligand such as tri(tert-butyl)phosphine, tri(n-hexyl)phosphine, tricyclohexylphosphine, di(1-adamantyl)-n-butylphosphine, or 2-dicyclohexylphosphino-2′,6′-dimethoxy-1,1′-biphenyl can be used. In addition, an organic base such as sodium tert-butoxide, an inorganic base such as potassium carbonate, cesium carbonate, or sodium carbonate, or the like can be used. Furthermore, toluene, xylene, mesitylene, benzene, tetrahydrofuran, dioxane, or the like can be used as a solvent. The reagents that can be used in the reaction are not limited to these reagents.

The reaction performed in Synthesis Schemes (S-1) and (S-2) shown above is not limited to the Buchwald-Hartwig reaction. The Migita-Kosugi-Stille coupling reaction using an organotin compound, a coupling reaction using a Grignard reagent, the Ullmann reaction using copper or a copper compound, or the like can be used.

In the case where the compound 2 and the compound 3 have different structures in Synthesis Scheme (S-1) shown above, it is preferable that the compound 1 and the compound 2 be reacted first to form a coupling product and then the obtained coupling product and the compound 3 be reacted. In the case where the compound 1 is reacted with the compound 2 and the compound 3 in different stages, it is preferable that the compound 1 be a dihalogen compound and that X¹⁰ and X¹¹ be different halogens and selectively subjected to amination reactions one by one.

Furthermore, in the case where the compound 5 and the compound 6 have different structures in Synthesis Scheme (S-2), it is preferable that the compound 4 and the compound 5 be reacted first to form a coupling product and then the obtained coupling product and the compound 6 be reacted.

### Embodiment 3

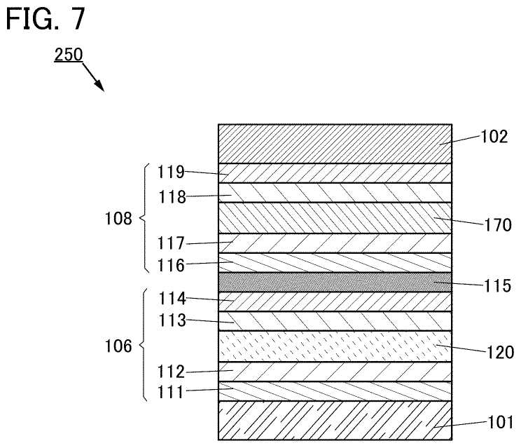

In this embodiment, a light-emitting element having a structure different from the structure of the light-emitting element described in Embodiment 1 will be described below with reference to FIG. 7. Note that in FIG. 7, a portion having a similar function to a portion denoted by a reference numeral shown in FIG. 1(A) is represented by the same hatch pattern and the reference numeral is omitted in some cases. In addition, common reference numerals are used for portions having similar functions, and a detailed description thereof is omitted in some cases.

### <Structure Example 2 of Light-Emitting Element>

FIG. 7 is a schematic cross-sectional view of a light-emitting element 250. The light-emitting element 250 illustrated in FIG. 7 includes a plurality of light-emitting units (a light-emitting unit 106 and a light-emitting unit 108) between a pair of electrodes (the electrode 101 and the electrode 102). One of the plurality of light-emitting units preferably has a structure similar to that of the EL layer 100 illustrated in FIG. 1(A). In other words, the light-emitting element 150 illustrated in FIG. 1(A) includes one light-emitting unit while the light-emitting element 250 includes a plurality of light-emitting units. Note that the electrode 101 functions as an anode and the electrode 102 functions as a cathode in the light-emitting element 250 in the following description; however, the functions may be reversed as the structure of the light-emitting element 250.

In the light-emitting element 250 illustrated in FIG. 7, the light-emitting unit 106 and the light-emitting unit 108 are stacked, and a charge-generation layer 115 is provided between the light-emitting unit 106 and the light-emitting unit 108. Note that the light-emitting unit 106 and the light-emitting unit 108 may have the same structure or different structures. For example, a structure similar to that of the EL layer 100 is preferably used for the light-emitting unit 108.

The light-emitting element 250 includes a light-emitting layer 120 and a light-emitting layer 170. The light-emitting unit 106 includes the hole-injection layer 111, the hole-transport layer 112, an electron-transport layer 113, and an electron-injection layer 114 in addition to the light-emitting layer 120. The light-emitting unit 108 includes a hole-injection layer 116, a hole-transport layer 117, the electron-transport layer 118, and the electron-injection layer 119 in addition to the light-emitting layer 170.

In the light-emitting element 250, any layer included in each of the light-emitting unit 106 and the light-emitting unit 108 contains the compound of one embodiment of the present invention. Note that the layer containing the compound is preferably the light-emitting layer 120 or the light-emitting layer 170.

The charge-generation layer 115 may have either a structure in which an acceptor substance that is an electron acceptor is added to a hole-transport material or a structure in which a donor substance that is an electron donor is added to an electron-transport material. Alternatively, both of these structures may be stacked.

In the case where the charge-generation layer 115 contains a composite material of an organic compound and an acceptor substance, the composite material that can be used for the hole-injection layer 111 described in Embodiment 1 is used as the composite material. As the organic compound, a variety of compounds such as an aromatic amine compound, a carbazole compound, an aromatic hydrocarbon, and a high molecular compound (an oligomer, a dendrimer, a polymer, or the like) can be used. Note that a substance having a hole mobility of 1×10⁻⁶ cm²/Vs or higher is preferably used as the organic compound. However, other substances may also be used as long as they have a property of transporting more holes than electrons. Since the composite material of an organic compound and an acceptor substance has excellent carrier-injection and carrier-transport properties, low-voltage driving or low-current driving can be achieved. Note that in the case where a surface of a light-emitting unit on the anode side is in contact with the charge-generation layer 115, the charge-generation layer 115 can also serve as a hole-injection layer or a hole-transport layer of the light-emitting unit; thus, a structure in which a hole-injection layer or a hole-transport layer is not provided in the light-emitting unit may be employed. Alternatively, in the case where a surface of the light-emitting unit on the cathode side is in contact with the charge-generation layer 115, the charge-generation layer 115 can also serve as an electron-injection layer or an electron-transport layer of the light-emitting unit; thus, a structure in which an electron-injection layer or an electron-transport layer is not provided in the light-emitting unit may be employed.

Note that the charge-generation layer 115 may have a stacked structure in which a layer containing the composite material of an organic compound and an acceptor substance and a layer formed of another material are combined. For example, a layer containing the composite material of an organic compound and an acceptor substance and a layer containing one compound selected from electron-donating substances and a compound having a high electron-transport property may be combined. Moreover, a layer containing the composite material of an organic compound and an acceptor substance and a layer containing a transparent conductive film may be combined.

Note that the charge-generation layer 115 sandwiched between the light-emitting unit 106 and the light-emitting unit 108 injects electrons into one of the light-emitting units and injects holes into the other of the light-emitting units when voltage is applied to the electrode 101 and the electrode 102. For example, in FIG. 7, the charge-generation layer 115 injects electrons into the light-emitting unit 106 and injects holes into the light-emitting unit 108 when voltage is applied such that the potential of the electrode 101 is higher than the potential of the electrode 102.

Note that in terms of outcoupling efficiency, the charge-generation layer 115 preferably has a property of transmitting visible light (specifically, the charge-generation layer 115 has a visible-light transmittance of 40% or higher). Moreover, the charge-generation layer 115 functions even when it has lower conductivity than the pair of electrodes (the electrode 101 and the electrode 102).

Forming the charge-generation layer 115 using the above-described materials can inhibit an increase in driving voltage in the case where the light-emitting layers are stacked.

The light-emitting element having two light-emitting units has been described with reference to FIG. 7; however, a light-emitting element in which three or more light-emitting units are stacked can be similarly employed. With a plurality of light-emitting units partitioned by the charge-generation layer between a pair of electrodes as in the light-emitting element 250, it is possible to achieve a light-emitting element that can emit high-luminance light with the current density kept low and has a long lifetime. Moreover, a light-emitting element with low power consumption can be achieved.

Note that in each of the above-described structures, the emission colors of guest materials used for the light-emitting unit 106 and the light-emitting unit 108 may be the same or different. In the case where guest materials having functions of emitting light of the same color are used for the light-emitting unit 106 and the light-emitting unit 108, the light-emitting element 250 exhibits high emission luminance at a small current value, which is preferable. In the case where guest materials having functions of emitting light of different colors are used for the light-emitting unit 106 and the light-emitting unit 108, the light-emitting element 250 exhibits multi-color light emission, which is preferable. In that case, with the use of a plurality of light-emitting materials with different emission wavelengths in one or both of the light-emitting layer 120 and the light-emitting layer 170, light emission with different emission peaks are synthesized and thus an emission spectrum of the light exhibited by the light-emitting element 250 has at least two local maximum values.

The above structure is also suitable for obtaining white light emission. When the light-emitting layer 120 and the light-emitting layer 170 emit light of complementary colors, white light emission can be obtained. It is particularly favorable to select the guest materials so that white light emission with high color rendering properties or light emission of at least red, green, and blue can be obtained.

One or both of the light-emitting layer 120 and the light-emitting layer 170 preferably have the structure of the light-emitting layer 130 described in Embodiment 1. With such a structure, a light-emitting element with favorable emission efficiency and favorable reliability can be obtained. The guest material contained in the light-emitting layer 130 is a fluorescent material. Thus, when one or both of the light-emitting layer 120 and the light-emitting layer 170 have the structure of the light-emitting layer 130 described in Embodiment 1, a light-emitting element with high efficiency and high reliability can be obtained.

In the case of a light-emitting element in which three or more light-emitting units are stacked, the emission colors of guest materials used in the light-emitting units may be the same or different. In the case where a plurality of light-emitting units that exhibit the same emission color are included, the emission color exhibited by the plurality of light-emitting units can have higher emission luminance at a smaller current value than another color. Such a structure can be suitably used for adjustment of emission colors. The structure is particularly suitable when guest materials that exhibit different emission colors with different emission efficiencies are used. For example, when three layers of light-emitting units are included, the emission intensity of fluorescence and phosphorescence can be adjusted with two layers of light-emitting units that contain a fluorescent material of the same color and one layer of a light-emitting unit that contains a phosphorescent material that exhibits an emission color different from that of the fluorescent material. That is, the intensity of emitted light of each color can be adjusted with the number of light-emitting units.

In the case of the light-emitting element including two layers of fluorescent units and one layer of phosphorescent unit, a light-emitting element including two layers of light-emitting units containing a blue fluorescent material and one layer of light-emitting unit containing a yellow phosphorescent material, a light-emitting element including two layers of light-emitting units containing a blue fluorescent material and one layer of light-emitting unit containing a red phosphorescent material and a green phosphorescent material, or a light-emitting element including two layers of light-emitting units containing a blue fluorescent material and one layer of light-emitting unit containing a red phosphorescent material, a yellow phosphorescent material, and a green phosphorescent material is preferably used, in which case white light emission can be obtained efficiently. Thus, the light-emitting element of one embodiment of the present invention can be combined with a phosphorescent unit, as appropriate.

At least one of the light-emitting layer 120 and the light-emitting layer 170 may further be divided into layers and the divided layers may contain different light-emitting materials. That is, at least one of the light-emitting layer 120 and the light-emitting layer 170 can consist of two or more layers. For example, in the case where the light-emitting layer is formed by stacking a first light-emitting layer and a second light-emitting layer in this order from the hole-transport layer side, the first light-emitting layer is formed using a material having a hole-transport property as a host material and the second light-emitting layer is formed using a material having an electron-transport property as a host material. In this case, the light-emitting materials contained in the first light-emitting layer and the second light-emitting layer may be the same or different, and may have functions of exhibiting light emission of the same color or exhibiting light emission of different colors. White light emission with high color rendering properties that is formed of three primary colors or four or more emission colors can also be obtained by using a plurality of light-emitting materials having functions of exhibiting light emission of different colors.

Note that this embodiment can be combined as appropriate with the other embodiments.

### Embodiment 4

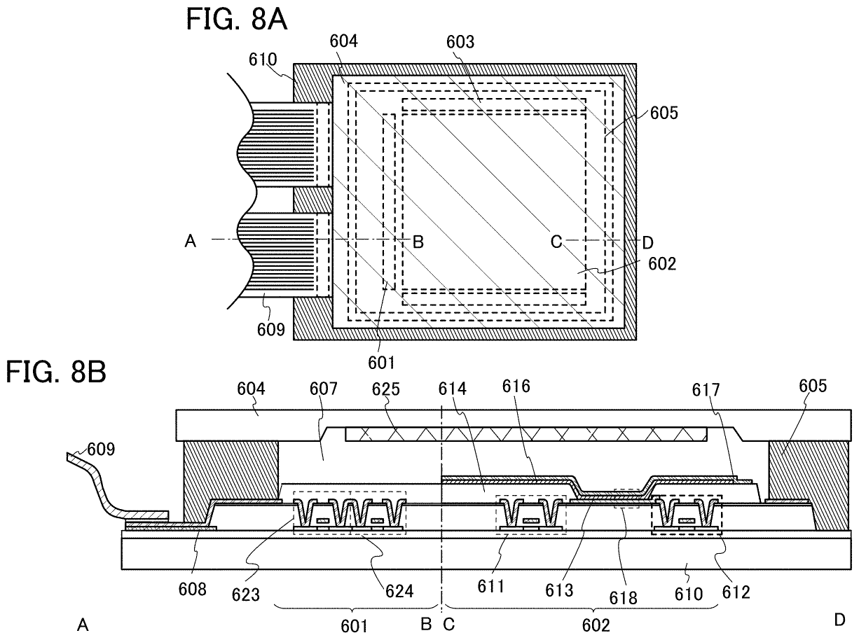

In this embodiment, a light-emitting device including the light-emitting elements described in Embodiment 1 and Embodiment 3 will be described with reference to FIG. 8(A) and FIG. 8(B).

FIG. 8(A) is a top view illustrating a light-emitting device and FIG. 8(B) is a cross-sectional view taken along A-B and C-D in FIG. 8(A). This light-emitting device includes a driver circuit portion (source side driver circuit) 601, a pixel portion 602, and a driver circuit portion (gate side driver circuit) 603, which are indicated by dotted lines, as components controlling light emission of a light-emitting element. Furthermore, 604 denotes a sealing substrate, 625 denotes a desiccant, 605 denotes a sealant, and a portion surrounded by the sealant 605 is a space 607.

Note that a lead wiring 608 is a wiring for transmitting signals to be input to the source side driver circuit 601 and the gate side driver circuit 603 and receives a video signal, a clock signal, a start signal, a reset signal, and the like from an FPC (flexible printed circuit) 609 serving as an external input terminal. Although only the FPC is illustrated here, a printed wiring board (PWB) may be attached to the FPC. The light-emitting device in this specification includes not only the light-emitting device itself but also the state where the FPC or the PWB is attached thereto.

Next, a cross-sectional structure of the above light-emitting device is described with reference to FIG. 8(B). The driver circuit portion and the pixel portion are formed over an element substrate 610; here, the source side driver circuit 601, which is the driver circuit portion, and one pixel in the pixel portion 602 are illustrated.

Note that in the source side driver circuit 601, a CMOS circuit in which an n-channel TFT 623 and a p-channel TFT 624 are combined is formed. The driver circuit may be formed of a variety of CMOS circuits, PMOS circuits, or NMOS circuits. Although a driver-integrated type where the driver circuit is formed over the substrate is described in this embodiment, the driver circuit is not necessarily integrated and can be formed not over the substrate but outside the substrate.

The pixel portion 602 is formed of pixels including a switching TFT 611, a current controlling TFT 612, and a first electrode 613 electrically connected to a drain thereof. Note that an insulator 614 is formed to cover an end portion of the first electrode 613. The insulator 614 can be formed using a positive photosensitive resin film.

In order to improve the coverage with a film formed over the insulator 614, the insulator 614 is formed to have a surface with curvature at its upper end portion or lower end portion. For example, in the case where photosensitive acrylic is used as a material of the insulator 614, only the upper end portion of the insulator 614 preferably has a curved surface. The radius of curvature of the curved surface is preferably greater than or equal to 0.2 μm and less than or equal to 0.3 μm. Either a negative or positive photosensitive material can be used as the insulator 614.

An EL layer 616 and a second electrode 617 are each formed over the first electrode 613. Here, as a material used for the first electrode 613 functioning as an anode, a material with a high work function is desirably used. For example, a single-layer film of an ITO film, an indium tin oxide film containing silicon, an indium oxide film containing zinc oxide at 2 wt % or higher and 20 wt % or lower, a titanium nitride film, a chromium film, a tungsten film, a Zn film, a Pt film, or the like, a stacked layer of titanium nitride and a film containing aluminum as its main component, a three-layer structure of a titanium nitride film, a film containing aluminum as its main component, and a titanium nitride film, or the like can be used. Note that the stacked-layer structure enables low wiring resistance, a favorable ohmic contact, and a function as an anode.

The EL layer 616 is formed by a variety of methods such as an evaporation method using an evaporation mask, an inkjet method, and a spin coating method. A material contained in the EL layer 616 may be a low molecular compound or a high molecular compound (including an oligomer or a dendrimer).

As a material used for the second electrode 617, which is formed over the EL layer 616 and functions as a cathode, a material with a low work function (e.g., Al, Mg, Li, Ca, or an alloy or a compound thereof, such as MgAg, MgIn, or AlLi) is preferably used. Note that in the case where light generated in the EL layer 616 passes through the second electrode 617, a stacked layer of a thin metal film and a transparent conductive film (e.g., ITO, indium oxide containing zinc oxide at 2 wt % or higher and 20 wt % or lower, indium tin oxide containing silicon, or zinc oxide (ZnO)) is preferably used for the second electrode 617.

Note that the first electrode 613, the EL layer 616, and the second electrode 617 constitute a light-emitting element 618. The light-emitting element 618 is preferably a light-emitting element having the structures described in Embodiment 1 and Embodiment 2. In the light-emitting device of this embodiment, the pixel portion, which includes a plurality of light-emitting elements, may include both the light-emitting element with the structure described in Embodiment 1 and Embodiment 2 and a light-emitting element with another structure.

The sealing substrate 604 and the element substrate 610 are attached to each other with the sealant 605, so that a structure in which the light-emitting element 618 is provided in the space 607 surrounded by the element substrate 610, the sealing substrate 604, and the sealant 605 is formed. Note that the space 607 is filled with a filler, and may be filled with an inert gas (nitrogen, argon, or the like) or a resin and/or a desiccant.

Note that an epoxy-based resin or glass frit is preferably used for the sealant 605. Furthermore, these materials are preferably materials that transmit as little moisture or oxygen as possible. As a material used for the sealing substrate 604, a plastic substrate formed of FRP (Fiber Reinforced Plastics), PVF (polyvinyl fluoride), polyester, acrylic, or the like can be used in addition to a glass substrate and a quartz substrate.

As described above, the light-emitting device using the light-emitting elements described in Embodiment 1 and Embodiment 3 can be obtained.

### <Structure Example 1 of Light-Emitting Device>

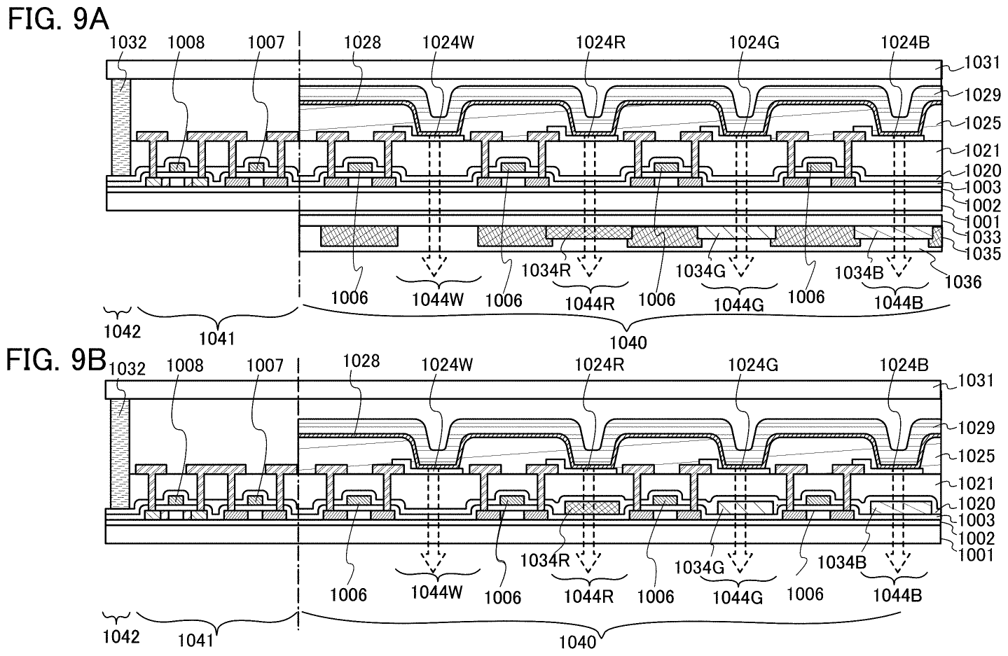

As an example of a light-emitting device, FIG. 9 illustrates a light-emitting device in which a light-emitting element exhibiting white light emission is formed and a coloring layer (a color filter) is formed.

FIG. 9(A) illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition wall 1026, an EL layer 1028, a second electrode 1029 of the light-emitting elements, a sealing substrate 1031, a sealant 1032, a red pixel 1044R, a green pixel 1044G, a blue pixel 1044B, a white pixel 1044W, and the like.

In FIG. 9(A) and FIG. 9(B), coloring layers (a red coloring layer 1034R, a green coloring layer 1034G, and a blue coloring layer 1034B) are provided on a transparent base material 1033. A black layer (black matrix) 1035 may be additionally provided. The transparent base material 1033 provided with the coloring layers and the black layer is positioned and fixed to the substrate 1001. Note that the coloring layers and the black layer are covered with an overcoat layer 1036. In FIG. 9(A), there are a light-emitting layer from which light is emitted to the outside without passing through the coloring layer and light-emitting layers from which light is emitted to the outside through the coloring layers of the respective colors. The light that does not pass through the coloring layers is white, and the light that passes through the coloring layers is red, green, and blue, so that an image can be displayed using pixels of the four colors.

FIG. 9(B) illustrates an example in which the red coloring layer 1034R, the green coloring layer 1034G, and the blue coloring layer 1034B are formed between the gate insulating film 1003 and the first interlayer insulating film 1020. As illustrated in FIG. 9(B), the coloring layers may be provided between the substrate 1001 and the sealing substrate 1031.

The above-described light-emitting device is a light-emitting device having a structure in which light is extracted on the substrate 1001 side where the TFTs are formed (bottom emission type), but may be a light-emitting device having a structure in which light is extracted on the sealing substrate 1031 side (top emission type).

### <Structure Example 2 of Light-Emitting Device>

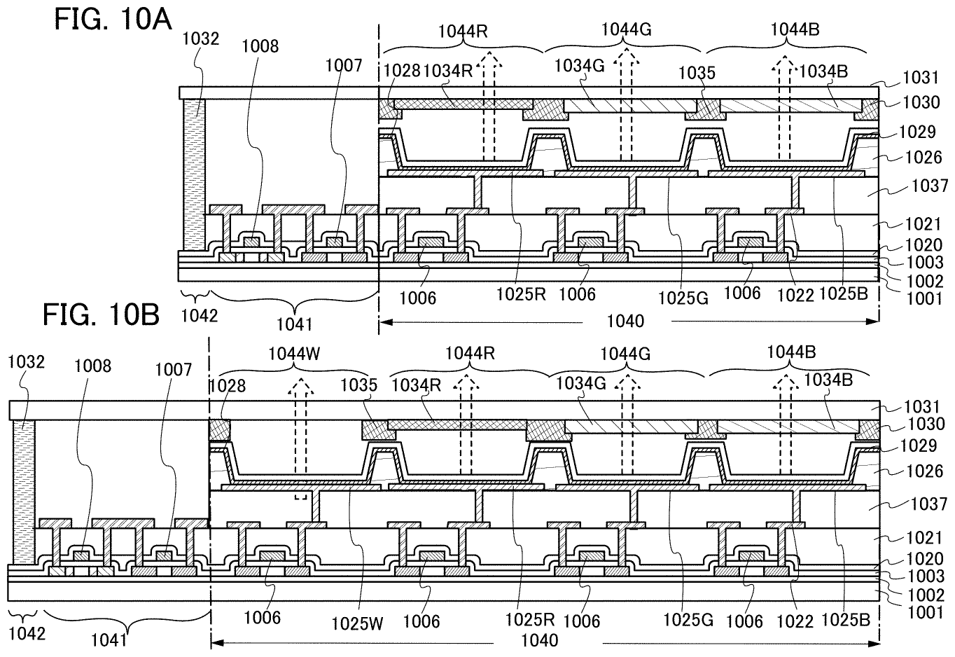

FIG. 10(A) and FIG. 10(B) each illustrate a cross-sectional view of a top-emission light-emitting device. In this case, a substrate that does not transmit light can be used as the substrate 1001. The process up to the formation of a connection electrode that connects the TFT and the anode of the light-emitting element is performed in a manner similar to that of a bottom-emission light-emitting device. Then, a third interlayer insulating film 1037 is formed to cover an electrode 1022. This insulating film may have a planarization function. The third interlayer insulating film 1037 can be formed using a material similar to that of the second interlayer insulating film 1021 or using other various materials.

A lower electrode 1025W, a lower electrode 1025R, a lower electrode 1025G, and a lower electrode 1025B of the light-emitting elements are anodes here, but may be cathodes. Furthermore, in the case of the top-emission light-emitting device illustrated in FIG. 10(A) and FIG. 10(B), the lower electrode 1025W, the lower electrode 1025R, the lower electrode 1025G, and the lower electrode 1025B are preferably reflective electrodes. Note that the second electrode 1029 preferably has a function of reflecting light and a function of transmitting light. A microcavity structure is preferably employed between the second electrode 1029 and the lower electrode 1025W, the lower electrode 1025R, the lower electrode 1025G, and the lower electrode 1025B, in which case light with a specific wavelength is amplified. The structure of the EL layer 1028 is an element structure similar to the structures described in Embodiment 1 and Embodiment 3, with which white light emission can be obtained.

In FIG. 9(A), FIG. 9(B), FIG. 10(A), and FIG. 10(B), the structure of the EL layer for providing white light emission can be achieved by, for example, using a plurality of light-emitting layers or using a plurality of light-emitting units. Note that the structure providing white light emission is not limited thereto.

In the top emission structure illustrated in FIG. 10(A) and FIG. 10(B), sealing can be performed with the sealing substrate 1031 on which the coloring layers (the red coloring layer 1034R, the green coloring layer 1034G, and the blue coloring layer 1034B) are provided. The sealing substrate 1031 may be provided with a black layer (black matrix) 1030 that is positioned between pixels. The coloring layers (the red coloring layer 1034R, the green coloring layer 1034G, and the blue coloring layer 1034B) and a black layer (black matrix) 1035 may be covered with an overcoat layer. Note that a substrate having a light-transmitting property is used as the sealing substrate 1031.

FIG. 10(A) illustrates a structure in which full color display is performed using three colors of red, green, and blue; alternatively, full color display may be performed using four colors of red, green, blue, and white as illustrated in FIG. 10(B). The structure performing full color display is not limited to them. For example, full color display may be performed using four colors of red, green, blue, and yellow.

In the light-emitting element of one embodiment of the present invention, a fluorescent material is used as a guest material. Since a fluorescent material has a sharper spectrum than a phosphorescent material, light emission with high color purity can be obtained. Accordingly, when the light-emitting element is used for the light-emitting device described in this embodiment, the light-emitting device can have high color reproducibility.

As described above, the light-emitting device using the light-emitting elements described in Embodiment 1 and Embodiment 3 can be obtained.

Note that this embodiment can be combined as appropriate with the other embodiments.

### Embodiment 5

In this embodiment, electronic appliances and display devices of embodiments of the present invention will be described.

According to one embodiment of the present invention, an electronic appliance and a display device that have a flat surface, favorable emission efficiency, and high reliability can be manufactured. In addition, an electronic appliance and a display device that have a curved surface, favorable emission efficiency, and high reliability can be manufactured according to one embodiment of the present invention. Moreover, a light-emitting element having high color reproducibility can be obtained as described above.

Examples of the electronic appliance include a television device, a desktop or laptop personal computer, a monitor of a computer or the like, a digital camera, a digital video camera, a digital photo frame, a mobile phone, a portable game machine, a portable information terminal, an audio reproducing device, and a large game machine such as a pachinko machine.

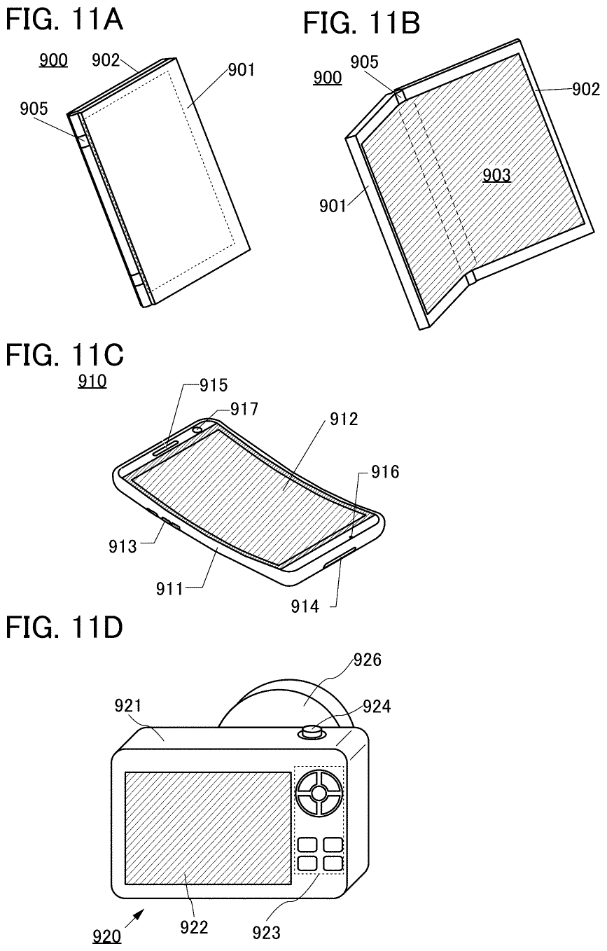

A portable information terminal 900 illustrated in FIGS. 11(A) and 11(B) includes a housing 901, a housing 902, a display portion 903, a hinge portion 905, and the like.

The housing 901 and the housing 902 are joined together with the hinge portion 905. The portable information terminal 900 can be opened as illustrated in FIG. 11(B) from a folded state (FIG. 11(A)). Thus, the portable information terminal 900 has high portability when carried and has excellent visibility when used because of its large display region.

In the portable information terminal 900, the flexible display portion 903 is provided across the housing 901 and the housing 902 which are joined together with the hinge portion 905.

The light-emitting device manufactured using one embodiment of the present invention can be used for the display portion 903. Thus, a highly reliable portable information terminal can be manufactured.

The display portion 903 can display at least one of document data, a still image, a moving image, and the like. When document data is displayed on the display portion, the portable information terminal 900 can be used as an e-book reader.

When the portable information terminal 900 is opened, the display portion 903 is held with a large radius of curvature. For example, the display portion 903 is held while including a curved portion with a radius of curvature of greater than or equal to 1 mm and less than or equal to 50 mm, preferably greater than or equal to 5 mm and less than or equal to 30 mm. Part of the display portion 903 can display an image while being curved since pixels are continuously arranged from the housing 901 to the housing 902.

The display portion 903 functions as a touch panel and can be controlled with a finger, a stylus, or the like.

The display portion 903 is preferably formed using one flexible display. Thus, a seamless, continuous image can be displayed between the housing 901 and the housing 902. Note that a structure in which each of the housing 901 and the housing 902 is provided with a display may be employed.

The hinge portion 905 preferably includes a locking mechanism so that an angle formed by the housing 901 and the housing 902 does not become larger than a predetermined angle when the portable information terminal 900 is opened. For example, an angle at which they become locked (they are not opened any further) is preferably greater than or equal to 90° and less than 180° and can be typically 90°, 120°, 135°, 150°, 175°, or the like. In this way, the convenience, safety, and reliability of the portable information terminal 900 can be improved.

When the hinge portion 905 includes a locking mechanism, excessive force is not applied to the display portion 903; thus, breakage of the display portion 903 can be prevented. Therefore, a highly reliable portable information terminal can be achieved.

The housing 901 and the housing 902 may be provided with a power button, an operation button, an external connection port, a speaker, a microphone, or the like.

One of the housing 901 and the housing 902 is provided with a wireless communication module, and data can be transmitted and received through a computer network such as the Internet, a LAN (Local Area Network), or Wi-Fi (registered trademark).

A portable information terminal 910 illustrated in FIG. 11(C) includes a housing 911, a display portion 912, an operation button 913, an external connection port 914, a speaker 915, a microphone 916, a camera 917, and the like.

The light-emitting device manufactured using one embodiment of the present invention can be used for the display portion 912. Thus, the portable information terminal can be manufactured with a high yield.

The portable information terminal 910 includes a touch sensor in the display portion 912. A variety of operations such as making a call and inputting a character can be performed by touch on the display portion 912 with a finger, a stylus, or the like.

In addition, with operation of the operation button 913, the power can be turned ON and OFF and types of images displayed on the display portion 912 can be switched. For example, a mail creation screen can be switched to a main menu screen.

When a sensing device such as a gyroscope sensor or an acceleration sensor is provided inside the portable information terminal 910, the direction of display on the screen of the display portion 912 can be automatically switched by determining the orientation (horizontal or vertical) of the portable information terminal 910. Furthermore, the direction of display on the screen can be switched by touch on the display portion 912, operation of the operation button 913, sound input using the microphone 916, or the like.

The portable information terminal 910 has, for example, one or more functions selected from a telephone set, a notebook, an information browsing system, and the like. Specifically, it can be used as a smartphone. The portable information terminal 910 is capable of executing a variety of applications such as mobile phone calls, e-mailing, text viewing and writing, music playback, video playback, Internet communication, and games, for example.

A camera 920 illustrated in FIG. 11(D) includes a housing 921, a display portion 922, operation buttons 923, a shutter button 924, and the like. Furthermore, a detachable lens 926 is attached to the camera 920.

The light-emitting device manufactured using one embodiment of the present invention can be used for the display portion 922. Thus, a highly reliable camera can be manufactured.

Although the camera 920 here is configured such that the lens 926 is detachable from the housing 921 for replacement, the lens 926 may be integrated with the housing 921.

A still image or a moving image can be taken with the camera 920 at the press of the shutter button 924. The display portion 922 has a function of a touch panel, and images can also be taken by the touch on the display portion 922.

Note that a stroboscope, a viewfinder, or the like can be additionally attached to the camera 920. Alternatively, they may be incorporated into the housing 921.

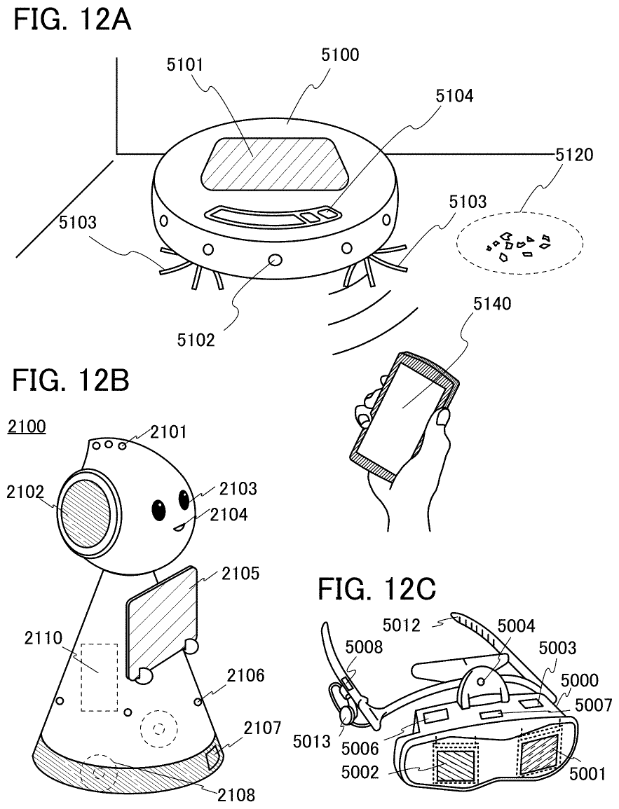

FIG. 12(A) is a schematic view illustrating an example of a cleaning robot.

A cleaning robot 5100 includes a display 5101 placed on its top surface, a plurality of cameras 5102 placed on its side surface, a brush 5103, and operation buttons 5104. Although not illustrated, the bottom surface of the cleaning robot 5100 is provided with a tire, an inlet, and the like. Furthermore, the cleaning robot 5100 includes a variety of sensors such as an infrared sensor, an ultrasonic sensor, an acceleration sensor, a piezoelectric sensor, an optical sensor, and a gyroscope sensor. In addition, the cleaning robot 5100 has a wireless communication means.

The cleaning robot 5100 is self-propelled, detects dust 5120, and sucks up the dust through the inlet provided on its bottom surface.

The cleaning robot 5100 can determine whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of vacuumed dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic appliance 5140 such as a smartphone. The portable electronic appliance 5140 can display images taken by the cameras 5102. Accordingly, an owner of the cleaning robot 5100 can monitor the room even from the outside. The display on the display 5101 can be checked by the portable electronic appliance 5140 such as a smartphone.

The light-emitting device of one embodiment of the present invention can be used for the display 5101.

A robot 2100 illustrated in FIG. 12(B) includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting the speaking voice of a user, environmental sounds, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect the presence of an obstacle in the direction where the robot 2100 moves forward with the moving mechanism 2108. The robot 2100 can move safely by recognizing the surroundings with the upper camera 2103, the lower camera 2106, and the obstacle sensor 2107.

The light-emitting device of one embodiment of the present invention can be used for the display 2105.

FIG. 12(C) illustrates an example of a goggle-type display. The goggle-type display includes, for example, a housing 5000, a display portion 5001, a speaker 5003, an LED lamp 5004, an operation key 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared ray), a microphone 5008, a second display portion 5002, a support 5012, and an earphone 5013.

The light-emitting device of one embodiment of the present invention can be used for the display portion 5001 and the second display portion 5002.

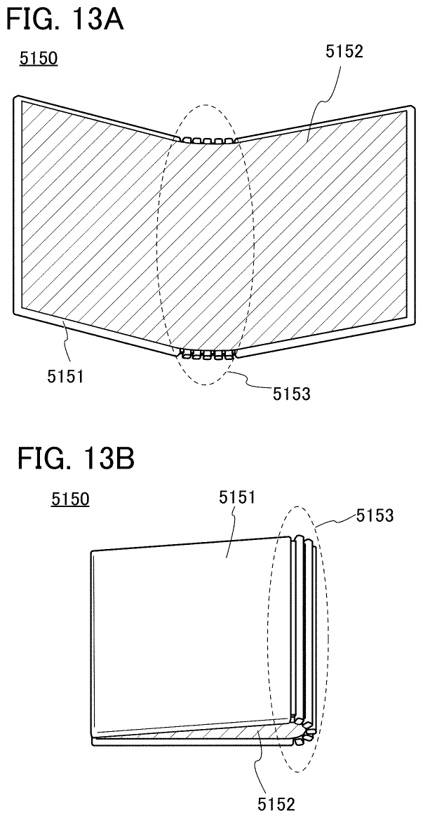

FIGS. 13(A) and 13(B) illustrate a foldable portable information terminal 5150. The foldable portable information terminal 5150 includes a housing 5151, a display region 5152, and a bend portion 5153. FIG. 13(A) illustrates the portable information terminal 5150 that is opened. FIG. 13(B) illustrates the portable information terminal 5150 that is folded. Despite its large display region 5152, the portable information terminal 5150 is compact in size and has excellent portability when folded.

The display region 5152 can be folded in half with the bend portion 5153. The bend portion 5153 is formed of a stretchable member and a plurality of supporting members; in the case where the display region is folded, the stretchable member stretches and the bend portion 5153 has a radius of curvature of 2 mm or more, preferably 5 mm or more.

Note that the display region 5152 may be a touch panel (input/output device) including a touch sensor (input device). The light-emitting device of one embodiment of the present invention can be used for the display region 5152.

This embodiment can be combined as appropriate with the other embodiments.

### Embodiment 6

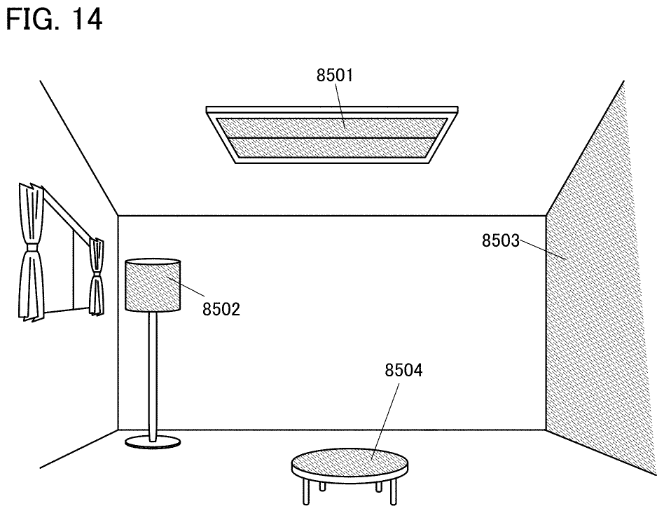

In this embodiment, examples in which the light-emitting element of one embodiment of the present invention is used for a variety of lighting devices will be described with reference to FIG. 14. With the use of the light-emitting element of one embodiment of the present invention, a highly reliable lighting device with high emission efficiency can be manufactured.

Forming the light-emitting element of one embodiment of the present invention over a flexible substrate enables an electronic appliance or a lighting device that has a light-emitting region with a curved surface to be obtained.

Furthermore, a light-emitting device in which the light-emitting element of one embodiment of the present invention is used can also be used for lighting for motor vehicles; for example, such lighting can be provided on a windshield, a ceiling, and the like.

FIG. 14 illustrates an example in which the light-emitting element is used for an indoor lighting device 8501. Since the light-emitting element can have a larger area, a lighting device having a large area can also be formed. In addition, a lighting device 8502 in which a light-emitting region has a curved surface can also be formed with the use of a housing with a curved surface. A light-emitting element described in this embodiment is in the form of a thin film, which allows the housing to be designed more freely. Thus, the lighting device can be elaborately designed in a variety of ways. Furthermore, a wall of the room may be provided with a large-sized lighting device 8503. The lighting devices 8501, 8502, and 8503 may be provided with a touch sensor to be turned on or off

Moreover, when the light-emitting element is used on the surface side of a table, a lighting device 8504 which has a function of a table can be obtained. When the light-emitting element is used as part of other furniture, a lighting device having a function of the furniture can be obtained.

As described above, lighting devices and electronic appliances can be obtained by application of the light-emitting element of one embodiment of the present invention. Note that the light-emitting element can be used for lighting devices and electronic appliances in a variety of fields without being limited to the lighting devices and the electronic appliances described in this embodiment.

The structure described in this embodiment can be used in appropriate combination with the structures described in the other embodiments.

### Example 1

In this example, fabrication examples of a light-emitting element of one embodiment of the present invention and a comparative light-emitting element and the characteristics of the light-emitting elements are described. The structure of each of the light-emitting elements fabricated in this example is the same as that in FIG. 1(A). Table 1 show the details of the element structures.

The structures and abbreviations of compounds that were used are shown below.

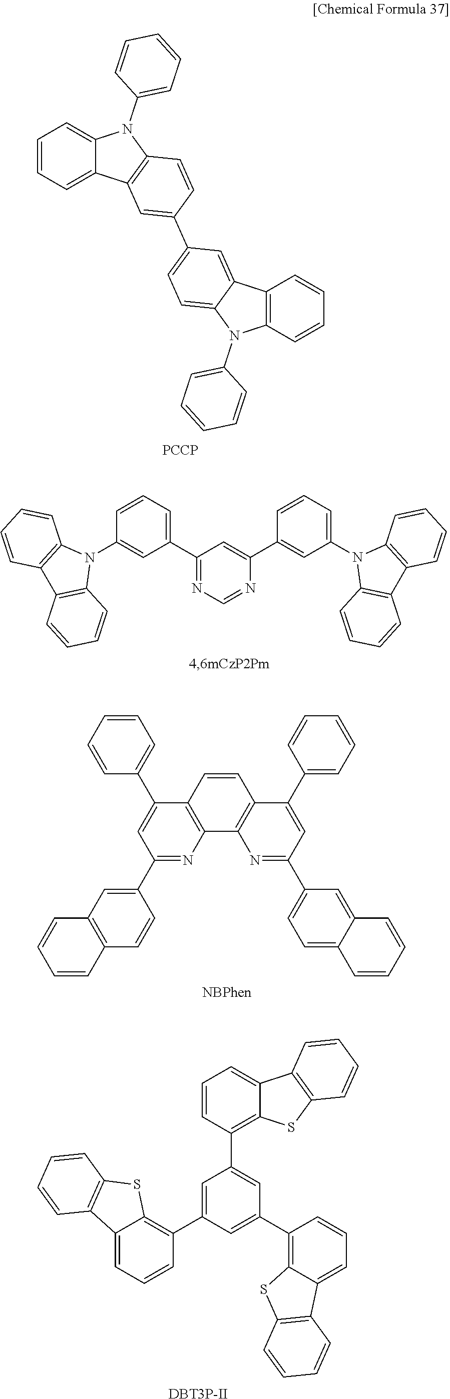

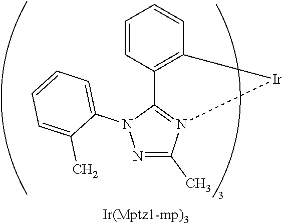

TABLE 1

| | | | Thickness | | Weight |
|---|---|---|---|---|---|
| | Layer | Numeral | (nm) | Material | ratio |
| Comparative | Electrode | 102 | 200 | Al | — |
| light- | Electron-injection | 119 | 1 | LiF | — |
| emitting | layer | | | | |
| element | Electron-transport | 118(2) | 10 | NBphen | — |
| 1 | layer | 118(1) | 20 | 4,6mCzP2Pm | — |
| | Light-emitting layer | 130 | 40 | 4,6mCzP2Pm:Ir(Mptzl-mp)₃ | 0.8:0.2 |
| | Hole-transport layer | 112 | 20 | PCCP | — |
| | Hole-injection layer | 111 | 40 | DBT3P-II:MoO₃ | 1:0.5 |
| | Electrode | 101 | 70 | ITSO | — |
| Light- | Electrode | 102 | 200 | Al | — |
| emitting | Electron-injection | 119 | 1 | LiF | — |
| element | layer | | | | |
| 2 | Electron-transport | 118(2) | 10 | NBphen | — |
| | layer | 118(1) | 20 | 4,6mCzP2Pm | — |
| | Light-emitting layer | 130 | 40 | 4,6mCzP2Prnir(Mptzl-mp)₃: | 0.8:0.2:0.01 |
| | | | | 2tBu-ptBuDPhA2Anth | |
| | Hole-transport layer | 112 | 20 | PCCP | — |
| | Hole-injection layer | 111 | 40 | DBT3P-II:MoO₃ | 1:0.5 |
| | Electrode | 101 | 70 | ITSO | — |

### <Fabrication of Light-Emitting Element>

Fabrication methods of the light-emitting element fabricated in this example will be described below.

### <<Fabrication of Comparative Light-Emitting Element 1>>

As the electrode 101, an ITSO film was formed to a thickness of 70 nm over a glass substrate. Note that the electrode area of the electrode 101 was set to 4 mm² (2 mm×2 mm).

Next, as the hole-injection layer 111, DBT3P-II and molybdenum oxide (MoO₃) were deposited over the electrode 101 by co-evaporation in a weight ratio (DBT3P-II:MoO₃) of 1:0.5 to a thickness of 40 nm.

Then, as the hole-transport layer 112, PCCP was deposited on the hole-injection layer 111 by evaporation to a thickness of 20 nm.

Next, as the light-emitting layer 130, 4,6mCzP2Pm and Ir(Mptz1-mp)₃ were deposited over the hole-transport layer 112 by co-evaporation at a weight ratio (4,6mCzP2Pm:Ir(Mptz1-mp)₃) of 0.8:0.2 to a thickness of 40 nm. In the light-emitting layer 130, Ir(Mptz1-mp)₃ is a phosphorescent material containing Ir and 4,6mCzP2Pm and Ir(Mptz1-mp)₃ form an exciplex in combination.

Next, as the electron-transport layer 118, 4,6mCzP2Pm and NBPhen were sequentially deposited by evaporation to a thickness of 20 nm and to a thickness of 10 nm, respectively, over the light-emitting layer 130. Then, as the electron-injection layer 119, LiF was deposited on the electron-transport layer 118 by evaporation to a thickness of 1 nm.

Next, as the electrode 102, aluminum (Al) was formed over the electron-injection layer 119 to a thickness of 200 nm.

Next, in a glove box containing a nitrogen atmosphere, a comparative light-emitting element 1 was sealed by fixing a glass substrate for sealing to the glass substrate on which the organic materials were formed using a sealant for organic EL. Specifically, the sealant was applied to the periphery of the organic materials formed on the glass substrate, the glass substrate was bonded to the glass substrate for sealing, irradiation with ultraviolet light having a wavelength of 365 nm at 6 J/cm² was performed, and heat treatment at 80° C. for one hour was performed. Through the above steps, the comparative light-emitting element 1 was obtained.

### <<Fabrication of Light-Emitting Element 2>>

A light-emitting element 2 is different from the above-described comparative light-emitting element 1 only in the component of the light-emitting layer 130, and other steps of the fabrication method are the same as those for the comparative light-emitting element 1. The details of the element structures are as shown in Table 1; thus, the details of the fabrication methods are omitted. Note that 2-tert-butyl-N,N,N′,N′-tetrakis(4-tert-butylphenyl)-9,10-anthracenediamine (abbreviation: 2tBu-ptBuDPhA2Anth), which is an organic compound represented by Structural Formula (100), is a guest material including protecting groups around a luminophore in the light-emitting layer 130 of the light-emitting element 2.

### <Characteristics of Light-Emitting Elements>

Next, the characteristics of the fabricated comparative light-emitting element 1 and light-emitting element 2 were measured. Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.).

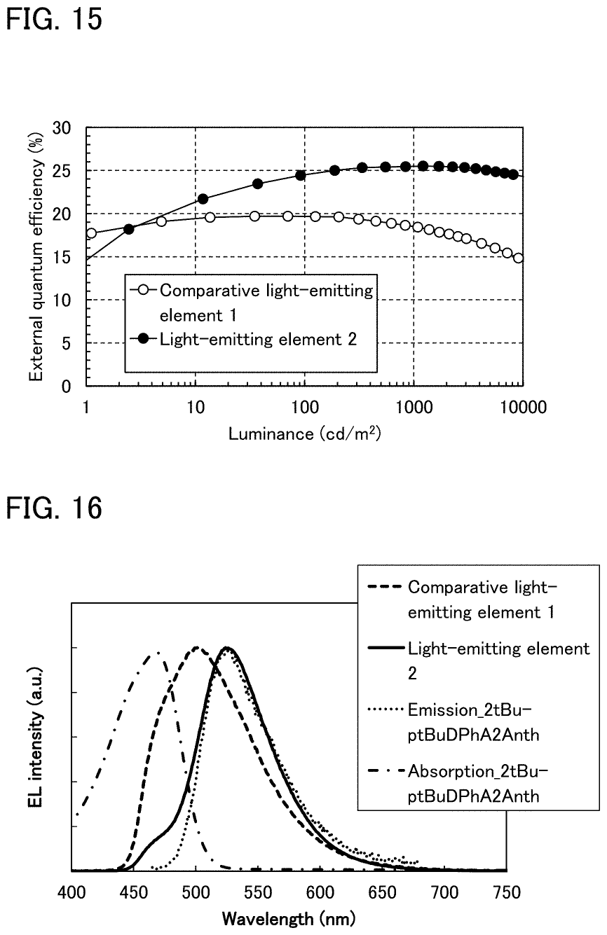

FIG. 15 shows the external quantum efficiency-luminance characteristics of the comparative light-emitting element 1 and the light-emitting element 2. FIG. 16 shows the electroluminescence spectra of the comparative light-emitting element 1 and the light-emitting element 2 to which a current at a current density of 2.5 mA/cm² was supplied. Note that the measurements of the light-emitting elements were performed at room temperature (in an atmosphere maintained at 23° C.). FIG. 16 also shows absorption and emission spectra of a toluene solution of 2tBu-ptBuDPhA2Anth, which is the guest material of the light-emitting element 2.

Note that an ultraviolet-visible light spectrophotometer (V550, manufactured by JASCO Corporation) was used for measuring the absorption and emission spectra of the toluene solution of 2tBu-ptBuDPhA2Anth. The absorption and emission spectra shown in FIG. 16 were each obtained by subtraction of the measured spectrum of toluene only put in a quartz cell from the spectrum of the toluene solution of 2tBu-ptBuDPhA2Anth.

Table 2 shows the element characteristics of the comparative light-emitting element 1 and the light-emitting element 2 at around 1000 cd/m².

TABLE 2

| | | Current | CIE | | Current | Power | External quantum |
|---|---|---|---|---|---|---|---|
| | Voltage | density | chromaticity | Luminance | efficiency | efficiency | efficiency |
| | (v) | (mA/cm²) | (x, y) | (cd/m²) | (cd/A) | (lm/W) | (%) |
| Comparative | 3.50 | 2.22 | (0.213, 0.468) | 1087 | 49.0 | 44.0 | 18.4 |
| light-emitting | | | | | | | |
| element 1 | | | | | | | |
| Light-emitting | 3.10 | 0.94 | (0.272, 0.613) | 839 | 88.8 | 90.0 | 25.4 |
| element 2 | | | | | | | |

As shown in FIG. 16, the emission spectrum of the comparative light-emitting element 1 had a peak wavelength of 502 nm and a half width of 91 nm. This is different from the emission spectra obtained from 4,6mCzP2Pm and Ir(Mptz1-mp)₃, indicating that light emission obtained from the comparative light-emitting element 1 is light emission of the exciplex formed by 4,6mCzP2Pm and Ir(Mptz1-mp)₃. In addition, the emission spectrum of the light-emitting element 2 had a peak wavelength of 524 nm and a half width of 67 nm. Although the emission spectrum of the light-emitting element 2 is green light emission originating mainly from 2tBu-ptBuDPhA2Anth, the emission spectrum of the light-emitting element 2 is different from the emission spectrum of 2tBu-ptBuDPhA2Anth as shown in FIG. 16.

Here, the emission spectrum of the light-emitting element 2 includes the light emission at around 440 nm to around 470 nm, which is different from that of 2tBu-ptBuDPhA2Anth. The light-emitting element 2 includes the exciplex of 4,6mCzP2Pm and Ir(Mptz1-mp)₃ as a material exhibiting light emission and 2tBu-ptBuDPhA2Anth, which is the guest material. The light emission at around 440 nm to around 470 nm is also included in the exciplex of 4,6mCzP2Pm and Ir(Mptz1-mp)₃ as shown in FIG. 16. The light emission from both the exciplex and the guest material was thus found to be obtained from the light-emitting element 2 according to the above description and FIG. 16. As described above, multicolor light emission can be obtained from the light-emitting element of one embodiment of the present invention. Furthermore, the excitation energy of the exciplex can contribute to the light emission of the exciplex and the light emission of the guest material, as shown in FIG. 4(C).

Although the light-emitting element 2 exhibits light emission originating from the fluorescent material, it exhibited very high emission efficiency with an external quantum efficiency exceeding 25% as shown in FIG. 15 and Table 2. According to the results, since the fluorescent material including protecting groups around a luminophore is used in the light-emitting element of one embodiment of the present invention, non-radiative deactivation of triplet excitons is inhibited, and both the singlet excitation energy and the triplet excitation energy are efficiently converted into the light emission of the fluorescent material and the exciplex.

Since the generation probability of singlet excitons which are generated by recombination of carriers (holes and electrons) injected from the pair of electrodes is at most 25%, the external quantum efficiency of a fluorescent element in the case where the light extraction efficiency to the outside is 30% is at most 7.5%. However, the light-emitting element 2 has external quantum efficiency higher than 7.5%. This is because, in addition to light emission originating from singlet excitons generated by recombination of carriers (holes and electrons) injected from the pair of electrodes, light emission originating from energy transfer from triplet excitons or light emission originating from singlet excitons generated from triplet excitons by reverse intersystem crossing in the exciplex is obtained from the fluorescent material. That is, the light-emitting element 2 can be regarded as a light-emitting element utilizing ExEF.

### <CV Measurement Results>

Then, the electrochemical characteristics (oxidation reaction characteristics and reduction reaction characteristics) of 4,6mCzP2Pm and Ir(MPtz1-mp)₃ used for the light-emitting layers of the light-emitting elements were measured by cyclic voltammetry (CV) measurement. The measurement method and the calculation method are shown below.

An electrochemical analyzer (ALS model 600A or 600C, manufactured by BAS Inc.) was used as the measurement apparatus. A solution for the CV measurement was prepared in the following manner: tetra-n-butylammonium perchlorate (n-Bu₄NClO₄, produced by Tokyo Chemical Industry Co., Ltd., catalog No. T0836) as a supporting electrolyte was dissolved in dehydrated dimethylformamide (DMF, produced by Sigma-Aldrich Co. LLC., 99.8%, catalog No. 22705-6) as a solvent at a concentration of 100 mmol/L, and the object to be measured was dissolved therein at a concentration of 2 mmol/L. A platinum electrode (PTE platinum electrode, manufactured by BAS Inc.) was used as a working electrode, another platinum electrode (Pt counter electrode for VC-3 (5 cm), manufactured by BAS Inc.) was used as an auxiliary electrode, and an Ag/Ag⁺ electrode (RE7 reference electrode for nonaqueous solvent, manufactured by BAS Inc.) was used as a reference electrode. Note that the measurement was performed at room temperature (20 to 25° C.). In addition, the scan speed in the CV measurement was fixed to 0.1 V/sec, and an oxidation potential Ea [V] and a reduction potential Ec [V] with respect to the reference electrode were measured. The potential Ea is an intermediate potential of an oxidation-reduction wave, and the potential Ec is an intermediate potential of a reduction-oxidation wave. Here, since the potential energy of the reference electrode used in this example with respect to the vacuum level is known to be −4.94 [eV], the HOMO level and the LUMO level can be calculated by the following formulae: HOMO level [eV]=−4.94-Ea and LUMO level [eV]=−4.94-Ec.

According to the CV measurement results, the oxidation potential of 4,6mCzP2Pm was 0.95 V and the reduction potential was −2.06 V. In addition, the HOMO level of 4,6mCzP2Pm, which was calculated from the CV measurement, was −5.89 eV and the LUMO level was −2.88 eV. The oxidation potential of Ir(Mptz1-mp)₃ was 0.49 V and the reduction potential was −3.17 V. The HOMO level of Ir(Mptz1-mp)₃, which was calculated from the CV measurement, was −5.39 eV and the LUMO level was −1.77 eV.

As described above, the LUMO level of 4,6mCzP2Pm is lower than the LUMO level of Ir(Mptz1-mp)₃, and the HOMO level of Ir(Mptz1-mp)₃ is higher than the HOMO level of 4,6mCzP2Pm. Thus, in the case where the compounds are used in a light-emitting layer, electrons and holes are efficiently injected into 4,6mCzP2Pm and Ir(Mptz1-mp)₃, respectively, so that 4,6mCzP2Pm and Ir(Mptz1-mp)₃ can form an exciplex.

It is also found that an absorption band on the longest wavelength side of the absorption spectrum of 2tBu-ptBuDPhA2Anth and the emission spectrum of the exciplex overlap with each other according to FIG. 16. Therefore the light-emitting element 2 is capable of emitting light by receiving excitation energy of the above-described exciplex.

Note that the emission spectrum obtained from the exciplex of 4,6mCzP2Pm and Ir(Mptz1-mp)₃ has a peak on the shorter wavelength side than the emission spectrum obtained from 2tBu-ptBuDPhA2Anth as shown in FIG. 16. Thus, the excitation energy of the exciplex can transfer to 2tBu-ptBuDPhA2Anth efficiently. Accordingly, a multicolor light-emitting element with high emission efficiency can be fabricated according to one embodiment of the present invention.

### <Reliability Measurement of Light-Emitting Elements>

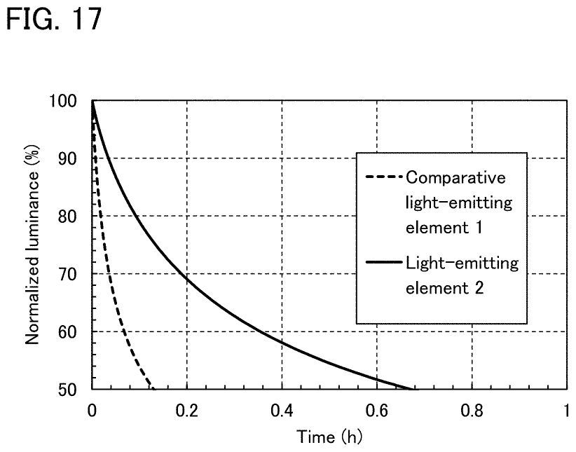

Next, driving tests at a constant current of 2.0 mA were performed on the comparative light-emitting element 1 and the light-emitting element 2. The results are shown in FIG. 17. The light-emitting element 2 including the fluorescent material in the light-emitting layer has higher reliability than the comparative light-emitting element 1 as shown in FIG. 17. This indicates that the addition of the fluorescent material enables excitation energy in the light-emitting layer to be efficiently converted into light emission. Since the emission speed of the fluorescent material is high, molecules in an excited state in the light-emitting layer can immediately return to a ground state by transferring the excitation energy to the fluorescent material. For this reason, the addition of the fluorescent material can inhibit degradation of a molecule or generation of a quenching factor, which might cause luminance degradation. If a general fluorescent material is used in a triplet sensitizing element, triplet excitons in the light-emitting layer are deactivated, so that a light-emitting element having high emission efficiency and high reliability is difficult to fabricate. However, since the light-emitting element of one embodiment of the present invention uses the fluorescent material including protecting groups around a luminophore, deactivation of triplet excitons can be inhibited. Consequently, a light-emitting element with high efficiency and high reliability can be fabricated.

According to the light-emitting element of one embodiment of the present invention, a multicolor light-emitting element with high efficiency and high reliability can be provided as described above.

### Example 2

In this example, fabrication examples of light-emitting elements of one embodiment of the present invention and comparative light-emitting elements, which are different from those in the above example, and the characteristics of the light-emitting elements are described. The structure of each of the light-emitting elements fabricated in this example is the same as that in FIG. 1(A). Table 3 show the details of the element structures. The structures and abbreviations of compounds that were used are shown below. Note that the above example and embodiments can be referred to for other organic compounds.

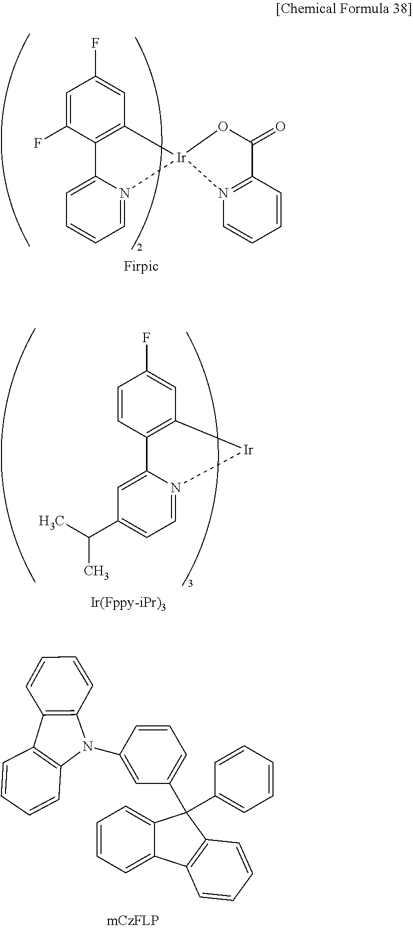

TABLE 3

| | | | Thickness | | |
|---|---|---|---|---|---|
| | Layer | Numeral | (nm) | Material | Weight ratio |
| Comparative | Electrode | 102 | 200 | Al | — |
| light-emitting | Electron-injection | 119 | 1 | LiF | — |
| element | layer | | | | |
| 3 | Electron-transport | 118(2) | 10 | NBphen | — |
| | layer | 118(1) | 20 | 4,6mCzP2Pm | — |
| | Light-emitting | 130(2) | 20 | 4,6mCzP2Pm:PCCP:Firpic | 0.8:0.2:0.1 |
| | layer | 130(1) | 20 | 4,6mCzP2Pm:PCCP:Firpic | 0.5:0.5:0.1 |
| | Hole-transport | 112 | 20 | PCCP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Light-emitting | Electrode | 102 | 200 | Al | — |
| element | Electron-injection | 119 | 1 | LiF | — |
| 4 | layer | | | | |
| | Electron-transport | 118(2) | 10 | NBphen | — |
| | layer | 118(1) | 20 | 4,6mCzP2Pm | — |
| | Light-emitting | 130(2) | 20 | 4,6mCzP2Pm:PCCPFirpic: | 0.8:0.2:0.1:0.01 |
| | layer | | | 2tBu-ptBuDPhA2Anth | |
| | | 130(1) | 20 | 4,6mCzP2Pm:PCCPFirpic: | 0.5:0.5:0.1:0.01 |
| | | | | 2tBu-ptBuDPhA2Anth | |
| | Hole-transport | 112 | 20 | PCCP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Comparative | Electrode | 102 | 200 | Al | — |
| light-emitting | Electron-injection | 119 | 1 | LiF | — |
| element | layer | | | | |
| 5 | Electron-transport | 118(2) | 10 | NBphen | — |
| | layer | 118(1) | 20 | 4,6mCzP2Pm | — |
| | Light-emitting | 130(2) | 20 | 4,6mCzP2Pm:PCCP:Ir(Fppy-iPr)₃ | 0.8:0.2:0.1 |
| | layer | 130(1) | 20 | 4,6mCzP2Pm:PCCP:Ir(Fppy-iPr)₃ | 0.5:0.5:0.1 |
| | Hole-transport | 112 | 20 | mCzFLP | — |
| | layer | | | | |
| | Hole-injection | 111 | 30 | DBT3P-II:MoO₃ | 1:0.5 |
| | layer | | | | |
| | Electrode | 101 | 70 | ITSO | — |
| Light-emitting | Electrode | 102 | 200 | Al | — |
| element | Electron-injection | 119 | 1 | LiF | — |
| 6 | layer | | | | |
| | Electron-transport | 118(2) | 10 | NBphen | — |
| | layer | 118(1) | 20 | 4,6mCzP2Pm | — |
| | Light-emitting | 130(2) | 20 | 4,6mCzP2Pm:PCCP:Ir(Fppy-iPr)₃: | 0.8:0.2:0.1:0.01 |
| | layer | | | 2tBu-ptBuDPhA2Anth | |
| | | 130(1) | 20 | 4,6mCzP2Pm:PCCP:Ir(Fppy-iPr)₃: | 0.5:0.5:0.1:0.01 |
| | | | | 2tBu-ptBuDPhA2Anth | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |

### <Fabrication of Light-Emitting Elements>

Fabrication methods of the light-emitting elements fabricated in this example will be described below.

### <<Fabrication of Comparative Light-Emitting Element 3>>

As the electrode 101, an ITSO film was formed to a thickness of 70 nm over a glass substrate. Note that the electrode area of the electrode 101 was set to 4 mm² (2 mm×2 mm).

Next, as the hole-injection layer 111, DBT3P-II and molybdenum oxide (MoO₃) were deposited over the electrode 101 by co-evaporation in a weight ratio (DBT3P-II:MoO₃) of 1:0.5 to a thickness of 40 nm.

Then, as the hole-transport layer 112, PCCP was deposited on the hole-injection layer 111 by evaporation to a thickness of 20 nm.

Next, as a light-emitting layer 130(1), 4,6mCzP2Pm, PCCP, and Firpic were deposited over the hole-transport layer 112 by co-evaporation at a weight ratio (4,6mCzP2Pm:PCCP:Firpic) of 0.5:0.5:0.1 to a thickness of 20 nm. Successively, as a light-emitting layer 130(2), 4,6mCzP2Pm, PCCP, and Firpic were deposited over the light-emitting layer 130(1) by co-evaporation at a weight ratio (4,6mCzP2Pm:PCCP:Firpic) of 0.8:0.2:0.1 to a thickness of 20 nm.

Next, as the electron-transport layer 118, 4,6mCzP2Pm and NBPhen were sequentially deposited by evaporation to a thickness of 20 nm and to a thickness of 10 nm, respectively, over the light-emitting layer 130. Then, as the electron-injection layer 119, LiF was deposited on the electron-transport layer 118 by evaporation to a thickness of 1 nm.

Next, as the electrode 102, aluminum (Al) was formed over the electron-injection layer 119 to a thickness of 200 nm.

Next, in a glove box containing a nitrogen atmosphere, a comparative light-emitting element 3 was sealed by fixing a glass substrate for sealing to the glass substrate on which the organic materials were formed using a sealant for organic EL. Specifically, the sealant was applied to the periphery of the organic materials formed on the glass substrate, the glass substrate was bonded to the glass substrate for sealing, irradiation with ultraviolet light having a wavelength of 365 nm at 6 J/cm² was performed, and heat treatment at 80° C. for one hour was performed. Through the above steps, the comparative light-emitting element 3 was obtained.

### <<Fabrication of Light-Emitting Element 4, Comparative Light-Emitting Element 5, and Light-Emitting Element 6>>

The fabrication steps of a light-emitting element 4 are different from those of the comparative light-emitting element 3 described above in the light-emitting layer 130 while the fabrication steps of a comparative light-emitting element 5 and a light-emitting element 6 were different from those of the comparative light-emitting element 3 in the hole-transport layer 112 and the light-emitting layer 130; the other steps were the same as those of the comparative light-emitting element 3. The details of the element structures are as shown in Table 3; thus, the details of the fabrication methods are omitted.

The comparative light-emitting element 3 and the comparative light-emitting element 5 do not include a fluorescent material in the light-emitting layer 130, whereas the light-emitting element 4 and the light-emitting element 6 include a fluorescent material including protecting groups. In this example, 4,6mCzP2Pm and PCCP are a combination forming an exciplex and Firpic and Ir(Fppy-iPr)₃ are phosphorescent materials including Ir. Hence, the light-emitting element 4 and the light-emitting element 6 are light-emitting elements in which the exciplex or the phosphorescent material serves as an energy donor and therefore triplet excitation energy can be converted into fluorescence. Moreover, the light-emitting element 4 and the light-emitting element 6 can be said to include a light-emitting layer obtained by adding the fluorescent material to a light-emitting layer capable of utilizing ExTET.

### <Characteristics of Light-Emitting Elements>

Next, the element characteristics of the comparative light-emitting element 3, the light-emitting element 4, the comparative light-emitting element 5, and the light-emitting element 6 fabricated above were measured. Note that the measurement method is similar to that in Example 1.

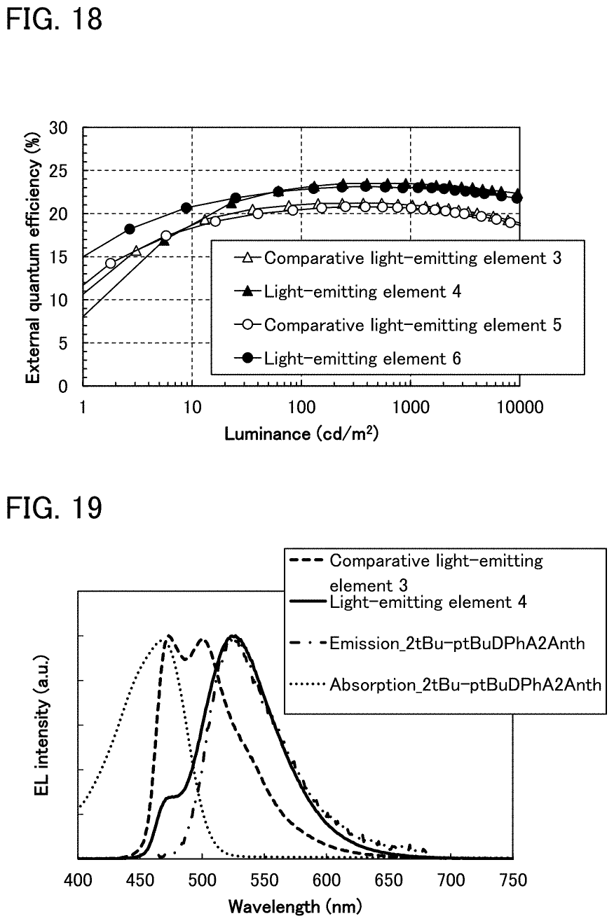

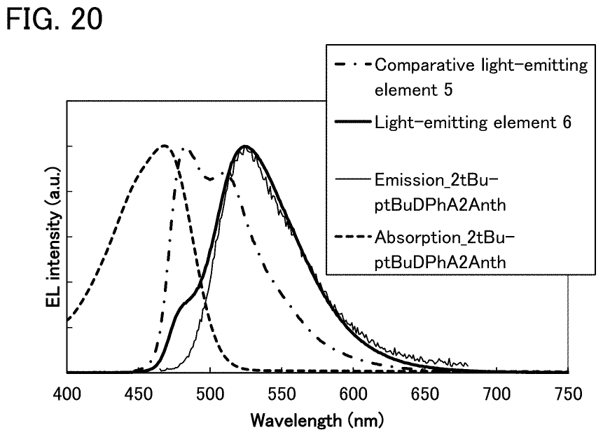

FIG. 18 shows the external quantum efficiency-luminance characteristics of the comparative light-emitting element 3, the light-emitting element 4, the comparative light-emitting element 5, and the light-emitting element 6. FIG. 19 shows electroluminescence spectra of the comparative light-emitting element 3 and the light-emitting element 4 to which a current at a current density of 2.5 mA/cm² was supplied. FIG. 20 shows electroluminescence spectra of the comparative light-emitting element 5 and the light-emitting element 6 to which a current at a current density of 2.5 mA/cm² was supplied. Note that the measurements of the light-emitting elements were performed at room temperature (in an atmosphere maintained at 23° C.). FIG. 19 and FIG. 20 show emission and absorption spectra of a toluene solution of 2tBu-ptBuDPhA2Anth, which is the guest material of the light-emitting element 4 and the light-emitting element 6.

Table 4 shows the element characteristics of the comparative light-emitting element 3, the light-emitting element 4, the comparative light-emitting element 5, and the light-emitting element 6 at around 1000 cd/m².

TABLE 4

| | | | | | | | External |
|---|---|---|---|---|---|---|---|
| | | Current | CIE | | Current | Power | quantum |
| | Voltage | density | chromaticity | Luminance | efficiency | efficiency | efficiency |
| | (V) | (mA/cm²) | (x, y) | (cd/m²) | (cd/A) | (lmW) | (%) |
| Compamtive | 3.40 | 2.09 | (0.179, 0.422) | 1040 | 49.7 | 46.0 | 21.0 |
| light-emitting | | | | | | | |
| element | | | | | | | |
| 3 | | | | | | | |
| Light-emitting | 3.20 | 1.13 | (0.262, 0.605) | 904 | 80.2 | 78.8 | 23.5 |
| element | | | | | | | |
| 4 | | | | | | | |
| Compamtive | 3.50 | 1.88 | (0.189, 0.505) | 1013 | 54.0 | 48.5 | 20.6 |
| light-emitting | | | | | | | |
| element | | | | | | | |
| 5 | | | | | | | |
| Light-emitting | 3.20 | 0.73 | (0.282, 0.619) | 585 | 80.7 | 79.2 | 23.1 |
| element | | | | | | | |
| 6 | | | | | | | |

As shown in FIG. 19, the emission spectrum of the comparative light-emitting element 3 had peak wavelengths of 473 nm and 501 nm and a half width of 72 nm. This is light emission originating from Firpic. In addition, the emission spectrum of the light-emitting element 4 had a peak wavelength of 527 nm and a half width of 69 nm. Although the emission spectrum of the light-emitting element 4 is green light emission originating mainly from 2tBu-ptBuDPhA2Anth, the emission spectrum of the light-emitting element 4 is different from the emission spectrum of 2tBu-ptBuDPhA2Anth as shown in FIG. 19. As in the case of the light-emitting element 2 described in Example 1, the emission spectrum obtained from the light-emitting element 4 was found to include light emission of Firpic, which is an energy donor, in addition to the light emission of 2tBu-ptBuDPhA2Anth. Consequently, multicolor light emission can be obtained from the light-emitting element of one embodiment of the present invention. Moreover, the excitation energy of Firpic, which is an Ir complex, can contribute to light emission of Firpic and light emission of the guest material, as shown in FIG. 5(B).

As shown in FIG. 20, the emission spectrum of the comparative light-emitting element 5 had peak wavelengths of 482 nm and 507 nm and a half width of 65 nm. This is light emission originating from Ir(Fppy-iPr)₃. In addition, the emission spectrum of the light-emitting element 6 had a peak wavelength of 524 nm and a half width of 68 nm. Although the emission spectrum of the light-emitting element 6 is green light emission originating mainly from 2tBu-ptBuDPhA2Anth, the emission spectrum of the light-emitting element 6 is different from the emission spectrum of 2tBu-ptBuDPhA2Anth as shown in FIG. 20. As in the case of the light-emitting element 2 described in Example 1, the emission spectrum obtained from the light-emitting element 6 was found to include light emission of Ir(Fppy-iPr)₃, which is an energy donor, in addition to the light emission of 2tBu-ptBuDPhA2Anth. Consequently, multicolor light emission can be obtained from the light-emitting element of one embodiment of the present invention. Moreover, the excitation energy of Ir(Fppy-iPr)₃, which is an Ir complex, can contribute to light emission of Ir(Fppy-iPr)₃ and light emission of the guest material, as shown in FIG. 5(B).

Although the light-emitting element 4 and the light-emitting element 6 exhibit light emission originating from the fluorescent material, they exhibited high emission efficiency with an external quantum efficiency exceeding 20% as shown in FIG. 18 and Table 4. This result indicates that in the light-emitting elements of one embodiment of the present invention, non-radiative deactivation of triplet excitons is inhibited, contributing to efficient conversion into light emission. Thus, it was found that the use of a guest material including protecting groups in a light-emitting layer can inhibit energy transfer of triplet excitation energy from a host material to a guest material by the Dexter mechanism and non-radiative deactivation of triplet excitation energy.

### <CV Measurement Results>

Then, the electrochemical characteristics (oxidation reaction characteristics and reduction reaction characteristics) of 4,6mCzP2Pm and PCCP used for the light-emitting layers of the light-emitting elements were measured by cyclic voltammetry (CV) measurement. The measurement was performed in a manner similar to the method described in Example 1.

As described above, the HOMO level of 4,6mCzP2Pm, which was calculated from the CV measurement, was −5.89 eV and the LUMO level was −2.88 eV. Similarly, the HOMO level of PCCP was −5.63 eV and the LUMO level was −1.96 eV.

As described above, the LUMO level of 4,6mCzP2Pm is lower than the LUMO level of PCCP, and the HOMO level of PCCP is higher than the HOMO level of 4,6mCzP2Pm. Thus, in the case where the compounds are used in a light-emitting layer, electrons and holes are efficiently injected into 4,6mCzP2Pm and PCCP, respectively, so that 4,6mCzP2Pm and PCCP can form an exciplex. Light emission originating from Firpic is obtained as the emission spectrum of the comparative light-emitting element 3, and light emission originating from Ir(Fppy-iPr)₃ is obtained as the emission spectrum of the comparative light-emitting element 5. This means that the excitation energy is supplied from 4,6mCzP2Pm and PCCP to Firpic or Ir(Fppy-iPr)₃. Therefore, the comparative light-emitting element 3 and the comparative light-emitting element 5 can be regarded as light-emitting elements utilizing ExTET. The light-emitting element 4 can be regarded as a light-emitting element in which a fluorescent material including protecting groups is added to the comparative light-emitting element 3, and the light-emitting element 6 can be regarded as a light-emitting element in which a fluorescent material including protecting groups is added to the comparative light-emitting element 5. In other words, the light-emitting element 4 and the light-emitting element 6 are each a light-emitting element in which a fluorescent material including protecting groups is added to a light-emitting element utilizing ExTET.

It is also found that an absorption band on the longest wavelength side of the absorption spectrum of 2tBu-ptBuDPhA2Anth and the emission spectrum of Firpic overlap with each other as shown in FIG. 19. Therefore the light-emitting element 4 is capable of emitting light by receiving excitation energy of Firpic described above. Similarly, it is also found that an absorption band on the longest wavelength side of the absorption spectrum of 2tBu-ptBuDPhA2Anth and the emission spectrum of Ir(Fppy-iPr)₃ overlap with each other as shown in FIG. 20. Therefore the light-emitting element 4 is capable of emitting light by receiving excitation energy of Ir(Fppy-iPr)₃.

### <Reliability Measurement of Light-Emitting Elements>

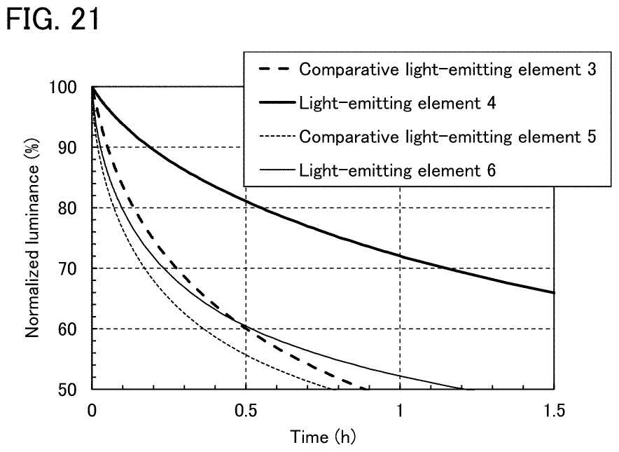

Next, driving tests at a constant current of 2.0 mA were performed on the comparative light-emitting element 3, the light-emitting element 4, the comparative light-emitting element 5, and the light-emitting element 6. The results are shown in FIG. 21. According to FIG. 21, the light-emitting element 4 and the light-emitting element 6 which include the fluorescent material in the light-emitting layer have higher reliability than the comparative light-emitting element 3 and the comparative light-emitting element 5. This indicates that the addition of the fluorescent material enables excitation energy in the light-emitting layer to be efficiently converted into light emission, as described in Example 1. Thus, a fluorescent material including protecting groups is used in the triplet sensitizing element as the light-emitting element of one embodiment of the present invention, whereby the light-emitting element can have high efficiency and high reliability.

Accordingly, the light-emitting elements of one embodiment of the present invention can favorably use an exciplex or a phosphorescent material as a host material. Moreover, a structure in which a fluorescent material is added to a light-emitting layer which can utilize ExTET can be favorably employed.

### Example 3

In this example, fabrication examples of light-emitting elements of one embodiment of the present invention and comparative light-emitting elements, which are different from those in the above example, and the characteristics of the light-emitting elements are described. The structure of each of the light-emitting elements fabricated in this example is the same as that in FIG. 1(A). Table 5 show the details of the element structures. The structure and abbreviation of a compound that was used are shown below. Note that the above examples and embodiments can be referred to for other organic compounds.

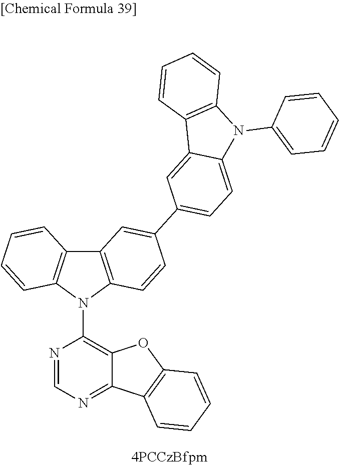 [SMILES: c1ccc(-n2c3ccccc3c3cc(-c4ccc5c(c4)c4ccccc4n5-c4ncnc5c4oc4ccccc45)ccc32)cc1]

TABLE 5

| | | | Thickness | | |
|---|---|---|---|---|---|
| | Layer | Numeral | (mm) | Material | Weight ratio |
| Comparative | Electrode | 102 | 200 | Al | — |
| light-emitting | Electron- | 119 | 1 | LiF | — |
| element | injection layer | | | | |
| 7 | Electron- | 118(2) | 10 | NBphen | — |
| | transport layer | 118(1) | 20 | 4,6mCzP2Pm | — |
| | Light-emitting | 130 | 40 | 4,6mCzP2Pm:4PCCzBfpm | 0.8:0.2 |
| | layer | | | | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Comparative | Electrode | 102 | 200 | Al | — |
| light-emitting | Electron- | 119 | 1 | LiF | — |
| elementlayer | injection layer | | | | |
| 8 | Electron- | 118(2) | 10 | NBphen | — |
| | transport layer | 118(1) | 20 | 4,6mCzP2Pm | — |
| | Light-emitting | 130 | 40 | 4,6mCzP2Pm:4PCCzBfpm:Firpic | 0.8:0.2:0.1 |
| | layer | | | | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Light-emitting | Electrode | 102 | 200 | Al | — |
| element | Electron- | 119 | 1 | LiF | — |
| 9 | injection layer | | | | |
| | Electron- | 118(2) | 10 | NBphen | — |
| | transport layer | 118(1) | 20 | 4,6mCzP2Pm | — |
| | Light-emitting | 130 | 40 | 4,6mCzP2Pm:4PCCzBfpm:Firpic: | 0.8:0.2:0.1:0.01 |
| | layer | | | 2,6tBu-mmtBuDPhA2Anth | |
| | Hole-transport | 112 | 20 | PCCP | — |
| | layer | | | | |
| | Hole-injection | 111 | 40 | DBT3P-II:MoO₃ | 1:0.5 |
| | layer | | | | |
| | Electrode | 101 | 70 | ITSO | — |

### <<Fabrication of Comparative Light-Emitting Element 7>>

As the electrode 101, an ITSO film was formed to a thickness of 70 nm over a glass substrate. Note that the electrode area of the electrode 101 was set to 4 mm² (2 mm×2 mm).

Next, as the hole-injection layer 111, DBT3P-II and molybdenum oxide (MoO₃) were deposited over the electrode 101 by co-evaporation in a weight ratio (DBT3P-II:MoO₃) of 1:0.5 to a thickness of 40 nm.

Then, as the hole-transport layer 112, mCzFLP was deposited on the hole-injection layer 111 by evaporation to a thickness of 20 nm.

Next, as the light-emitting layer 130, 4,6mCzP2Pm and 4-(9′-phenyl-3,3′-bi-9H-carbazol-9-yl)benzofuro[3,2-d]pyrimidine (abbreviation: 4PCCzBfpm) were deposited over the hole-transport layer 112 by co-evaporation in a weight ratio (4,6mCzP2Pm:4PCCzBfpm) of 0.8:0.2 to a thickness of 40 nm. In the comparative light-emitting element 7, light emission originating from 4PCCzBfpm, which is a TADF material, is obtained.

Next, as the electron-transport layer 118, 4,6mCzP2Pm and NBPhen were sequentially deposited by evaporation to a thickness of 20 nm and to a thickness of 10 nm, respectively, over the light-emitting layer 130. Then, as the electron-injection layer 119, LiF was deposited on the electron-transport layer 118 by evaporation to a thickness of 1 nm.

Next, as the electrode 102, aluminum (Al) was formed over the electron-injection layer 119 to a thickness of 200 nm.

Next, in a glove box containing a nitrogen atmosphere, a comparative light-emitting element 7 was sealed by fixing a glass substrate for sealing to the glass substrate on which the organic materials were formed using a sealant for organic EL. Specifically, the sealant was applied to the periphery of the organic materials formed on the glass substrate, the glass substrate was bonded to the glass substrate for sealing, irradiation with ultraviolet light having a wavelength of 365 nm at 6 J/cm² was performed, and heat treatment at 80° C. for one hour was performed. Through the above steps, the comparative light-emitting element 7 was obtained.

### <<Fabrication of Comparative Light-Emitting Element 8 and Light-Emitting Element 9>>

A comparative light-emitting element 8 and a light-emitting element 9 are different from the above-described comparative light-emitting element 7 only in the component of the light-emitting layer 130, and other steps of the fabrication method are the same as those for the comparative light-emitting element 7. The details of the element structures are as shown in Table 5; thus, the details of the fabrication methods are omitted. In the light-emitting layer 130 of the light-emitting element 9, Firpic is a phosphorescent material including Ir and serves as an energy donor. Moreover, 2,6-di-tert-butyl-N,N,N′,N′-tetrakis(3.5-di-tert-butylphenyl)-9,10-anthracenediamine (abbreviation: 2,6tBu-mmtBuDPhA2Anth), which is an organic compound represented by Structural Formula (103), is a guest material including protecting groups around a luminophore.

### <Characteristics of Light-Emitting Elements>

Next, the characteristics of the comparative light-emitting element 7, the comparative light-emitting element 8, and the light-emitting element 9 fabricated above were measured. Note that the measurement method is similar to that in Example 1.

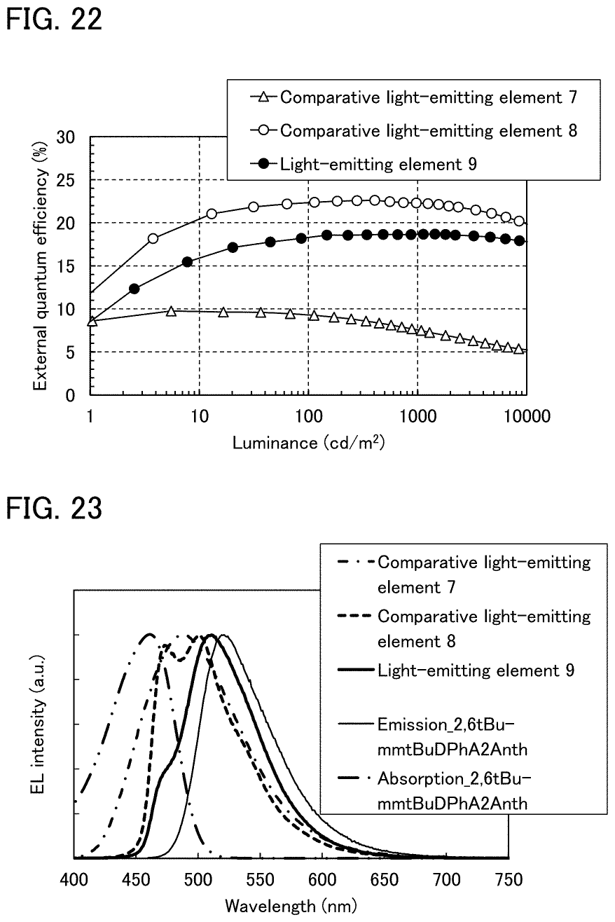

FIG. 22 shows the external quantum efficiency-luminance characteristics of the comparative light-emitting element 7, the comparative light-emitting element 8, and the light-emitting element 9. FIG. 23 shows electroluminescence spectra of the comparative light-emitting element 7, the comparative light-emitting element 8, and the light-emitting element 9 to which a current at a current density of 2.5 mA/cm² was supplied. Note that the measurements of the light-emitting elements were performed at room temperature (in an atmosphere maintained at 23° C.). FIG. 23 also shows emission and absorption spectra of a toluene solution of 2,6tBu-mmtBuDPhA2Anth, which is the guest material of the light-emitting element 9. The method of measuring the emission spectrum and the absorption spectrum of the toluene solution of 2,6tBu-mmtBuDPhA2Anth was the same as the method described in Example 1.

Table 6 shows the element characteristics of the comparative light-emitting element 7, the comparative light-emitting element 8, and the light-emitting element 9 at around 1000 cd/m².

TABLE 6

| | | | | | | | External |
|---|---|---|---|---|---|---|---|
| | | Current | CIE | | Current | Power | quantum |
| | Voltage | density | chromaticity | Luminance | efficiency | efficiency | efficiency |
| | (V) | (mA/cm²) | (x, y) | (cd/m²) | (cd/A) | (lm/W) | (%) |
| Comparative | 3.90 | 6.59 | (0.181, 0.328) | 1079 | 16.4 | 13.2 | 7.5 |
| light-emitting | | | | | | | |
| element | | | | | | | |
| 7 | | | | | | | |
| Comparative | 3.60 | 1.80 | (0.182, 0.426) | 973 | 54.1 | 47.2 | 22.3 |
| light-emitting | | | | | | | |
| element | | | | | | | |
| 8 | | | | | | | |
| Light-emitting | 3.70 | 1.97 | (0.220, 0.566) | 1130 | 57.3 | 48.6 | 18.7 |
| element | | | | | | | |
| 9 | | | | | | | |

As shown in FIG. 23, the emission spectrum of the comparative light-emitting element 7 had a peak wavelength of 488 nm and a half width of 92 nm. This is light emission originating from 4PCCzBfpm. In addition, the emission spectrum of the comparative light-emitting element 8 had peak wavelengths of 471 nm and 501 nm and a half width of 75 nm. The emission spectrum of the comparative light-emitting element 8 is light emission originating from Firpic. In addition, the emission spectrum of the light-emitting element 9 had a peak wavelength of 511 nm and a half width of 69 nm. Although the emission spectrum of the light-emitting element 9 is green light emission originating from 2,6tBu-mmtBuDPhA2Anth, the emission spectrum of the light-emitting element 9 is different from the emission spectrum of 2,6tBu-mmtBuDPhA2Anth as shown in FIG. 23. The emission spectrum obtained from the light-emitting element 9 was found to include light emission of Firpic, which is an energy donor, in addition to the light emission of 2,6tBu-mmtBuDPhA2Anth. Consequently, multicolor light emission can be obtained from the light-emitting element of one embodiment of the present invention.

Although the light-emitting element 9 exhibits light emission originating from the fluorescent material, it exhibited high emission efficiency with an external quantum efficiency exceeding 15% as shown in FIG. 22 and Table 6. This result indicates that in the light-emitting element of one embodiment of the present invention, non-radiative deactivation of triplet excitons is inhibited, contributing to efficient conversion into light emission. Thus, it was found that the use of a guest material including protecting groups in a light-emitting layer can inhibit energy transfer of triplet excitation energy from a host material to a guest material by the Dexter mechanism and non-radiative deactivation of triplet excitation energy.

As described above, 4PCCzBfpm is a TADF material and Firpic is a phosphorescent material. It is also found that an absorption band on the longest wavelength side of the absorption spectrum of 2,6tBu-mmtBuDPhA2Anth, the emission spectrum of 4PCCzBfpm, and the emission spectrum of Firpic overlap with each other as shown in FIG. 23. Therefore the light-emitting element 9 is capable of emitting light by receiving excitation energy of 4PCCzBfpm and/or Firpic described above.

### <Fluorescence Lifetime Measurement of Light-Emitting Elements>

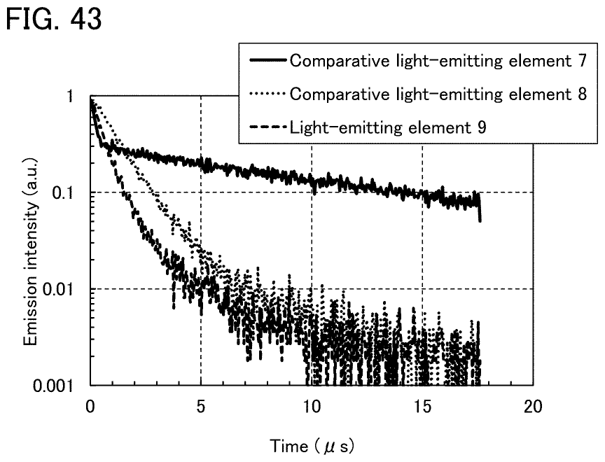

Next, the fluorescence lifetimes of the comparative light-emitting element 7, the comparative light-emitting element 8, and the light-emitting element 9 were measured. A picosecond fluorescence lifetime measurement system (manufactured by Hamamatsu Photonics K.K.) was used for the measurements. In the measurements, a square wave pulse voltage was applied to the light-emitting elements, and time-resolved measurement of light emission, which was attenuated from the falling of the voltage, was performed with a streak camera. The pulse voltage was applied at a frequency of 10 Hz, and data with a high S/N ratio was obtained by integrating data obtained by repeated measurements. The measurements were performed at room temperature (300 K) under the conditions of an applied pulse voltage of approximately 3 V to 4 V, a pulse time width of 100 μsec, a negative bias voltage of −5 V (when the elements were not driven), and a measurement time range of 20 μsec so that the luminance of the light-emitting elements becomes around 1000 cd/m². FIG. 43 shows the measurement results. Note that in the measurement results in FIG. 43, the vertical axis represents the emission intensity normalized to that in a state where carriers are steadily injected (the pulse voltage is applied). The horizontal axis represents time elapsed after the falling of the pulse voltage.

Fitting of attenuation curves shown in FIG. 43 using an exponential function revealed that the comparative light-emitting element 7 exhibited light emission including a prompt fluorescence component of 0.2 μs or shorter and a delayed fluorescence component of approximately 11 μs and the proportion of the delayed fluorescence component was approximately 30%. The light emission originating from 4PCCzBfpm was observed in the comparative light-emitting element 7. Thus, 4PCCzBfpm was found to be a TADF material.

It was found that the comparative light-emitting element 8 exhibited light emission including an emission component of approximately 1 μs and the light-emitting element 9 exhibited light emission including a fluorescence component of 0.4 μs or shorter. In the comparative light-emitting element 8, a delayed fluorescence component of 10 μs or longer was not observed and phosphorescence was observed as shown in FIG. 43. In the light-emitting element 9, light emission earlier than that in the comparative light-emitting element 8 was observed. This indicates that fluorescence was observed and the excitation energy was efficiently converted into light emission in the light-emitting element 9.

### <Reliability Measurement of Light-Emitting Elements>

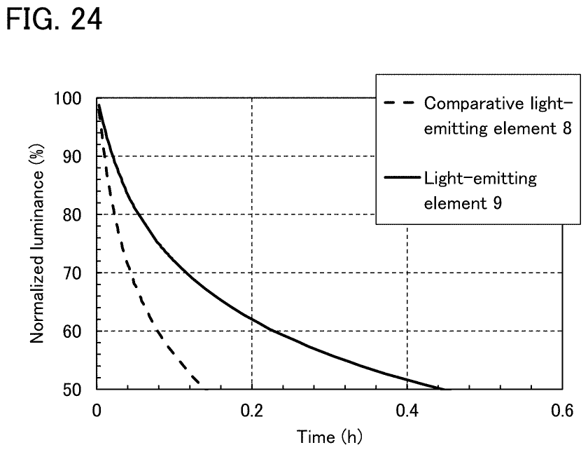

Next, driving tests at a constant current of 2.0 mA were performed on the comparative light-emitting element 8 and the light-emitting element 9. The results are shown in FIG. 24. According to FIG. 24, the light-emitting element 9 including the fluorescent material in the light-emitting layer has higher reliability than the comparative light-emitting element 8. This indicates that the addition of the fluorescent material enables excitation energy in the light-emitting layer to be efficiently converted into light emission, as described in Example 1. Thus, a fluorescent material including protecting groups is used in the triplet sensitizing element as the light-emitting element of one embodiment of the present invention, whereby the light-emitting element can have high efficiency and high reliability.

### Example 4

In this example, fabrication examples of light-emitting elements of one embodiment of the present invention and comparative light-emitting elements, which are different from those in the above example, and the characteristics of the light-emitting elements are described. The structure of each of the light-emitting elements fabricated in this example is the same as that in FIG. 1(A). Table 7 show the details of the element structures. The structures and abbreviations of compounds that were used are shown below. Note that the above examples and embodiments can be referred to for other organic compounds.

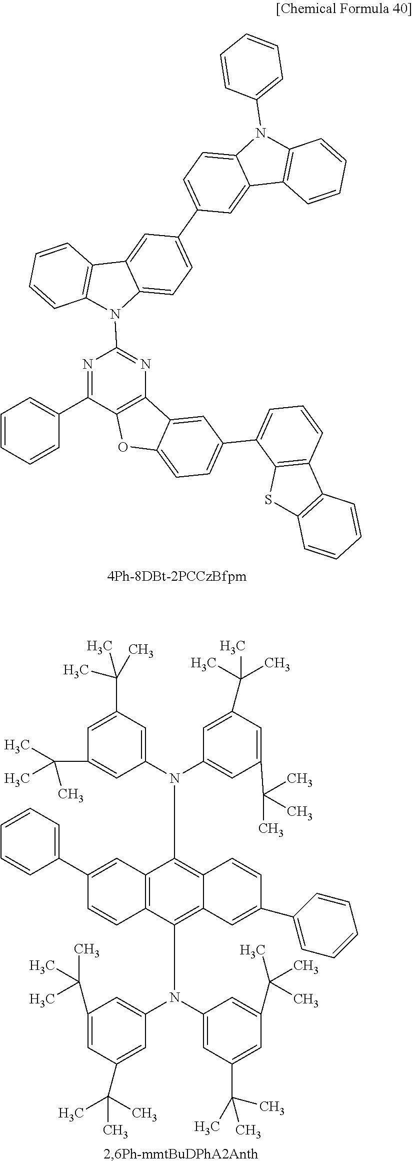

TABLE 7

| | | | Thickness | | |
|---|---|---|---|---|---|
| | Layer | Numeral | (nm) | Material | Weight ratio |
| Comparative | Electrode | 102 | 200 | Al | — |
| light-emitting | Electron- | 119 | 1 | LiF | — |
| element | injection layer | | | | |
| 10 | Electron- | 118(2) | 10 | NBphen | — |
| | transport layer | 118(1) | 20 | 4,6mCzP2Pm | — |
| | Light-emitting | | | | |
| | layer | 130 | 40 | 4,6mCzP2Pm:4Ph-8DBt-2PCCzBfpm | 1:0.1 |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Light- | Electrode | 102 | 200 | Al | — |
| emitting | Electron- | 119 | 1 | LiF | — |
| element | injection layer | | | | |
| 11 | Electron- | 118(2) | 10 | NBphen | — |
| | transport layer | 118(1) | 20 | 4,6mCzP2Pm | — |
| | Light-emitting | 130 | 40 | 4,6mCzP2Pm:4Ph-8DBt-2PCCzBfpm: | 1:0.1:0.01 |
| | layer | | | 2,6Ph-mmtBuDPhA2Anth | |
| | Hole-transport | 112 | 20 | PCCP | — |
| | layer | | | | |
| | Hole-injection | 111 | 40 | DBT3P-II:MoO₃ | 1:0.5 |
| | layer | | | | |
| | Electrode | 101 | 70 | ITSO | — |

### <<Fabrication of Comparative Light-Emitting Element 10 and Light-Emitting Element 11>>

A comparative light-emitting element 10 and a light-emitting element 11 are different from the above-described comparative light-emitting element 8 only in the component of the light-emitting layer 130, and other steps of the fabrication method are the same as those for the comparative light-emitting element 8. The details of the element structures are as shown in Table 7; thus, the details of the fabrication methods are omitted. Note that 8-(dibenzothiophen-4-yl)-4-phenyl-2-(9′-phenyl-3,3′-bi-9H-carbazol-9-yl)-[1]benzofuro[3,2-d]pyrimidine (abbreviation: 4Ph-8DBt-2PCCzBfpm) is a TADF material in the light-emitting layer 130 of the comparative light-emitting element 10 and the light-emitting element 11. Furthermore, 2,6-diphenyl-N,N,N′,N′-tetrakis(3,5-di-tert-butylphenyl)-9,10-anthracenediamine (abbreviation: 2,6Ph-mmtBuDPhA2Anth) is a guest material including protecting groups around a luminophore in the light-emitting layer 130 of the light-emitting element 11. The light-emitting element 11 is the light-emitting element of one embodiment of the present invention illustrated in FIG. 6(C).

### <Characteristics of Light-Emitting Elements>

Next, the characteristics of the comparative light-emitting element 10 and the light-emitting element 11 fabricated above were measured. The measurements were performed in a manner similar to those in Example 1.

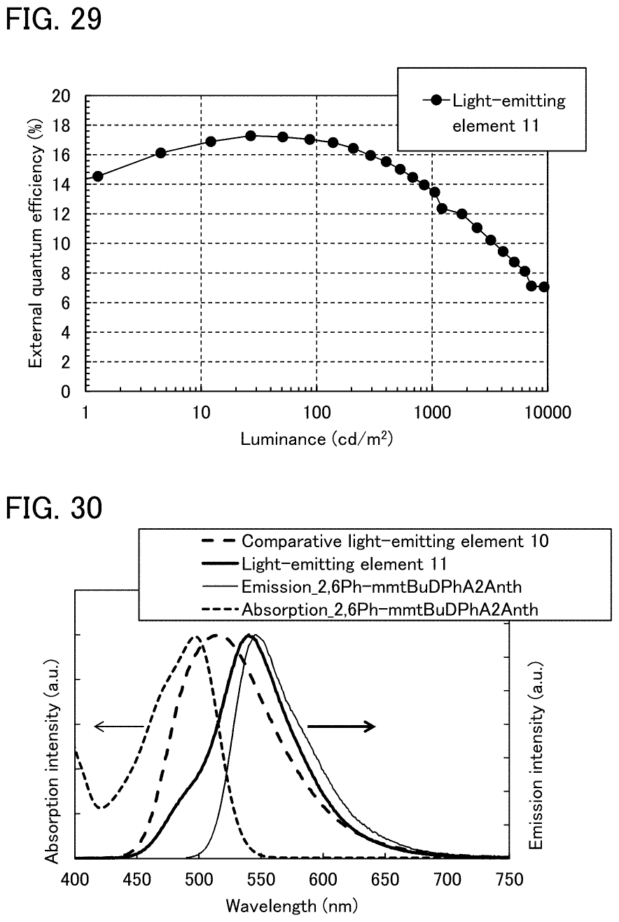

FIG. 29 shows the external quantum efficiency-luminance characteristics of the light-emitting element 11. FIG. 30 shows electroluminescence spectra of the comparative light-emitting element 10 and the light-emitting element 11 to which a current at a current density of 2.5 mA/cm² was supplied. Note that the measurements of the light-emitting elements were performed at room temperature (in an atmosphere maintained at 23° C.). FIG. 30 shows absorption and emission spectra of a toluene solution of 2,6Ph-mmtBuDPhA2Anth, which is the guest material of the light-emitting element 11. The method of measuring the emission spectrum and the absorption spectrum of the toluene solution of 2,6Ph-mmtBuDPhA2Anth was the same as the method described in Example 1.

Table 8 shows the element characteristics of the comparative light-emitting element 10 and the light-emitting element 11 at around 1000 cd/m².

TABLE 8

| | | Current | CIE | | Current | Power | External |
|---|---|---|---|---|---|---|---|
| | Voltage | density | chromaticity | Luminance | efficiency | efficiency | quantum |
| | (V) | (mA/cm²) | (x, y) | (cd/m²) | (cd/A) | (lm/W) | efficiency |
| Comparative | 3.80 | 6.59 | (0.264, 0.549) | 1105 | 56.3 | 46.5 | 18.8 |
| light-emitting | | | | | | | |
| element | | | | | | | |
| 10 | | | | | | | |
| Light-emitting | 3.90 | 2.21 | (0.331, 0.587) | 1054 | 47.6 | 38.4 | 13.5 |
| element | | | | | | | |
| 11 | | | | | | | |

As shown in FIG. 30, the emission spectrum of the comparative light-emitting element 10 had a peak wavelength of 516 nm and a half width of 93 nm. This is light emission originating from 4Ph-8DBt-2PCCzBfpm. In addition, the emission spectrum of the light-emitting element 11 had a peak wavelength of 540 nm and a half width of 71 nm. Although this includes green light emission originating from 2,6Ph-mmtBuDPhA2Anth, the emission spectrum of the light-emitting element 11 is different from the emission spectrum of 2,6Ph-mmtBuDPhA2Anth as shown in FIG. 30. The emission spectrum obtained from the light-emitting element 11 was found to include light emission of 4Ph-8DBt-2PCCzBfpm, which is an energy donor, in addition to the light emission of 2,6Ph-mmtBuDPhA2Anth. Consequently, multicolor light emission can be obtained from the light-emitting element of one embodiment of the present invention.

Although the light-emitting element 11 exhibits light emission originating from the fluorescent material, it exhibited high emission efficiency with an external quantum efficiency whose maximum value exceeding 15% as shown in FIG. 29 and Table 8. This result indicates that in the light-emitting element of one embodiment of the present invention, non-radiative deactivation of triplet excitons is inhibited, contributing to efficient conversion into light emission. Thus, it was found that the use of a guest material including protecting groups in a light-emitting layer can inhibit energy transfer of triplet excitation energy from a host material to a guest material by the Dexter mechanism and non-radiative deactivation of triplet excitation energy.

As described above, 4Ph-8DBt-2PCCzBfpm is a TADF material. It is also found that an absorption band on the longest wavelength side of the absorption spectrum of 2,6Ph-mmtBuDPhA2Anth and the emission spectrum of 4Ph-8DBt-2PCCzBfpm overlap with each other as shown in FIG. 30. Thus, 2,6Ph-mmtBuDPhA2Anth was found to emit light by receiving excitation energy of 4Ph-8DBt-2PCCzBfpm in the light-emitting element 11.

### <Fluorescence Lifetime Measurement of Light-Emitting Elements>

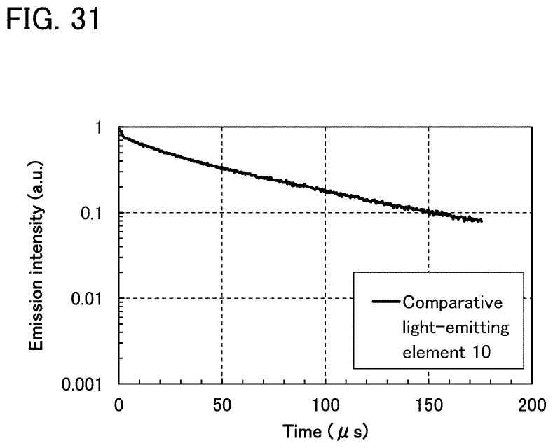

Next, the fluorescence lifetime of the comparative light-emitting element 10 was measured. A picosecond fluorescence lifetime measurement system (manufactured by Hamamatsu Photonics K.K.) was used for the measurement. In the measurement, a square wave pulse voltage was applied to the light-emitting elements, and time-resolved measurement of light emission, which was attenuated from the falling of the voltage, was performed with a streak camera. The pulse voltage was applied at a frequency of 10 Hz, and data with a high S/N ratio was obtained by integrating data obtained by repeated measurements. The measurements were performed at room temperature (300 K) under the conditions of an applied pulse voltage of approximately 3 V to 4 V, a pulse time width of 100 μsec, a negative bias voltage of −5 V (when the elements were not driven), and a measurement time range of 200 μsec so that the luminance of the light-emitting elements becomes around 1000 cd/m². FIG. 31 shows the measurement results. Note that in FIG. 31, the vertical axis represents the emission intensity normalized to that in a state where carriers are steadily injected (the pulse voltage is applied). The horizontal axis represents time elapsed after the falling of the pulse voltage.

Fitting of attenuation curves shown in FIG. 31 using an exponential function revealed that the comparative light-emitting element 10 exhibited light emission including a prompt fluorescence component of 0.4 μs or shorter and a delayed fluorescence component of approximately 89 μs. The light emission originating from 4Ph-8DBt-2PCCzBfpm was observed in the comparative light-emitting element 10. Thus, 4Ph-8DBt-2PCCzBfpm was found to be a TADF material.

### <Reliability Measurement of Light-Emitting Elements>

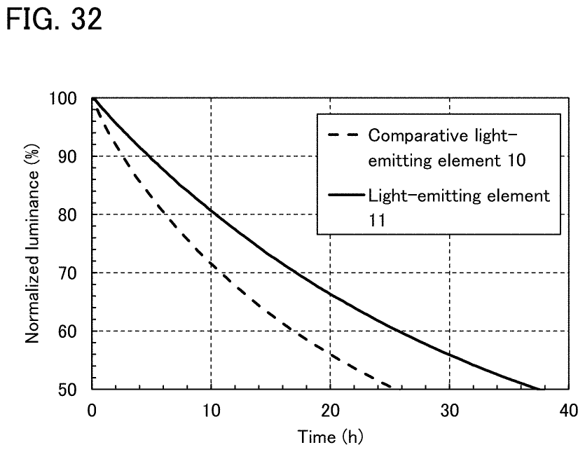

Next, driving tests at a constant current of 2.0 mA were performed on the comparative light-emitting element 10 and the light-emitting element 11. The results are shown in FIG. 32. According to FIG. 32, the light-emitting element 11 including the fluorescent material in the light-emitting layer has higher reliability than the comparative light-emitting element 10. This indicates that the addition of the fluorescent material enables excitation energy in the light-emitting layer to be efficiently converted into light emission, as described in Example 1. Thus, a fluorescent material including protecting groups is used in the triplet sensitizing element as the light-emitting element of one embodiment of the present invention, whereby the light-emitting element can have high efficiency and high reliability.

### Example 5

In this example, fabrication examples of light-emitting elements of one embodiment of the present invention and comparative light-emitting elements, which are different from those in the above example, and the characteristics of the light-emitting elements are described. The structure of each of the light-emitting elements fabricated in this example is the same as that in FIG. 1(A). Table 9 show the details of the element structures. The structure and abbreviation of a compound that was used are shown below. Note that the above examples and embodiments can be referred to for other organic compounds.

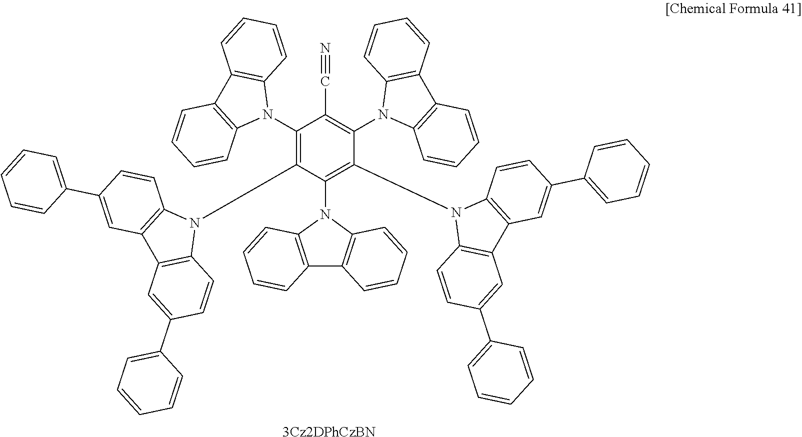 [SMILES: N#Cc1c(-n2c3ccccc3c3ccccc32)c(-n2c3ccc(-c4ccccc4)cc3c3cc(-c4ccccc4)ccc32)c(-n2c3ccccc3c3ccccc32)c(-n2c3ccc(-c4ccccc4)cc3c3cc(-c4ccccc4)ccc32)c1-n1c2ccccc2c2ccccc21 ; "3Cz2DPhCzBN"]

TABLE 9

| | | | Thickness | | Weight |
|---|---|---|---|---|---|
| | Layer | Numeral | (nm) | Material | ratio |
| Comparative | Electrode | 102 | 200 | Al | — |
| light-emitting | Electron- | 119 | 1 | LiF | — |
| element | injection layer | | | | |
| 12 | Electron- | 118(2) | 15 | NBphen | — |
| | transport layer | 118(1) | 20 | 4,6mCzP2Pm | — |
| | Light-emitting | 130 | 30 | 4,6mCzP2Pm:3Cz2DPhCzBN | 1:0.1 |
| | layer | | | | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Light- | Electrode | 102 | 200 | Al | — |
| emitting | Electron- | 119 | 1 | LiF | — |
| element | injection layer | | | | |
| 13 | Electron- | 118(2) | 10 | NBphen | — |
| | transport layer | 118(1) | 20 | 4,6mCzP2Pm | — |
| | Light-emitting | 130 | 40 | 4,6mCzP2Pm:3Cz2DPhCzBN: | 1:0.1:0.01 |
| | layer | | | 2,6Ph-mmtBuDPhA2Anth | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |

### <<Fabrication of Comparative Light-Emitting Element 12 and Light-Emitting Element 13>>

A comparative light-emitting element 12 is different from the above-described comparative light-emitting element 8 only in the thickness structures of the light-emitting layer 130 and an electron-transport layer 118(2), and other steps of the fabrication method are the same as those for the comparative light-emitting element 8. A light-emitting element 13 is different from the above-described comparative light-emitting element 8 only in the component of the light-emitting layer 130, and other steps of the fabrication method are the same as those for the comparative light-emitting element 8. The details of the element structures are as shown in Table 9; thus, the details of the fabrication methods are omitted. Note that 2,4,6-tris(9H-carbazol-9-yl)-3,5-bis(3,6-diphenylcarbazol-9-yl)benzonitrile (abbreviation: 3C2zDPhCzBN) is a TADF material in the light-emitting layer 130 of the comparative light-emitting element 12 and the light-emitting element 13. This is described in Non-Patent Document 1. Furthermore, 2,6Ph-mmtBuDPhA2Anth is a guest material including protecting groups around a luminophore in the light-emitting layer 130 of the light-emitting element 13. The light-emitting element 13 is the light-emitting element of one embodiment of the present invention illustrated in FIG. 6(C).

### <Characteristics of Light-Emitting Elements>

Next, the characteristics of the comparative light-emitting element 12 and the light-emitting element 13 fabricated above were measured. The measurements were performed in a manner similar to those in Example 1

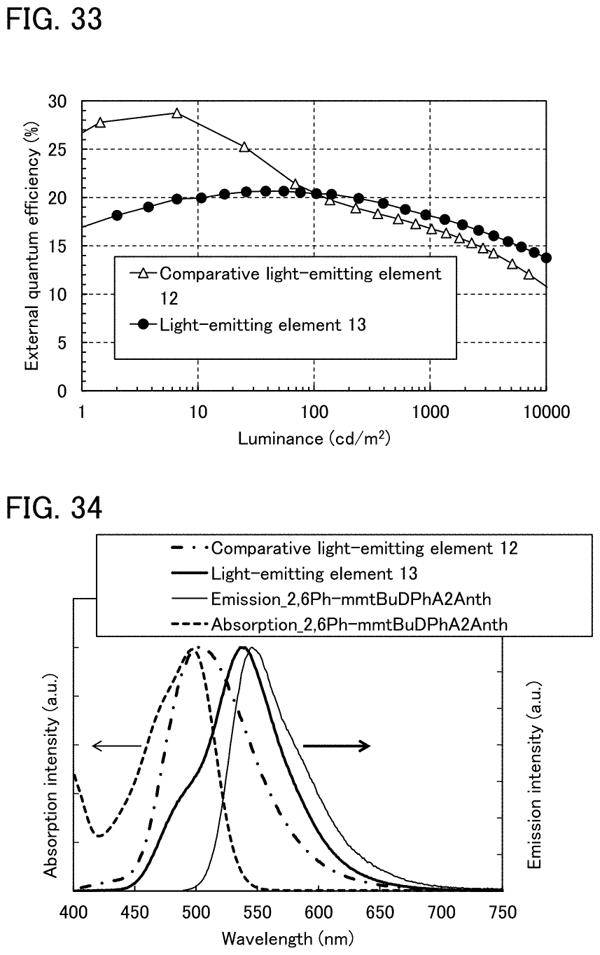

FIG. 33 shows the external quantum efficiency-luminance characteristics of the comparative light-emitting element 12 and the light-emitting element 13. FIG. 34 shows electroluminescence spectra of the comparative light-emitting element 12 and the light-emitting element 13 to which a current at a current density of 2.5 mA/cm² was supplied. Note that the measurements of the light-emitting elements were performed at room temperature (in an atmosphere maintained at 23° C.). FIG. 34 shows absorption and emission spectra of a toluene solution of 2,6Ph-mmtBuDPhA2Anth, which is the guest material of the light-emitting element 13.

Table 10 shows the element characteristics of the comparative light-emitting element 12 and the light-emitting element 13 at around 1000 cd/m².

TABLE 10

| | | | | | | | External |
|---|---|---|---|---|---|---|---|
| | | Current | CIE | | Current | Power | quantum |
| | Voltage | density | chromaticity | Luminance | efficiency | efficiency | efficiency |
| | (V) | (mA/cm2) | (x, y) | (cd/m2) | (cd/A) | (lm/W) | (%) |
| Comparative | 3.50 | 2.20 | (0.221, 0.507) | 1027 | 46.8 | 42.0 | 16.8 |
| light-emitting | | | | | | | |
| element | | | | | | | |
| 12 | | | | | | | |
| Light-emitting | 4.60 | 1.45 | (0.305, 0.585) | 915 | 63.3 | 43.2 | 18.2 |
| element | | | | | | | |
| 13 | | | | | | | |

As shown in FIG. 34, the emission spectrum of the comparative light-emitting element 12 had a peak wavelength of 506 nm and a half width of 81 nm. This is light emission originating from 3C2zDPhCzBN. In addition, the emission spectrum of the light-emitting element 13 had a peak wavelength of 540 nm and a half width of 73 nm. Although this includes green light emission originating from 2,6Ph-mmtBuDPhA2Anth, the emission spectrum of the light-emitting element 13 is different from the emission spectrum of 2,6Ph-mmtBuDPhA2Anth as shown in FIG. 34. The emission spectrum obtained from the light-emitting element 13 was found to include light emission of 3C2zDPhCzBN, which is an energy donor, in addition to the light emission of 2,6Ph-mmtBuDPhA2Anth. Consequently, multicolor light emission can be obtained from the light-emitting element of one embodiment of the present invention.

Although the light-emitting element 13 exhibits light emission originating from the fluorescent material, it exhibited high emission efficiency with an external quantum efficiency whose maximum value exceeding 20% as shown in FIG. 33 and Table 10. This result indicates that in the light-emitting element of one embodiment of the present invention, non-radiative deactivation of triplet excitons is inhibited, contributing to efficient conversion into light emission. Thus, it was found that the use of a guest material including protecting groups in a light-emitting layer can inhibit energy transfer of triplet excitation energy from a host material to a guest material by the Dexter mechanism and non-radiative deactivation of triplet excitation energy. The light-emitting element 13 is found to have higher emission efficiency than the comparative light-emitting element 12 in which only the TADF material is a light-emitting material.

As described above, 3C2zDPhCzBN is a TADF material. It is also found that an absorption band on the longest wavelength side of the absorption spectrum of 2,6Ph-mmtBuDPhA2Anth and the emission spectrum of 3C2zDPhCzBN overlap with each other as shown in FIG. 34. Thus, 2,6Ph-mmtBuDPhA2Anth was found to emit light by receiving excitation energy of 3C2zDPhCzBN in the light-emitting element 13.

### Example 6

In this example, fabrication examples of light-emitting elements of one embodiment of the present invention and comparative light-emitting elements, which are different from those in the above example, and the characteristics of the light-emitting elements are described. The structure of each of the light-emitting elements fabricated in this example is the same as that in FIG. 1(A). Table 11 show the details of the element structures. The structures and abbreviations of compounds that were used are shown below. Note that the above examples and embodiments can be referred to for other organic compounds.

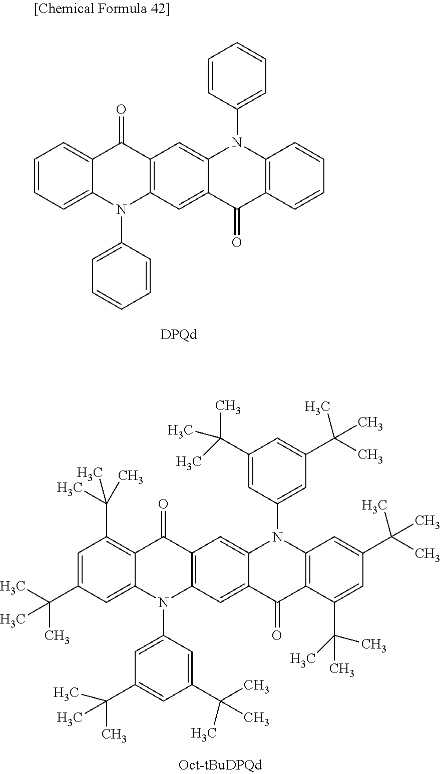 [SMILES: O=c1c2ccccc2n(-c2ccccc2)c2cc3c(=O)c4ccccc4n(-c4ccccc4)c3cc12 ; CC(C)(C)c1cc(-n2c3cc4c(=O)c5c(C(C)(C)C)cc(C(C)(C)C)cc5n(-c5cc(C(C)(C)C)cc(C(C)(C)C)c5)c4cc3c(=O)c3c(C(C)(C)C)cc(C(C)(C)C)cc32)cc(C(C)(C)C)c1]

TABLE 11

| | | | Thickness | | Weight |
|---|---|---|---|---|---|
| | Layer | Numeral | (nm) | Material | ratio |
| Comparative | Electrode | 102 | 200 | Al | — |
| light-emitting | Electron- | 119 | 1 | LiF | — |
| element | injection layer | | | | |
| 14 | Electron- | 118(2) | 10 | NBphen | — |
| | transport layer | 118(1) | 20 | 4,6mCzP2Pm | — |
| | Light-emitting | 130 | 30 | 4,6mCzP2Pm:3Cz2DPhCzBN | 1:0.1 |
| | layer | | | | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Comparative | Electrode | 102 | 200 | Al | — |
| light-emitting | Electron- | 119 | 1 | LiF | — |
| element | injection layer | | | | |
| 15 | Electron- | 118(2) | 10 | NBphen | — |
| | transport layer | 118(1) | 20 | 4,6mCzP2Pm | — |
| | Light-emitting | 130 | 40 | 4,6mCzP2Pm:3Cz2DPhCzBN: | 1:0.1:0.01 |
| | layer | | | DPQd | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |
| | Electrode | 101 | 70 | ITSO | — |
| Light- | Electrode | 102 | 200 | Al | — |
| emitting | Electron- | 119 | 1 | LiF | — |
| element | injection layer | | | | |
| 16 | Electron- | 118(2) | 10 | NBphen | — |
| | transport layer | 118(1) | 20 | 4,6mCzP2Pm | — |
| | Light-emitting | 130 | 40 | 4,6mCzP2Pm:3Cz2DPhCzBN: | 1:0.1:0.01 |
| | layer | | | Oct-tBuDPQd | |
| | Hole-transport | 112 | 20 | mCzFLP | — |
| | layer | | | | |
| | Hole-injection | 111 | 40 | DBT3P-II:MoO₃ | 1:0.5 |
| | layer | | | | |

### <<Fabrication of Comparative Light-Emitting Element 14, Comparative Light-Emitting Element 15, and Light-Emitting Element 16>>

A comparative light-emitting element 14, a comparative light-emitting element 15, and a light-emitting element 16 are different from the above-described comparative light-emitting element 8 only in the component of the light-emitting layer 130, and other steps of the fabrication method are the same as those for the comparative light-emitting element 8. The details of the element structures are as shown in Table 11; thus, the details of the fabrication methods are omitted. Note that 3C2zDPhCzBN is a TADF material in the light-emitting layer 130 of the comparative light-emitting element 14, the comparative light-emitting element 15, and the light-emitting element 16. In the comparative light-emitting element 15, N,N′-diphenylquinacridone (abbreviation: DPQd) is a fluorescent material that does not include protecting groups around a luminophore. Furthermore, 1,3,8,10-tetra-tert-butyl-7,14-bis(3,5-di-tert-butylphenyl)-5,12-dihydroquino[2,3-b] acridine-7,14-dione (abbreviation: Oct-tBuDPQd) is a guest material including protecting groups around a luminophore in the light-emitting layer 130 of the light-emitting element 16. The light-emitting element 16 is the light-emitting element of one embodiment of the present invention illustrated in FIG. 6(C).

### <Characteristics of Light-Emitting Elements>

Next, the characteristics of the comparative light-emitting element 14, the comparative light-emitting element 15, and the light-emitting element 16 fabricated above were measured. The measurements were performed in a manner similar to those in Example 1.

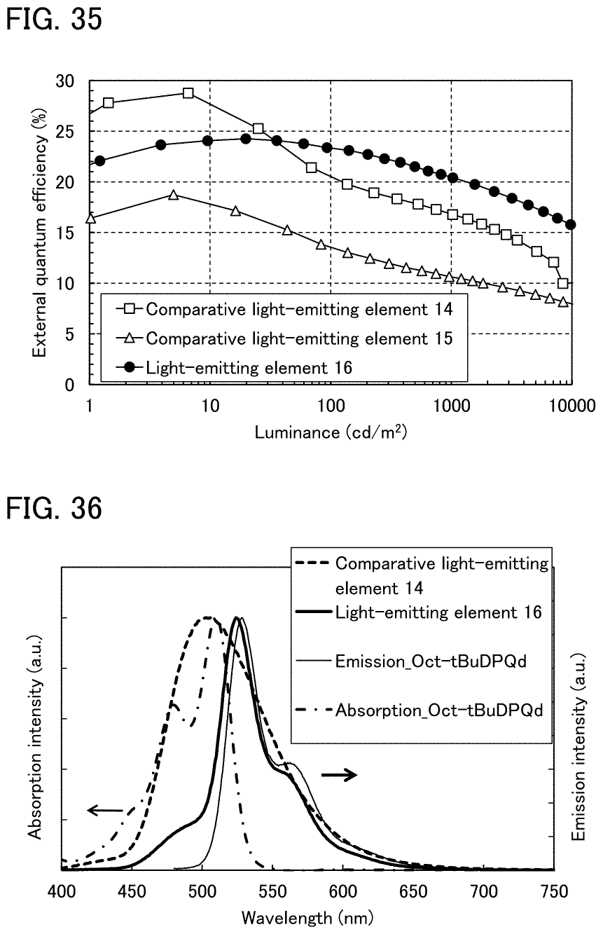

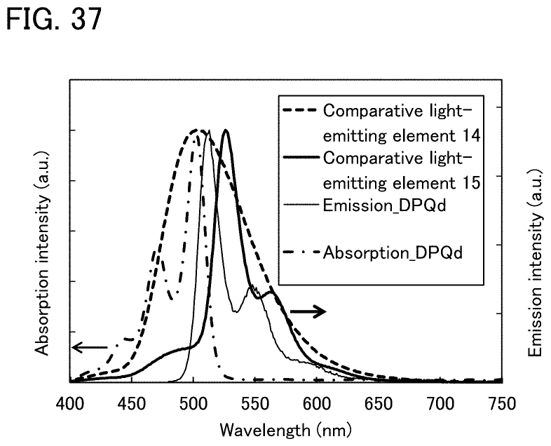

FIG. 35 shows the external quantum efficiency-luminance characteristics of the comparative light-emitting element 14, the comparative light-emitting element 15, and the light-emitting element 16. FIG. 36 shows electroluminescence spectra of the comparative light-emitting element 14 and the light-emitting element 16 to which a current at a current density of 2.5 mA/cm² was supplied. FIG. 37 shows electroluminescence spectra of the comparative light-emitting element 14 and the light-emitting element 15 to which a current at a current density of 2.5 mA/cm² was supplied. Note that the measurements of the light-emitting elements were performed at room temperature (in an atmosphere maintained at 23° C.). FIG. 36 shows absorption and emission spectra of a toluene solution of Oct-tBuDPQd, which is the guest material of the light-emitting element 16. FIG. 37 shows absorption and emission spectra of a toluene solution of DPQd, which is the guest material of the comparative light-emitting element 15.

Table 12 shows the element characteristics of the comparative light-emitting element 14, the comparative light-emitting element 15, and the light-emitting element 16 at around 1000 cd/m².

TABLE 12

| | | | | | | | External |
|---|---|---|---|---|---|---|---|
| | | Current | CIE | | Current | Power | quantum |
| | Voltage | density | chromaticity | Luminance | efficiency | efficiency | efficiency |
| | (V) | (mA/cm²) | (x, y) | (cd/m²) | (cd/A) | (lm/W) | (%) |
| Comparative | 3.50 | 2.20 | (0.221, 0.507) | 1027 | 46.8 | 42.0 | 16.8 |
| light-emitting | | | | | | | |
| element | | | | | | | |
| 14 | | | | | | | |
| Comparative | 3.70 | 2.47 | (0.261, 0.629) | 960 | 38.9 | 33.1 | 10.7 |
| light-emitting | | | | | | | |
| element | | | | | | | |
| 15 | | | | | | | |
| Light-emitting | 4.00 | 1.39 | (0.258, 0.641) | 1029 | 73.8 | 57.9 | 20.4 |
| element | | | | | | | |
| 16 | | | | | | | |

As shown in FIG. 36 and FIG. 37, the emission spectrum of the comparative light-emitting element 14 had a peak wavelength of 506 nm and a half width of 81 nm. This is light emission originating from 3C2zDPhCzBN. In addition, the emission spectrum of the light-emitting element 16 had a peak wavelength of 524 nm and a half width of 33 nm. Although this includes green light emission originating from Oct-tBuDPQd, the emission spectrum of the light-emitting element 16 is different from the emission spectrum of Oct-tBuDPQd as shown in FIG. 36. The emission spectrum obtained from the light-emitting element 16 was found to include light emission of 3C2zDPhCzBN, which is an energy donor, in addition to the light emission of Oct-tBuDPQd. Consequently, multicolor light emission can be obtained from the light-emitting element of one embodiment of the present invention. In addition, the emission spectrum of the comparative light-emitting element 15 had a peak wavelength of 526 nm and a half width of 26 nm. Although this includes green light emission originating from DPQd, the emission spectrum of the comparative light-emitting element 15 is different from the emission spectrum of DPQd as shown in FIG. 37. The emission spectrum obtained from the comparative light-emitting element 15 was found to include light emission of 3C2zDPhCzBN, which is an energy donor, in addition to the light emission of DPQd.

Although the light-emitting element 16 exhibits light emission originating from the fluorescent material, it exhibited high emission efficiency with an external quantum efficiency whose maximum value exceeding 20% as shown in FIG. 35 and Table 12. This result indicates that in the light-emitting element of one embodiment of the present invention, non-radiative deactivation of triplet excitons is inhibited, contributing to efficient conversion into light emission. The results show that the light-emitting element 16 has higher external quantum efficiency than the comparative light-emitting element 15. The comparative light-emitting element 15 differs from the light-emitting element 16 in the fluorescent material used for the light-emitting layer. The results show that a light-emitting element can have higher emission efficiency by using a fluorescent material including protecting groups than by using a fluorescent material not including protecting groups. This is because deactivation of the triplet excitation energy by the Dexter mechanism in the light-emitting layer is inhibited.

### Reference Example 1

In this reference example, a synthesis method of 2tBu-ptBuDPhA2Anth, which is a fluorescent material including protecting groups used in Example 1 and Example 2, will be described.

1.2 g (3.1 mmol) of 2-tert-butylanthracene, 1.8 g (6.4 mmol) of bis(4-tert-butylphenyl)amine, 1.2 g (13 mmol) of sodium t-butoxide, and 60 mg (0.15 mmol) of 2-dicyclohexylphosphino-2′,6′-dimethoxy-1,1′-biphenyl (abbreviation: SPhos) were put into a 200 mL three-neck flask, and the air in the flask was replaced with nitrogen. To this mixture was added 35 mL of xylene, and the mixture was degassed under reduced pressure; then, 40 mg (70 μmol) of bis(dibenzylideneacetone)palladium(0) was added to the mixture and the mixture was stirred for 4 hours at 170° C. under a nitrogen stream.

After the stirring, 400 mL of toluene was added to the obtained mixture, which was then subjected to suction filtration through Florisil (Wako Pure Chemical Industries, Ltd., Catalog Number: 066-05265), Celite (Wako Pure Chemical Industries, Ltd., Catalog Number: 537-02305), and aluminum oxide to give a filtrate. The obtained filtrate was concentrated to give a brown solid.

This solid was purified by silica gel column chromatography (developing solvent: hexane:toluene=9:1) to obtain an objective yellow solid. The obtained yellow solid was recrystallized with toluene, hexane, and ethanol to give 1.5 g of an objective yellow solid in a yield of 61%. The synthesis scheme is shown in (A-1) below.

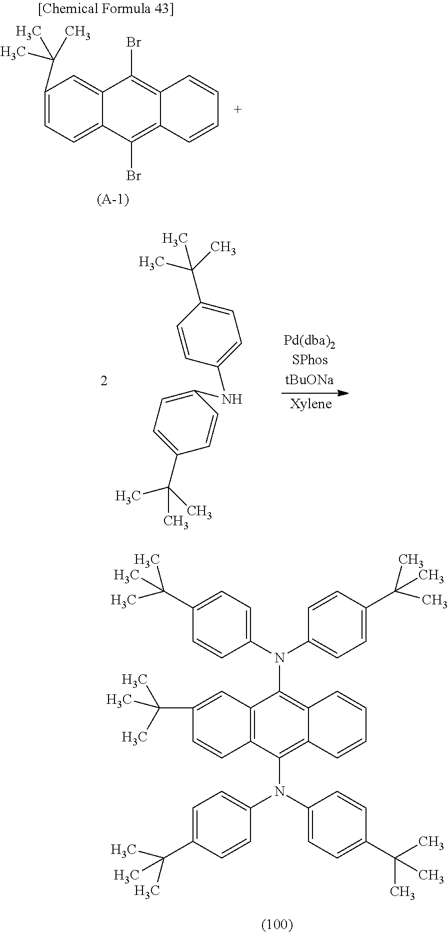

By a train sublimation method, 1.5 g of the obtained yellow solid was purified by sublimation. In the sublimation purification, the yellow solid was heated at 315° C. under a pressure of 4.5 Pa for 15 hours. After the sublimation purification, 1.3 g of an objective yellow solid was obtained at a collection rate of 89%.

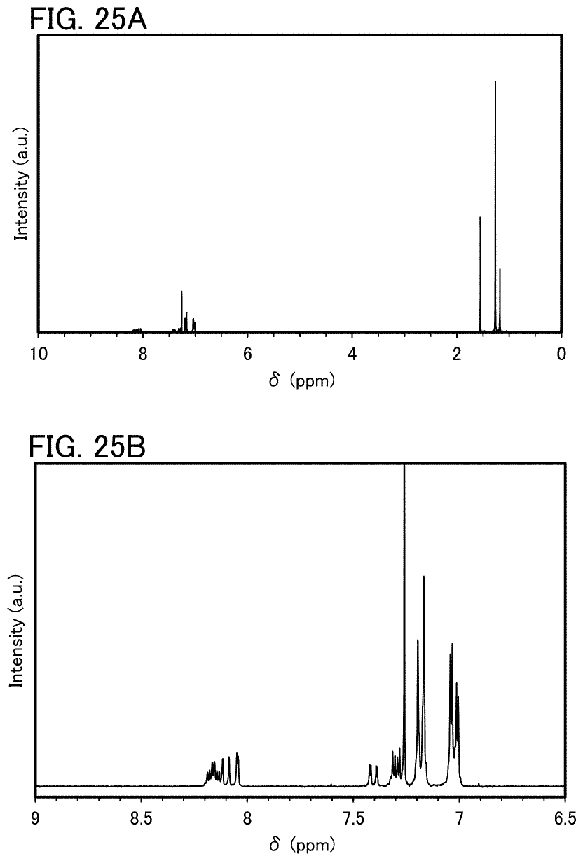

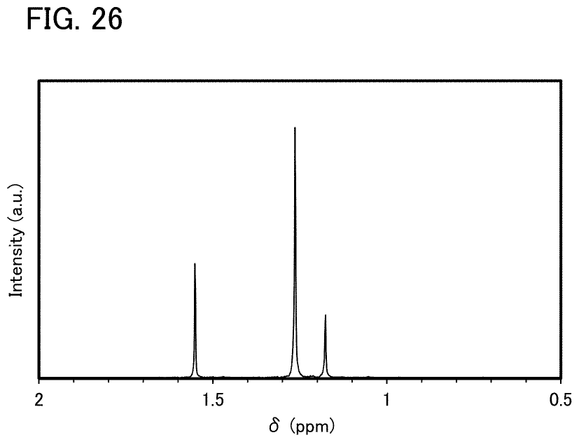

Results of ¹H NMR measurement of the yellow solid obtained in this synthesis will be described below. FIG. 25 and FIG. 26 are the ¹H-NMR charts. Note that FIG. 25(B) is an enlarged diagram of the range of 6.5 ppm to 9.0 ppm of FIG. 25(A). FIG. 26 is an enlarged diagram of the range of 0.5 ppm to 2.0 ppm of FIG. 25(A). The results indicate that 2tBu-ptBuDPhA2Anth, which was the objective substance, was obtained.

¹H NMR (CDCl₃, 300 MHz): σ=8.20-8.13 (m, 2H), 8.12 (d, J=8.8 Hz, 1H), 8.05 (d, J=2.0 Hz, 1H), 7.42 (dd, J=9.3 Hz, 2.0 Hz, 1H), 7.32-7.26 (m, 2H) 7.20 (d, J=8.8 Hz, 8H), 7.04 (dd, J=8.8 Hz, 2.4 Hz, 8H), 1.26 (s, 36H), 1.18 (s, 9H).

### Reference Example 2

In this reference example, a synthesis method of 2,6tBu-mmtBuDPhA2Anth, which is a fluorescent material including protecting groups used in Example 3, will be described.

1.1 g (2.5 mmol) of 2,6-di-tert-butylanthracene, 2.3 g (5.8 mmol) of bis(3,5-tert-butylphenyl)amine, 1.1 g (11 mmol) of sodium t-butoxide, and 60 mg (0.15 mmol) of 2-dicyclohexylphosphino-2′,6′-dimethoxy-1,1′-biphenyl (abbreviation: SPhos) were put into a 200 mL three-neck flask, and the air in the flask was replaced with nitrogen. To this mixture was added 25 mL of xylene, and the mixture was degassed under reduced pressure; then, 40 mg (70 μmol) of bis(dibenzylideneacetone)palladium(0) was added to the mixture and the mixture was stirred for 6 hours at 150° C. under a nitrogen stream.

After the stirring, 400 mL of toluene was added to the obtained mixture, which was then subjected to suction filtration through Florisil, Celite, and aluminum oxide to give a filtrate. The obtained filtrate was concentrated to give a brown solid.

This solid was purified by silica gel column chromatography (developing solvent; hexane:toluene=9:1) to obtain an objective yellow solid. The obtained yellow solid was recrystallized with hexane and methanol to give 0.45 g of an objective yellow solid in a yield of 17%. The synthesis scheme of Step 1 is shown in (B-1) below.

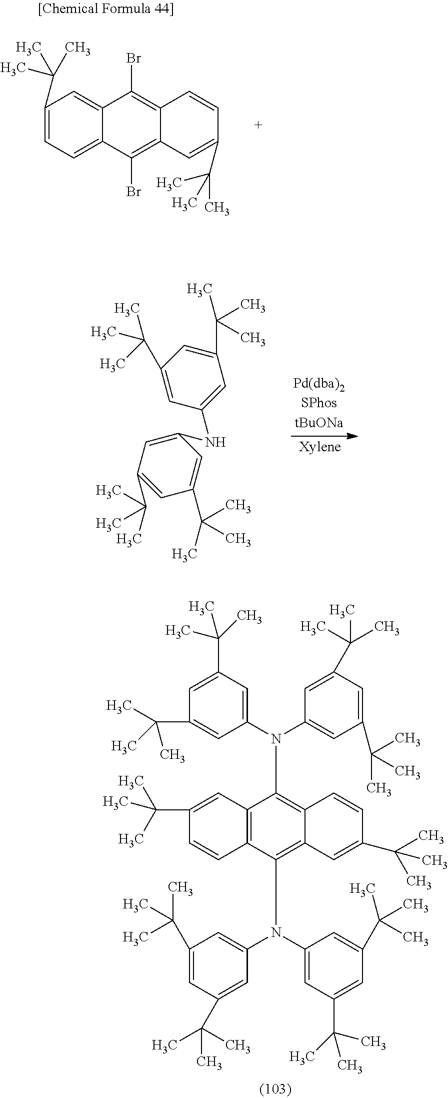 [SMILES: CC(C)(C)c1ccc2c(Br)c3cc(C(C)(C)C)ccc3c(Br)c2c1 ; CC(C)(C)c1cc(Nc2cc(C(C)(C)C)cc(C(C)(C)C)c2)cc(C(C)(C)C)c1 ; CC(C)(C)c1cc(N(c2cc(C(C)(C)C)cc(C(C)(C)C)c2)c2c3ccc(C(C)(C)C)cc3c(N(c3cc(C(C)(C)C)cc(C(C)(C)C)c3)c3cc(C(C)(C)C)cc(C(C)(C)C)c3)c3ccc(C(C)(C)C)cc23)cc(C(C)(C)C)c1]

By a train sublimation method, 0.45 g of the obtained yellow solid was purified by sublimation. In the sublimation purification, the yellow solid was heated at 275° C. under a pressure of 5.0 Pa for 15 hours. After the sublimation purification, 0.37 g of an objective yellow solid was obtained at a collection rate of 82%.

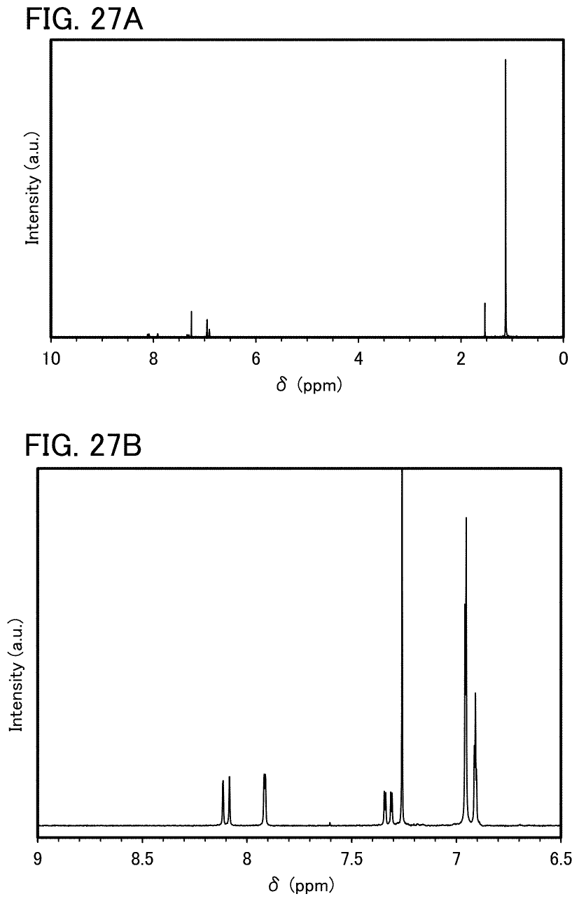

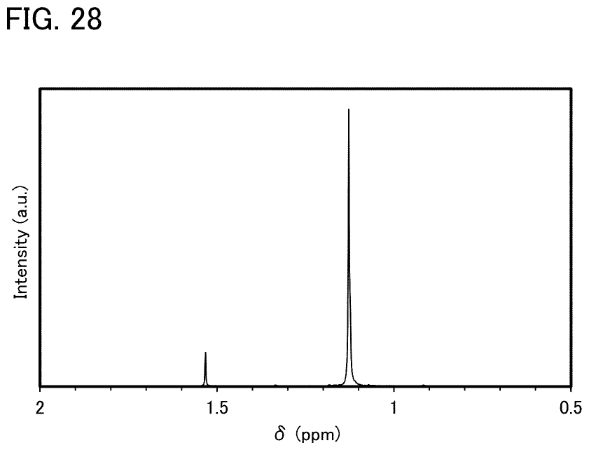

Results of ¹H NMR measurement of the yellow solid obtained in Step 1 described above will be described below. FIG. 27 and FIG. 28 are the ¹H-NMR charts. Note that FIG. 27(B) is an enlarged chart of the range of 6.5 ppm to 9.0 ppm of FIG. 28(A). FIG. 28 is an enlarged chart of the range of 0.5 ppm to 2.0 ppm of FIG. 27(A). The results indicate that 2,6tBu-mmtBuDPhA2Anth was obtained.

¹H NMR (CDCl₃, 300 MHz): σ=8.11 (d, J=9.3 Hz, 2H), 7.92 (d, J=1.5 Hz, 1H), 7.34 (dd, J=9.3 Hz, 2.0 Hz, 2H), 6.96-6.95 (m, 8H), 6.91-6.90 (m, 4H), 1.13-1.12 (m, 90H).

### Reference Example 3

In this reference example, a synthesis method of 2,6Ph-mmtBuDPhA2Anth, which is a fluorescent material including protecting groups used in Example 4, will be described.

### Step 1: Synthesis of 2,6Ph-mmtBuDPhA2Anth

1.8 g (3.6 mmol) of 9,10-dibromo-2,6-diphenylanthracene, 2.8 g (7.2 mmol) of bis(3,5-tert-butylphenyl)amine, 1.4 g (15 mmol) of sodium t-butoxide, and 60 mg (0.15 mmol) of SPhos were put into a 200 mL three-neck flask, and the air in the flask was replaced with nitrogen. To this mixture was added 36 mL of xylene, and the mixture was degassed under reduced pressure; then, 40 mg (70 μmol) of bis(dibenzylideneacetone)palladium(0) was added to the mixture and the mixture was stirred for 3 hours at 150° C. under a nitrogen stream. After the stirring, 400 mL of toluene was added to the obtained mixture, which was then subjected to suction filtration through Florisil, Celite, and aluminum oxide to give a filtrate. The obtained filtrate was concentrated to give a brown solid. This solid was purified by silica gel column chromatography (developing solvent: hexane:toluene=9:1) to obtain a yellow solid. The obtained yellow solid was recrystallized with ethyl acetate and ethanol to give 0.61 g of an objective yellow solid in a yield of 15%. The synthesis scheme of Step 1 is shown in (C-1) below.

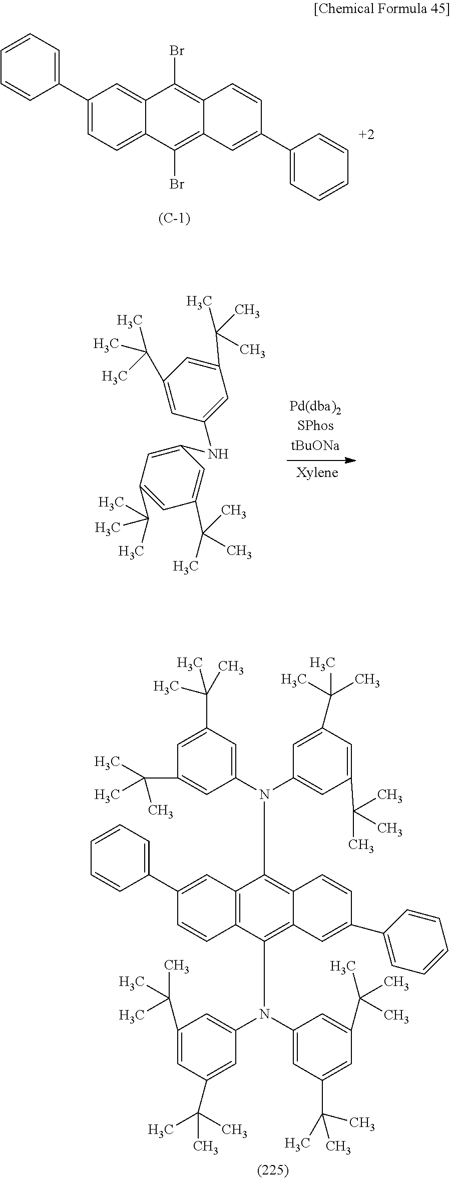

By a train sublimation method, 0.61 g of the obtained yellow solid was purified by sublimation. In the sublimation purification, the yellow solid was heated at 280° C. under a pressure of 3.8 Pa for 15 hours. After the sublimation purification, 0.56 g of an objective yellow solid was obtained at a collection rate of 91%.

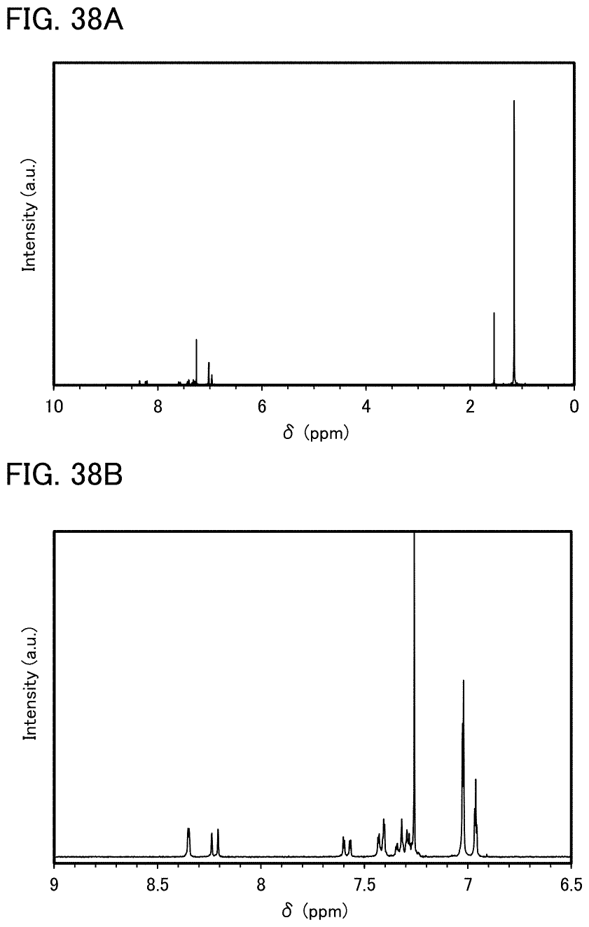

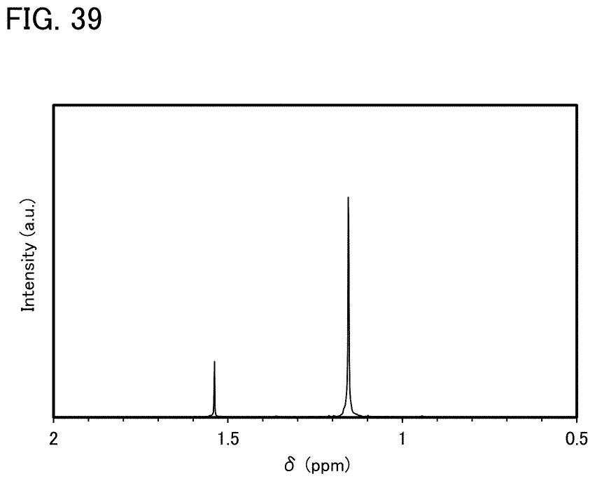

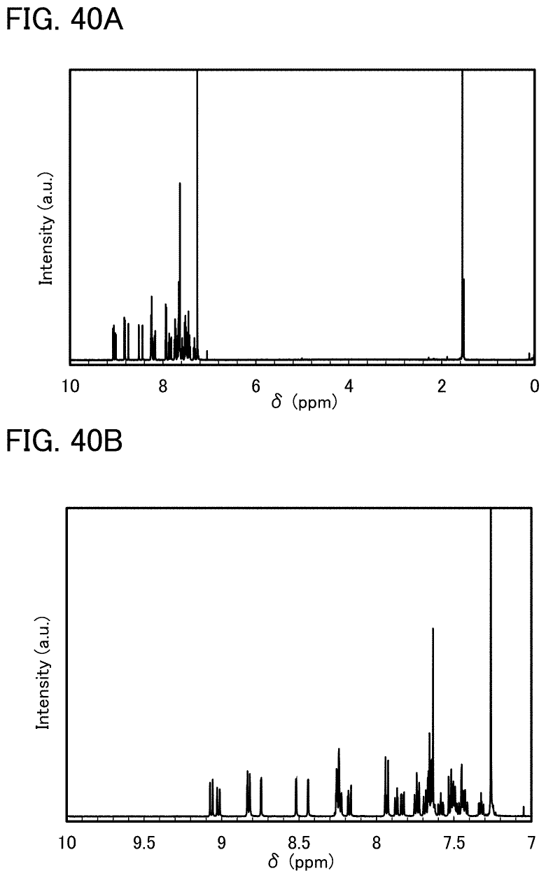

Results of ¹H NMR measurement of the yellow solid obtained in Step 1 described above will be described below. FIG. 38 and FIG. 39 are the ¹H-NMR charts. Note that FIG. 38(B) is an enlarged chart of the range of 6.5 ppm to 9.0 ppm of FIG. 38(A). FIG. 39 is an enlarged chart of the range of 0.5 ppm to 2.0 ppm of FIG. 38(A). The results indicate that 2,6Ph-mmtBuDPhA2Anth was obtained. ¹H NMR (CDCl₃, 300 MHz): σ=8.35 (d, J=1.5 Hz, 2H), 8.24 (d, J=8.8 Hz, 2H), 7.60 (dd, J=1.5 Hz, 8.8 Hz, 2H), 7.43-7.40 (m, 4H), 7.35-7.24 (m, 6H), 7.03-7.02 (m, 8H), 6.97-6.96 (m, 4H), 1.16 (s, 72H).

### Reference Example 4

In this reference example, a synthesis method of 4Ph-8DBt-2PCCzBfpm, which is a TADF material used in Example 4, will be described.

<Step 1; Synthesis of 2,8-dichloro-4-phenyl-[1]benzofuro[3,2-d]pyrimidine>

First, into a 500 mL three-neck flask, 10 g (37 mmol) of 2,4,8-trichloro-[1]benzofuro[3,2-d]pyrimidine, 4.5 g (371 mmol) of phenylboronic acid, 37 g of a 2M aqueous solution of potassium carbonate, 180 mL of toluene, and 18 mL of ethanol were put. This mixture in the flask was degassed and the air in the flask was replaced with nitrogen. To this mixture, 1.3 g (1.8 mmol) of bis(triphenylphosphine)palladium(II) dichloride was added, followed by stirring at 80° C. for 16 hours. After the predetermined time elapsed, the obtained reaction mixture was concentrated, water was added, and the mixture was suction-filtered. The obtained residue was washed with ethanol to give a solid. This solid was dissolved in toluene, followed by suction filtration through a filter medium in which Celite, alumina, and Celite are stacked in this order. The obtained filtrate was concentrated, so that 11 g of a white solid which was the object was obtained in a yield of 91%. The synthesis scheme of Step 1 is shown in (D-1) below.

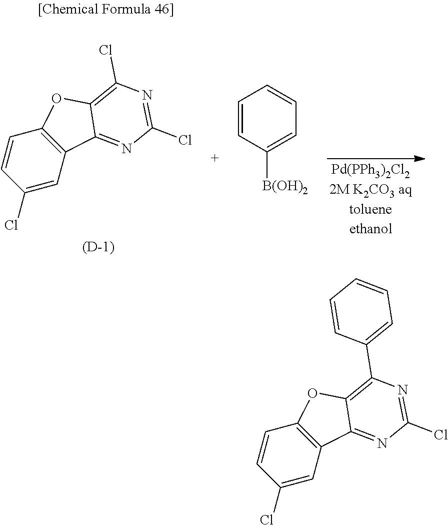 [SMILES: Clc1ccc2oc3c(Cl)nc(Cl)nc3c2c1 ; OB(O)c1ccccc1 ; "(D-1)" ; Clc1ccc2oc3c(-c4ccccc4)nc(Cl)nc3c2c1]

### Step 2; Synthesis of 8-chloro-4-phenyl-2-(9′-phenyl-3,3′-bi-9H-carbazol-9-yl)-[1]benzofuro[3,2-d]pyrimidine

Next, into a 300 mL three-neck flask, 5.0 g (16 mmol) of 2,8-dichloro-4-phenyl-[1]benzofuro[3,2-d]pyrimidine obtained in Step 1, 6.5 g (16 mmol) of 9-phenyl-3,3′-bi-9H-carbazole, 3.1 g (32 mmol) of tert-sodium butoxide, and 150 mL of xylene were put, and the air in the flask was replaced with nitrogen. Then, 224 mg (0.64 mmol) of di-tert-butyl(1-methyl-2,2-diphenylcyclopropyl)phosphine (abbreviation: cBRIDP) and 58 mg (0.16 mmol) of allylpalladium(II)chloride dimer were added thereto, and the mixture was heated and stirred at 90° C. for 7 hours. Water was added to the obtained reaction mixture, and an aqueous layer was subjected to extraction with toluene. The obtained solution of the extract and an organic layer were combined and washed with saturated saline, and anhydrous magnesium sulfate was added to the organic layer for drying. The obtained mixture was gravity-filtered and the filtrate was concentrated to give a solid. This solid was purified by silica gel column chromatography. As a developing solvent, a mixed solvent of toluene:hexane=1:1 was used. The obtained fraction was concentrated, so that 5.5 g of a yellow solid which was the object was obtained in a yield of 50%. The synthesis scheme of Step 2 is shown in (D-2) below.

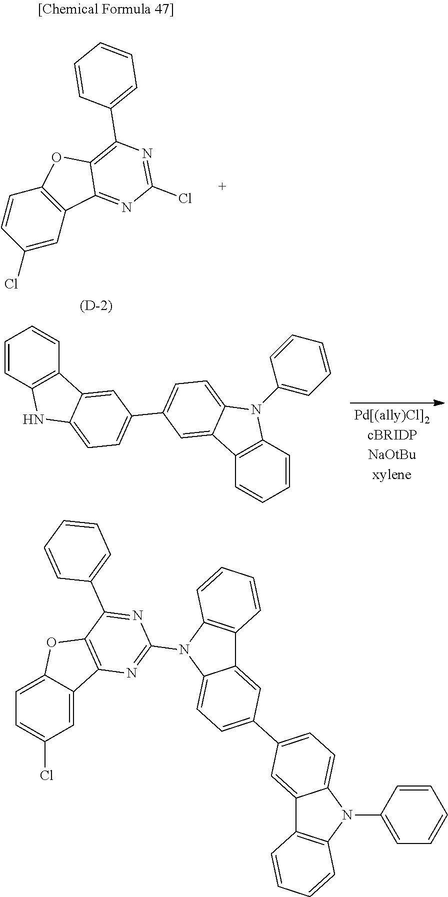

### Step 3; Synthesis of 8-(dibenzothiophen-4-yl)-4-phenyl-2-(9′-phenyl-3,3′-bi-9H-carbazol-9-yl)-[1]benzofuro[3,2-d]pyrimidine (abbreviation: 4Ph-8DBt-2PCCzBfpm)

Next, into a three-neck flask, 2.25 g (3.3 mmol) of 8-chloro-4-phenyl-2-(9′-phenyl-3,3′-bi-9H-carbazol-9-yl)[1]benzofuro[3,2-d]pyrimidine obtained in Step 2 above, 0.82 g (3.6 mmol) of 4-dibenzothiopheneboronic acid, 1.5 g (9.8 mmol) of cesium fluoride, and 35 mL of xylene were put, and the air in the flask was replaced with nitrogen. The temperature of this mixture was raised to 60° C., 60 mg (0.065 mmol) of tris(dibenzylideneacetone)dipalladium(0) and 77 mg (0.2 mmol) of 2′-(dicyclohexylphosphino)acetophenone ethylene ketal were added, and the mixture was heated and stirred at 100° C. for 16 hours. Furthermore, 30 mg (0.032 mmol) of tris(dibenzylideneacetone)dipalladium(0) and 36 mg (0.1 mmol) of 2′-(dicyclohexylphosphino)acetophenone ethylene ketal were added to this mixture, and the mixture was heated and stirred at 110° C. for 7 hours and then at 120° C. for 7 hours. Water was added to the obtained reaction product, the mixture was suction-filtered, and the residue was washed with ethanol. This solid was dissolved in toluene, followed by suction filtration through a filter medium in which Celite, alumina, and Celite are stacked in this order. The obtained filtrate was concentrated and recrystallization from toluene was performed, so that 1.87 g of a yellow solid which was the object was obtained in a yield of 68%. The synthesis scheme of Step 3 is shown in (D-3) below.

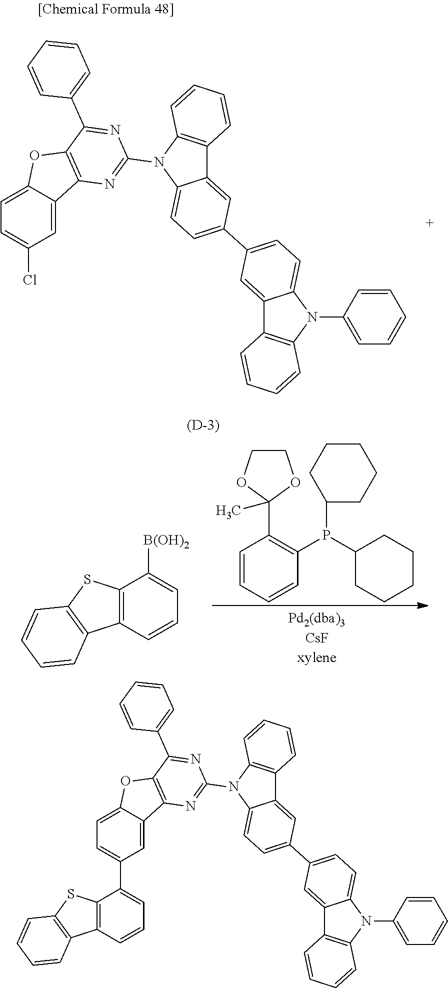 [SMILES: Clc1ccc2oc3c(-c4ccccc4)nc(-n4c5ccccc5c5cc(-c6ccc7c(c6)c6ccccc6n7-c6ccccc6)ccc54)nc3c2c1 ; "(D-3)" ; OB(O)c1cccc2c1sc1ccccc12 ; CC1(c2ccccc2P(C2CCCCC2)C2CCCCC2)OCCO1 ; c1ccc(-c2nc(-n3c4ccccc4c4cc(-c5ccc6c(c5)c5ccccc5n6-c5ccccc5)ccc43)nc3c2oc2ccc(-c4cccc5c4sc4ccccc45)cc23)cc1]

Analysis results by nuclear magnetic resonance (¹H-NMR) spectroscopy of the yellow solid obtained in Step 3 above are shown below. In addition, ¹H-NMR charts are shown in FIGS. 40(A) and (B). Note that FIG. 40(B) is a chart showing an enlarged view of the range of 7.0 ppm to 10.0 ppm in FIG. 40(A). These reveal that 4Ph-8DBt-2PCCzBfpm was obtained.

¹H-NMR. δ (CDCl₃): 7.33 (t, 1H), 7.41-7.53 (m, 7H), 7.59 (t, 1H), 7.62-7.70 (m, 7H), 7.72-7.75 (m, 2H), 7.83 (dd, 1H), 7.87 (dd, 1H), 7.93-7.95 (m, 2H), 8.17 (dd, 1H), 8.23-8.26 (m, 4H), 8.44 (d, 1H), 8.52 (d, 1H), 8.75 (d, 1H), 8.2 (d, 2H), 9.02 (d, 1H), 9.07 (d, 1H).

### Reference Example 5

In this reference example, a synthesis method of Oct-tBuDPQd, which is a fluorescent material including protecting groups used in Example 6, will be described.

### Step 1: Synthesis of 1,4-cyclohexadiene-1,4-dicarboxylic Acid and 2,5-bis[(3,5-di-tert-butylphenyl)amino]-dimethylester

5.6 g (24 mmol) of 1,4-cyclohexanedione-2,5-dicarboxylic dimethyl and 10 g (48 mmol) of 3,5-di-tert-butylaniline were put into a 200 mL three-neck flask equipped with a reflux pipe, and this mixture was stirred at 170° C. for 2 hours. Methanol was added to the obtained reddish-orange solid to form a slurry, and the mixture was collected by suction filtration. The obtained solid was washed with hexane and methanol and dried, so that 12 g of an objective reddish-orange solid was obtained in a yield of 82%. The synthesis scheme of Step 1 is shown in (E-1) below.

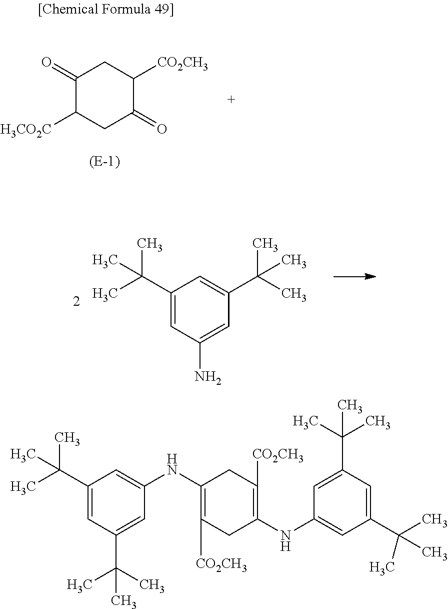 [SMILES: COC(=O)C1CC(=O)C(C(=O)OC)CC1=O ; CC(C)(C)c1cc(N)cc(C(C)(C)C)c1 ; COC(=O)C1=C(Nc2cc(C(C)(C)C)cc(C(C)(C)C)c2)CC(C(=O)OC)=C(Nc2cc(C(C)(C)C)cc(C(C)(C)C)c2)C1]

Given below are ¹H NMR numerical data of the obtained solid. The data reveal that an objective compound was obtained.

¹H NMR (chloroform-d, 500 MHz): δ=10.6 (s, 2H), 7.20 (t, J=1.5 Hz, 2H), 6.94 (d, J=2.0 Hz, 4H), 3.65 (s, 6H), 3.48 (s, 4H), 1.33 (s, 36H).

### Step 2: Synthesis of 1,4-benzenedicarboxylic Acid and 2,5-bis[(3,5-di-tert-butylphenyl)amino]-dimethylester

12 g (20 mmol) of 1,4-cyclohexadiene-1,4-dicarboxylic acid and 2,5-bis[(3,5-di-tert-butylphenyl)amino]-dimethylester, which were obtained in Step 1, and 150 mL of toluene were put into a 300 mL three-neck flask equipped with a reflux pipe. The mixture was refluxed for 15 hours with air bubbles. After stirring, the precipitated solid was collected by suction filtration and the obtained solid was washed with hexane and methanol, so that 7.3 g of an objective red solid was obtained. The obtained filtrate was concentrated and a solid is further obtained. This solid was washed with hexane and methanol and collected by suction filtration, so that 3.1 g of an objective red solid was obtained. Thus, 10.4 g of the objective compounds were obtained in total in a yield of 85%. The synthesis scheme of Step 2 is shown in (E-2) below.

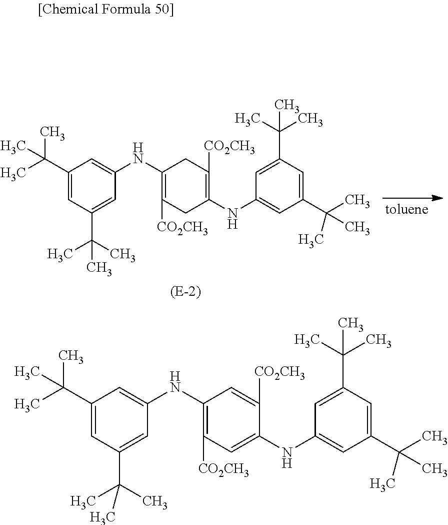

Given below are ¹H NMR numerical data of the obtained solid. The data reveal that an objective compound was obtained.

¹H NMR (chloroform-d, 500 MHz): δ=8.84 (s, 2H), 8.18 (s, 2H), 7.08 (d, J=2.0 Hz, 4H), 7.20 (t, J=1.0 Hz, 2H), 3.83 (s, 6H), 1.34 (s, 36H).

### Step 3: Synthesis of 1,4-benzenedicarboxylic Acid and 2,5-bis[N,N-bis(3,5-di-tert-butylphenyl)amino]-dimethylester

4.0 g (6.7 mmol) of 1,4-benzenedicarboxylic acid and 2,5-bis[(3,5-di-tert-butylphenyl)amino]-dimethylester, which were obtained in Step 2, 3.9 g (14.6 mmol) of 1-bromo-3,5-di-tert-butylbenzene, 0.46 g (7.3 mmol) of copper, 50 mg (0.26 mmol) of copper iodide, 1.0 g (7.3 mmol) of potassium carbonate, and 10 mL of xylene were put into a 200 mL three-neck flask equipped with a reflux pipe, the mixture was degassed at reduced pressure, and the air in the flask was replaced with nitrogen. This mixture was refluxed for 20 hours. To the obtained mixture, 0.46 g (7.3 mmol) of copper and 50 mg of copper iodide (0.26 mmol) were added, and the mixture was further refluxed for 16 hours. Dichloromethane was added to the obtained mixture to form a slurry. The solid was removed by suction filtration, and the obtained filtrate was concentrated. The obtained solid was washed with hexane and ethanol. The washed solid was recrystallized with hexane/toluene to give 4.4 g of a yellow solid, which was an objective compound, in a yield of 72%. The synthesis scheme of Step 3 is shown in (E-3) below.

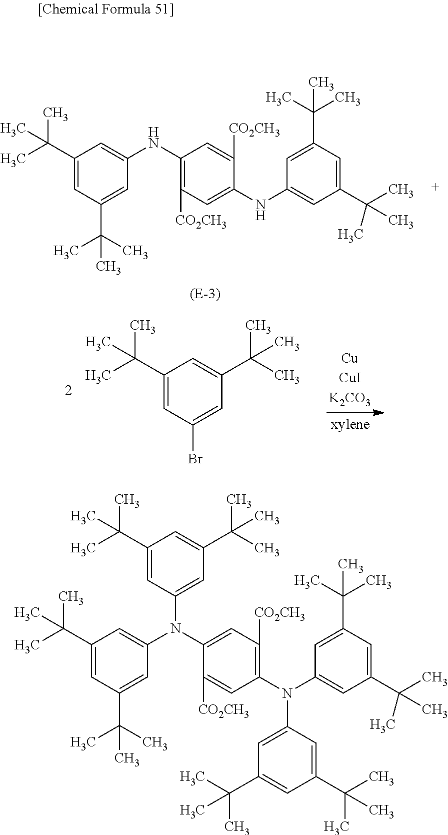

Given below are ¹H NMR numerical data of the obtained solid. The data reveal that an objective compound was obtained.

¹H NMR (chloroform-d, 500 MHz): δ=7.48 (s, 2H), 6.97 (t, J=2.0 Hz, 4H), 7.08 (d, J=1.5 Hz, 8H), 3.25 (s, 6H), 1.23 (s, 72H).

### Step 4: Synthesis of 1,3,8,10-tetra-tert-butyl-7,14-bis(3,5-di-tert-butylphenyl)-5,12-dihydroquino[2,3-b]acridine-7,14-dione (abbreviation: Oct-tBuDPQd)

4.4 g (4.8 mmol) of 1,4-benzenedicarboxylic acid and 2,5-bis[N,N′-bis(3,5-di-tert-butylphenyl)amino]-dimethyl ester, which were obtained in Step 3, and 20 mL of methanesulfonate were put into a 100 mL three-neck flask equipped with a reflux pipe, and the mixture was stirred at 160° C. for 7 hours. The mixture was cooled to room temperature, slowly poured into 300 mL of ice water, and then left until it reached room temperature. This mixture was filtered by gravity filtration, and the obtained solid was washed with water and a saturated aqueous solution of sodium hydrogencarbonate. This solid was dissolved in toluene, the obtained toluene solution was washed with water and saturated saline, and drying was performed with magnesium sulfate. This mixture was filtered through Celite (produced by Wako Pure Chemical Industries, Ltd., Catalog No.: 537-02305) and aluminum oxide. The obtained filtrate was concentrated to give 3.3 g of a blackish-brown solid. The obtained solid was purified by silica gel column chromatography (developing solvent: hexane:ethyl acetate=20:1) to give 150 mg of a reddish-orange solid, which was an objective compound, in a yield of 5%. The synthesis scheme of Step 4 is shown in (E-4) below.

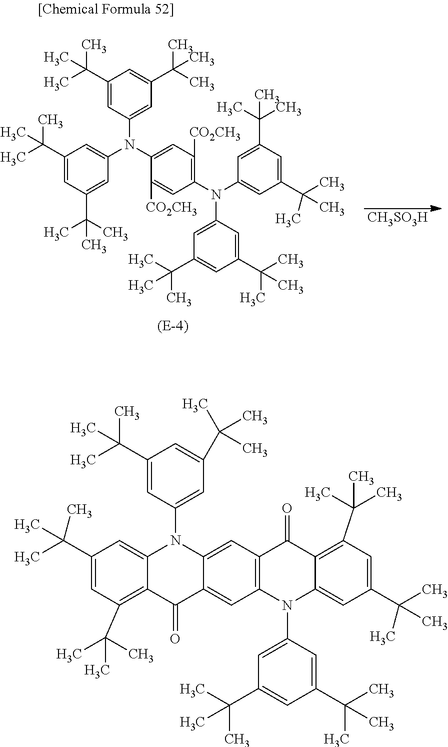

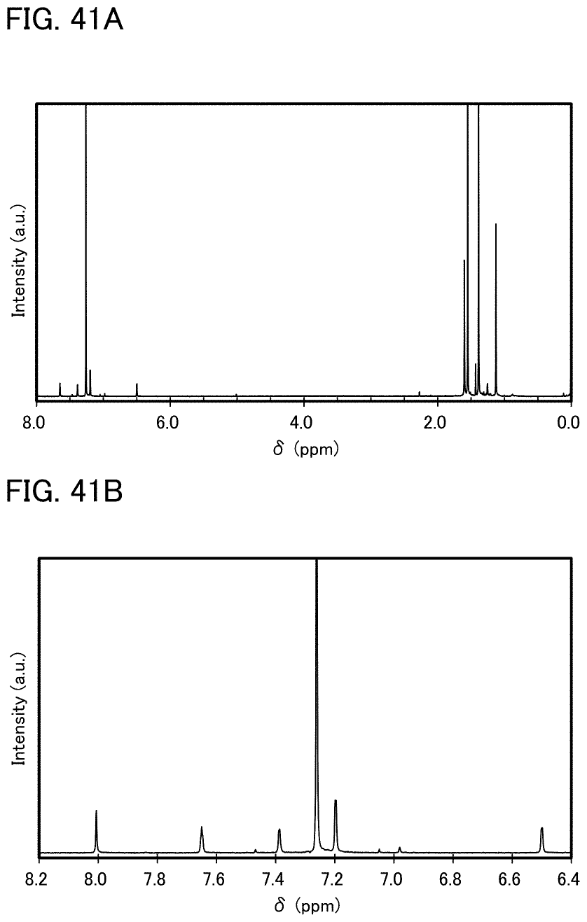

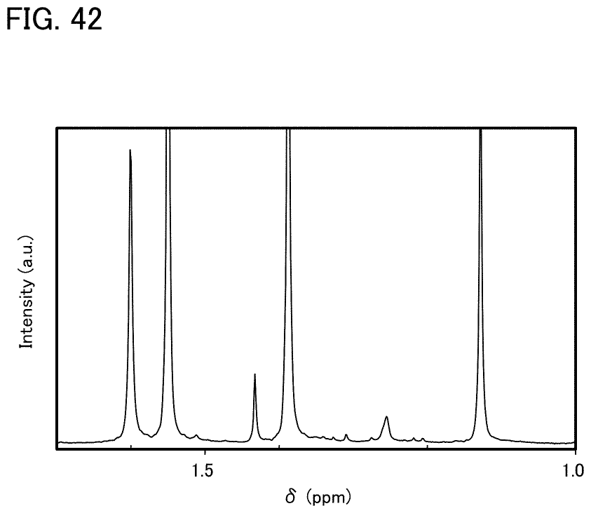

Results of ¹H NMR measurement of the yellow solid obtained in Step 4 described above will be described below. FIGS. 41(A) and 41(B) and FIG. 42 are the charts. Note that FIG. 41(B) is an enlarged chart of the range of 6.5 ppm to 9.0 ppm of FIG. 41(A). FIG. 42 is an enlarged chart of the range of 0.5 ppm to 2.0 ppm of FIG. 41(A). The results indicate that Oct-tBuDPQd was obtained.

¹H NMR (chloroform-d, 500 MHz): δ=8.00 (s, 2H), 7.65 (t, J=2.0 Hz, 2H), 7.39 (d, J=1.0 Hz, 4H), 7.20 (d, J=2.0 Hz, 2H), 6.50 (d, J=1.0 Hz, 2H), 1.60 (s, 18H), 1.39 (s, 36H), 1.13 (s, 18H).

### REFERENCE NUMERALS

100: EL layer, 101: electrode, 102: electrode, 106: light-emitting unit, 108: light-emitting unit, 111: hole-injection layer, 112: hole-transport layer, 113: electron-transport layer, 114: electron-injection layer, 115: charge-generation layer, 116: hole-injection layer, 117: hole-transport layer, 118: electron-transport layer, 119: electron-injection layer, 120: light-emitting layer, 130: light-emitting layer, 131: compound, 132: compound, 133: compound, 134: compound, 135: compound, 150: light-emitting element, 170: light-emitting layer, 250: light-emitting element, 301: guest material, 302: guest material, 310: luminophore, 320: protecting group, 330: host material, 601: source side driver circuit, 602: pixel portion, 603: gate side driver circuit, 604: sealing substrate, 605: sealant, 607: space, 608: wiring, 609: FPC, 610: element substrate, 611: switching TFT, 612: current control TFT, 613: electrode, 614: insulator, 616: EL layer, 617: electrode, 618: light-emitting element, 623: n-channel TFT, 624: p-channel TFT, 625: desiccant, 900: portable information terminal, 901: housing, 902: housing, 903: display portion, 905: hinge portion, 910: portable information terminal, 911: housing, 912: display portion, 913: operation button, 914: external connection port, 915: speaker, 916: microphone, 917: camera, 920: camera, 921: housing, 922: display portion, 923: operation button, 924: shutter button, 926: lens, 1001: substrate, 1002: base insulating film, 1003: gate insulating film, 1006: gate electrode, 1007: gate electrode, 1008: gate electrode, 1020: interlayer insulating film, 1021: interlayer insulating film, 1022: electrode, 1024B: electrode, 1024G: electrode, 1024R: electrode, 1024W: electrode, 1025B: lower electrode, 1025G: lower electrode, 1025R: lower electrode, 1025W: lower electrode, 1026: partition, 1028: EL layer, 1029: electrode, 1031: sealing substrate, 1032: sealant, 1033: base material, 1034B: coloring layer, 1034G: coloring layer, 1034R: coloring layer, 1035: black layer, 1036: overcoat layer, 1037: interlayer insulating film, 1040: pixel portion, 1041: driver circuit portion, 1042: peripheral portion, 1044B: blue pixel, 1044G: green pixel, 1044R: red pixel, 1044W: white pixel, 2100: robot, 2101: illuminance sensor, 2102: microphone, 2103: upper camera, 2104: speaker, 2105: display, 2106: lower camera, 2107: obstacle sensor, 2108: moving mechanism, 2110: arithmetic device, 5000: housing, 5001: display portion, 5002: display portion, 5003: speaker, 5004: LED lamp, 5005: operation key, 5006: connection terminal, 5007: sensor, 5008: microphone, 5012: supported portion, 5013: earphone, 5100: cleaning robot, 5101: display, 5102: camera, 5103: brush, 5104: operation button, 5120: dust, 5140: portable electronic appliance, 5150: portable information terminal, 5151: housing, 5152: display region, 5153: bend portion, 8501: lighting device, 8502: lighting device, 8503: lighting device, and 8504: lighting device.

1. A light-emitting element comprising:
a first electrode;
a light-emitting layer over the first electrode, the light-emitting layer comprising:
a first material capable of converting triplet excitation energy into light emission; and
a second material capable of converting singlet excitation energy into light emission; and
a second electrode over the light-emitting layer,
wherein a difference in excitation energy level between a lowest singlet excited state and a lowest triplet excited state of the first material is smaller than or equal to 0.2 eV,
wherein the second material comprises a luminophore and five or more protecting groups,
wherein the luminophore is a condensed aromatic ring or a condensed heteroaromatic ring,
wherein the five or more protecting groups each independently comprise any one of an alkyl group having 1 to 10 carbon atoms, a substituted or unsubstituted cycloalkyl group having 3 to 10 carbon atoms, and a trialkylsilyl group having 3 to 12 carbon atoms, and
wherein light emission is obtained from both the first material and the second material.

2. The light-emitting element according to claim 1, wherein at least four of the five protecting groups are each independently any one of an alkyl group having 3 to 10 carbon atoms, a substituted or unsubstituted cycloalkyl group having 3 to 10 carbon atoms, and a trialkylsilyl group having 3 to 12 carbon atoms.

3. A light-emitting element comprising:
a first electrode;
a light-emitting layer over the first electrode, the light-emitting layer comprising:
a first material capable of converting triplet excitation energy into light emission; and
a second material capable of converting singlet excitation energy into light emission,
a second electrode over the light-emitting layer,
wherein a difference in excitation energy level between a lowest singlet excited state and a lowest triplet excited state of the first material is smaller than or equal to 0.2 eV,
wherein the second material comprises a luminophore and at least four protecting groups,
wherein the luminophore is one of a condensed aromatic ring and a condensed heteroaromatic ring,
wherein the four protecting groups are not directly bonded to the one of the condensed aromatic ring and the condensed heteroaromatic ring,
wherein the four protecting groups each independently comprise any one of an alkyl group having 3 to 10 carbon atoms, a substituted or unsubstituted cycloalkyl group having 3 to 10 carbon atoms, and a trialkylsilyl group having 3 to 12 carbon atoms, and
wherein light emission is obtained from both the first material and the second material.

4. A light-emitting element comprising:
a first electrode;
a light-emitting layer between a pair of electrodes over the first electrode, the light-emitting layer comprising:
a first material capable of converting triplet excitation energy into light emission; and
a second material capable of converting singlet excitation energy into light emission,
a second electrode over the light-emitting layer,
wherein a difference in excitation energy level between a lowest singlet excited state and a lowest triplet excited state of the first material is smaller than or equal to 0.2 eV,
wherein the second material comprises a luminophore and two or more diarylamino groups,
wherein the luminophore is one of a condensed aromatic ring and a condensed heteroaromatic ring,
wherein the one of the condensed aromatic ring and the condensed heteroaromatic ring is bonded to the two or more diarylamino groups,
wherein aryl groups in the two or more diarylamino groups each independently comprise at least one protecting group,
wherein the protecting groups comprise any one of an alkyl group having 3 to 10 carbon atoms, a substituted or unsubstituted cycloalkyl group having 3 to 10 carbon atoms, and a trialkylsilyl group having 3 to 12 carbon atoms, and
wherein light emission is obtained from both the first material and the second material.

5. A light-emitting element comprising:
a first electrode;
a light-emitting layer over the first electrode, the light-emitting layer comprising:
a first material capable of converting triplet excitation energy into light emission; and
a second material capable of converting singlet excitation energy into light emission,
a second electrode over the light-emitting layer,
wherein a difference in excitation energy level between a lowest singlet excited state and a lowest triplet excited state is smaller than or equal to 0.2 eV,
wherein the second material comprises a luminophore and two or more diarylamino groups,
wherein the luminophore is one of a condensed aromatic ring and a condensed heteroaromatic ring,
wherein the condensed aromatic ring or the condensed heteroaromatic ring is bonded to the two or more diarylamino groups,
wherein the two or more diarylamino groups each independently comprise at least two protecting groups,
wherein the protecting groups each independently comprise any one of an alkyl group having 3 to 10 carbon atoms, a substituted or unsubstituted cycloalkyl group having 3 to 10 carbon atoms, and a trialkylsilyl group having 3 to 12 carbon atoms, and
wherein light emission is obtained from both the first material and the second material.

6. The light-emitting element according to claim 4, wherein the diarylamino group is a diphenylamino group.

7. The light-emitting element according to claim 2, wherein the alkyl group is a branched-chain alkyl group.

8. A light-emitting element comprising:
a first electrode;
a light-emitting layer between a pair of electrodes over the first electrode, the light-emitting layer comprising:
a first material capable of converting triplet excitation energy into light emission; and
a second material capable of converting singlet excitation energy into light emission,
a second electrode over the light-emitting layer,
wherein a difference in excitation energy level between a lowest singlet excited state and a lowest triplet excited state of the first material is smaller than or equal to 0.2 eV,
wherein the second material comprises a luminophore and a plurality of protecting groups,
wherein the luminophore is one of a condensed aromatic ring and a condensed heteroaromatic ring,
wherein at least one atom of the plurality of protecting groups is positioned directly on one plane of the condensed aromatic ring or the condensed heteroaromatic ring and at least one atom of the plurality of protecting groups is positioned directly on the other plane of the condensed aromatic ring or the condensed heteroaromatic ring, and
wherein light emission is obtained from both the first material and the second material.

9. A light-emitting element comprising:
a first electrode;
a light-emitting layer between a pair of electrodes over the first electrode, the light-emitting layer comprises comprising:
a first material capable of converting triplet excitation energy into light emission; and
a second material capable of converting singlet excitation energy into light emission,
a second electrode over the light-emitting layer,
wherein a difference in excitation energy level between a lowest singlet excited state and a lowest triplet excited state of the first material is smaller than or equal to 0.2 eV,
wherein the second material comprises a luminophore and two or more diphenylamino groups,
wherein the luminophore is a condensed aromatic ring or a condensed heteroaromatic ring,
wherein the condensed aromatic ring or the condensed heteroaromatic ring is bonded to the two or more diphenylamino groups,
wherein phenyl groups in the two or more diphenylamino groups each independently comprise protecting groups at a 3-position and a 5-position,
wherein the protecting groups each independently comprise any one of an alkyl group having 3 to 10 carbon atoms, a substituted or unsubstituted cycloalkyl group having 3 to 10 carbon atoms, and a trialkylsilyl group having 3 to 12 carbon atoms, and
wherein light emission is obtained from both the first material and the second material.

10. The light-emitting element according to claim 9, wherein the alkyl group is a branched-chain alkyl group.

11. The light-emitting element according to claim 7, wherein the branched-chain alkyl group comprises quaternary carbon.

12. The light-emitting element according to claim 1, wherein the condensed aromatic ring or the condensed heteroaromatic ring comprises any one of naphthalene, anthracene, fluorene, chrysene, triphenylene, tetracene, pyrene, perylene, coumarin, quinacridone and naphthobisbenzofuran.

13. The light-emitting element according to claim 1,
wherein the first material comprises a first organic compound and a second organic compound, and
wherein the first organic compound and the second organic compound are capable of forming an exciplex.

14. The light-emitting element according to claim 13, wherein the first organic compound is a phosphorescent compound.

15. The light-emitting element according to claim 1, wherein a peak wavelength of an emission spectrum of the first material is located on a shorter wavelength side than a peak wavelength of an emission spectrum of the second material.

16. (canceled)

17. The light-emitting element according to claim 1, wherein the first material is a compound exhibiting delayed fluorescence.

18. The light-emitting element according to claim 1, wherein an emission spectrum of the first material and an absorption band with a longest wavelength of an absorption spectrum of the second material overlap with each other.

19. The light-emitting element according to claim 1, wherein a concentration of the second material in the light-emitting layer is greater than or equal to 0.01 wt % and less than or equal to 2 wt %.

20. A light-emitting device comprising:
the light-emitting element according to claim 1; and
at least one of a color filter and a transistor.

21. An electronic appliance comprising:
the light-emitting device according to claim 20; and
at least one of a housing and a display portion.

22. A lighting device comprising:
the light-emitting element according to claim 1; and
a housing.
